(19) United States
(12) Patent Application Publication
(10) Pub. No.: US 2026/0164921 A1
(43) Pub. Date: Jun. 11, 2026

(54) LIGHT EMITTING DEVICE, FUSED POLYCYCLIC COMPOUND FOR THE SAME, AND ELECTRONIC DEVICE INCLUDING THE SAME

(71) Applicant: Samsung Display Co., Ltd., Yongin-si (KR)

(72) Inventors: Yuuki MIYAZAKI, Yokohama-shi (JP); Yasuhiko ASHIKARI, Yokohama-shi (JP); Yuta KAWANO, Yokohama-shi (JP)

(21) Appl. No.: 19/387,534

(22) Filed: Nov. 12, 2025

(30) Foreign Application Priority Data
Nov. 22, 2024 (JP) 2024-203705

(51) Int. Cl. H10K 50/12; H10K 50/858; H10K 59/38; H10K 85/30; H10K 85/40; H10K 85/60

(52) U.S. Cl. CPC H10K 50/121; H10K 50/858; H10K 59/38; H10K 85/342; H10K 85/346; H10K 85/40; H10K 85/626; H10K 85/633; H10K 85/654; H10K 85/656; H10K 85/6572; H10K 85/6574; H10K 85/658

(57) ABSTRACT

A light emitting device includes a first electrode, a second electrode, and an emission layer disposed between the first electrode and the second electrode, and including a first compound represented by Formula las described.

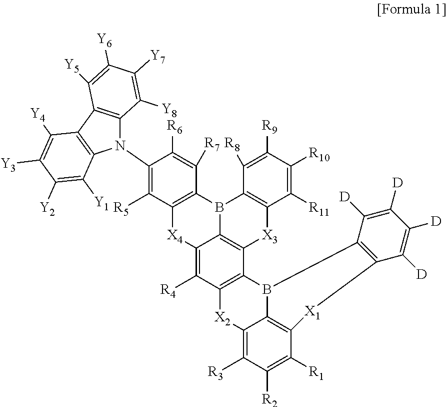

### CROSS-REFERENCE TO RELATED APPLICATIONS

This U.S. patent application claims priority to Japanese Patent Application No. 2024-203705, filed on Nov. 22, 2024, and all the benefits accruing therefrom under 35 U.S.C. § 119, the contents of which in its entirety is herein incorporated by reference.

### BACKGROUND

The present disclosure herein relates to a light emitting device, a fused polycyclic compound used in the light emitting device, and an electronic device including the light emitting device.

The development of an organic electroluminescence display device (OLED) as an image display is of interest and being actively conducted. The OLED display is different from a liquid crystal display, and at times, is referred to as a self-luminescent display in which holes and electrons injected from a first electrode and a second electrode recombine in an emission layer resulting in light emission of a selective wavelength. The emission layer includes a light emitting material that emits the light to achieve a functional display.

In the operation of an OLED a decrease of a driving voltage, and/or an increase of the emission efficiency and lifetime of the OLED are two important operational parameters or conditions that one seeks to optimize, and therefore, the development of materials for an OLED to achieve such conditions is always of interest and ongoing.

To develop an OLED with high efficiency, techniques on phosphorescence emission that uses energy in a triplet state, and fluorescence emission that uses the generating phenomenon of singlet excitons by the collision of triplet excitons (triplet-triplet annihilation, TTA) are being developed, as well as the development of thermally activated delayed fluorescence (TADF) materials that use delayed fluorescence phenomenon.

### SUMMARY

The present disclosure provides a light emitting device having improved emission efficiency and device lifetime.

The present disclosure also provides a fused polycyclic compound which is capable of improving the emission efficiency and device lifetime of a light emitting device.

The present disclosure also provides an electronic device having excellent display quality by including a light emitting element with improved emission efficiency and lifetime.

A light emitting device according to an embodiment of the inventive concept includes a first electrode, a second electrode disposed on the first electrode, and an emission layer disposed between the first electrode and the second electrode, and including a first compound represented by Formula 1.

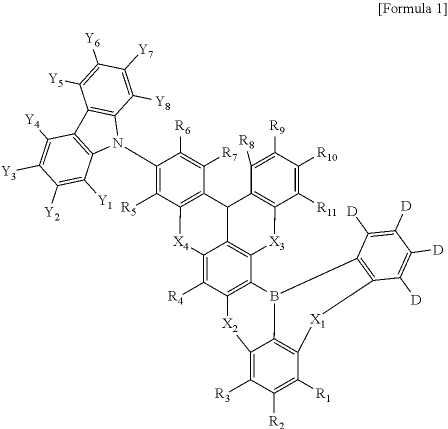

In Formula 1, X₁ to X₄ are each independently O, S or NAr, Ar is a substituted or unsubstituted aryl group of 6 to 30 ring-forming carbon atoms, or a substituted or unsubstituted heteroaryl group of 2 to 30 ring-forming carbon atoms, and R₁ to R₁₁ and Y₁ to Y₈ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and D is a deuterium atom.

In an embodiment, the first compound represented by Formula 1 may be represented by a compound of Formula 2-1, Formula 2-2, or Formula 2-3.

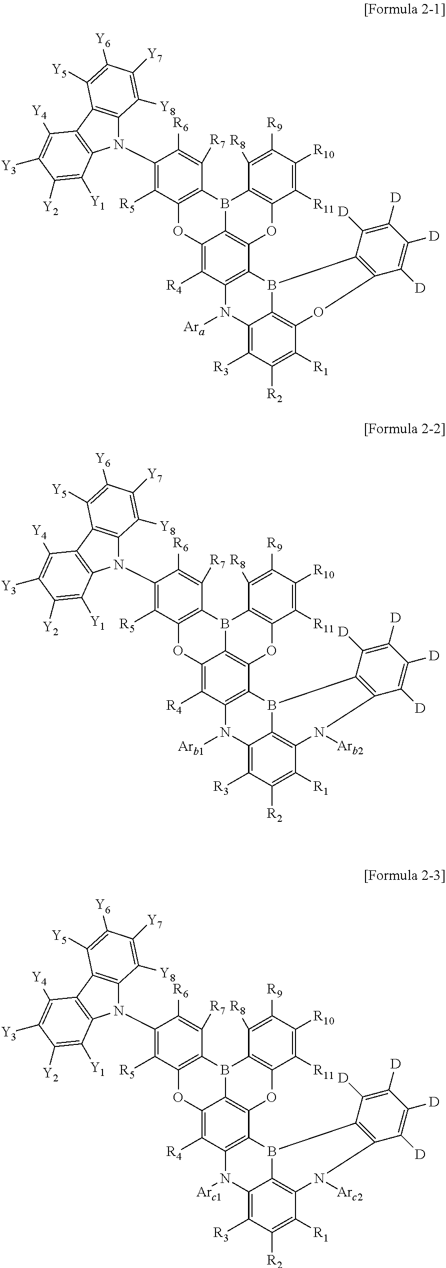

In Formula 2-1, Formula 2-2, and Formula 2-3, Arₐ, Ar_{b1}, Ar_{b2}, Ar_{c1}, Ar_{c2}, and Ar_{c3} are each independently a substituted or unsubstituted aryl group of 6 to 30 ring-forming carbon atoms, or a substituted or unsubstituted heteroaryl group of 2 to 30 ring-forming carbon atoms, and R₁ to R₁₁, Y₁ to Y₈ and D are the same as defined in Formula 1, and Formula 2-1, Formula 2-2, and Formula 2-3 may include a structure in which an arbitrary hydrogen atom is substituted with a deuterium atom. Arₐ, Ar_{b1}, Ar_{b2}, Ar_{c1}, Ar_{c2}, and Ar_{c3} may be each independently a substituted or unsubstituted phenyl group, a substituted or unsubstituted divalent biphenyl group, or a substituted or unsubstituted terphenyl group.

In an embodiment, the first compound represented by Formula 1 may be represented by a compound of Formula 2-4 to Formula 2-10 below.

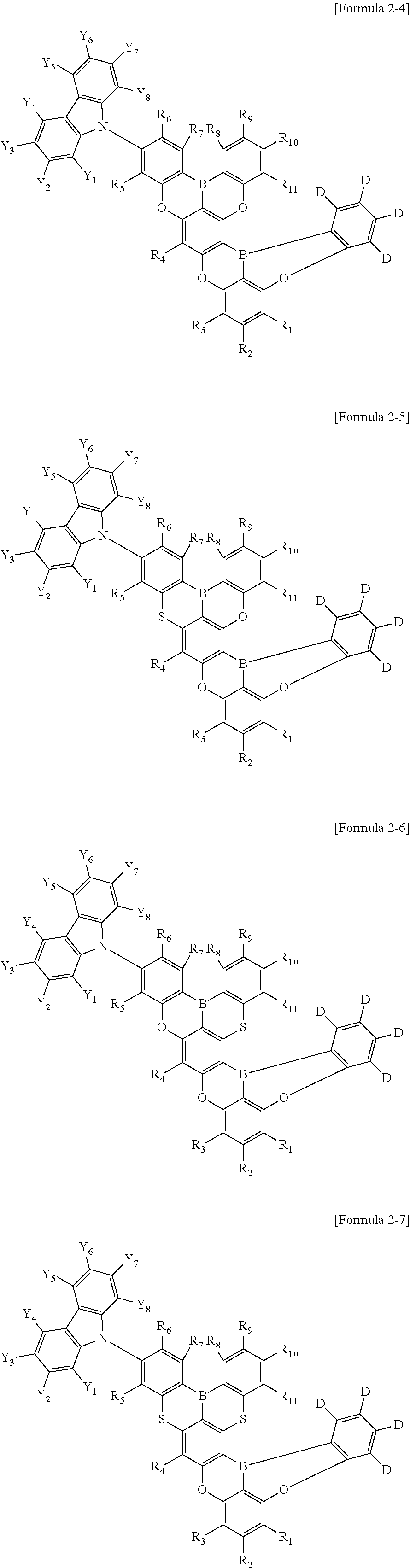

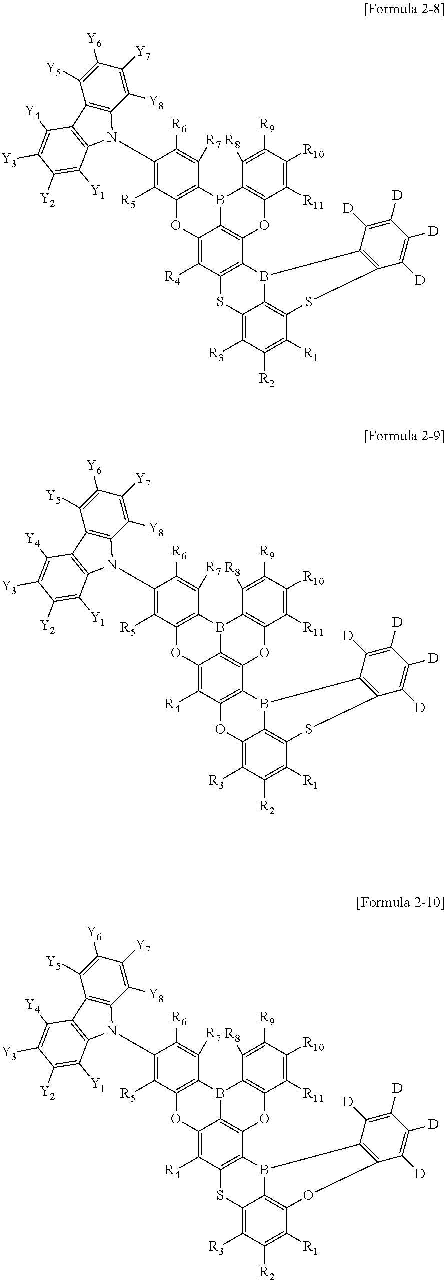

In Formula 2-4 to Formula 2-10, R₁ to R₁₁, Y₁ to Y₈ and D are the same as defined in Formula 1, and Formula 2-4 to Formula 2-10 may include a structure in which an arbitrary hydrogen atom is substituted with a deuterium atom.

In an embodiment, the first compound represented by Formula 1 may be represented by Formula 3-1 or Formula 3-2.

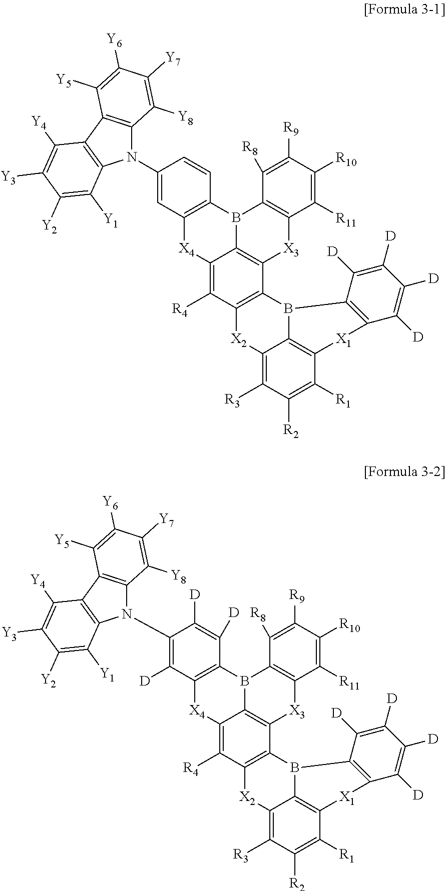

In Formula 3-1 and Formula 3-2, R₁ to R₄, R₈ to R₁₁, and Y₁ to Y₈ may be the same as defined in Formula 1.

In an embodiment, the first compound represented by Formula 1 may be represented by a compound of Formula 4-1 to Formula 4-8 below.

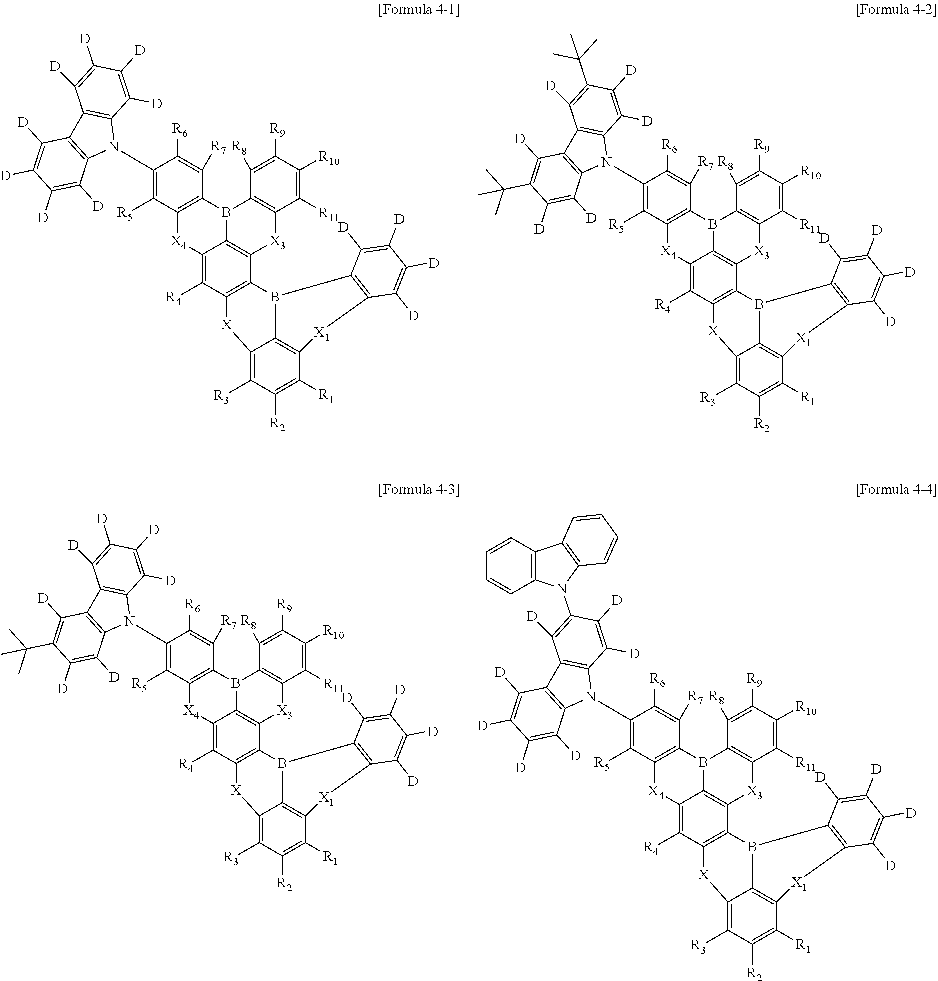

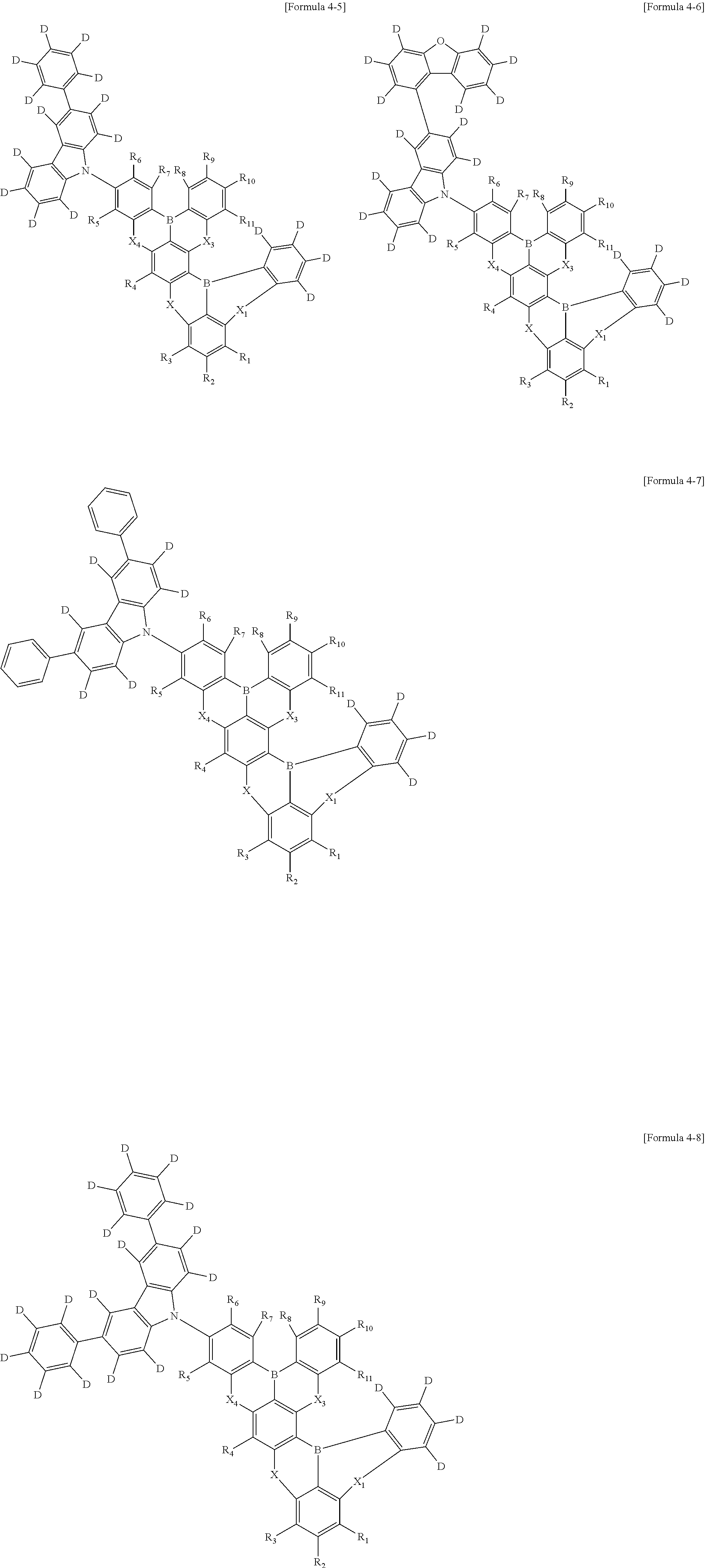

In Formula 4-1 to Formula 4-8, R₁ to R₁₁, and X₁ to X₄ are the same as defined in Formula 1, and Formula 4-1 to Formula 4-8 may include a structure in which an arbitrary hydrogen atom is substituted with a deuterium atom.

In an embodiment, the first compound represented by Formula 1 may be represented by any one among Formula 5-1 to Formula 5-12 below.

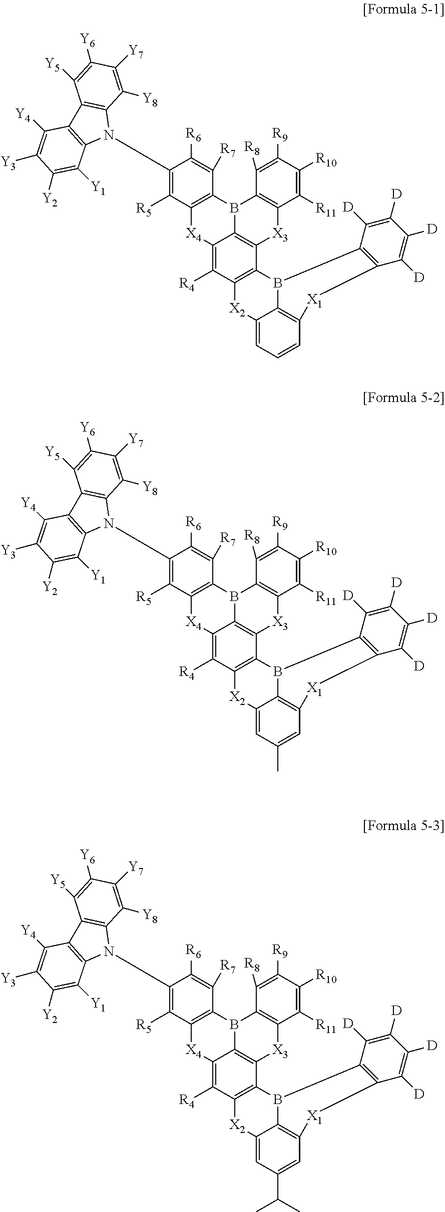

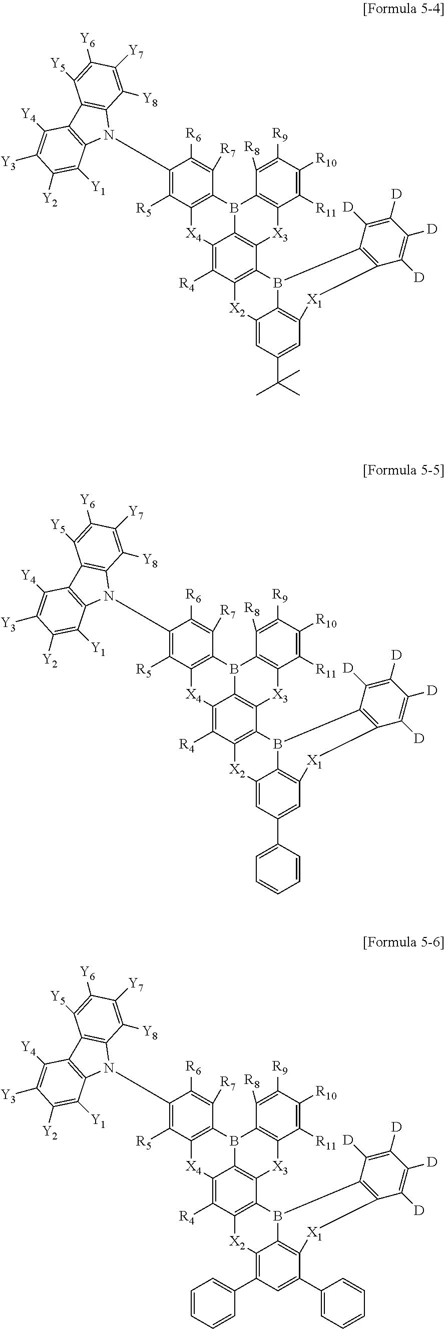

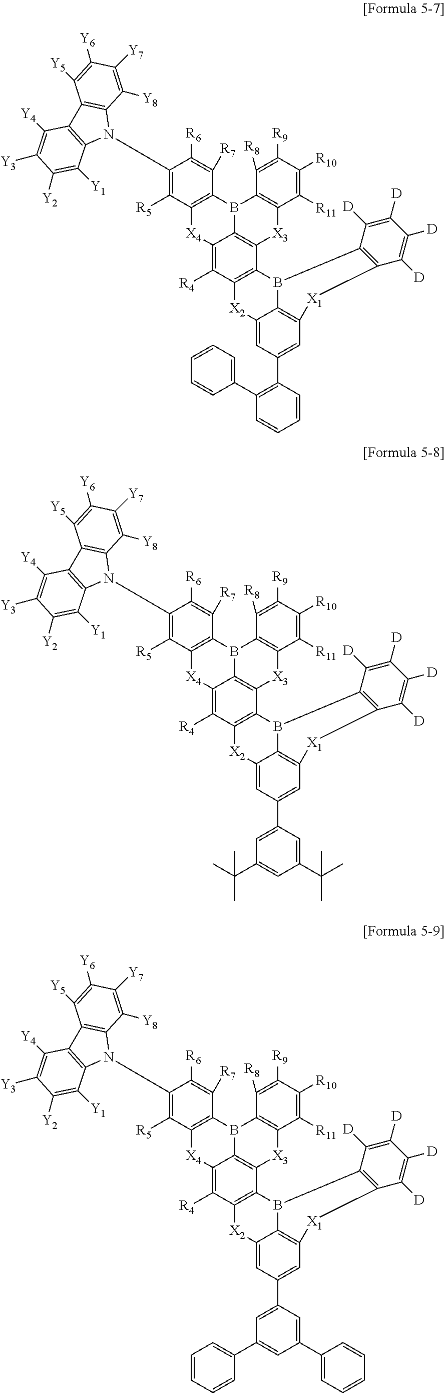

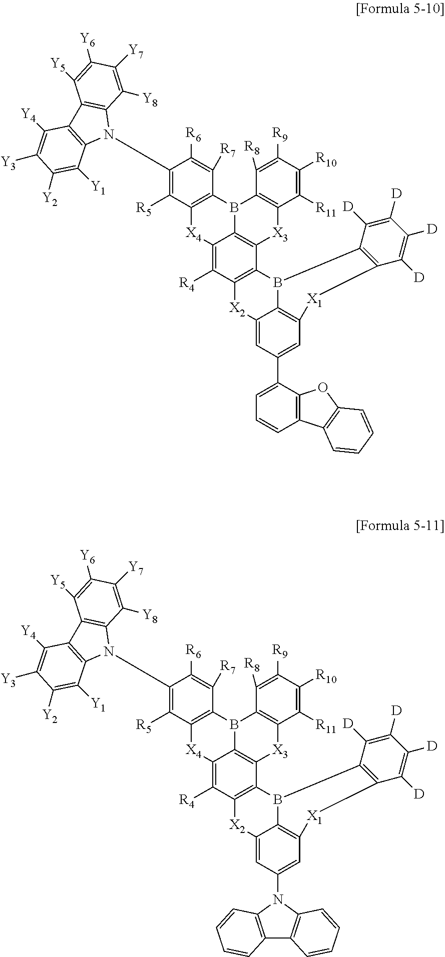

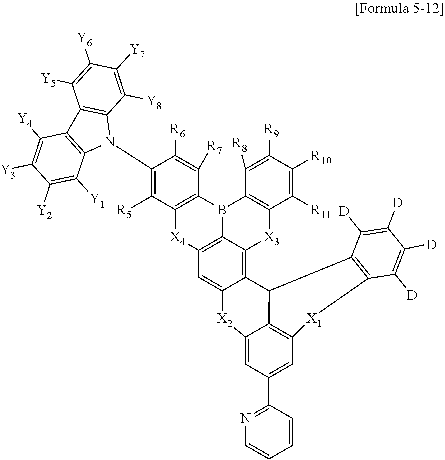

In Formula 5-1 to Formula 5-12, R₄ to R₁₁, Y₁ to Y₈, and X₁ to X₄ are the same as defined in Formula 1, and Formula 5-1 to Formula 5-12 may include a structure in which an arbitrary hydrogen atom is substituted with a deuterium atom.

In an embodiment, in Formula 1, R₈ to R₁₁ are each independently a hydrogen atom, a deuterium atom, or any one among Formula S-1 to Formula S-5 below. R₉, R₁₀, and R₁₁ may be each independently a hydrogen atom or a deuterium atom, and R₁₀ may be represented by any one among Formula S-1 to Formula S-5.

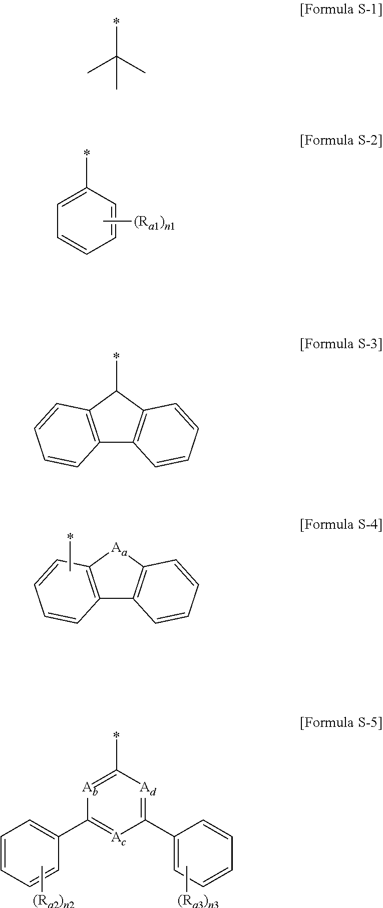

In Formula S-1 to Formula S-5, Aₐ is O, S, or NAr_{d}, A_{b}, A_{c}, and A_{d} are each independently N or CH, Ar_{d} is a substituted or unsubstituted aryl group of 6 to 30 ring-forming carbon atoms, and
Rₐ₁, Rₐ₂, and Rₐ₃ are each independently a hydrogen atom, a deuterium atom, a substituted or unsubstituted alkyl group of 1 to 20 carbon atoms, or a substituted or unsubstituted aryl group of 6 to 30 ring-forming carbon atoms,
n1 is an integer of 0 to 5, n2 and n3 are each independently an integer of 0 to 4, and
[symbol] represents a connection of the group Formula S-1 to Formula S-5 in the compound of Formula 1, and Formula S-1 to Formula S-5 may include a structure in which an arbitrary hydrogen atom is substituted with a deuterium atom.

An electronic device according to an embodiment of the inventive concept includes a base layer, a circuit layer disposed on the base layer, and a display device layer disposed on the circuit layer and including a light emitting device, wherein the light emitting device includes a first electrode, a second electrode disposed on the first electrode, and an emission layer disposed between the first electrode and the second electrode, and including the first compound represented by Formula 1.

In an embodiment, the light emitting device may further include a capping layer disposed on the second electrode, and a refractive index of the capping layer with respect to light in a wavelength range of about 550 nm to about 660 nm may be about 1.6 or more.

In an embodiment, the electronic device may further include a light control layer disposed on the display device layer and including a quantum dot, the light emitting device may emit a first color light, and the light control layer may include a first light control part including a first quantum dot converting the first color light into a second color light with a wavelength greater than the first color light, a second light control part including a second quantum dot converting the first color light into a third color light with a wavelength greater than the first color light and the second color light, and a third light control part transmitting the first color light.

In an embodiment, the electronic device may be selected from large-sized display devices such as televisions, monitors, and outdoor billboards, and small and medium-sized display devices such as personal computers, notebook computers, personal digital terminals, vehicle display devices, game consoles, portable electronic devices or cameras.

A fused polycyclic compound according represented by Formula 1.

### BRIEF DESCRIPTION OF THE FIGURES

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1 is a plan view of a display device according to an embodiment of an inventive concept;

FIG. 2 is a cross-sectional view of a display device according to an embodiment of an inventive concept;

FIG. 3 is a cross-sectional view schematically showing a light emitting device according to an embodiment of an inventive concept;

FIG. 4 is a cross-sectional view schematically showing a light emitting device according to an embodiment of an inventive concept;

FIG. 5 is a cross-sectional view schematically showing a light emitting device according to an embodiment of an inventive concept;

FIG. 6 is a cross-sectional view schematically showing a light emitting device according to an embodiment of an inventive concept;

FIG. 7 is a cross-sectional view of a display device according to embodiment of an inventive concept;

FIG. 8 is a cross-sectional view of a display device according to embodiment of an inventive concept;

FIG. 9 is a cross-sectional view showing a display device according to an embodiment of an inventive concept;

FIG. 10 is a cross-sectional view showing a display device according to an embodiment of an inventive concept;

FIG. 11 are pictorial representations of consumer products that could include a display device according to an embodiment of an inventive concept; and

FIG. 12 is a diagram showing a vehicle including display devices according to embodiments.

### DETAILED DESCRIPTION

The inventive concept may have various modifications and may be embodied in different forms, and example embodiments will be explained in detail with reference to the accompany drawings. The inventive concept may, however, be embodied in different forms and should not be construed as limited to the embodiments set forth herein. Rather, all modifications, equivalents, and substituents which are included in the spirit and technical scope of the inventive concept should be included in the inventive concept.

In the drawings, the dimensions of structures are exaggerated for clarity of illustration. Like reference numerals refer to like elements throughout.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element. As used herein, the singular forms are intended to include the plural forms as well, unless the context clearly indicates otherwise.

In the description, it will be further understood that the terms “comprises, includes, has” and/or “comprising, including, having,” when used in this specification, specify the presence of stated features, numerals, steps, operations, elements, components, or the combination thereof, but do not preclude the possibility of the presence or addition of one or more other features, numerals, steps, operations, elements, components, or the combination thereof.

In the description, when a layer, a film, a region, a plate, etc. is referred to as being “on” or “above” another part, it can be “directly on” the other part, or intervening layers may also be present. On the contrary, when a layer, a film, a region, a plate, etc. is referred to as being “under” or “below” another part, it can be “directly under” the other part, or intervening layers may also be present. Also, when an element is referred to as being disposed “on” another element, it can be disposed under the other element.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/of” includes any and all combinations of one or more of the associated listed items.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the description, the term “substituted” corresponds to a substitution of a hydrogen in a compound or an organic group moiety with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the exemplified substituents may be substituted as that term is defined above or unsubstituted. For example, a biphenyl group may be interpreted as a phenyl group substituted with a phenyl group.

In the description, the term “forming a ring in combination with an adjacent group” means forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with an adjacent group may be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In addition, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, the alkyl group may be a linear or branched type. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, or the like, without limitation.

In the description, a cycloalkyl group may mean a ring-type alkyl group. The carbon number of the cycloalkyl group may be 3 to 50, 3 to 30, 3 to 20, or 3 to 10. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, or the like, without limitation.

In the description, an alkenyl group means a hydrocarbon group including one or more carbon double bonds in the middle or at the terminal of an alkyl group having a carbon number of 2 or more. The alkenyl group may be a linear chain or a branched chain. The carbon number is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, or the like, without limitation.

In the description, an alkynyl group means a hydrocarbon group including one or more carbon triple bonds in the middle or at the terminal of an alkyl group having a carbon number of 2 or more. The alkynyl group may be a linear chain or a branched chain. The carbon number is not specifically limited, but may be 2 to 30, 2 to 20, or 2 to 10. Particular examples of the alkynyl group include an ethynyl group, a propynyl group, or the like, without limitation.

In the description, a hydrocarbon ring group means an optional functional group or substituent derived from an aliphatic hydrocarbon ring. The hydrocarbon ring group may be a saturated or unsaturated hydrocarbon ring group of 5 to 20 ring-forming carbon atoms.

In the description, an aryl group means an arbitrary functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, or the like, without limitation.

In the description, a fluorenyl group may be substituted, and two substituents may be combined with each other to form a spiro structure. Examples of a substituted fluorenyl group are as follows, but an embodiment of the inventive concept is not limited thereto.

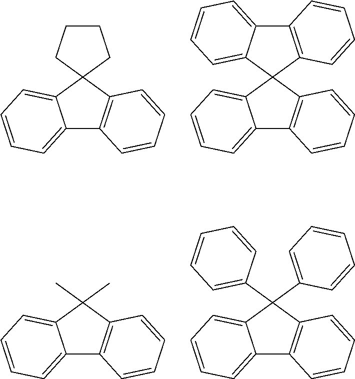

In the description, a heterocyclic group means an optional functional group or substituent derived from a ring including one or more among B, O, N, P, Si, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the description, a heterocyclic group may include one or more among B, O, N, P, Si and S as heteroatoms. If the heterocyclic group includes two or more heteroatoms, two or more heteroatoms may be the same or different. The heterocyclic group may be a monocyclic heterocyclic group or a polycyclic heterocyclic group, and has the concept including a heteroaryl group. The carbon number for forming rings of the heterocyclic group may be 2 to 30, 2 to 20, and 2 to 10.

In the description, an aliphatic heterocyclic group may include one or more among B, O, N, P, Si, and S as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, or the like, without limitation.

In the description, a heteroaryl group may include one or more among B, O, N, P, Si, and S as heteroatoms. If the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyridine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, or the like, without limitation.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, or the like, without limitation.

In the description, a germanium group includes an alkyl germanium group and an aryl germanium group. Examples of the germanium group include a trimethyl germanium group, a triethyl germanium group, a t-butyl dimethyl germanium group, a vinyl dimethyl germanium group, a propyl dimethyl germanium group, a triphenyl germanium group, a tribiphenyl germanium group, a phenyl dimethyl germanium group, a diphenyl germanium group, a phenyl germanium group, or the like, without limitation.

In the description, the carbon number of a carbonyl group is not specifically limited, but the carbon number may be 1 to 40, 1 to 30, or 1 to 20. For example, the carbonyl group may have the structures below but is not limited thereto.

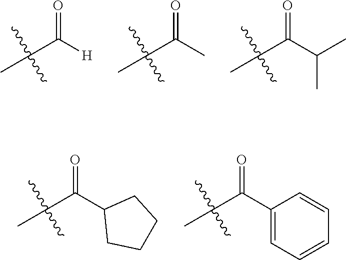

In the description, the carbon number of a sulfinyl group and sulfonyl group is not specifically limited but may be 1 to 30. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may mean the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, or the like, without limitation.

In the description, an oxy group may mean the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, phenoxy, benzyloxy, or the like. However, an embodiment of the inventive concept is not limited thereto.

In the description, a boron group may mean the above-defined alkyl group or aryl group, combined with a boron atom. The boron group includes an alkyl boron group and an aryl boron group. Examples of the boron group include a dimethyl boron group, a diethyl boron group, a t-butyl methyl boron group, a diphenyl boron group, a phenyl boron group, or the like, without limitation.

In the description, the carbon number of the amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, or the like, without limitation.

In the description, alkyl groups in an alkylthiol group, alkylsulfoxy group, alkylaryl group, alkylamino group, alkyl boron group, alkyl silyl group, and alkyl amine group may be the same as the examples of the above-described alkyl group.

In the description, aryl groups in an aryloxy group, arylthio group, arylsulfoxy group, arylamino group, aryl boron group, aryl silyl group, and aryl amine group may be the same as the examples of the above-described aryl group.

In the description, a direct linkage may mean a single bond.

Meanwhile, in the description,

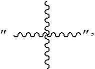

or [symbol] means a position that connects a group, an organic group moiety, to compound of interest.

Hereinafter, embodiments will be explained referring to the drawings.

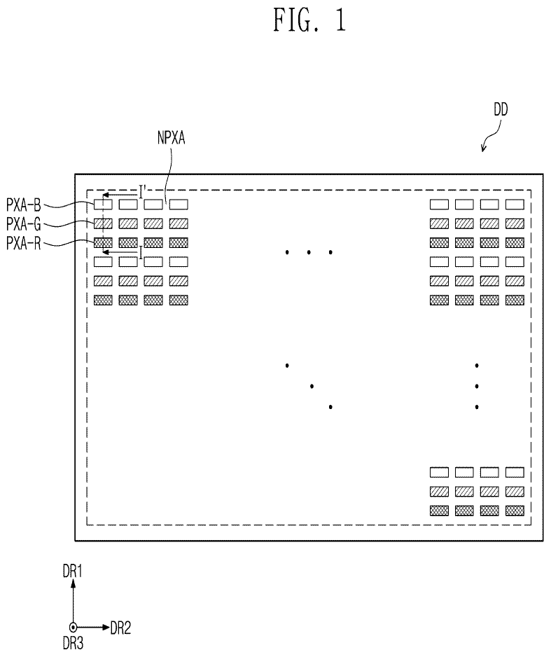

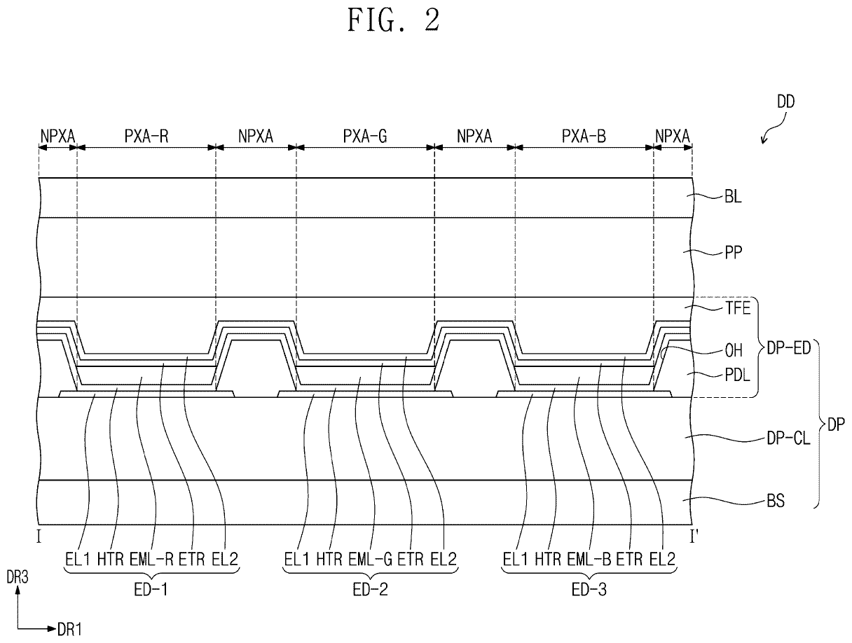

FIG. 1 is a plan view showing an embodiment of a display device DD. FIG. 2 is a cross-sectional view showing a portion of display device DD corresponding to line I-I′ in FIG. 1. The display device DD may include a display panel DP and an optical layer PP disposed on the display panel DP. The display panel DP includes light emitting devices ED-1, ED-2 and ED-3. The display device DD may include multiple light emitting devices ED-1, ED-2 and ED-3. The optical layer PP may be disposed on the display panel DP and control reflected light by external light at the display panel DP. The optical layer PP may include, for example, a polarization layer or a color filter layer. Meanwhile, different from the drawings, the optical layer PP may be omitted in the display device DD of an embodiment.

On the optical layer PP, a base substrate BL may be disposed. The base substrate BL may be a member providing a base surface where the optical layer PP is disposed. The base substrate BL may be a glass substrate, a metal substrate, a plastic substrate, or the like. However, an embodiment of the inventive concept is not limited thereto, and the base substrate BL may be an inorganic layer, an organic layer or a composite material layer. In addition, different from the drawings, the base substrate BL may be omitted in an embodiment.

The display device DD according to an embodiment may further include a filling layer (not shown). The filling layer (not shown) may be disposed between a display device layer DP-ED and a base substrate BL. The filling layer (not shown) may be an organic layer. The filling layer (not shown) may include at least one among an acrylic resin, a silicon-based resin and an epoxy-based resin.

The display panel DP may include a base layer BS, a circuit layer DP-CL provided on the base layer BS and a display device layer DP-ED. The display device layer DP-ED may include a pixel definition layer PDL, light emitting devices ED-1, ED-2 and ED-3 disposed in the pixel definition layer PDL, and an encapsulation layer TFE disposed on the light emitting devices ED-1, ED-2 and ED-3.

The base layer BS may be a member providing a base surface where the display device layer DP-ED is disposed. The base layer BS may be a glass substrate, a metal substrate, a plastic substrate, or the like. However, an embodiment of the inventive concept is not limited thereto, and the base layer BS may be an inorganic layer, an organic layer or a composite material layer.

In an embodiment, the circuit layer DP-CL is disposed on the base layer BS, and the circuit layer DP-CL may include multiple transistors (not shown). Each of the transistors (not shown) may include a control electrode, an input electrode, and an output electrode. For example, the circuit layer DP-CL may include switching transistors and driving transistors for driving the light emitting devices ED-1, ED-2 and ED-3 of the display device layer DP-ED.

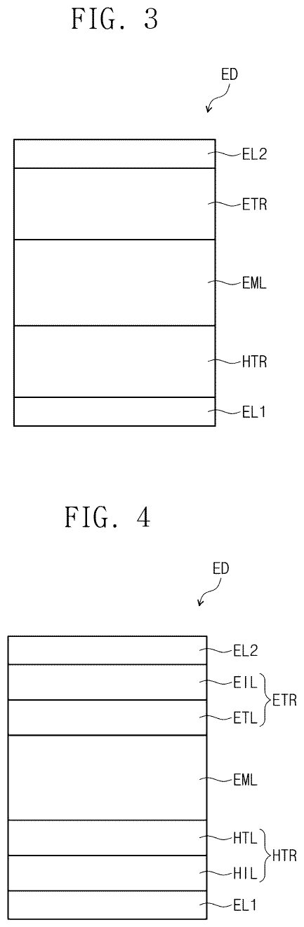

Each of the light emitting devices ED-1, ED-2 and ED-3 may have the structures of light emitting devices ED of embodiments according to FIG. 3 to FIG. 6, which will be explained later. Each of the light emitting devices ED-1, ED-2 and ED-3 may include a first electrode EL1, a hole transport region HTR, emission layers EML-R, EML-G and EML-B, an electron transport region ETR, and a second electrode EL2.

In FIG. 2, shown is an embodiment where the emission layers EML-R, EML-G and EML-B of light emitting devices ED-1, ED-2 and ED-3, which are in opening parts OH defined in a pixel definition layer PDL, are disposed, and a hole transport region HTR, an electron transport region ETR and a second electrode EL2 are provided as common layers in all light emitting devices ED-1, ED-2 and ED-3. However, an embodiment of the inventive concept is not limited thereto. Different from FIG. 2, in an embodiment, the hole transport region HTR and the electron transport region ETR may be patterned and provided in the opening parts OH defined in the pixel definition layer PDL. For example, in an embodiment, the hole transport region HTR, the emission layers EML-R, EML-G and EML-B, and the electron transport region ETR of the light emitting devices ED-1, ED-2 and ED-3 may be patterned by an ink jet printing method and provided.

An encapsulation layer TFE may cover the light emitting devices ED-1, ED-2 and ED-3. The encapsulation layer TFE may encapsulate a display device layer DP-ED. The encapsulation layer TFE may be a thin film encapsulation layer. The encapsulation layer TFE may be one layer or a stacked layer of multiple layers. The encapsulation layer TFE includes at least one insulating layer. The encapsulation layer TFE according to an embodiment may include at least one inorganic layer (hereinafter, encapsulating inorganic layer). In addition, the encapsulation layer TFE according to an embodiment may include at least one organic layer (hereinafter, encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, or the like. The encapsulating organic layer may include a photopolymerizable organic material, without specific limitation.

The encapsulation layer TFE may be disposed on the second electrode EL2 and may be disposed while filling the opening part OH.

Referring to FIG. 1 and FIG. 2, the display device DD may include a non-luminous area NPXA and luminous areas PXA-R, PXA-G and PXA-B. The luminous areas PXA-R, PXA-G and PXA-B may be areas emitting light produced from the light emitting devices ED-1, ED-2 and ED-3, respectively. The luminous areas PXA-R, PXA-G and PXA-B may be separated from each other on a plane.

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. Meanwhile, in the description, each of the luminous areas PXA-R, PXA-G and PXA-B may correspond to each pixel. The pixel definition layer PDL may divide the light emitting devices ED-1, ED-2 and ED-3. The emission layers EML-R, EML-G and EML-B of the light emitting devices ED-1, ED-2 and ED-3 may be disposed and divided in the opening parts OH defined in the pixel definition layer PDL.

The luminous areas PXA-R, PXA-G and PXA-B may be divided into multiple groups according to the color of light produced from the light emitting devices ED-1, ED-2 and ED-3. In the display device DD of an embodiment, shown in FIG. 1 and FIG. 2, three luminous areas PXA-R, PXA-G and PXA-B emitting red light, green light and blue light are illustrated as embodiments. For example, the display device DD of an embodiment may include a red luminous area PXA-R, a green luminous area PXA-G and a blue luminous area PXA-B, which are separated from each other.

In the display device DD according to an embodiment, multiple light emitting devices ED-1, ED-2 and ED-3 may emit light having different wavelength ranges. For example, in an embodiment, the display device DD may include a first light emitting device ED-1 emitting red light, a second light emitting device ED-2 emitting green light, and a third light emitting device ED-3 emitting blue light. That is, each of the red luminous area PXA-R, the green luminous area PXA-G, and the blue luminous area PXA-B of the display device DD may correspond to the first light emitting device ED-1, the second light emitting device ED-2, and the third light emitting device ED-3.

However, an embodiment of the inventive concept is not limited thereto, and the first to third light emitting devices ED-1, ED-2 and ED-3 may emit light in the same wavelength range, or at least one thereof may emit light in a different wavelength range. For example, all the first to third light emitting devices ED-1, ED-2 and ED-3 may emit blue light.

The luminous areas PXA-R, PXA-G and PXA-B in the display device DD according to an embodiment may be arranged in a stripe shape. Referring to FIG. 1, multiple red luminous areas PXA-R, multiple green luminous areas PXA-G and multiple blue luminous areas PXA-B may be arranged along a second direction axis DR2. In addition, the red luminous areas PXA-R, the green luminous areas PXA-G and the blue luminous areas PXA-B may be arranged by turns along a first direction axis DR1.

In FIG. 1 and FIG. 2, the areas of the luminous areas PXA-R, PXA-G and PXA-B are shown similar, but an embodiment of the inventive concept is not limited thereto. The areas of the luminous areas PXA-R, PXA-G and PXA-B may be different from each other according to the wavelength range of light emitted. Meanwhile, the areas of the luminous areas PXA-R, PXA-G and PXA-B may mean areas on a plane defined by the first direction axis DR1 and the second direction axis DR2.

Meanwhile, the arrangement type of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various combinations according to the properties of display quality required for the display device DD. For example, the arrangement type of the luminous areas PXA-R, PXA-G and PXA-B may be a pentile (PENTILE™) arrangement type, or a diamond (Diamond Pixel™) arrangement type.

In addition, the areas of the luminous areas PXA-R, PXA-G and PXA-B may be different from each other. For example, in an embodiment, the area of the green luminous area PXA-G may be smaller than the area of the blue luminous area PXA-B, but an embodiment of the inventive concept is not limited thereto.

Hereinafter, FIG. 3 to FIG. 6 are cross-sectional views schematically showing light emitting devices according to embodiments. A light emitting device ED of an embodiment may include a first electrode EL1, a second electrode EL2 facing the first electrode EL1, and at least one functional layer disposed between the first electrode EL1 and the second electrode EL2. The light emitting device ED of an embodiment may include a fused polycyclic compound of an embodiment described below in the at least one functional layer.

The light emitting device ED may include, as the at least one functional layer, a hole transport region HTR, an emission layer EML, an electron transport region ETR, or the like, stacked in order. That is, the light emitting device ED of an embodiment may include a first electrode EL1, a hole transport region HTR, an emission layer EML, an electron transport region ETR, and a second electrode, stacked in order.

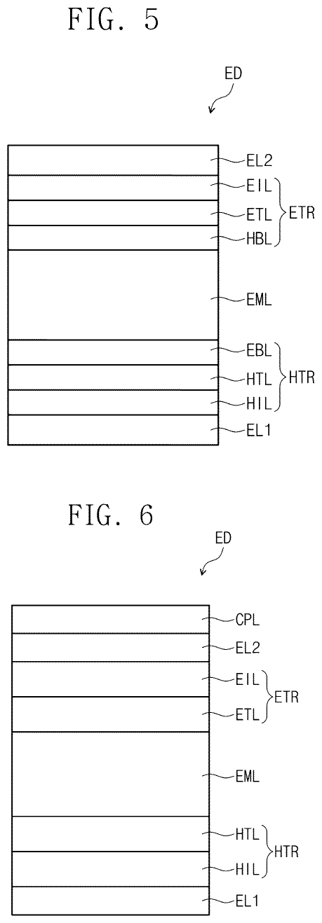

When compared with FIG. 3, FIG. 4 shows the cross-sectional view of a light emitting device ED of an embodiment, wherein a hole transport region HTR includes a hole injection layer HIL and a hole transport layer HTL, and an electron transport region ETR includes an electron injection layer EIL and an electron transport layer ETL. In addition, when compared with FIG. 3, FIG. 5 shows the cross-sectional view of a light emitting device ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting device ED of an embodiment, including a capping layer CPL disposed on the second electrode EL2.

The light emitting device ED may include a fused polycyclic compound of an embodiment described below in at least one functional layer of the light emitting device ED. In the light emitting device ED, the fused polycyclic compound may be included in at least one of the hole transport region HTR, the emission layer EML, and/or the electron transport region ETR. For example, in the light emitting device ED, the emission layer EML may include the fused polycyclic compound of an embodiment.

The first electrode EL1 may be formed using a metal material, a metal alloy or a conductive compound. The first electrode EL1 may be an anode or a cathode. However, an embodiment of the inventive concept is not limited thereto. In addition, the first electrode EL1 may be a pixel electrode. The first electrode EL1 may be a transmissive electrode, a transflective electrode, or a reflective electrode. The first electrode EL1 may include at least one selected from Ag, Mg, Cu, Al, Pt, Pd, Au, Ni, Nd, Ir, Cr, Li, Ca, LiF, Mo, Ti, W, In, Sn, Zn, compounds of two or more selected therefrom, mixtures of two or more selected therefrom, or oxides thereof.

If the first electrode EL1 is the transmissive electrode, the first electrode EL1 may include a transparent metal oxide such as indium tin oxide (ITO), indium zinc oxide (IZO), zinc oxide (ZnO), and indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, compounds thereof, or mixtures thereof (for example, a mixture of Ag and Mg). Also, the first electrode EL1 may have a structure including multiple layers including a reflective layer or a transflective layer formed using the above materials, and a transmissive conductive layer formed using ITO, IZO, ZnO, or ITZO. For example, the first electrode EL1 may include a three-layer structure of ITO/Ag/ITO. However, an embodiment of the inventive concept is not limited thereto. The first electrode EL1 may include the above-described metal materials, combinations of two or more metal materials selected from the above-described metal materials, or oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one among a hole injection layer HIL, a hole transport layer HTL, a buffer layer or an emission auxiliary layer (not shown), and an electron blocking layer EBL. The thickness of the hole transport region HTR may be, for example, from about 50 Å to about 15,000 Å.

The hole transport region HTR may have a single layer formed using a single material, a single layer formed using multiple different materials, or a multilayer structure including multiple layers formed using multiple different materials.

For example, the hole transport region HTR may have the structure of a single layer of a hole injection layer HIL or a hole transport layer HTL and may have a structure of a single layer formed using a hole injection material and a hole transport material. Otherwise, the hole transport region HTR may have a structure of a single layer formed using multiple different materials, or a structure stacked from the first electrode EL1 of hole injection layer HIL/hole transport layer HTL, hole injection layer HIL/hole transport layer HTL/buffer layer (not shown), hole injection layer HIL/buffer layer (not shown), hole transport layer HTL/buffer layer (not shown), or hole injection layer HIL/hole transport layer HTL/electron blocking layer EBL, without limitation.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1 below.

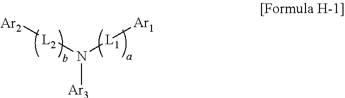

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. Indices, “a” and “b” may be each independently an integer of 0 to 10. Moreover, if “a” or “b” is an integer of 2 or more, each L₁ and L₂ may be the same or different, and independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-1, Ar₃ may be a substituted or unsubstituted aryl group of 6 to 30 ring-forming carbon atoms, or a substituted or unsubstituted heteroaryl group of 2 to 30 ring-forming carbon atoms.

The compound represented by Formula H-1 may be a monoamine compound. The compound represented by Formula H-1 may be a diamine compound in which at least one among Ar-1 to Ar₃ includes an amine group as a substituent. The compound represented by Formula H-1 may be a carbazole-based compound in which at least one among Ar and Ar₂ includes a substituted or unsubstituted carbazole group, or a fluorene-based compound in which at least one among Ar₁ and Ar₂ includes a substituted or unsubstituted fluorene group.

The compound represented by Formula H-1 may be represented by any one compound in Compound Group H below. However, the compounds shown in Compound Group H are only exemplary, and the compound represented by Formula H-1 is not limited to the compounds represented in Compound Group H.

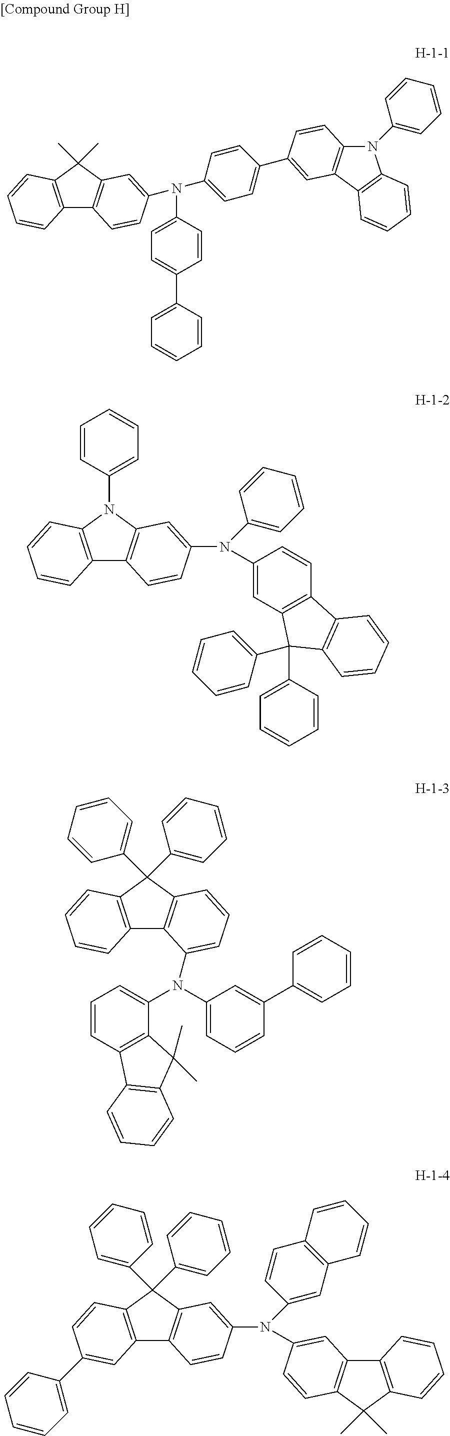 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

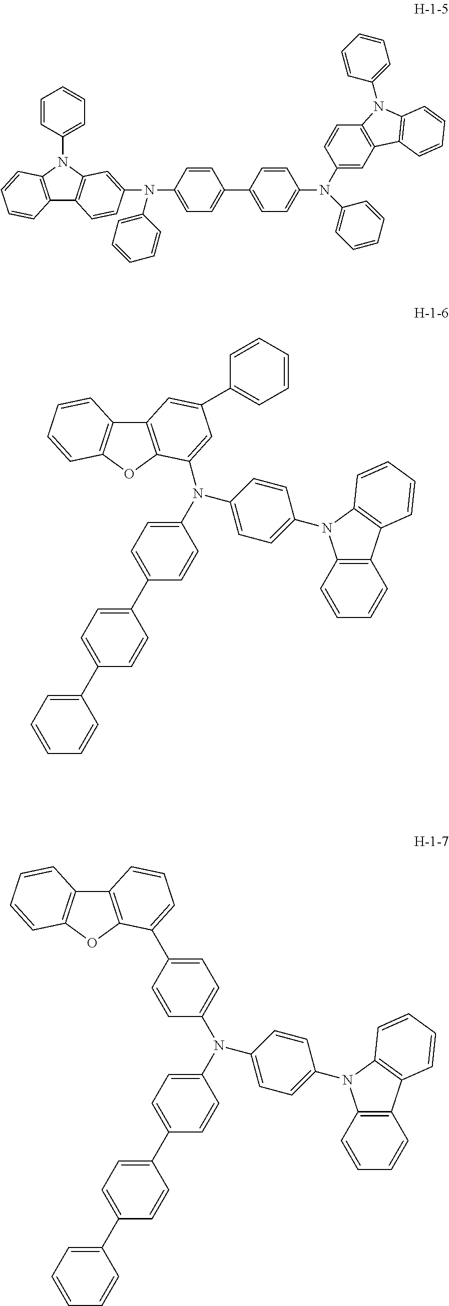 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

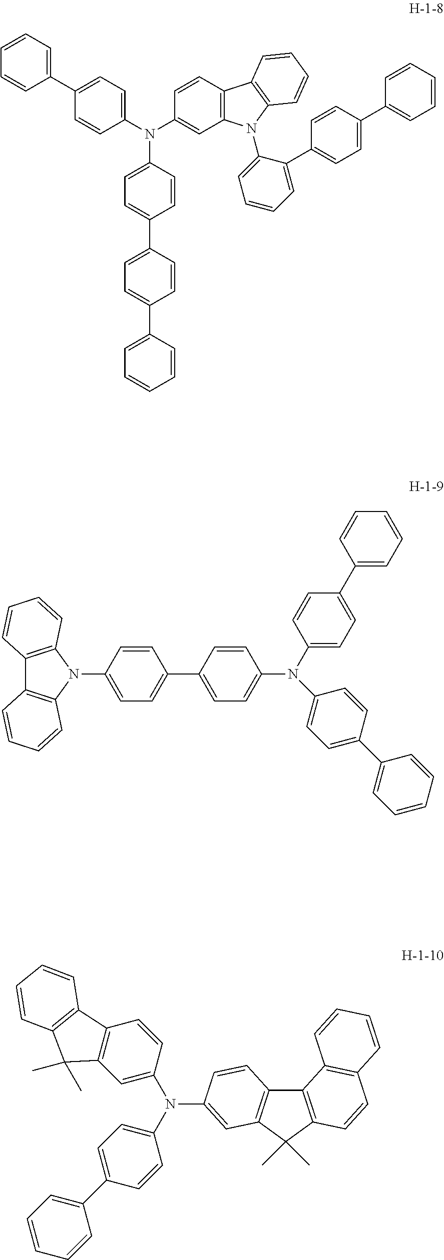 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

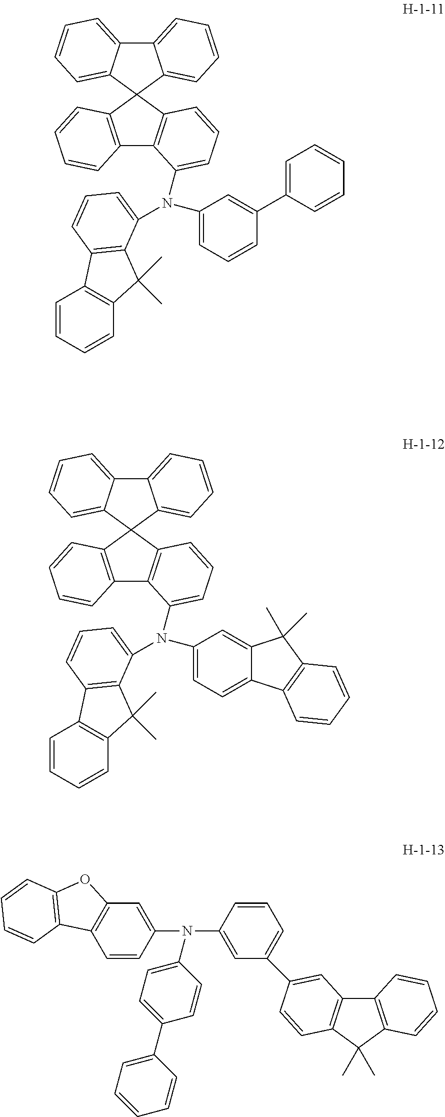 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

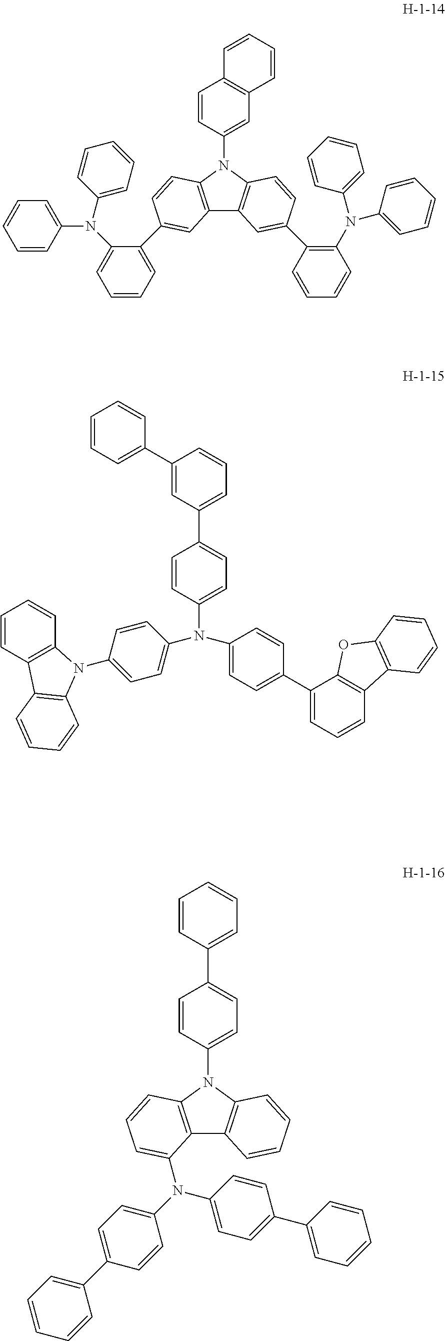 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

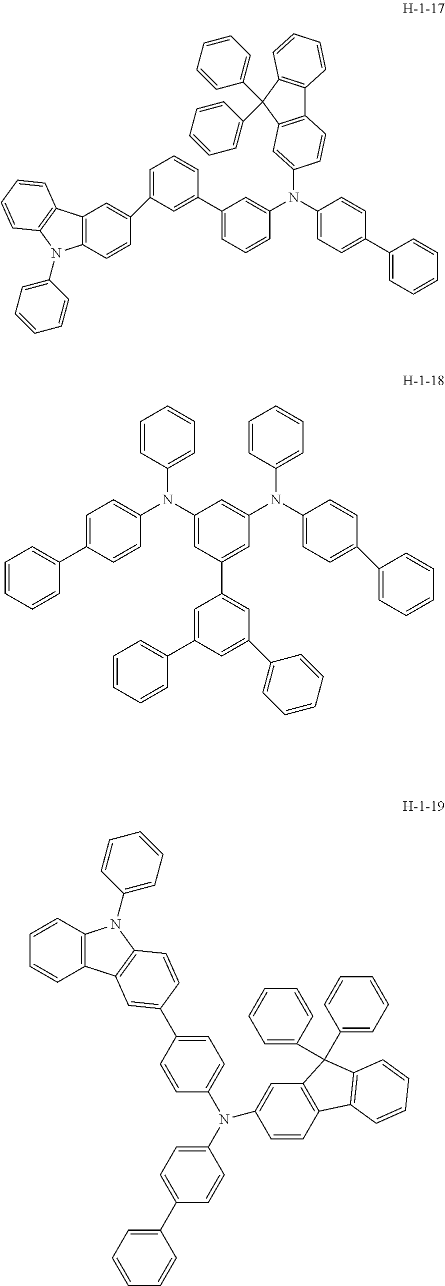 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenyl amino]triphenylamine (m-MTDATA), 4,4′,4″-tris(N,N-diphenylamino)triphenylamine (TDATA), 4,4′,4″-tris[N(2-naphthyl)-N-phenyl amino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrene sulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h]quinoxaline-2,3,6,7,10,11-hexacarbonitrile (HAT-CN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine](TAPC), 4,4′-bis[N,N′-(3-tolyl)amino]-3,3′-dimethylbiphenyl (HMTPD), 1,3-bis(N-carbazolyl)benzene (mCP), or the like.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

In an embodiment, the hole transport region HTR may include any one among the compounds in Compound Group H above.

The hole transport region HTR may include the compounds of the hole transport region in at least one among the hole injection layer HIL, hole transport layer HTL, and electron blocking layer EBL.

The thickness of the hole transport region HTR may be from about 100 Å to about 10,000 Å, for example, from about 100 Å to about 5,000 Å. In case where the hole transport region HTR includes a hole injection layer HIL, the thickness of the hole injection region HIL may be, for example, from about 30 Å to about 1,000 Å. If the hole transport region HTR includes a hole transport layer HTL, the thickness of the hole transport layer HTL may be from about 30 Å to about 1,000 Å. For example, if the hole transport region HTR includes an electron blocking layer, the thickness of the electron blocking layer EBL may be from about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without substantial increase of a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of metal halide compounds, quinone derivatives, metal oxides, and cyano group-containing compounds, without limitation. For example, the p-dopant may include metal halide compounds such as CuI and RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f. 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), or the like, without limitation.

As described above, the hole transport region HTR may further include at least one among a buffer layer (not shown) and an electron blocking layer EBL in addition to the hole injection layer HIL and the hole transport layer HTL. The buffer layer (not shown) may compensate resonance distance according to the wavelength of light emitted from an emission layer EML and may increase emission efficiency. As materials included in the buffer layer (not shown), materials which may be included in the hole transport region HTR may be used. The electron blocking layer EBL is a layer playing the role of blocking the injection of electrons from an electron transport region ETR to a hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed using a single material, a single layer formed using multiple different materials, or a multilayer structure having multiple layers formed using multiple different materials.

The light emitting device ED of an embodiment may include a fused polycyclic compound represented by Formula 1 below in at least one functional layer disposed between the first electrode EL1 and the second electrode EL2. In the light emitting device ED, the emission layer EML may include the fused polycyclic compound of an embodiment described herein. The emission layer EML may include the fused polycyclic compound of an embodiment as a dopant. The fused polycyclic compound of an embodiment may be a dopant material of the emission layer EML. Moreover, the fused polycyclic compound of an embodiment, may be referred to as a first compound.

The fused polycyclic compound of an embodiment has a structure in which at least five rings, e.g., five benzene rings (optionally substituted as indicated in Formula 1) are fused, to form a fused polycyclic heterocycle including a first boron atom and first and second heteroatoms, and has a structure in which two aromatic hydrocarbon rings are connected to the fused polycyclic heterocycle. A second boron atom, a third heteroatom, and a fourth heteroatom may be disposed as linking groups between the fused polycyclic heterocycle and the two aromatic hydrocarbon rings. The two aromatic hydrocarbon rings may be connected to the fused polycyclic heterocycle via the second boron atom, the third heteroatom, and the fourth heteroatom to form an additional fused ring.

In an embodiment, the fused polycyclic heterocycle included in the fused polycyclic compound may form five rings in which three substituted or unsubstituted benzene rings are connected through the first boron atom, the first heteroatom, and the second heteroatom. More specifically, in the three benzene rings included in the fused polycyclic heterocycle, the three benzene rings may be connected with the first boron atom as the center, the first benzene ring and the second benzene ring among the three benzene rings may be connected through the first heteroatom, and the remaining third benzene ring may be connected to the second benzene ring through the second heteroatom. The second benzene ring may be connected to both the first boron atom and the first and second heteroatoms.

The fused polycyclic compound of an embodiment may include four first substituents connected to the first benzene ring. The first substituent may be a deuterium atom. The first benzene ring may not have any other substituents other than the first substituent, i.e., a deuterium atom. The first boron atom may be connected to the first carbon atom among the carbon atoms constituting the first benzene ring, the second carbon atom may be connected to the first heteroatom, and the third to sixth carbon atoms may each be connected to the first substituent.

In an embodiment, two aromatic hydrocarbon rings included in the fused polycyclic compound may be connected to the fused polycyclic heterocycle via the second boron atom, the third heteroatom, and the fourth heteroatom to form an additional fused ring. More specifically, the fused polycyclic compound of an embodiment has a structure in which two aromatic hydrocarbon rings, a fourth benzene ring and a fifth benzene ring are connected to the fused polycyclic heterocycle, and the second boron atom, the third heteroatom, and the fourth heteroatom may be disposed as linking groups between the fused polycyclic heterocycle and the fourth and fifth benzene rings. The fourth and fifth benzene rings may be connected to the fused polycyclic heterocycle via the second boron atom, the third heteroatom, and the fourth heteroatom, thereby forming four additional fused rings.

The fourth benzene ring and the fifth benzene ring may be connected to the third benzene ring among the three benzene rings included in the fused polycyclic heterocycle. More specifically, the second boron atom, the third heteroatom, and the fourth heteroatom may be connected to the third benzene ring, and the fourth benzene ring and the third benzene ring may be connected via the second boron atom and the third heteroatom, and the fifth benzene ring and the third benzene ring may be connected via the second boron atom and the fourth heteroatom. The second boron atom may be connected to a carbon atom corresponding to a meta position with respect to the first boron atom among the carbon atoms constituting the third benzene ring. The third heteroatom may be connected to a carbon atom corresponding to an ortho position with respect to the first boron atom among the carbon atoms constituting the third benzene ring. The fourth heteroatom may be connected to a carbon atom corresponding to a para position with respect to the first boron atom among the carbon atoms constituting the third benzene ring. In addition, the third and fourth heteroatoms may be connected to carbon atoms corresponding to meta positions with respect to the second heteroatom among the carbon atoms constituting the third benzene ring, respectively.

The fused polycyclic compound of an embodiment may include a second substituent connected to the fifth benzene ring. The second substituent may include a carbazole moiety including a first nitrogen atom. As the first nitrogen atom and one carbon atom constituting the fifth benzene ring are connected, the second substituent may be connected to the fifth benzene ring. Specifically, the first nitrogen atom may be connected to a carbon atom corresponding to a para position with respect to the second boron atom among the carbon atoms constituting the fifth benzene ring and corresponding to a meta position with respect to the fourth heteroatom.

In an embodiment, the first to fourth heteroatoms may be each independently a nitrogen (N) atom, an oxygen (O) atom, or a sulfur (S) atom.

The fused polycyclic compound of an embodiment may be represented by Formula 1 below.

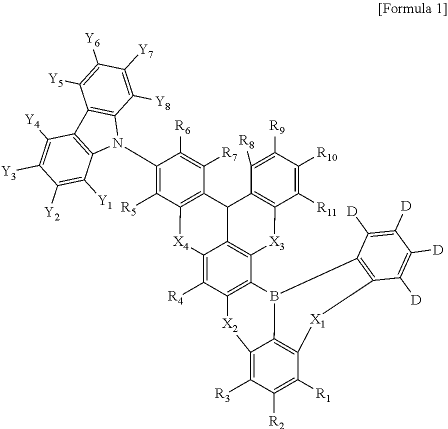

The fused polycyclic compound of an embodiment represented by Formula 1 may have a structure in which a fused polycyclic heterocycle is formed by fusing five rings centered on a first boron atom and first and second heteroatoms, and two aromatic hydrocarbon rings are connected to the fused polycyclic heterocycle. A second boron atom and third and fourth heteroatoms may be disposed as linking groups between the fused polycyclic heterocycle and the two aromatic hydrocarbon rings. The two aromatic hydrocarbon rings may be connected to the fused polycyclic heterocycle through the second boron atom, the third heteroatom, and the fourth heteroatom to form an additional fused ring.

In Formula 1, X₁ to X₄ are each independently O, S or NAr. For example, X₁ and X₂ may be each independently O or NAr, and X₃ and X₄ may be each independently O or S.

In Formula 1, Ar may be a substituted or unsubstituted aryl group of 6 to 30 ring-forming carbon atoms, or a substituted or unsubstituted heteroaryl group of 2 to 30 ring-forming carbon atoms. For example, Ar may be a substituted or unsubstituted phenyl group, a substituted or unsubstituted divalent biphenyl group, or a substituted or unsubstituted terphenyl group.

In Formula 1, R₁ to R₁₁ and Y₁ to Y₈ are each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted amine group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁ to R₁₁ may be each independently a hydrogen atom, a deuterium atom, a substituted or unsubstituted methyl group, a substituted or unsubstituted ethyl group, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, a substituted or unsubstituted dibenzothiophene group, a substituted or unsubstituted pyridine group, a substituted or unsubstituted pyrimidine group, or a substituted or unsubstituted triazine group, and Y₁ to Y₈ may be each independently a hydrogen atom, a deuterium atom, a substituted or unsubstituted methyl group, a substituted or unsubstituted t-butyl group, a substituted or unsubstituted phenyl group, a substituted or unsubstituted carbazole group, or a substituted or unsubstituted dibenzofuran group.

In Formula 1, D is a deuterium atom.

The benzene ring substituted with a deuterium atom D in Formula 1 corresponds to the first benzene ring described above, the benzene ring substituted with the substituents represented by R₁ to R₃ corresponds to the second benzene ring described above, the benzene ring substituted with the substituent represented by R₄ corresponds to the third benzene ring described above, the benzene ring substituted with the substituents represented by R₈ to R₁₁ corresponds to the fourth benzene ring described above, and the benzene ring substituted with the substituents represented by R₅ to R₇ may correspond to the fifth benzene ring described above. X₁ to X₄ may correspond to the first to fourth heteroatoms described above, respectively, and the nitrogen (N) atom connected to the benzene ring substituted with the substituents represented by R₅ to R₇ may correspond to the first nitrogen atom described above.

In Formula 1, R₈ to R₁₁ may be each independently a hydrogen atom, a deuterium atom, or any one represented by Formula S-1 to Formula S-5 below. For example, R₈, R₉ and R₁₁ may be each independently a hydrogen atom or a deuterium atom, and R₁₀ may be any one represented by Formula S-1 to Formula S-5 below.

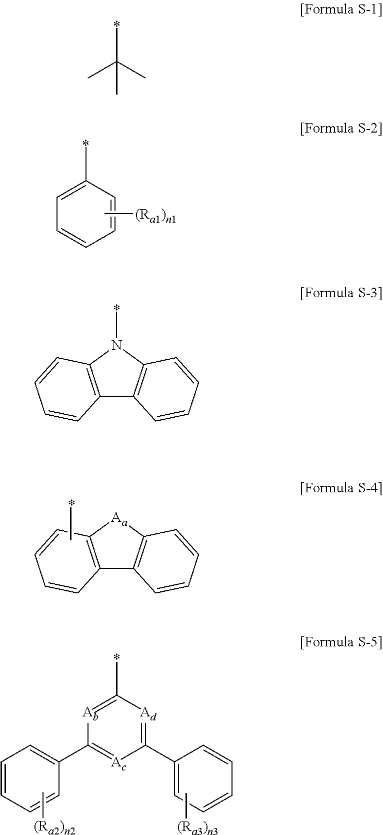

In Formula S-2, Formula S-4 and Formula S-5, Rₐ₁, Rₐ₂, and Rₐ₃ may be each independently a hydrogen atom, a deuterium atom, a substituted or unsubstituted alkyl group of 1 to 20 carbon atoms, or a substituted or unsubstituted aryl group of 6 to 30 ring-forming carbon atoms. For example, Rₐ₁, Rₐ₂, and Rₐ₃ may be each independently a hydrogen atom, a deuterium atom, a substituted or unsubstituted t-butyl group, a substituted or unsubstituted phenyl group, or a substituted or unsubstituted biphenyl group.

In Formula S-4, Aₐ may be O, S, or NAr_{d}. Ar_{d} may be a substituted or unsubstituted aryl group of 6 to 30 ring-forming carbon atoms. For example, Aₐ may be O or S. Aₐ may be NAr_{d}, and Ar_{d} may be a substituted or unsubstituted phenyl group.

In Formula S-5, A_{b}, A_{c}, and A_{d} may be each independently N or CH.

In Formula S-2, n1 may be an integer of 0 to 5. If n1 is 0, the first compound of an embodiment may not be substituted with Rₐ₁. A case of Formula S-2 where n1 is 5, and all n1 are hydrogen atoms, may be the same as a case of Formula S-2 where n1 is 0. If n1 is an integer of 2 or more, each of the Rₐ₁ provided in plurality may be all the same, or at least one of the plurality of Rₐ₁ may be different.

In Formula S-4, n2 may be an integer of 0 to 4. If n2 is 0, the first compound of an embodiment may not be substituted with Rₐ₂. A case of Formula S-4 where n2 is 4, and all n2 are hydrogen atoms, may be the same as a case of Formula S-4 where n2 is 0. If n2 is an integer of 2 or more, each of the Rₐ₂ provided in plurality may be all the same, or at least one of the plurality of Rₐ₂ may be different.

In Formula S-5, n3 may be an integer of 0 to 4. If n3 is 0, the first compound of an embodiment may not be substituted with Rₐ₃. A case of Formula S-5 where n3 is 4, and all n3 are hydrogen atoms, may be the same as a case of Formula S-5 where n3 is 0. If n3 is an integer of 2 or more, each of the Rₐ₃ provided in plurality may be all the same, or at least one of the plurality of Rₐ₃ may be different.

[symbol]

In Formula S-1 to S-5, may be a position that connects the groups of Formula S-1 to S-5 in the compounds of Formula 1.

In Formula S-1 to Formula S-5, an arbitrary hydrogen atom may be substituted with a deuterium atom. Formula S-1 to Formula S-5 may include a structure in which an arbitrary hydrogen atom is substituted with a deuterium atom.

The first compound represented by Formula 1 may be represented by any one among Formula 2-1 to Formula 2-10 below.

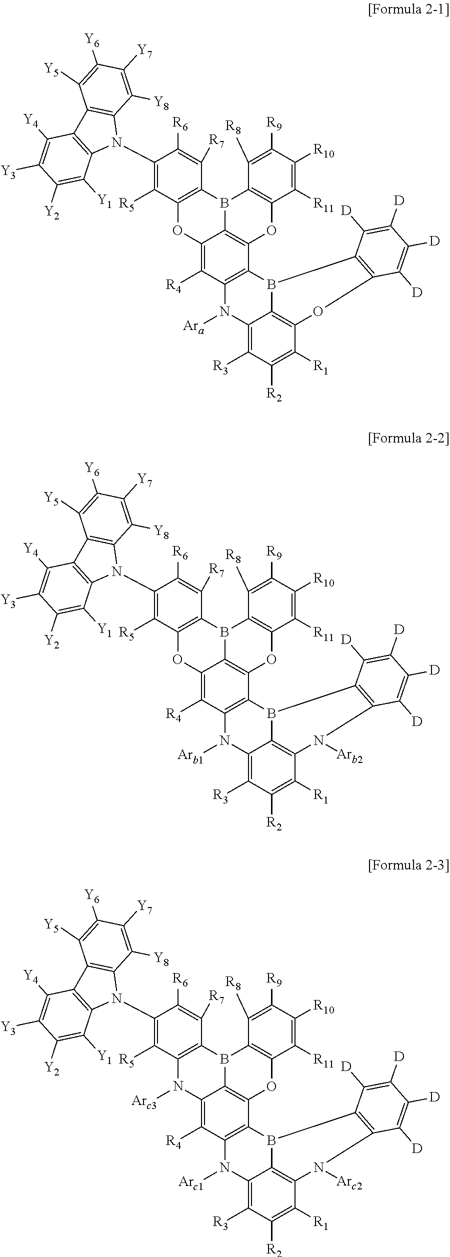

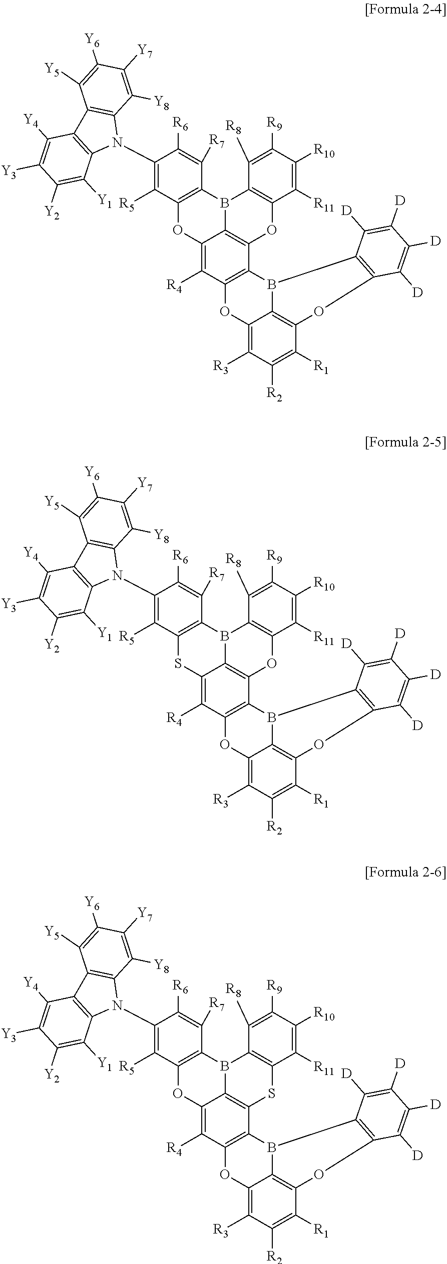

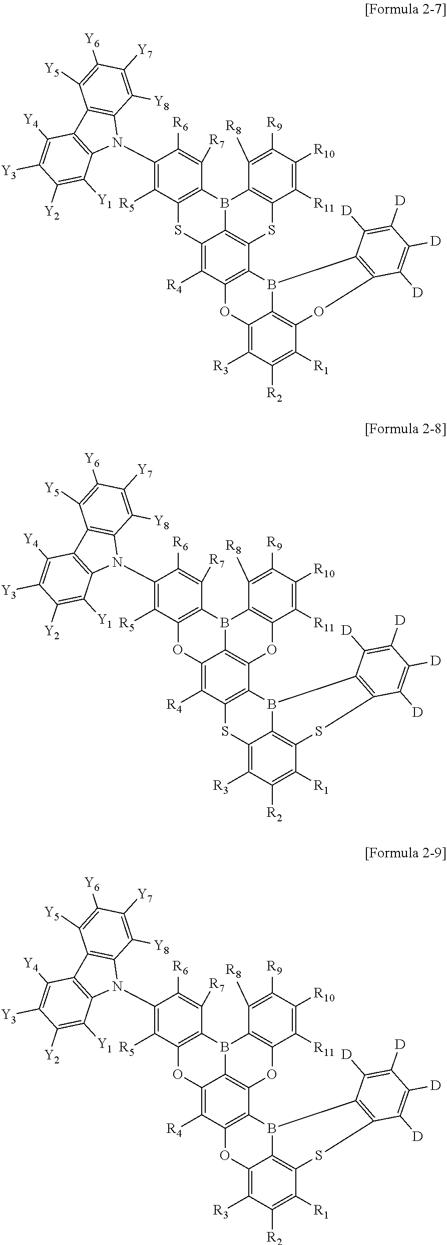

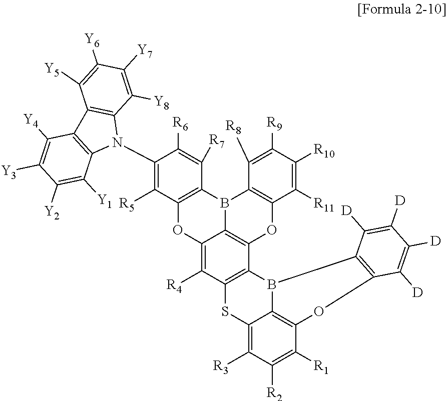

Formula 2-1 to Formula 2-10 represent compounds where the types of X₁ to X₄ in Formula 1 are specified. Formula 2-1, Formula 2-2, and Formula 2-3 represent compounds where X₁ to X₄ in Formula 1 are each independently O or NAr, and Formula 2-4 to Formula 2-10 represent compounds where X₁ to X₄ in Formula 1 are each independently O or S.

In Formula 2-1, Formula 2-2, and Formula 2-3, Arₐ, Ar_{b1}, Ar_{b2}, Ar_{c1}, Ar_{c2}, and Ar_{c3} may be each independently a substituted or unsubstituted aryl group of 6 to 30 ring-forming carbon atoms, or a substituted or unsubstituted heteroaryl group of 2 to 30 ring-forming carbon atoms. For example, Arₐ, Ar_{b1}, Ar_{b2}, Ar_{c1}, Ar_{c2}, and Ar_{c3} may be each independently a substituted or unsubstituted phenyl group, a substituted or unsubstituted divalent biphenyl group, or a substituted or unsubstituted terphenyl group.

In Formula 2-1 to Formula 2-10, the same groups defined in Formula 1 may be applied to R₁ to R₁₁, Y₁ to Y₈ and D.

In Formula 2-1 to Formula 2-10, an arbitrary hydrogen atom may be substituted with a deuterium atom. Formula 2-1 to Formula 2-10 may include a structure in which an arbitrary hydrogen atom is substituted with a deuterium atom.

The first compound represented by Formula 1 may be represented by Formula 3-1 or Formula 3-2 below.

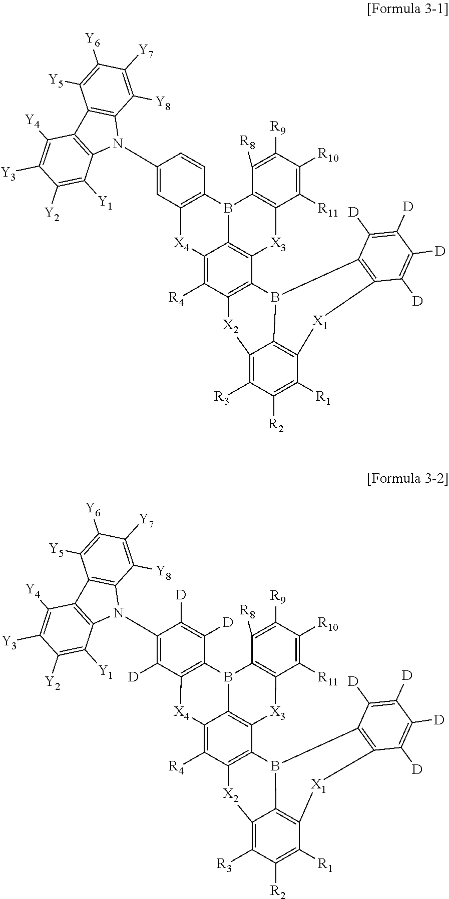

Formula 3-1 and Formula 3-2 represent cases where the types of R₅, R₆, and R₇ in Formula 1 are specified. Formula 3-1 represents a compound where R₅, R₆, and R₇ in Formula 1 are hydrogen atoms, and Formula 3-2 represents a compound where R₅, R₆, and R₇ in Formula 1 are deuterium atoms.

In Formula 3-1 and Formula 3-2, the same contents defined in Formula 1 may be applied to R₁ to R₄, R₈ to R₁₁, and Y₁ to Y₈.

The first compound represented by Formula 1 may be represented by any one among Formula 4-1 to Formula 4-8 below.

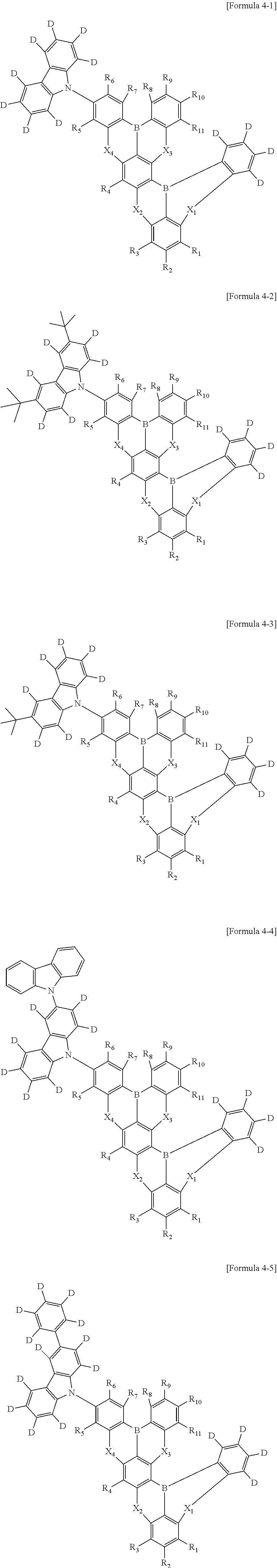

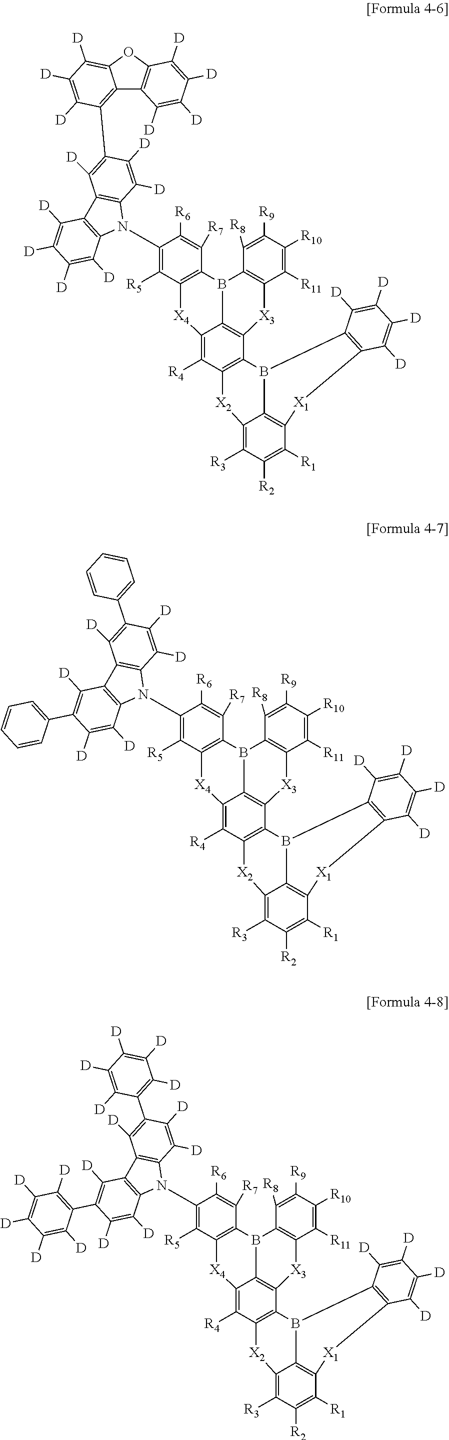

Formula 4-1 to Formula 4-8 represent cases where the types of Y₁ to Y₈ in Formula 1 are specified.

In Formula 4-1 to Formula 4-8, the same contents defined in Formula 1 may be applied to R₁ to R₁₁, and X₁ to X₄.

In Formula 4-1 to Formula 4-8, an arbitrary hydrogen atom may be substituted with a deuterium atom. Formula 4-1 to Formula 4-8 may include a structure in which an arbitrary hydrogen atom is substituted with a deuterium atom.

The first compound represented by Formula 1 may be represented by any one among Formula 5-1 to Formula 5-12 below.

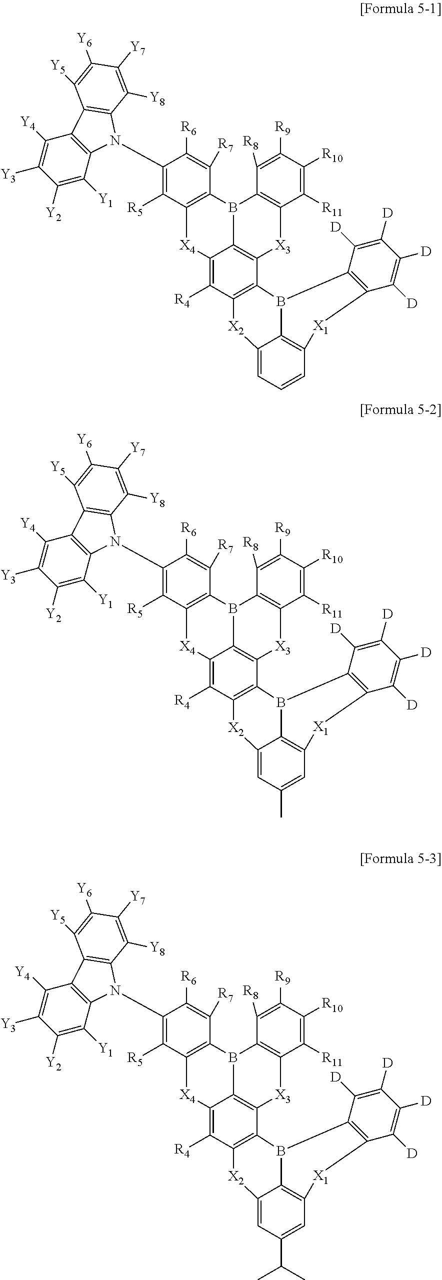

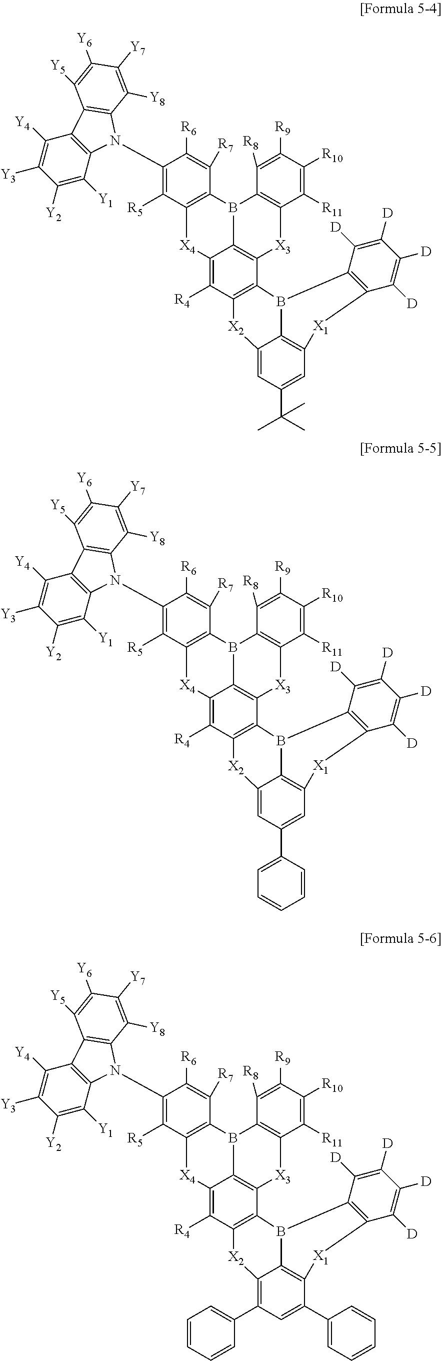

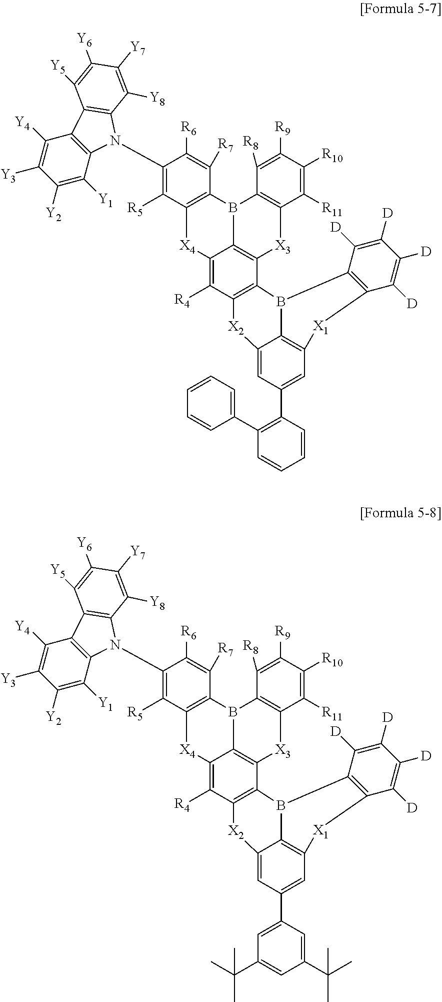

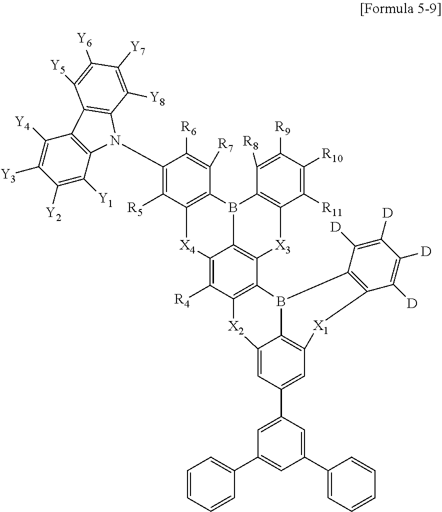

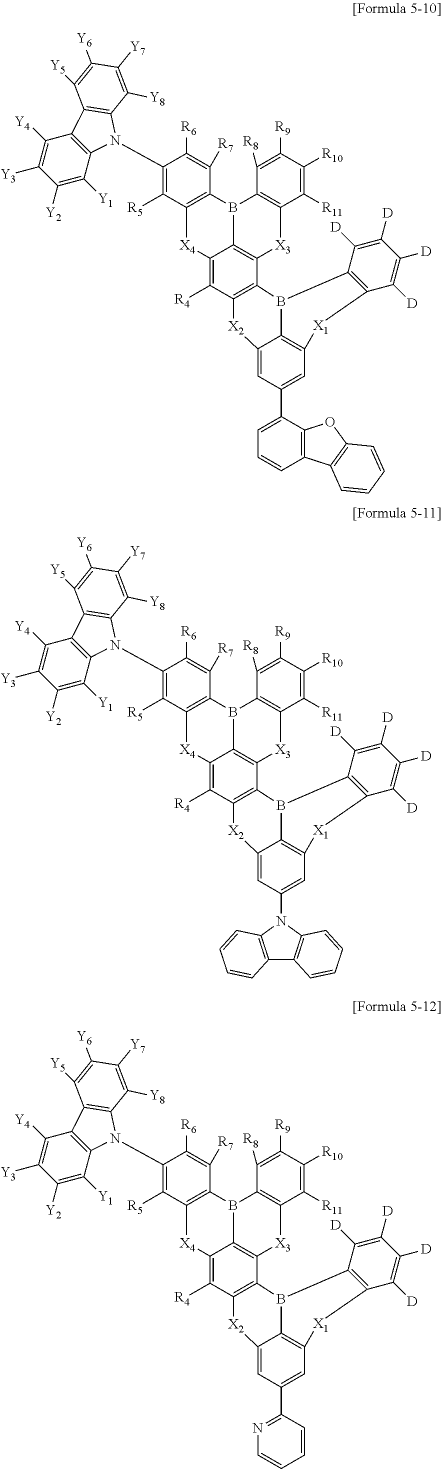

Formula 5-1 to Formula 5-12 represent compounds where the types of R₁ to R₃ in Formula 1 are specified.

In Formula 5-1 to Formula 5-12, the same groups defined in Formula 1 may be applied to R₄ to R₁₁, Y₁ to Y₈, and X₁ to X₄.

In Formula 5-1 to Formula 5-12, an arbitrary hydrogen atom may be substituted with a deuterium atom. Formula 5-1 to Formula 5-12 may include a structure in which an arbitrary hydrogen atom is substituted with a deuterium atom.

The fused polycyclic compound of an embodiment may be any one of the compounds represented in Compound Group 1 below. At least one functional layer included in the light emitting device ED of an embodiment may include at least one fused polycyclic compound among the compounds represented in Compound Group 1. The light emitting device ED of an embodiment may include at least one fused polycyclic compound among the compounds represented in Compound Group 1 in an emission layer EML.

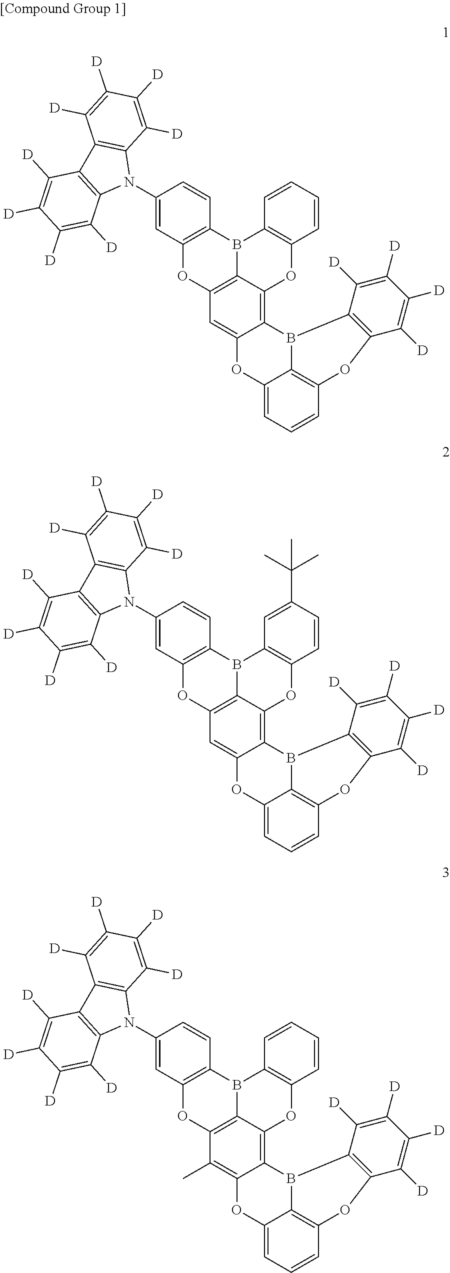 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1O2)O3]

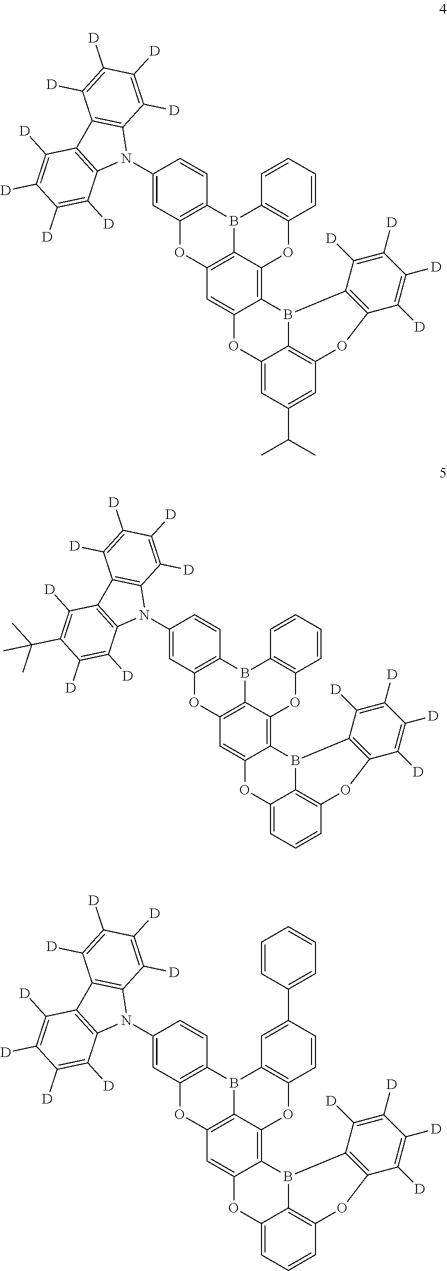 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3]

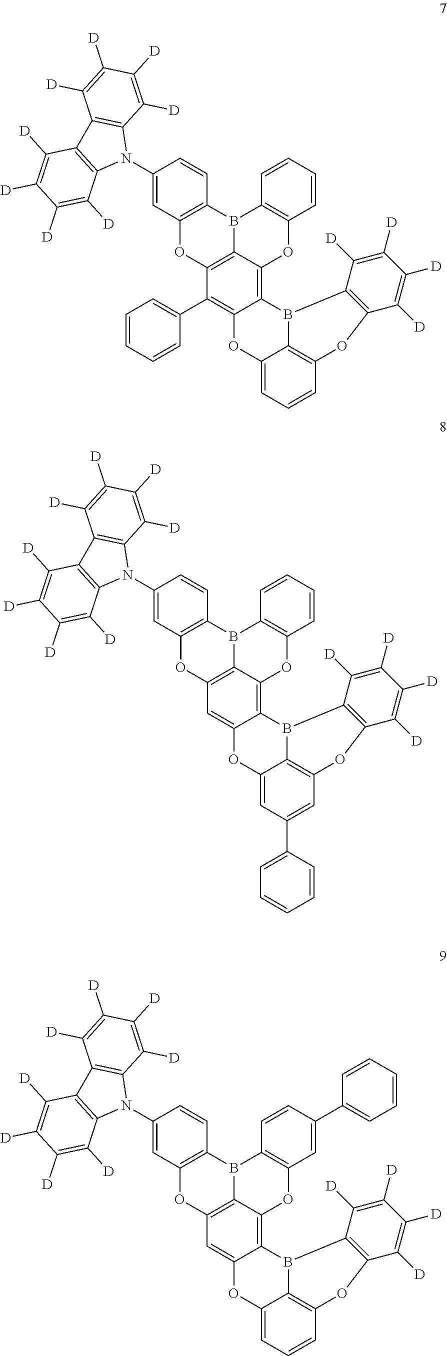 [SMILES: [2H]c1c([2H])c([2H])c2c(c1[2H])Oc1cccc3c1B2c1c2c4c(c(-c5ccccc5)c1O3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)O3]

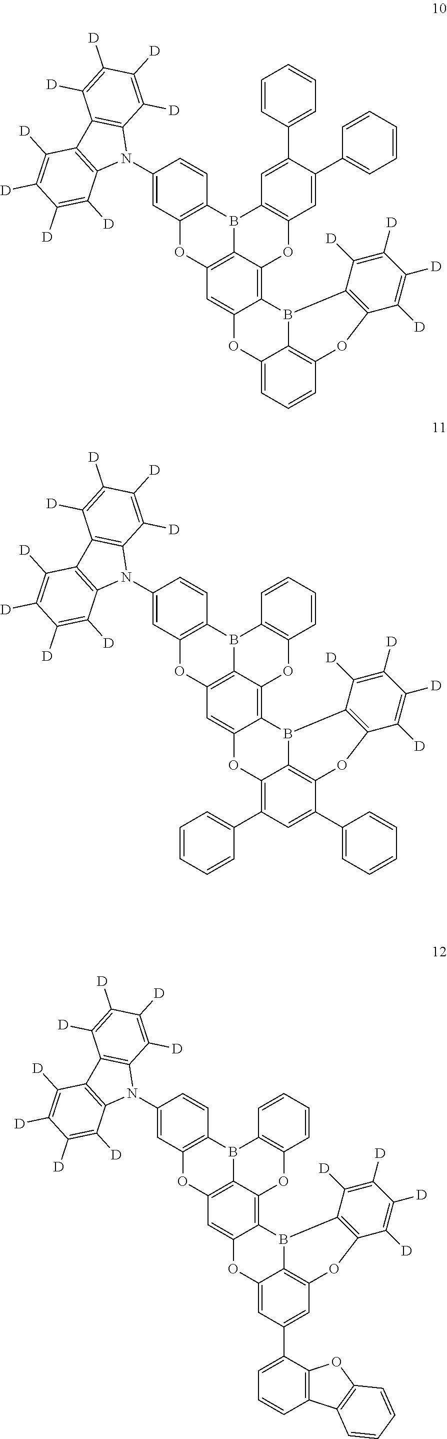

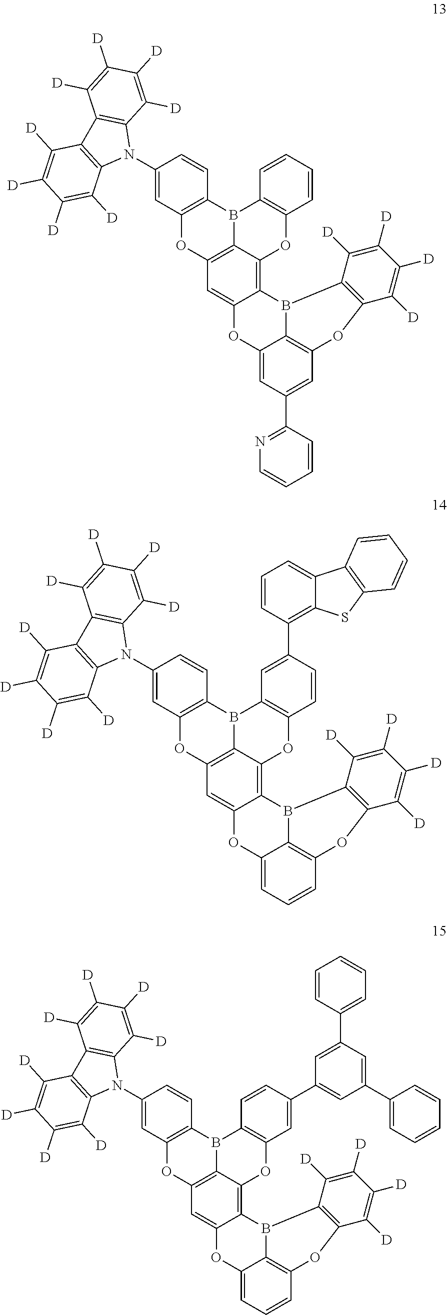

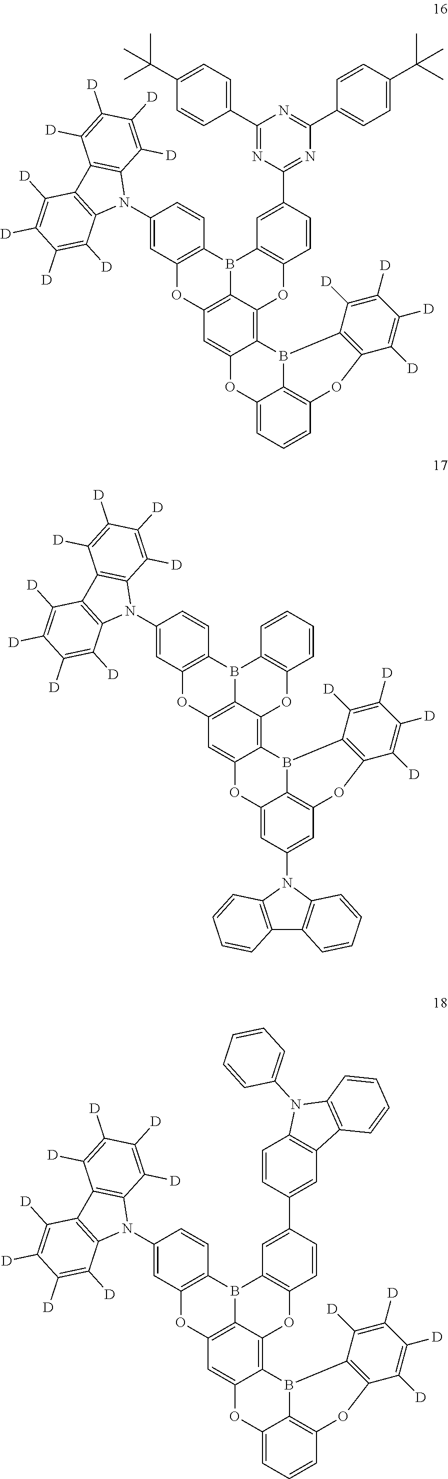

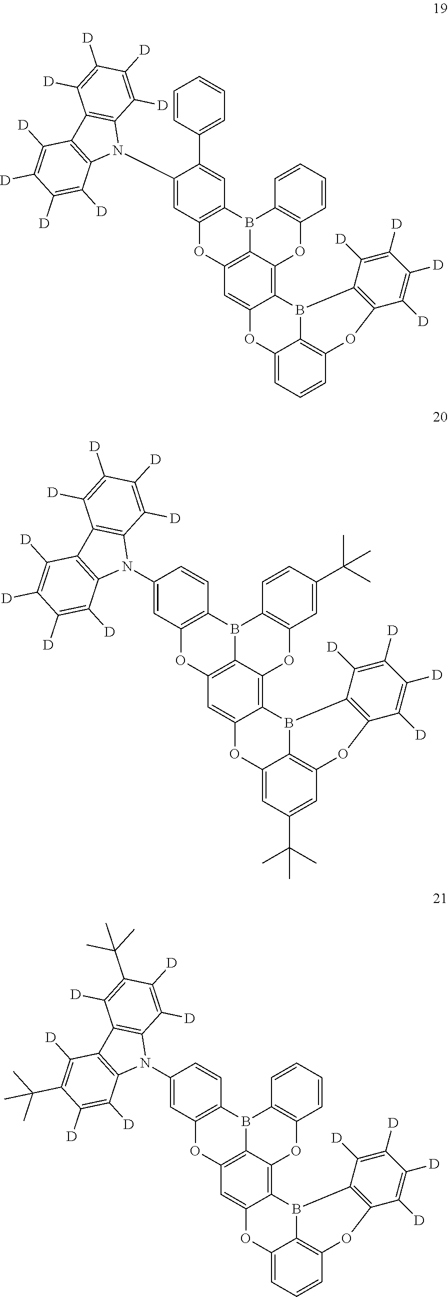 [SMILES: [2H]c1c([2H])c([2H])c2c(c1[2H])Oc1cccc3c1B2c1c(cc2c4c1Oc1ccccc1B4c1cc(-c4ccccc4)c(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(C(C)(C)C)cc3c1B2c1c(cc2c4c1Oc1cc(C(C)(C)C)ccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c(C(C)(C)C)c([2H])c5c5c([2H])c(C(C)(C)C)c([2H])c([2H])c54)cc1O2)O3]

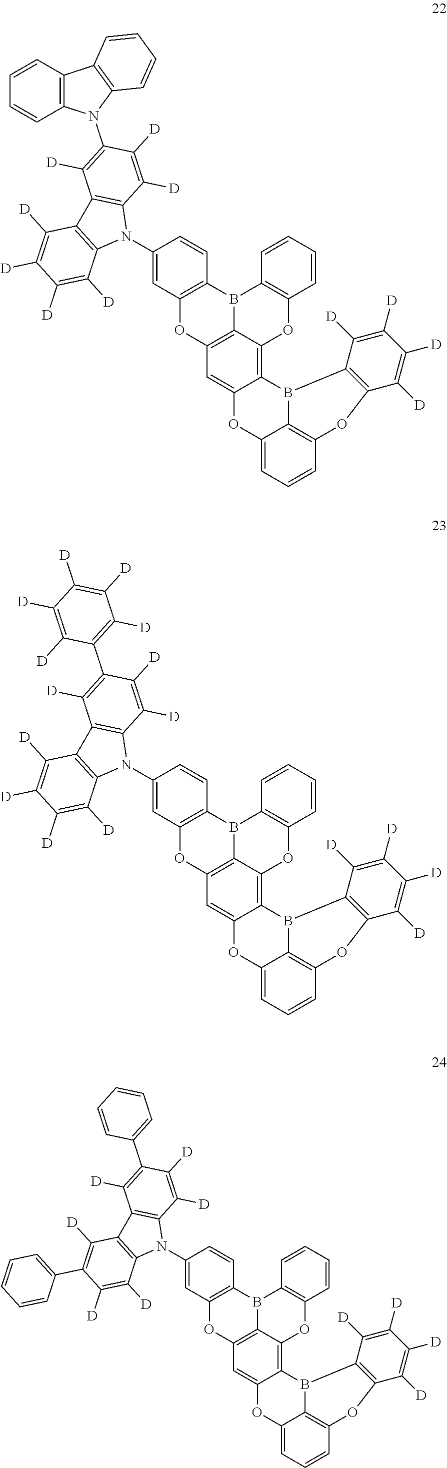

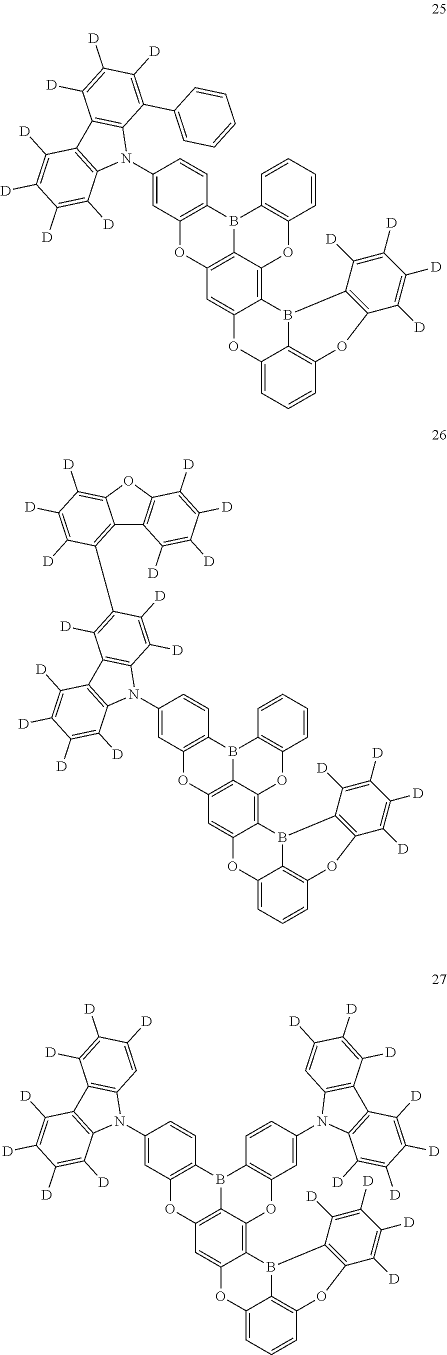

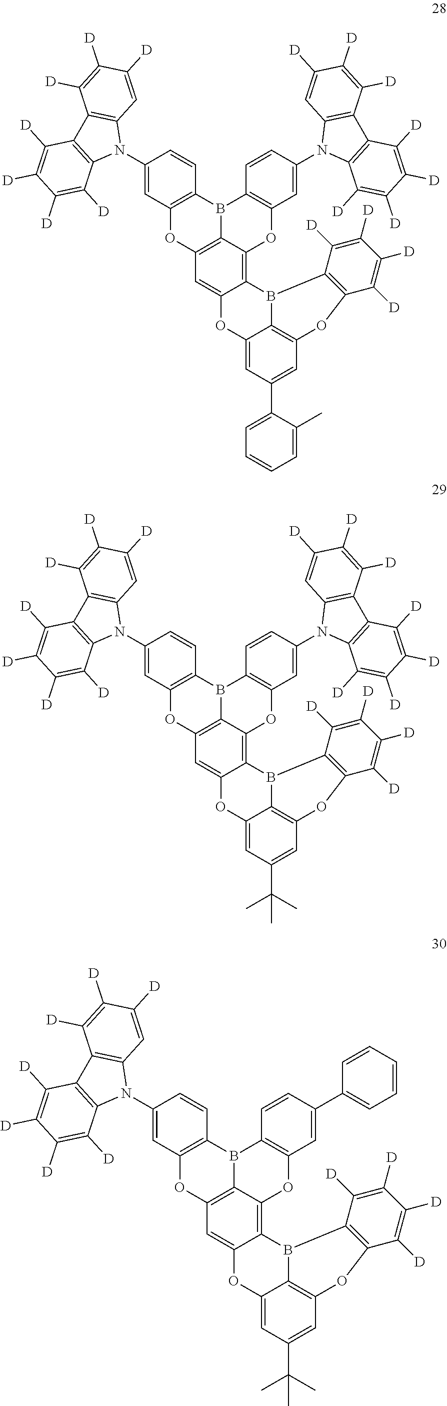

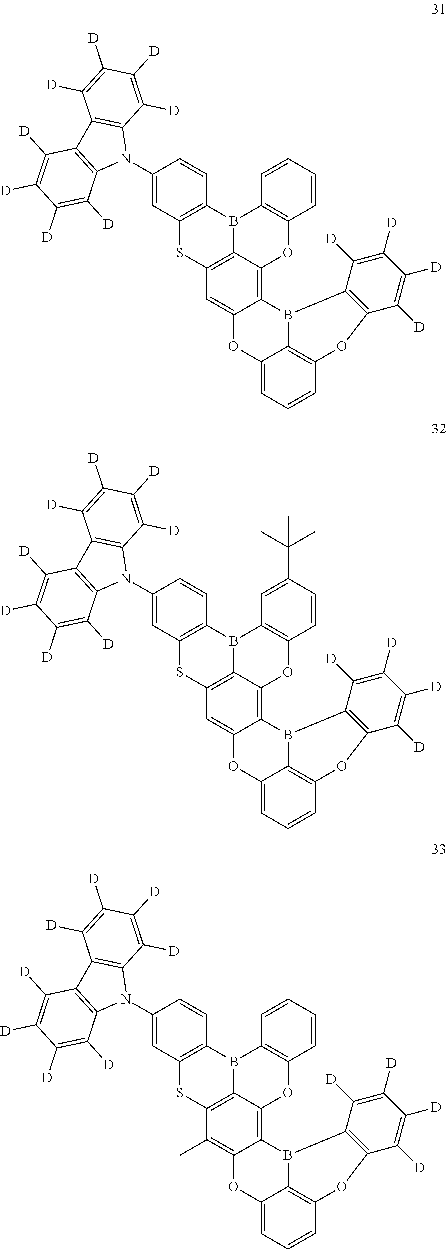 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1S2)O3]

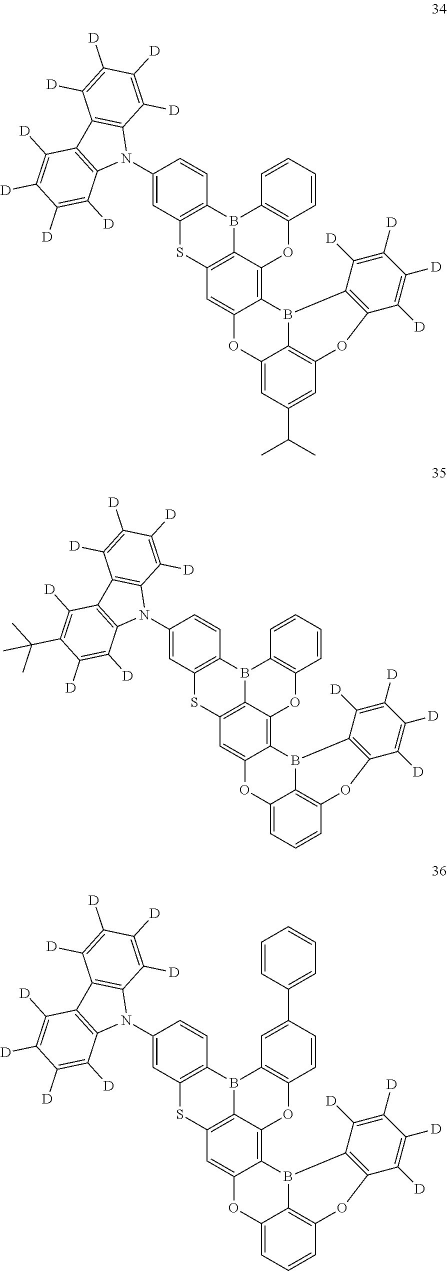 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1S2)O3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1S2)O3]

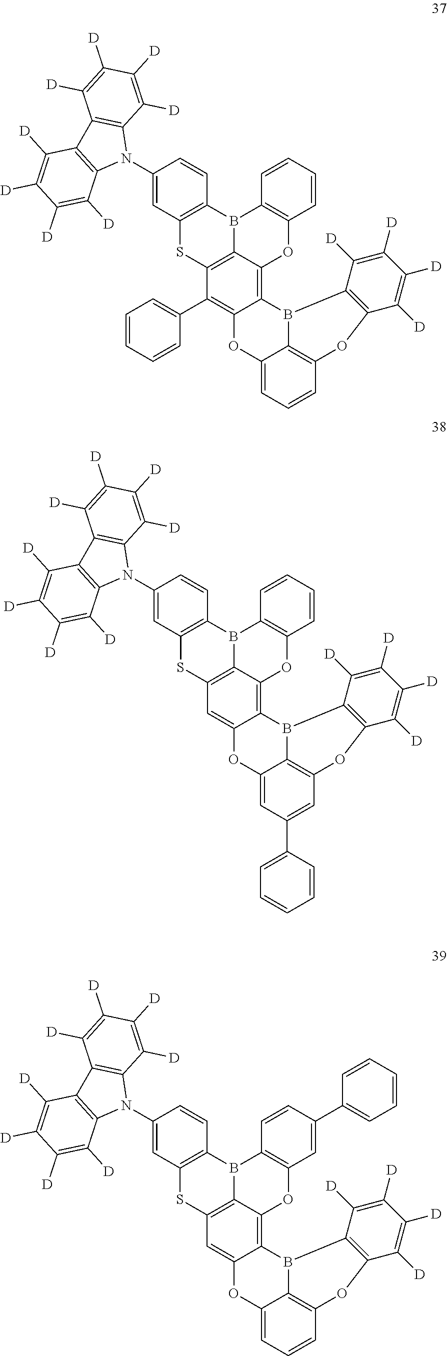 [SMILES: [2H]c1c([2H])c([2H])c2c(c1[2H])Oc1cccc3c1B2c1c2c4c(c(-c5ccccc5)c1O3)Sc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1S2)O3]

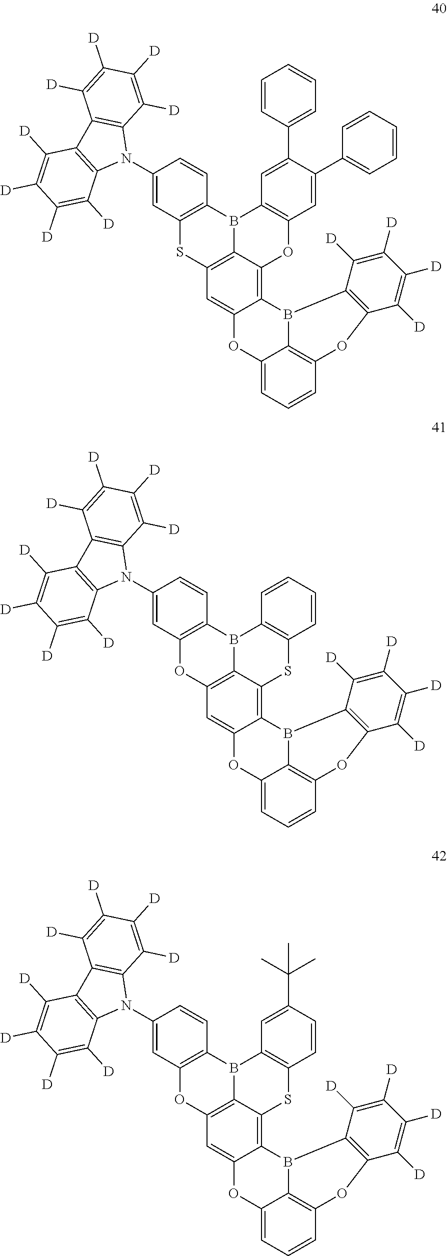 [SMILES: [2H]c1c([2H])c([2H])c2c(c1[2H])Oc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccc(C(C)(C)C)cc1B4c1ccc(-n4c5c([2H])c([2H])c([2H])c([2H])c5c5c([2H])c([2H])c([2H])c([2H])c54)cc1O2)O3]

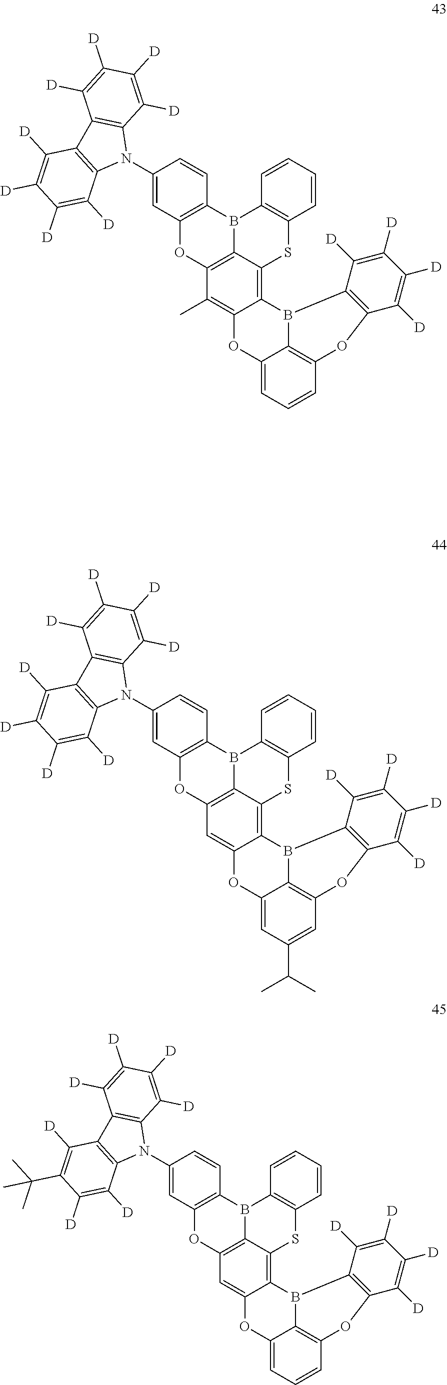 [SMILES: [2H]c1c([2H])c([2H])c2c(c1[2H])Oc1cccc3c1B2c1c(c(C)c2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(C(C)C)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c(C(C)(C)C)c([2H])c([2H])c54)cc1O2)O3]

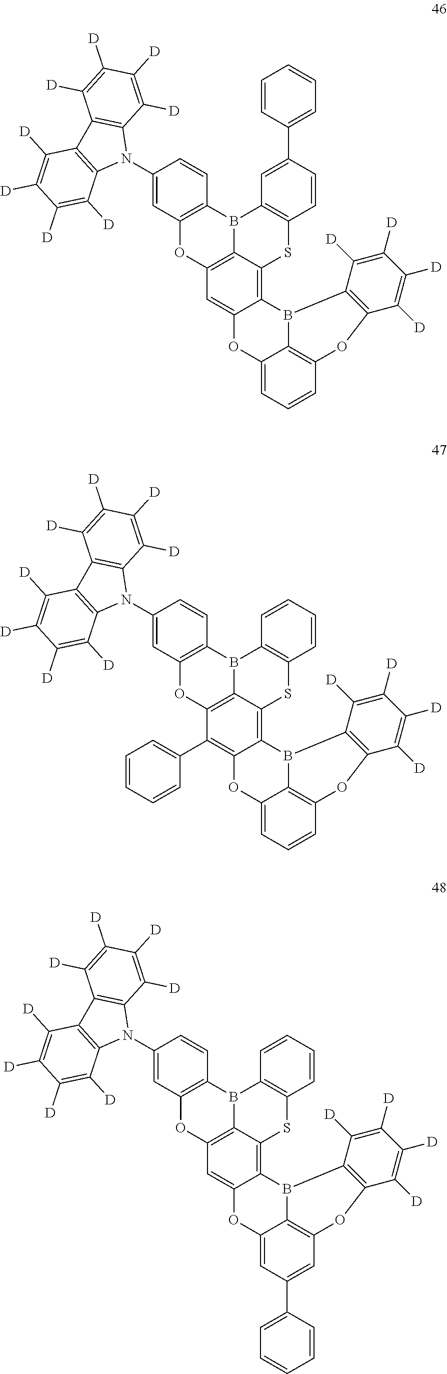 [SMILES: [2H]c1c([2H])c([2H])c2c(c1[2H])Oc1cccc3c1B2c1c(cc2c4c1Sc1ccc(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(c(-c2ccccc2)c2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(-c3ccccc3)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3]

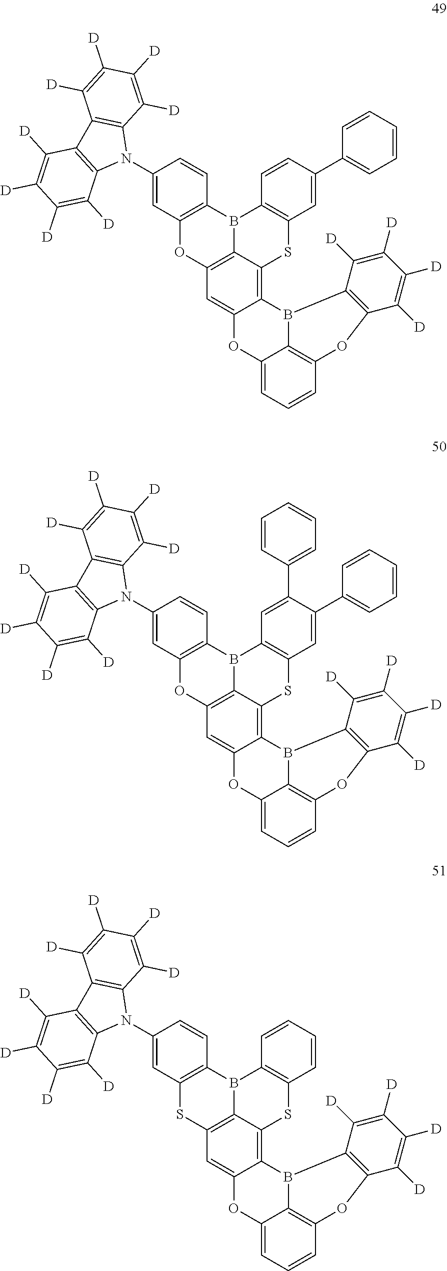 [SMILES: [2H]c1c([2H])c([2H])c2c(c1[2H])Oc1cccc3c1B2c1c(cc2c4c1Sc1cc(-c5ccccc5)ccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3]

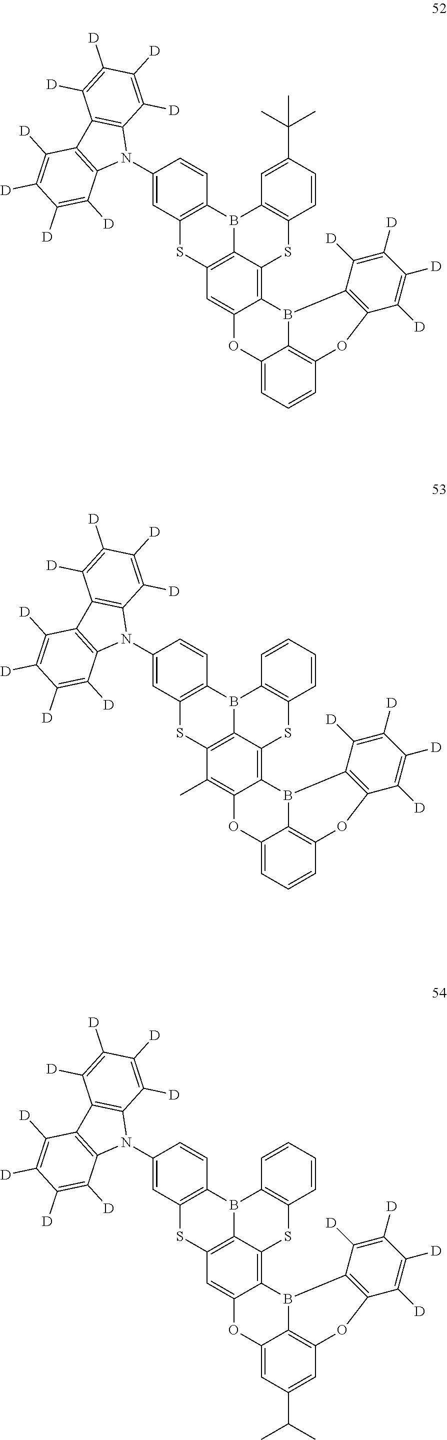 [SMILES: [2H]c1c([2H])c([2H])c2c(c1[2H])Oc1cccc3c1B2c1c(cc2c4c1Sc1ccc(C(C)(C)C)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(C)c2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cc(C(C)C)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3]

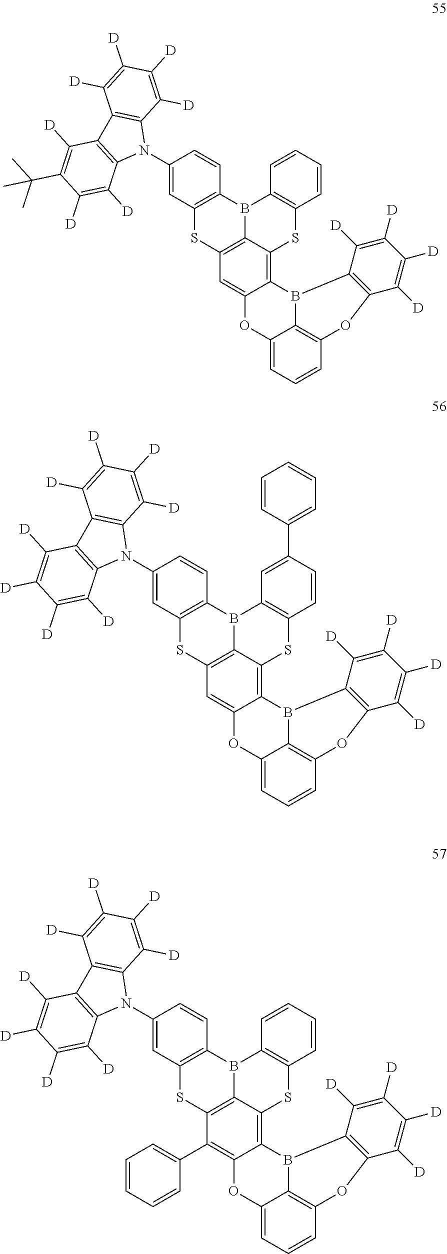 [SMILES: [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c(C(C)(C)C)c([2H])c([2H])c54)cc1S2)O3 ; [2H]c1c([2H])c([2H])c2c(c1[2H])Oc1cccc3c1B2c1c(cc2c4c1Sc1ccc(-c5ccccc5)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(-c2ccccc2)c2c4c1Sc1ccccc1B4c1ccc(-n4c5c([2H])c([2H])c([2H])c([2H])c5c5c([2H])c([2H])c([2H])c([2H])c54)cc1S2)O3]

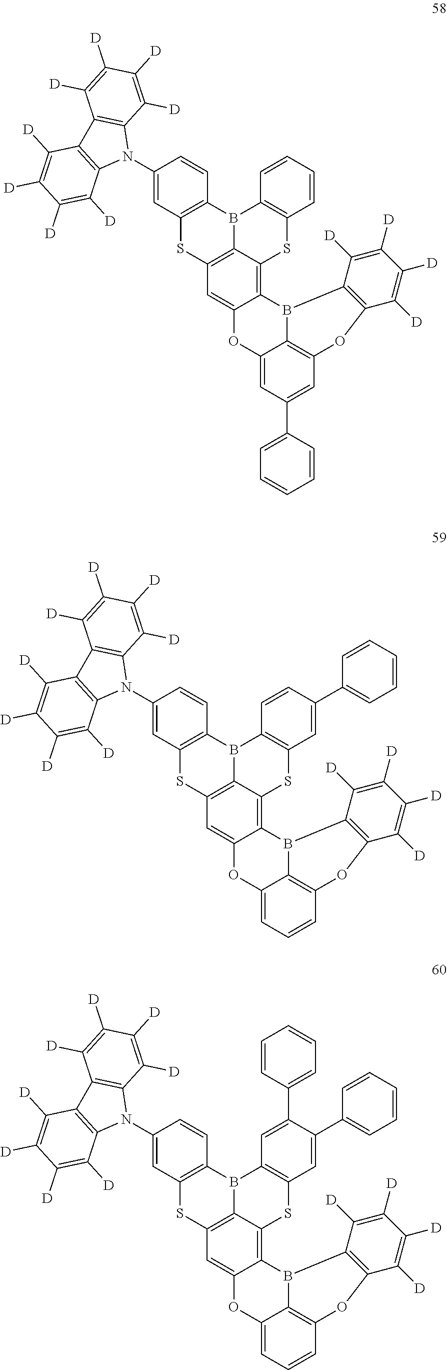 [SMILES: [2H]c1c([2H])c([2H])c2c(c1[2H])Oc1cc(-c3ccccc3)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1cc(-c5ccccc5)ccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1S2)O3]

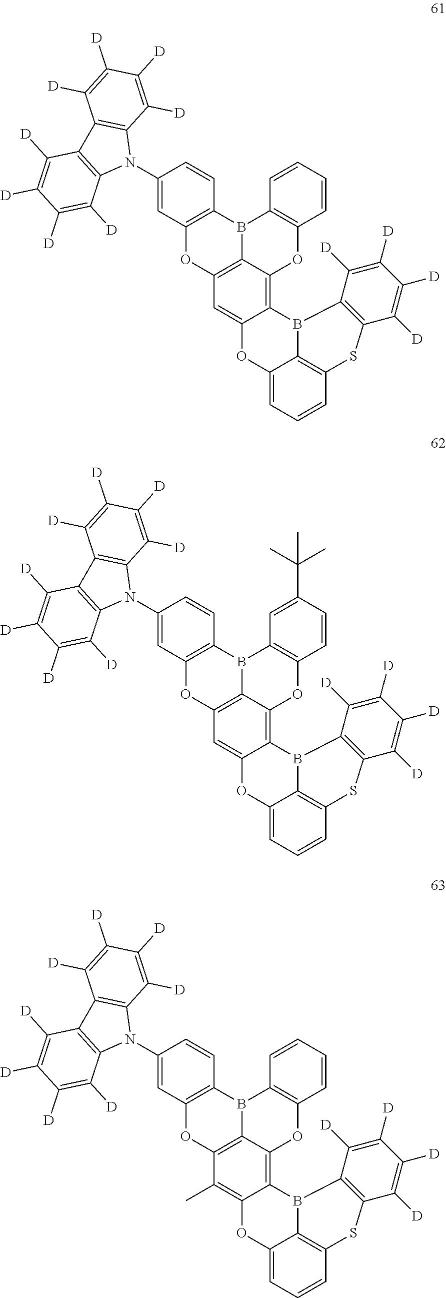 [SMILES: [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1O2)O3]

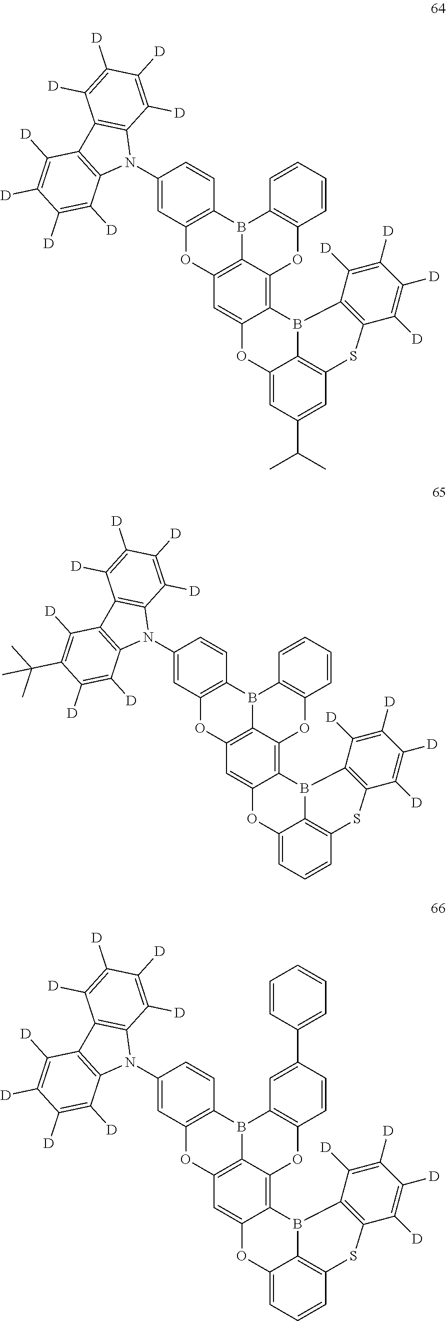 [SMILES: [2H]c1c([2H])c([2H])c2c(c1[2H])Sc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3]

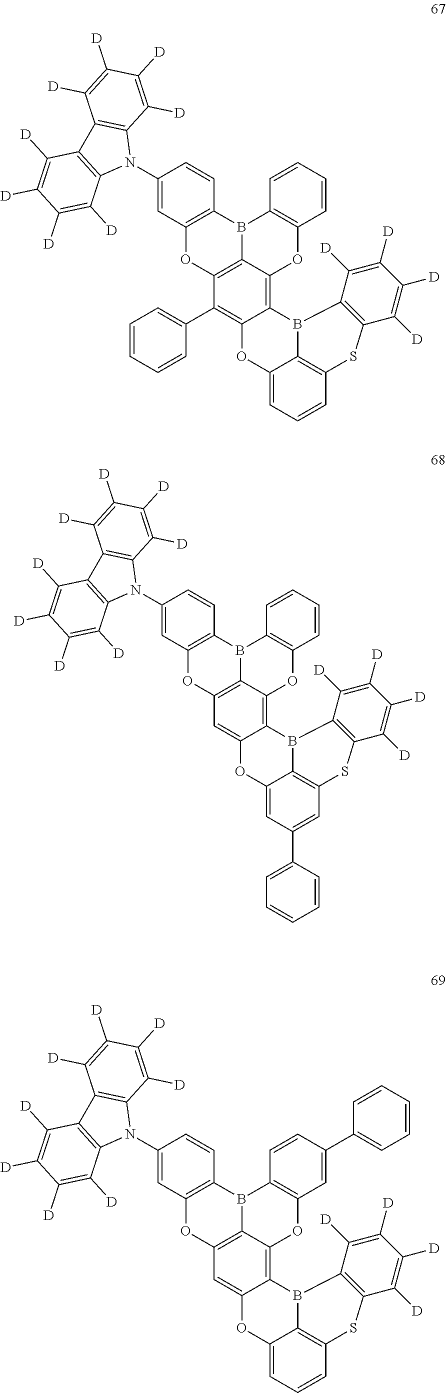 [SMILES: [2H]c1c([2H])c([2H])c2c(c1[2H])Sc1cccc3c1B2c1c2c4c(c(-c5ccccc5)c1O3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Sc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)O3]

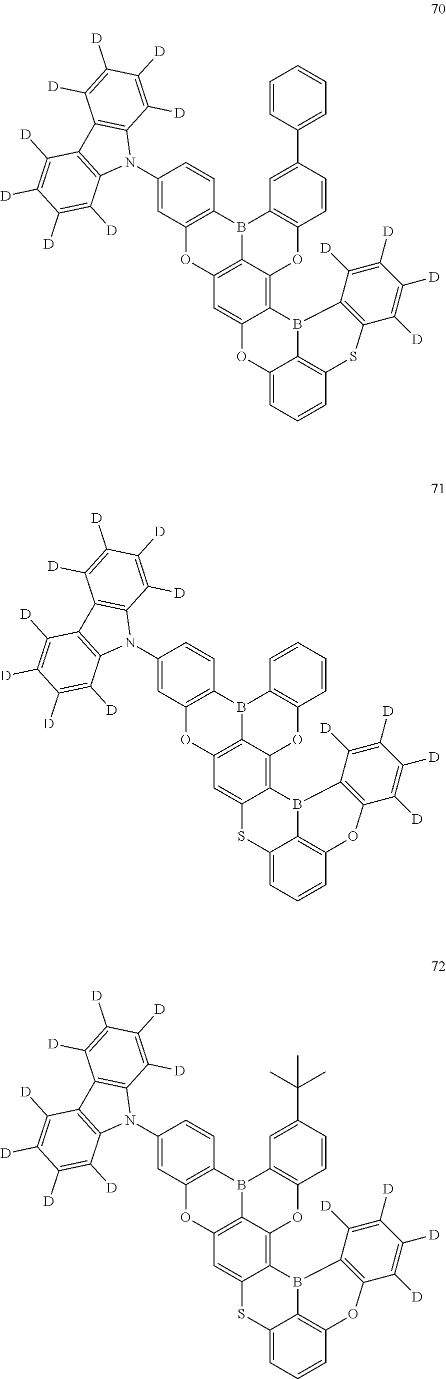 [SMILES: [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)S3]

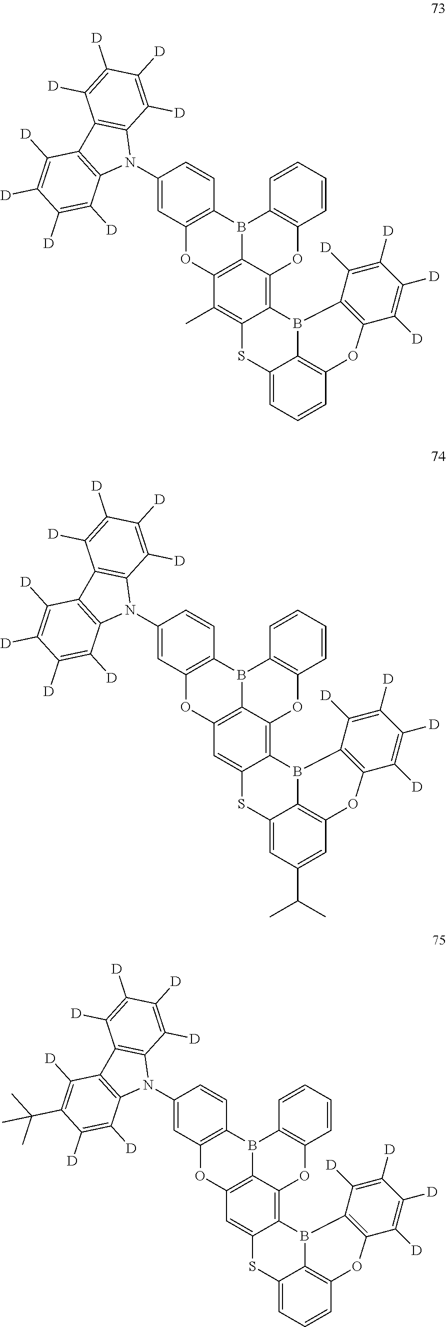 [SMILES: [2H]c1c([2H])c([2H])c2c(c1[2H])Oc1cccc3c1B2c1c2c4c(c(C)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)S3]

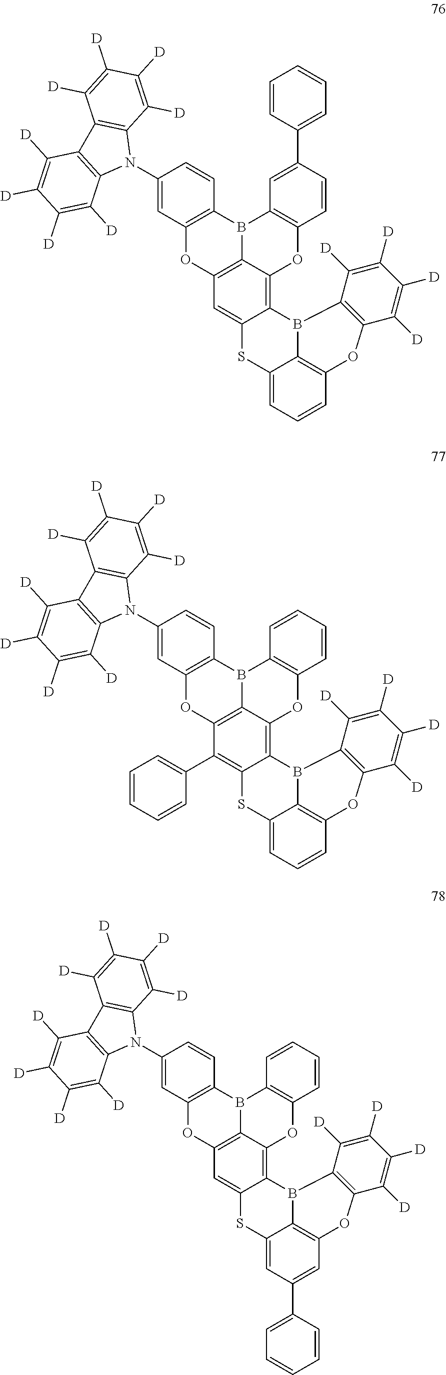 [SMILES: [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c2c4c(c(-c5ccccc5)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3]

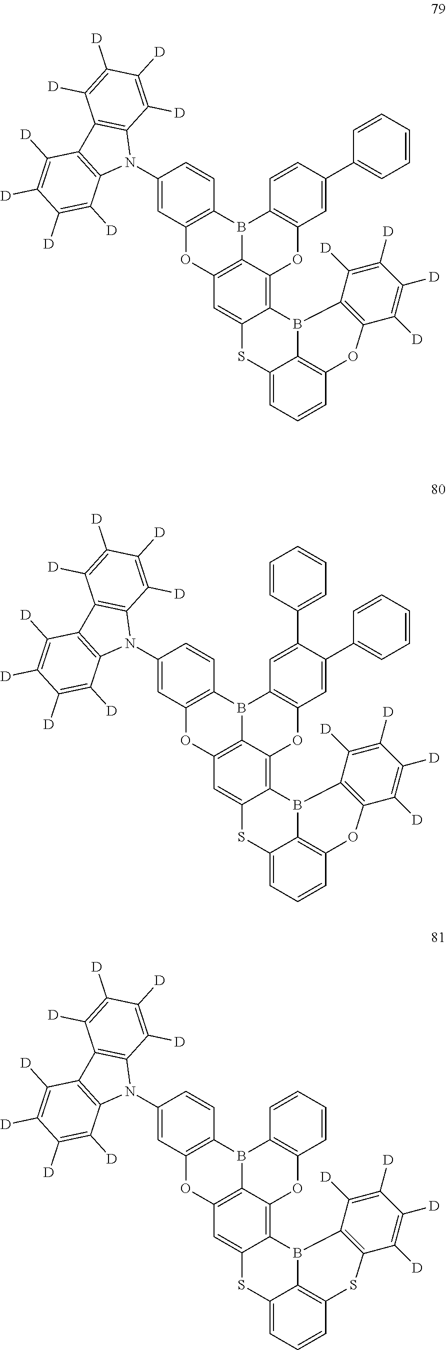 [SMILES: [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3]

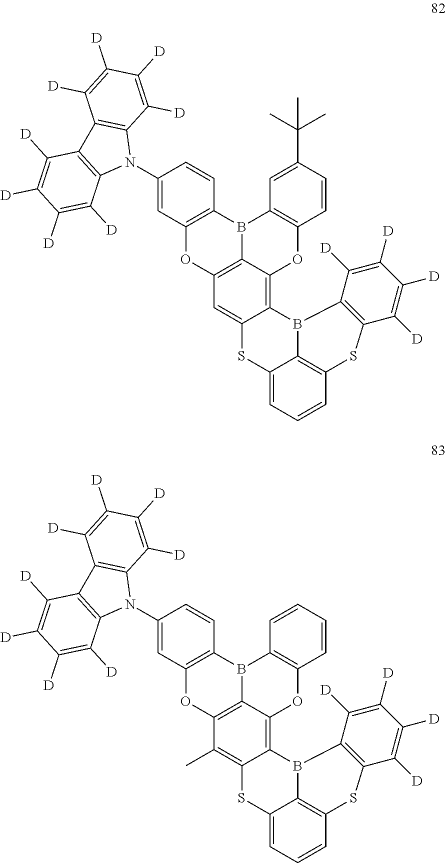 [SMILES: [2H]c1c([2H])c([2H])c2c(c1[2H])Sc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c2c4c(c(C)c1S3)Oc1cc(-n3c5c([2H])c([2H])c([2H])c([2H])c5c5c([2H])c([2H])c([2H])c([2H])c53)ccc1B4c1ccccc1O2]

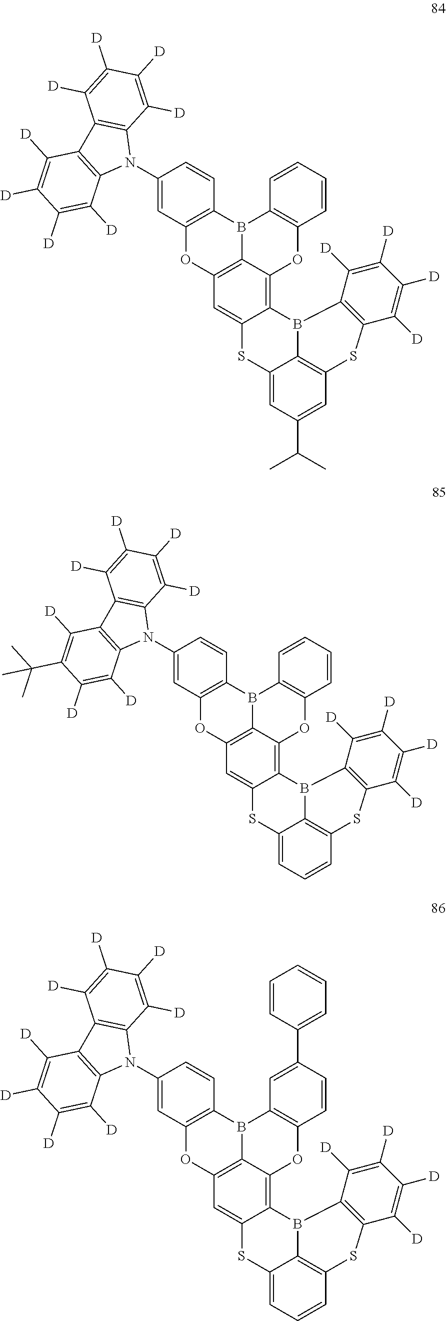 [SMILES: [2H]c1c([2H])c([2H])c2c(c1[2H])Sc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)S3 ; [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)S3]

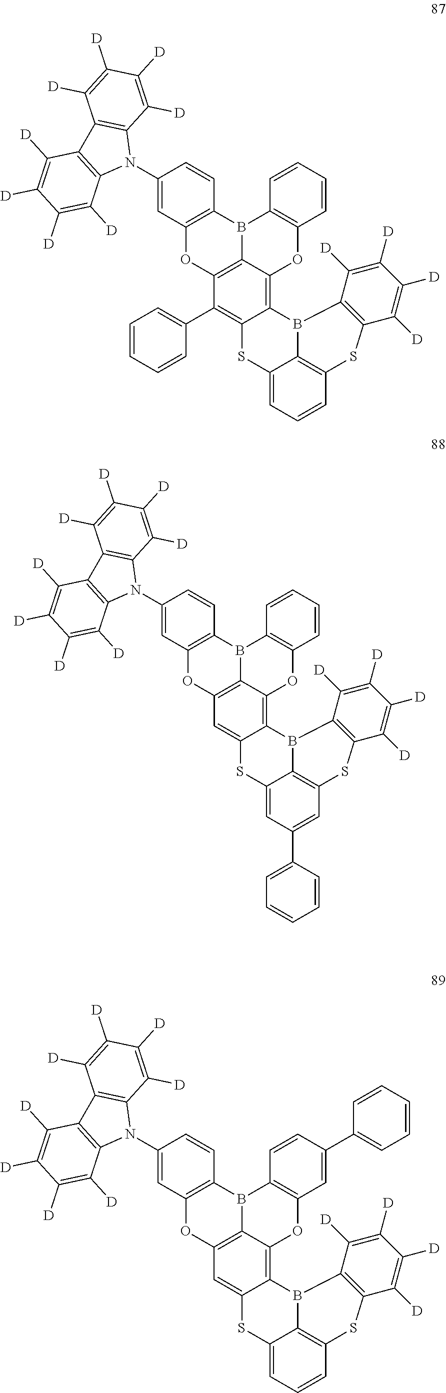 [SMILES: [2H]c1c([2H])c([2H])c2c(c1[2H])Sc1cccc3c1B2c1c2c4c(c(-c5ccccc5)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Sc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)S3]

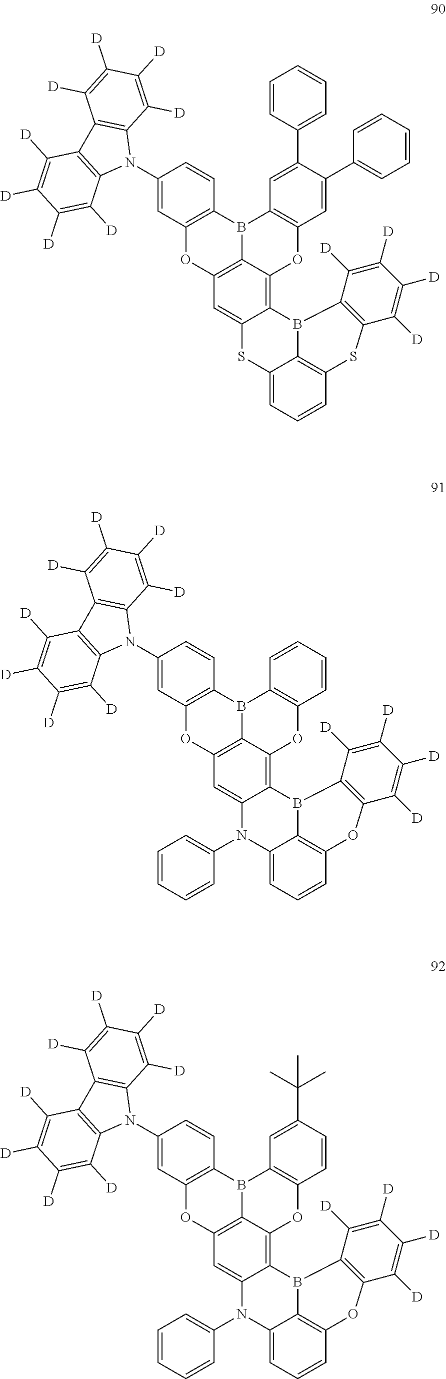 [SMILES: [2H]c1c([2H])c([2H])c2c(c1[2H])Sc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)N3c1ccccc1]

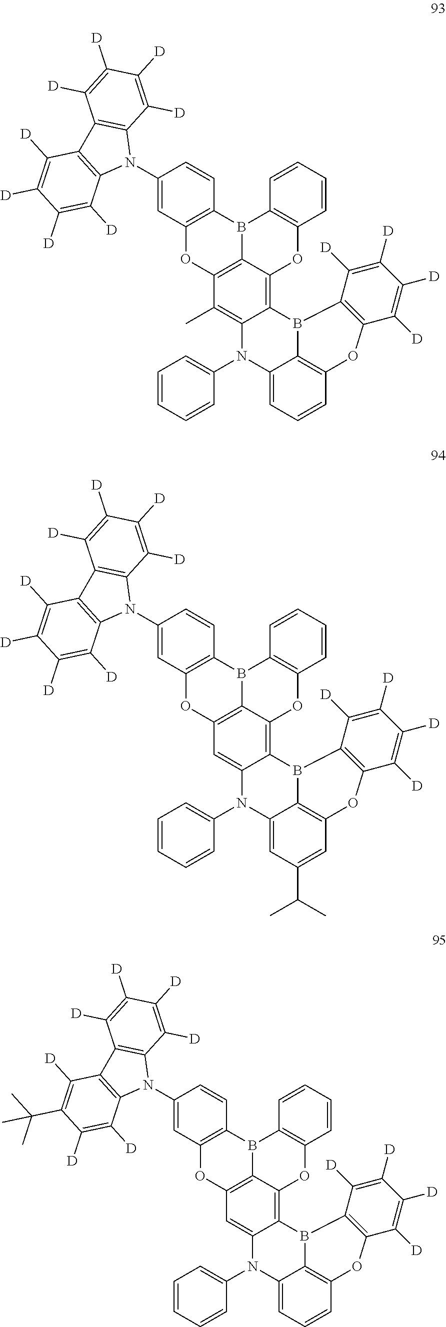 [SMILES: [2H]c1c([2H])c([2H])c2c(c1[2H])Oc1cccc3c1B2c1c2c4c(c(C)c1N3c1ccccc1)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)N3c1ccccc1]

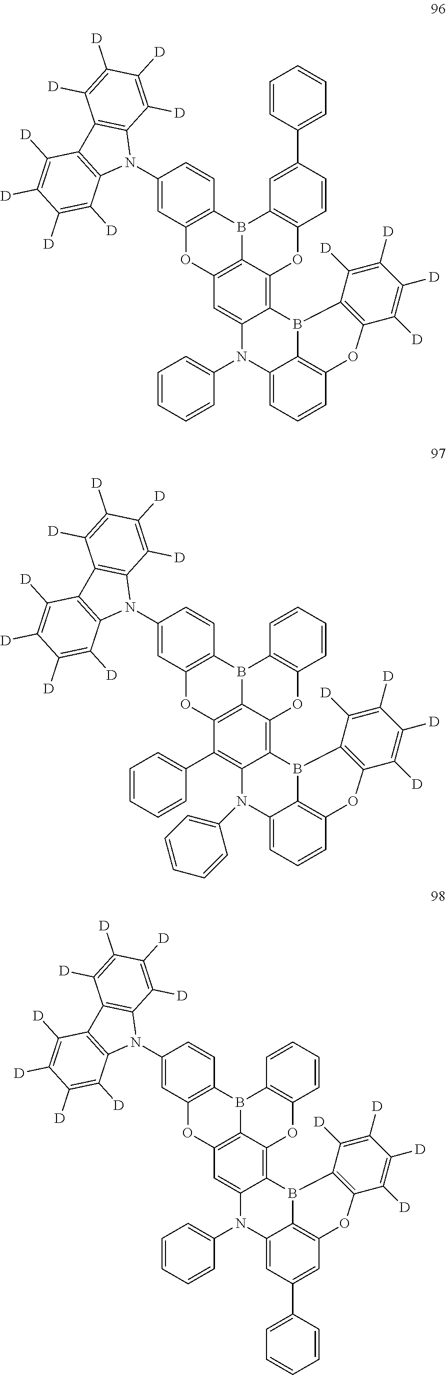

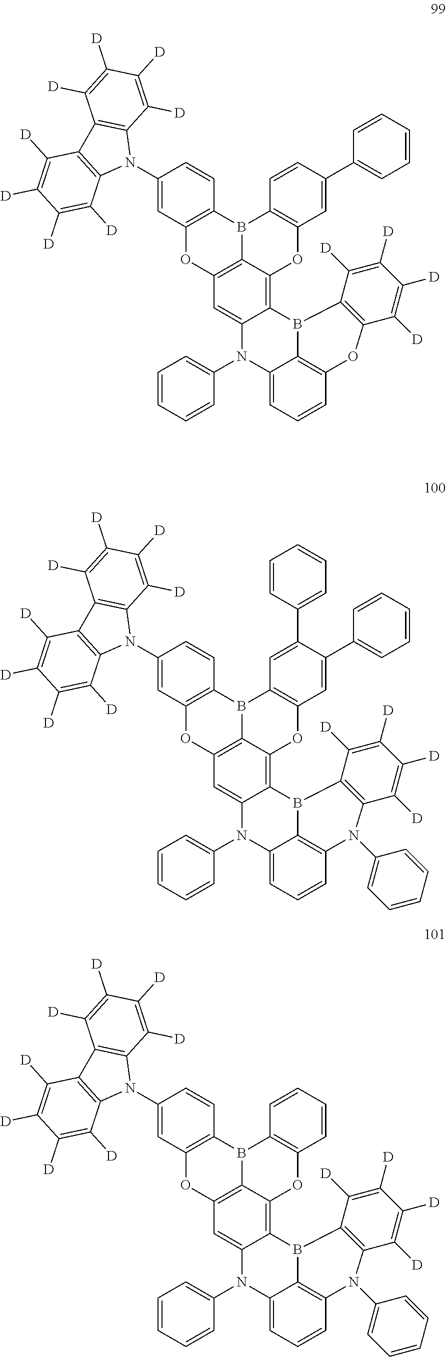

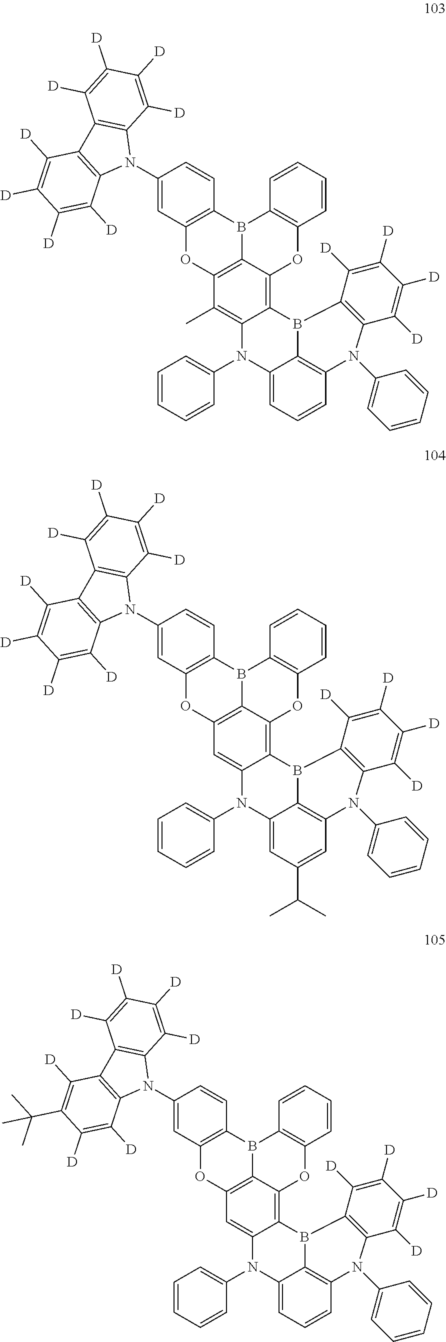

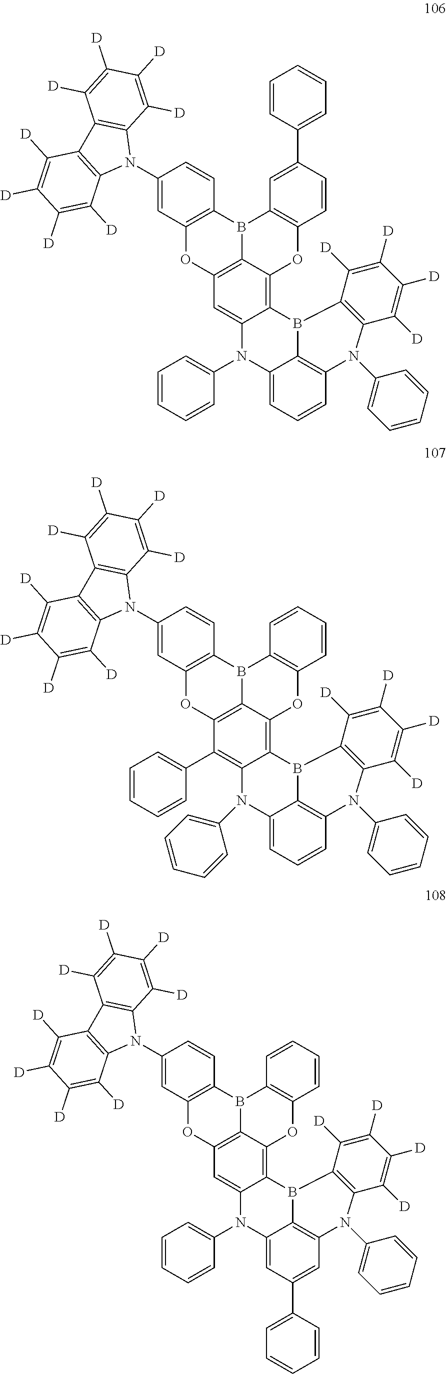

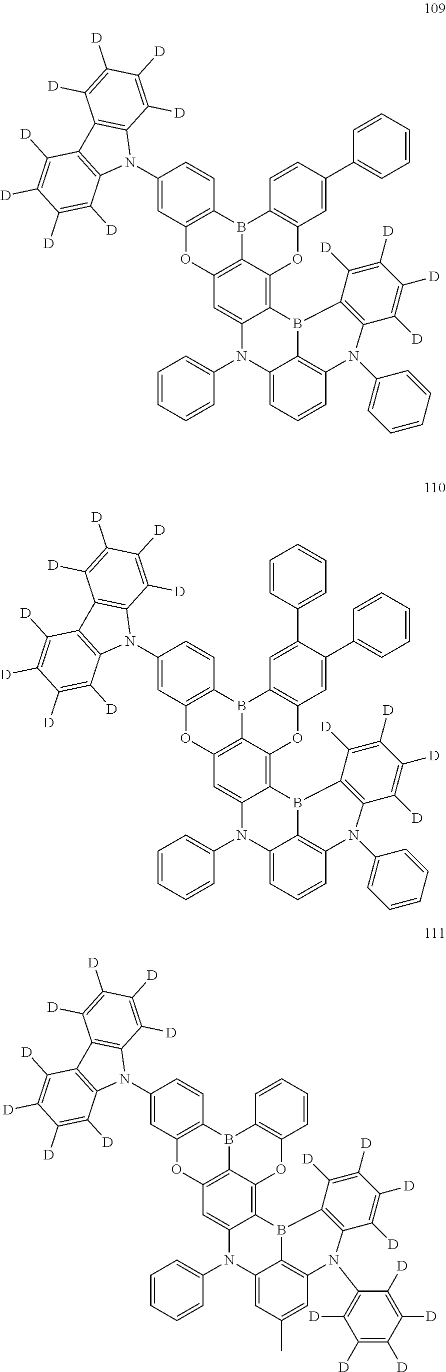

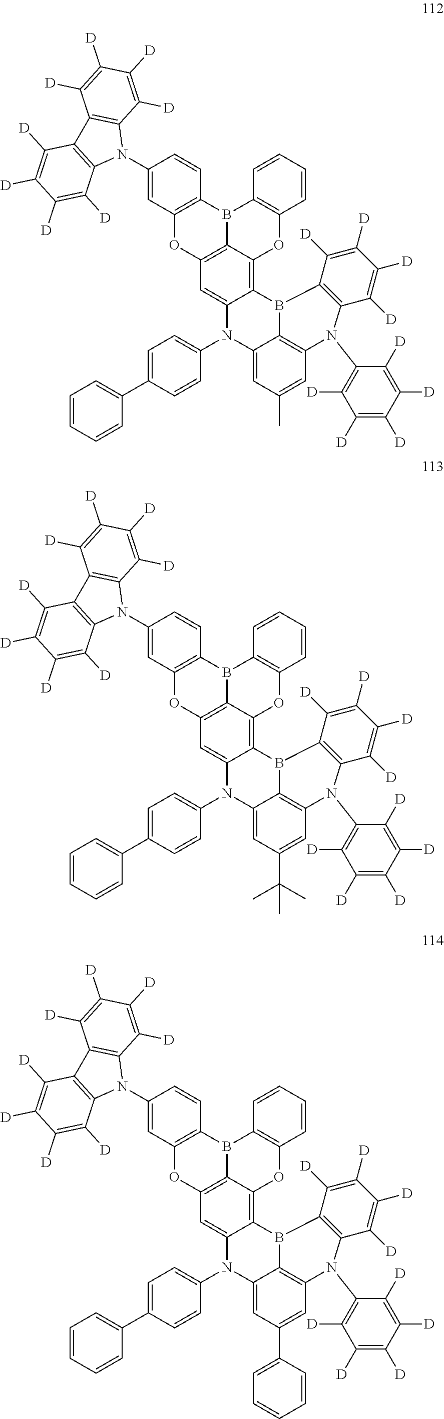

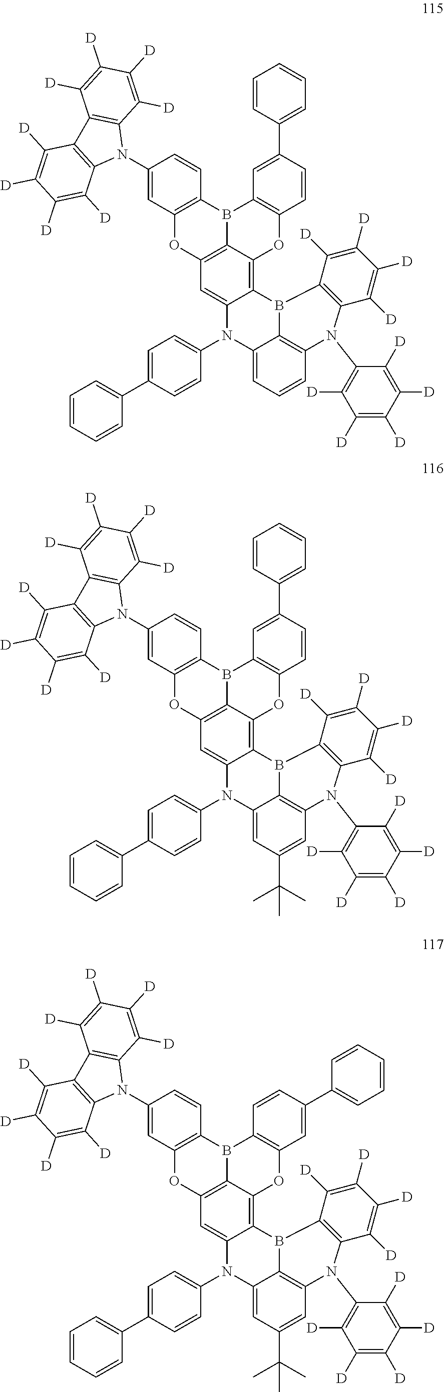

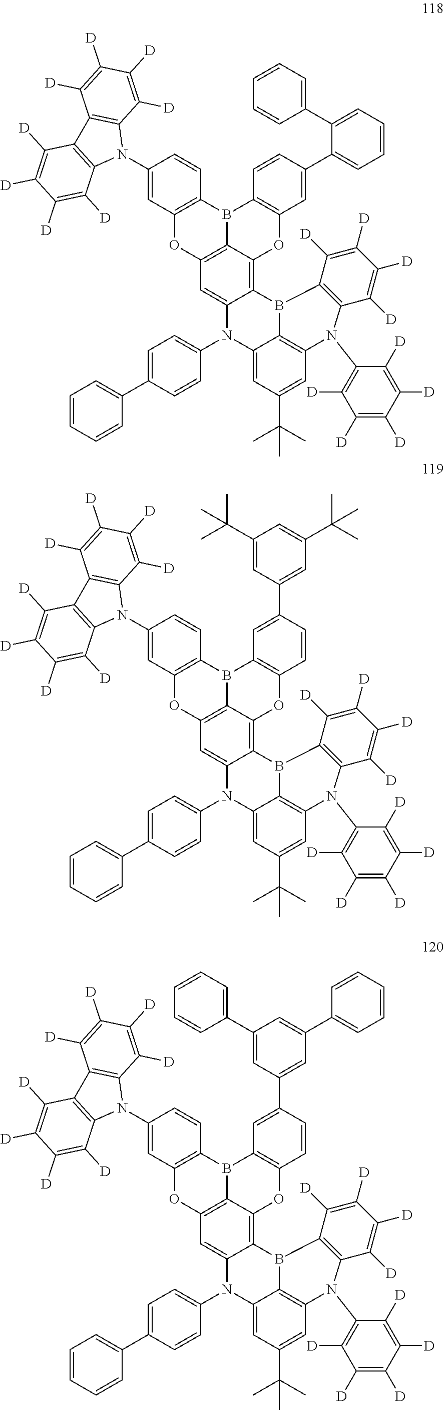

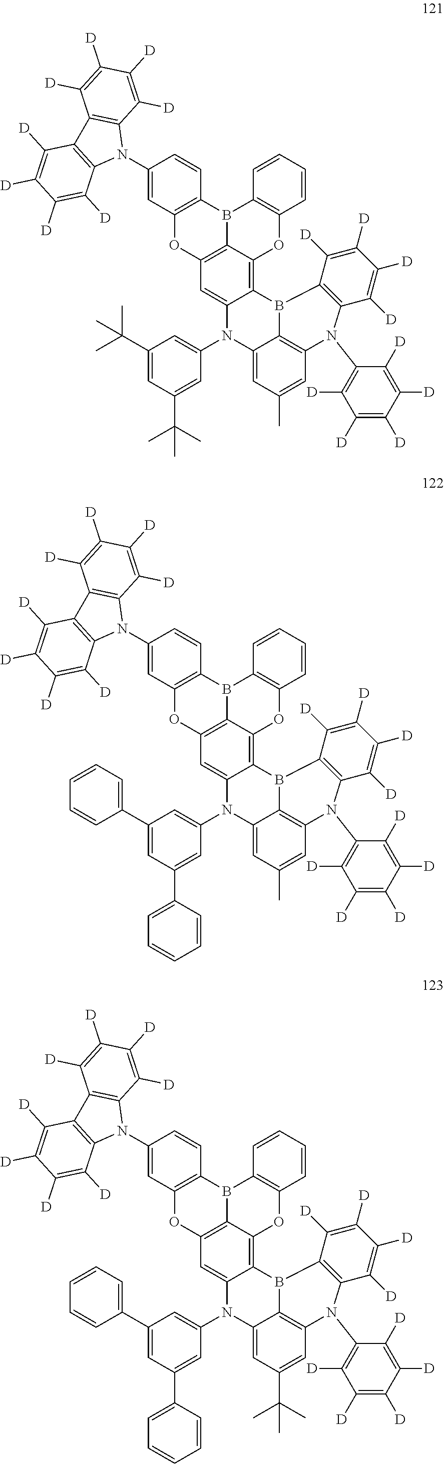

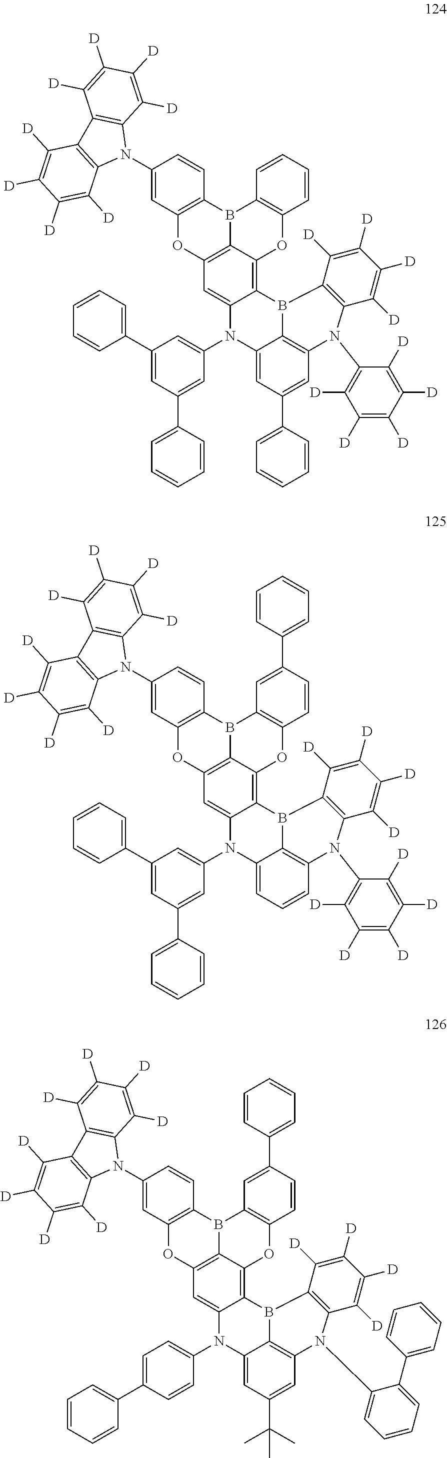

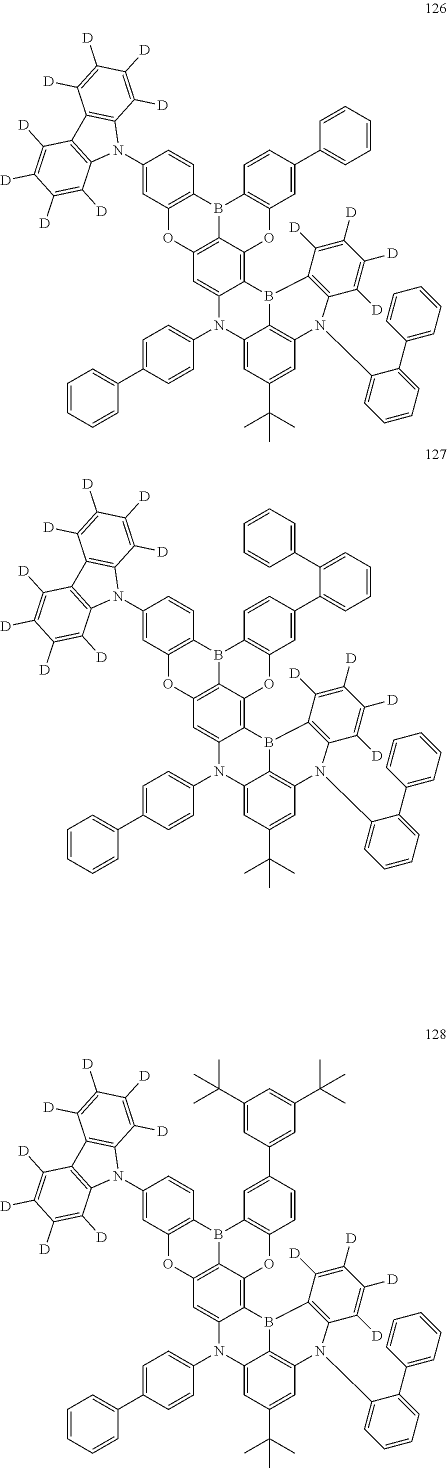

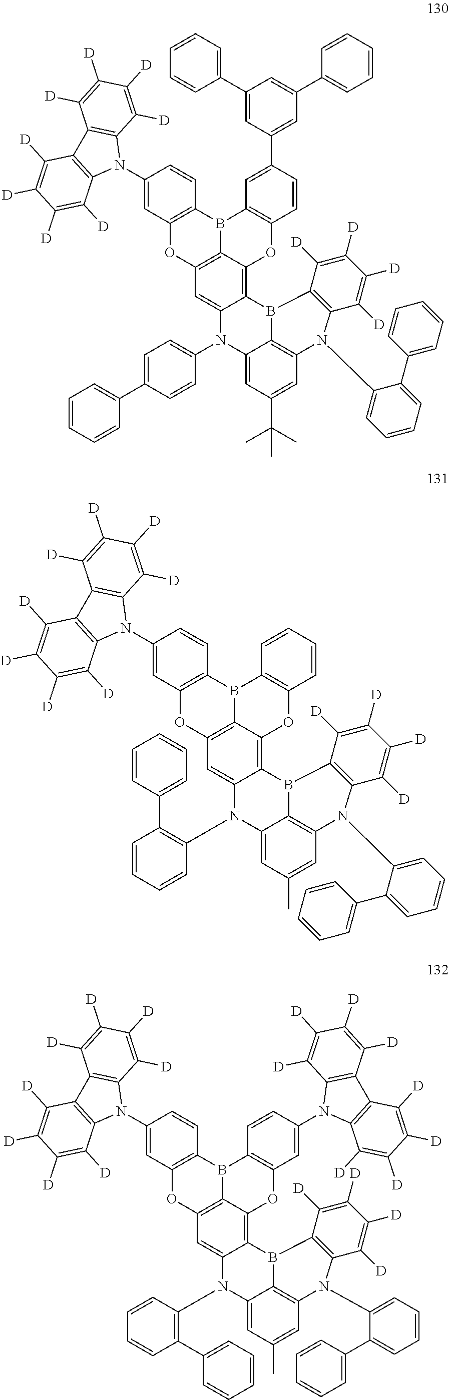

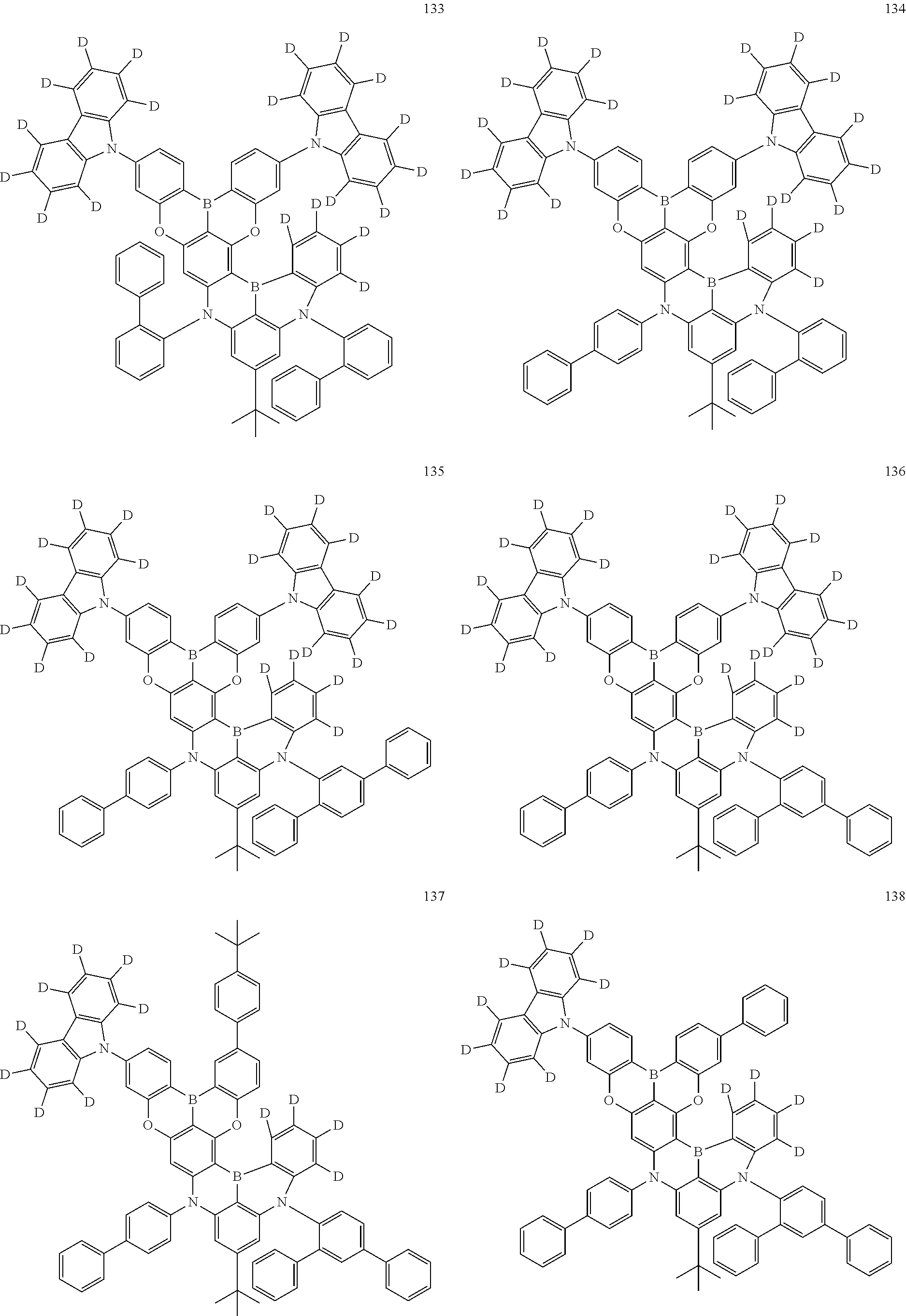

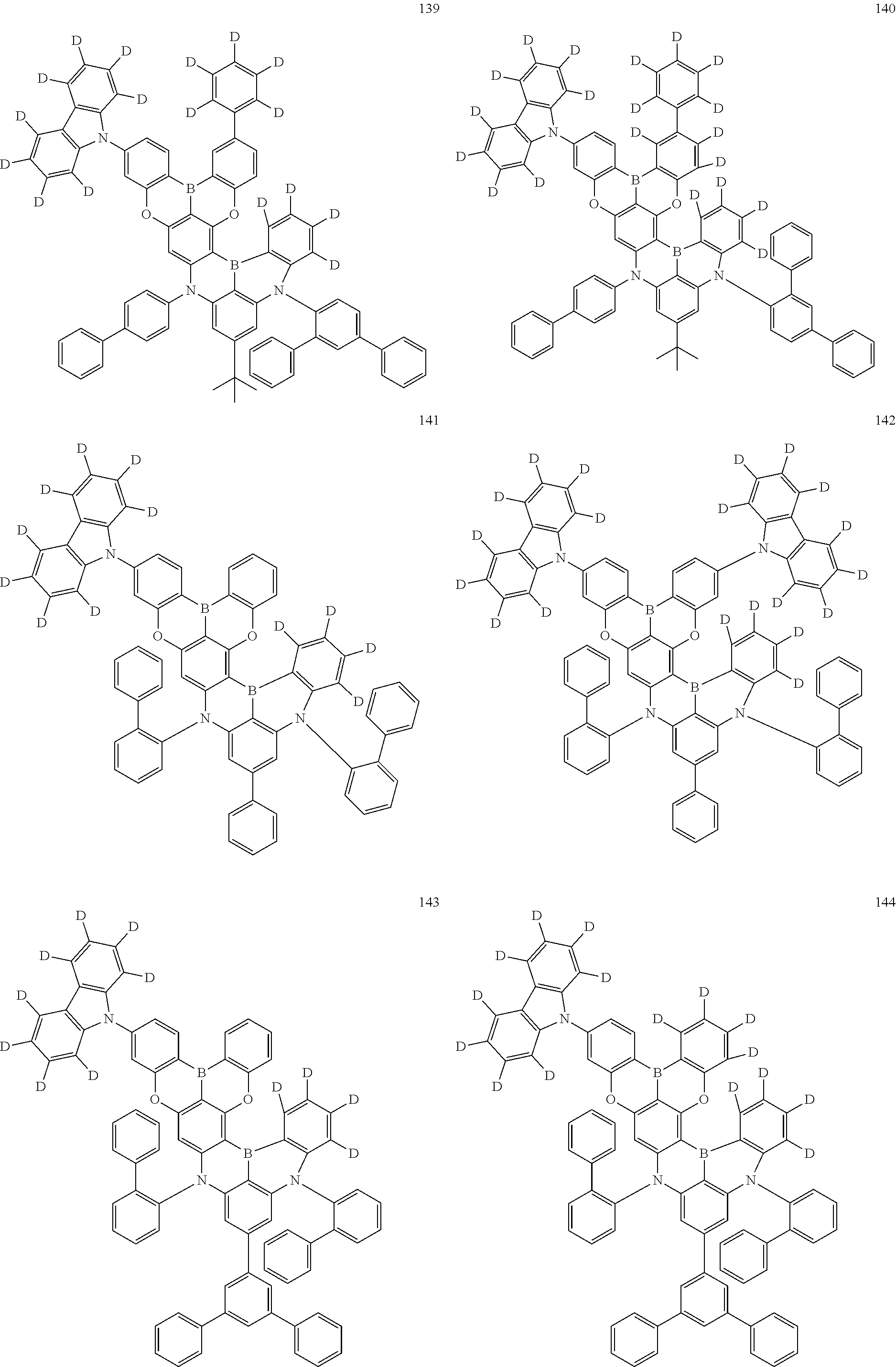

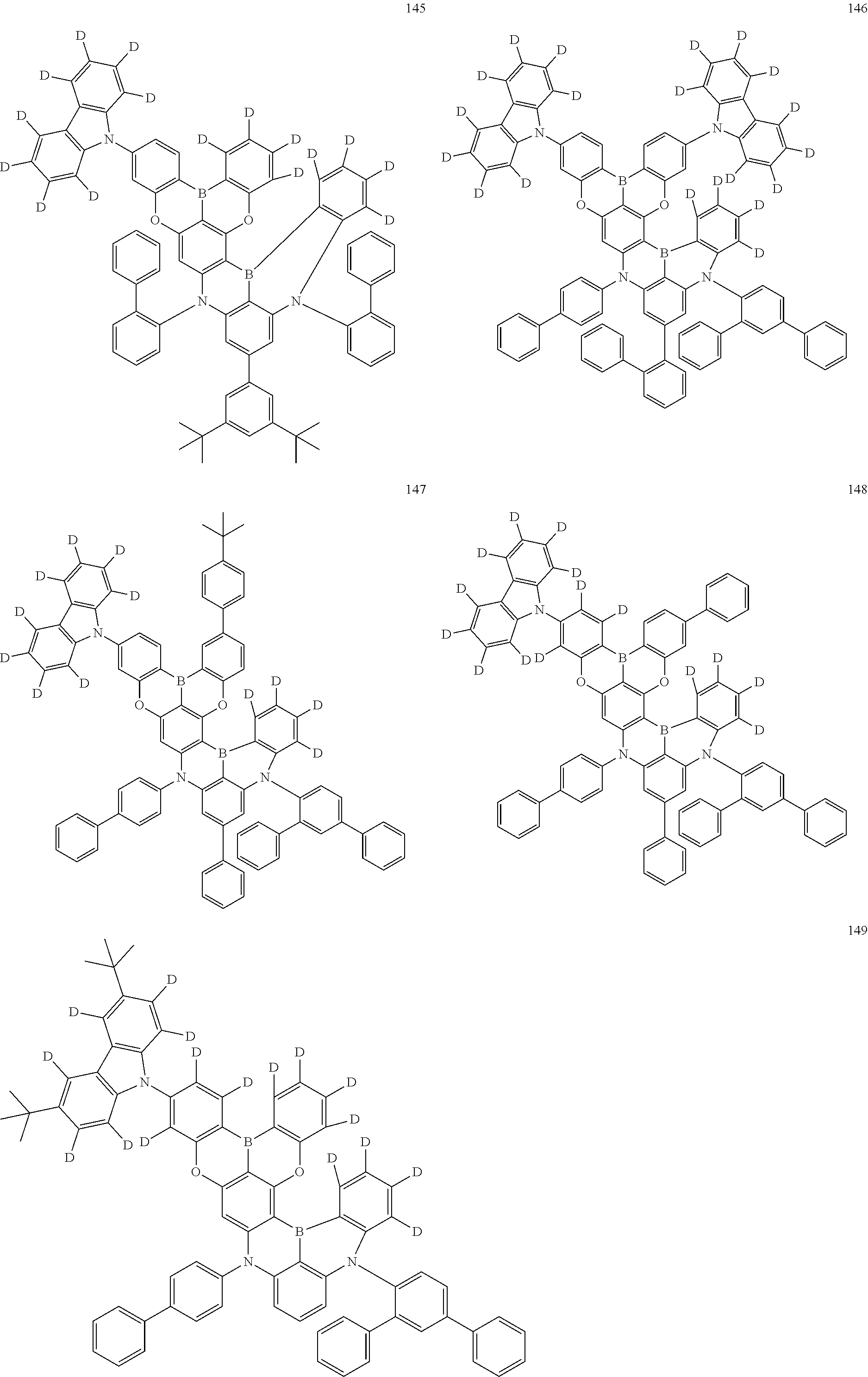

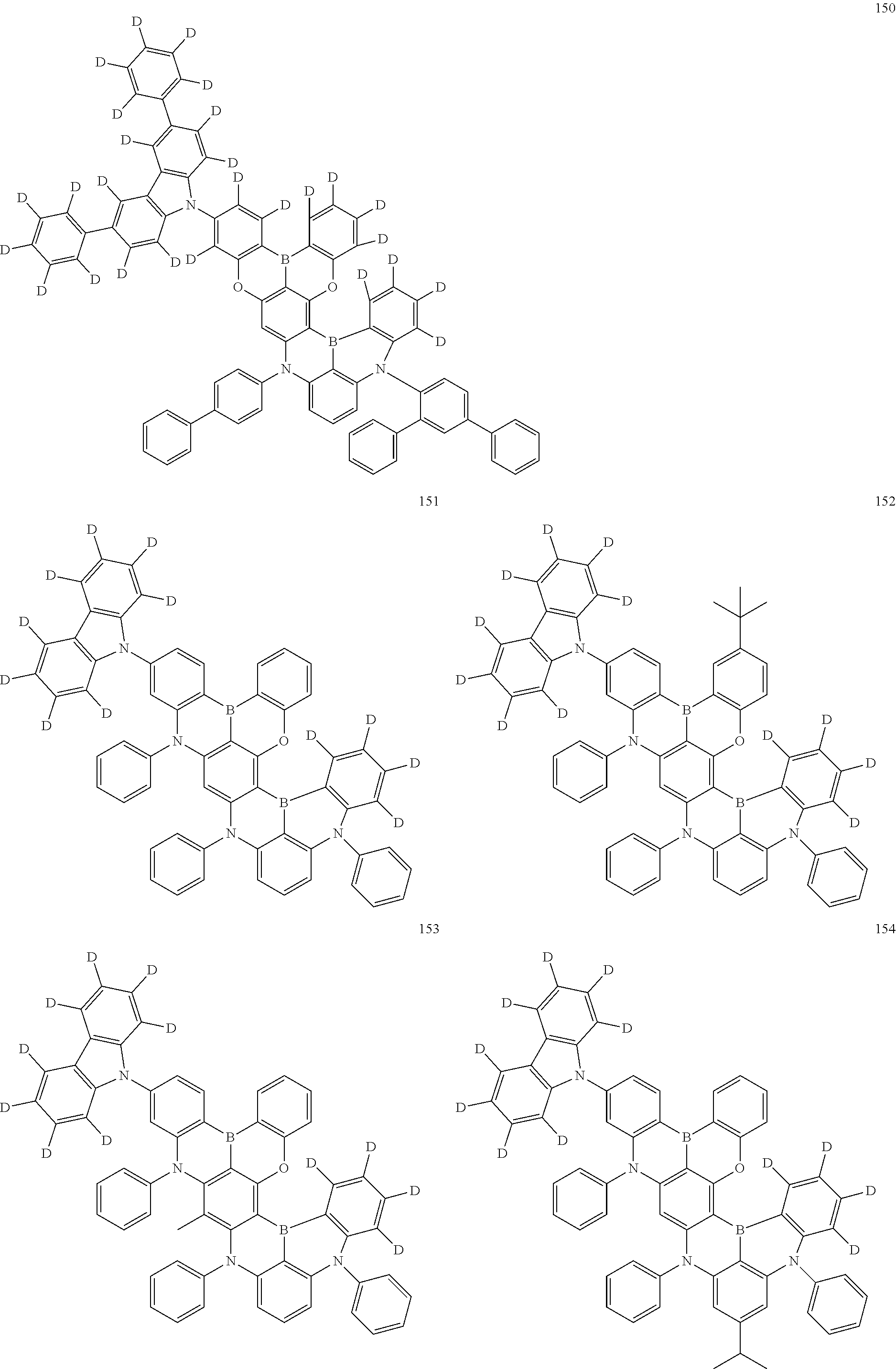

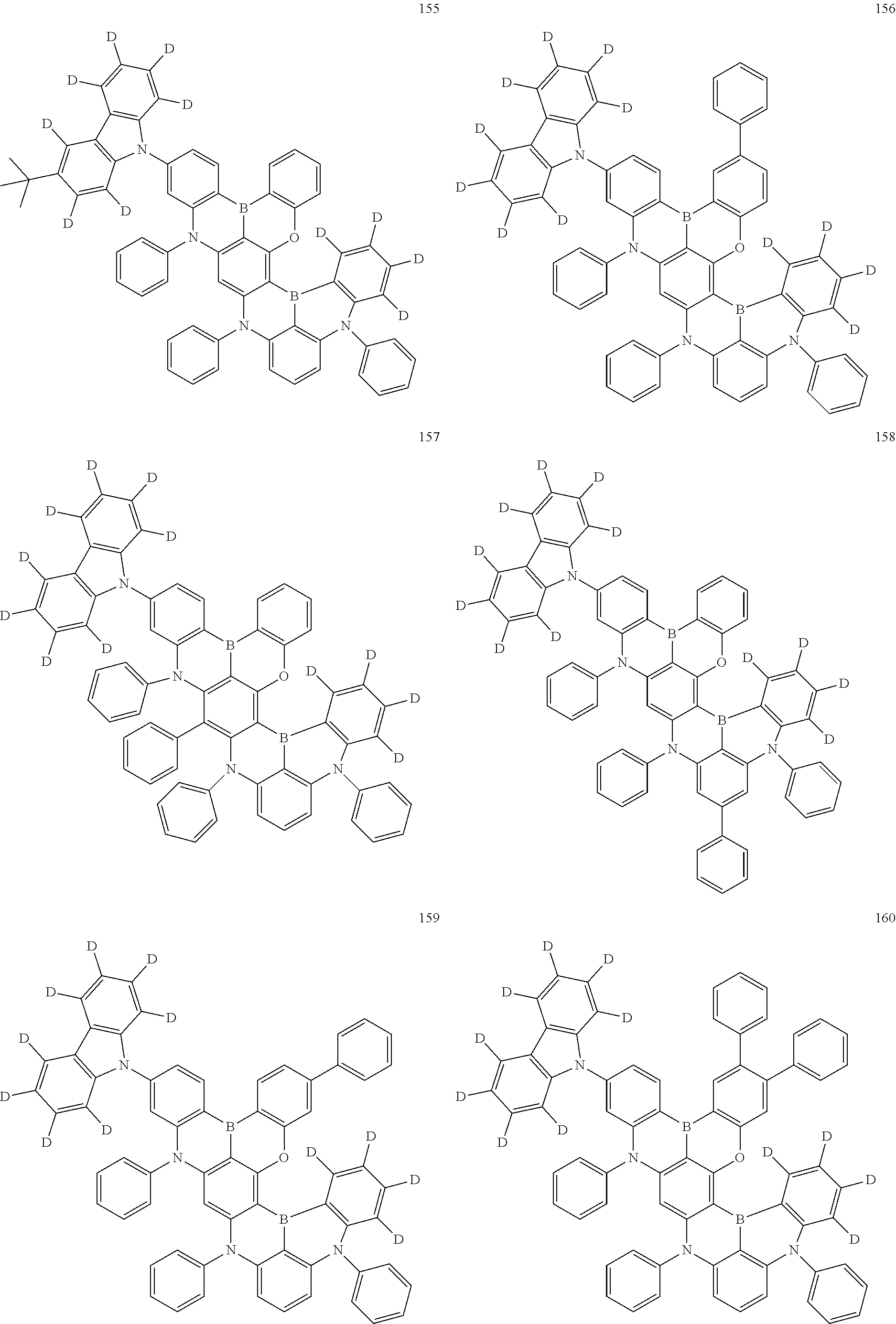

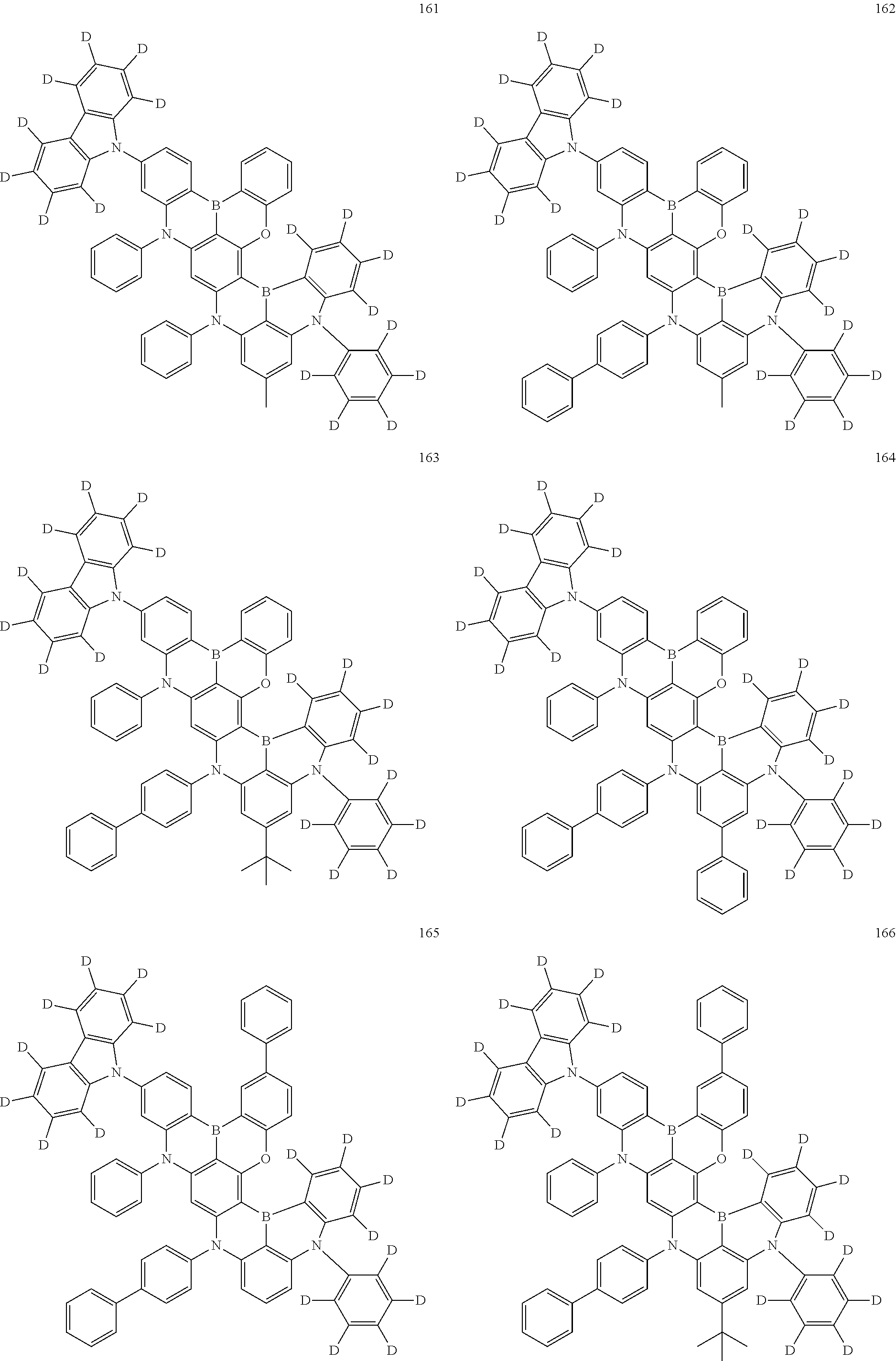

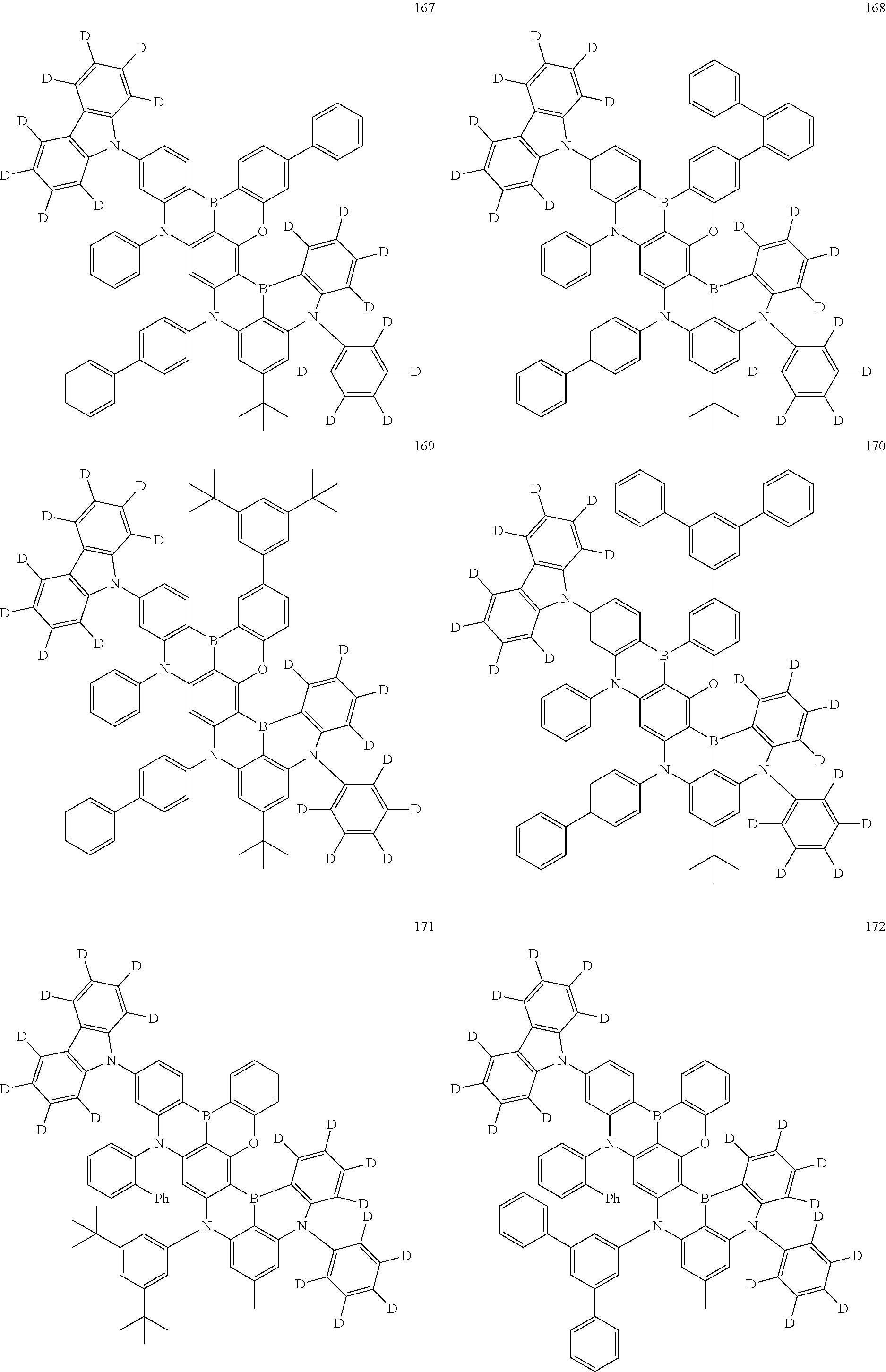

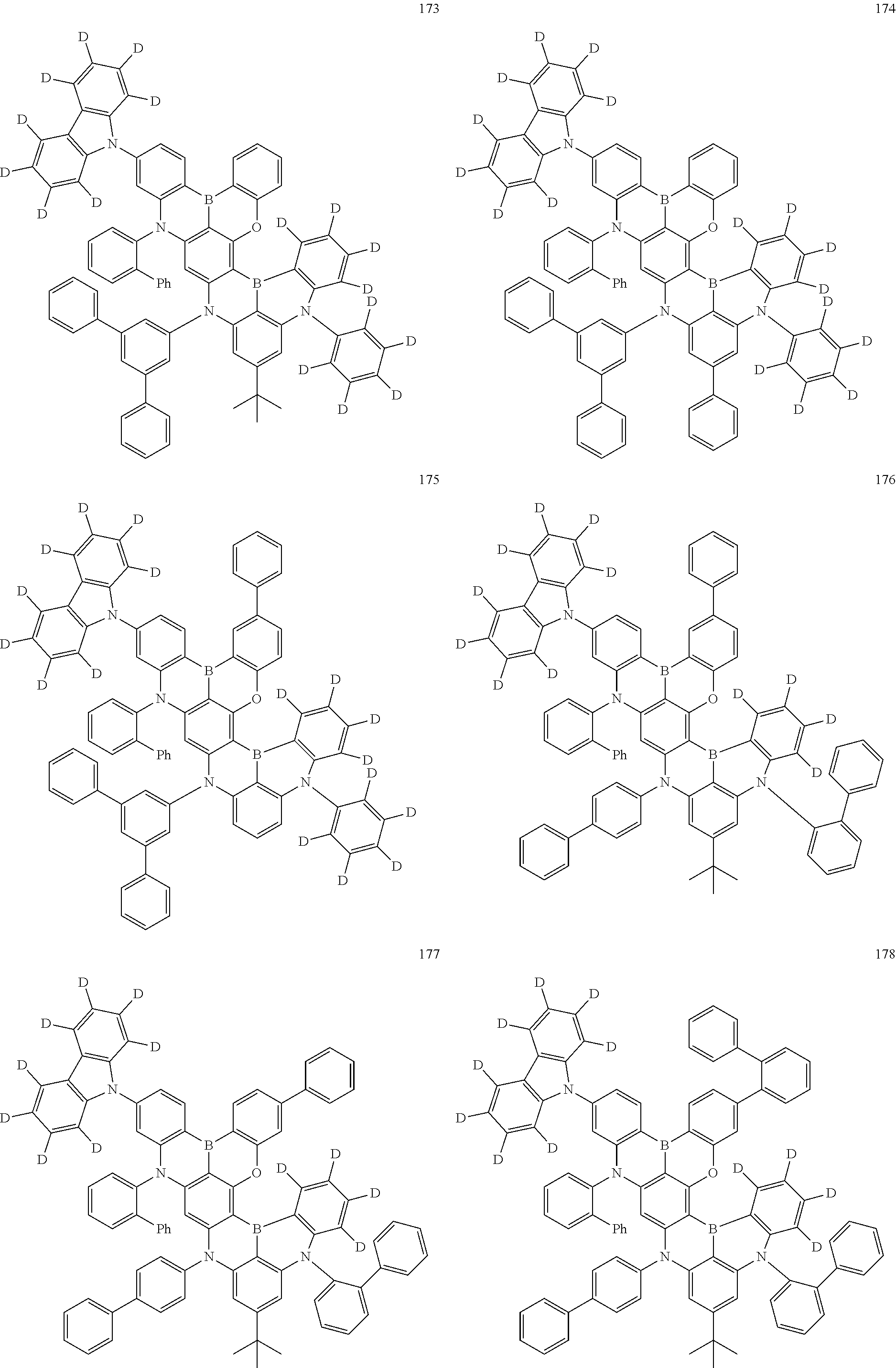

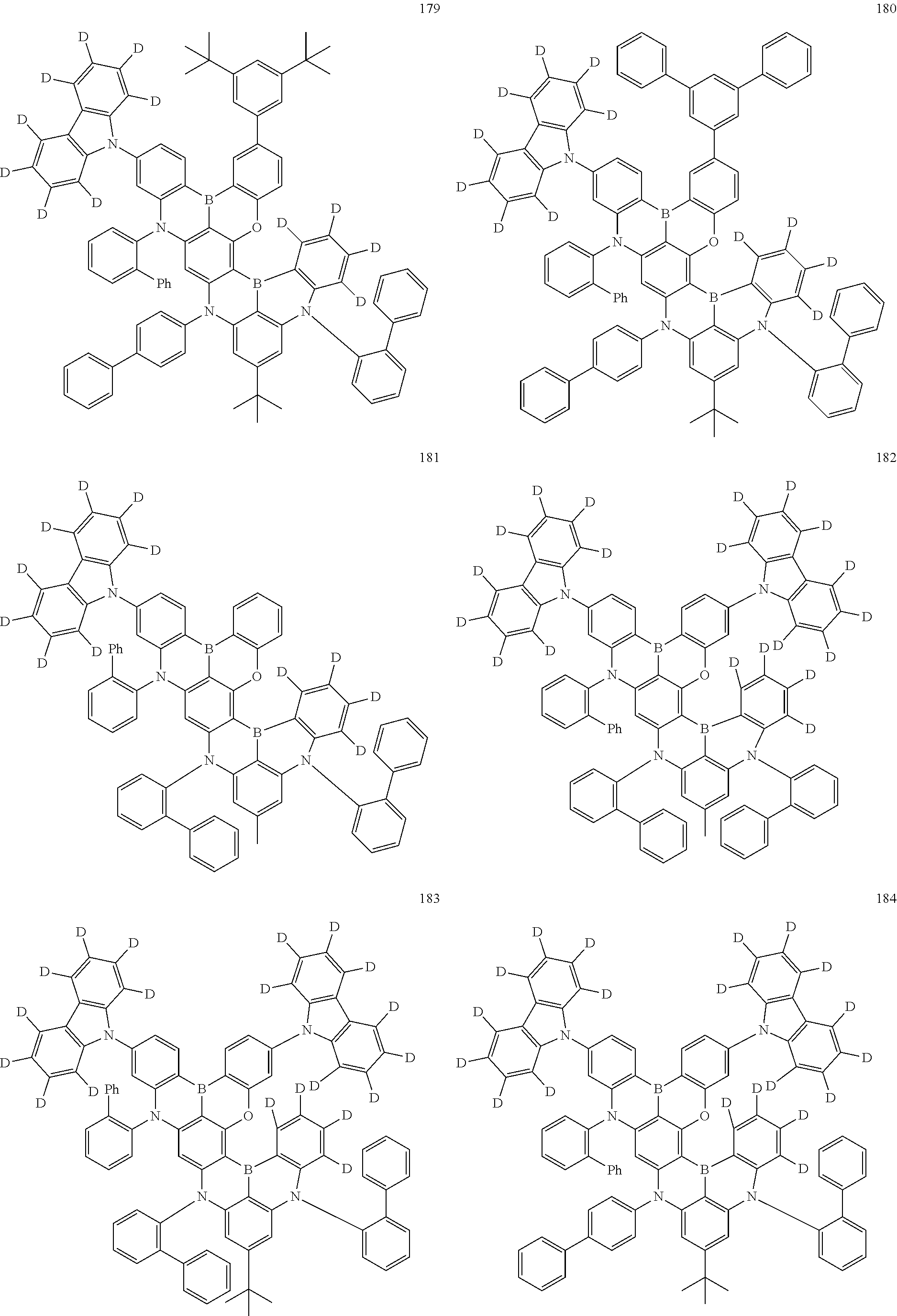

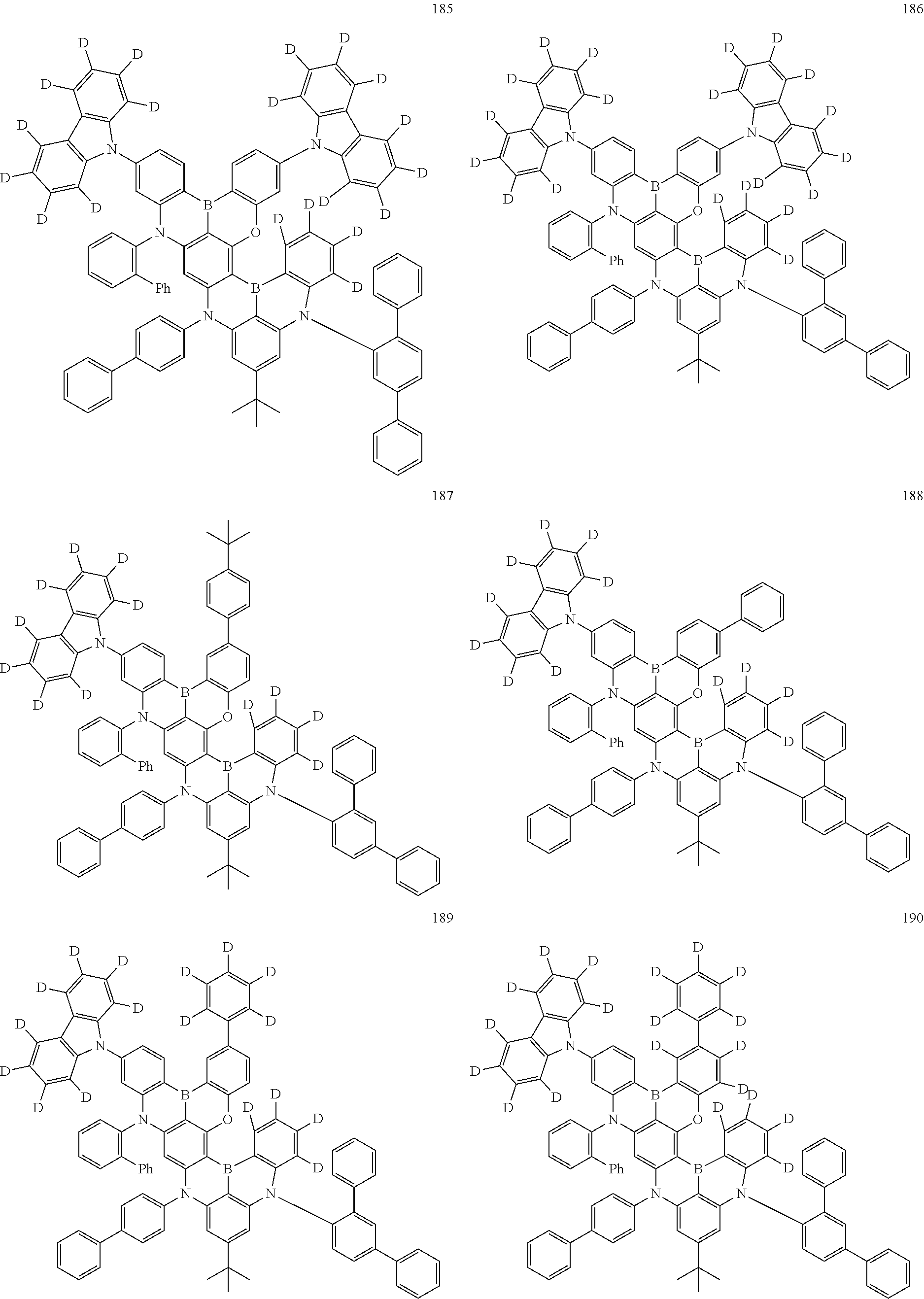

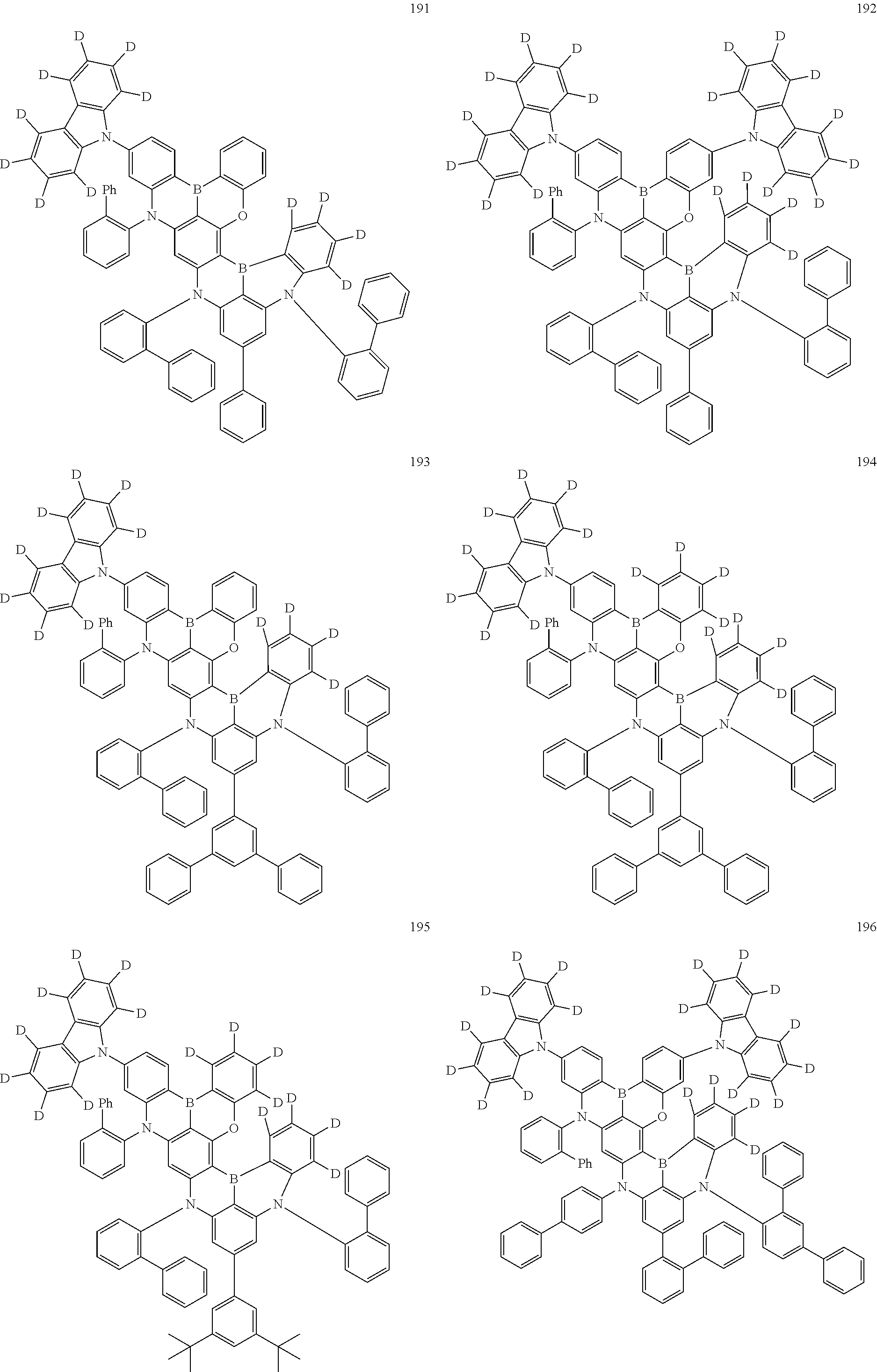

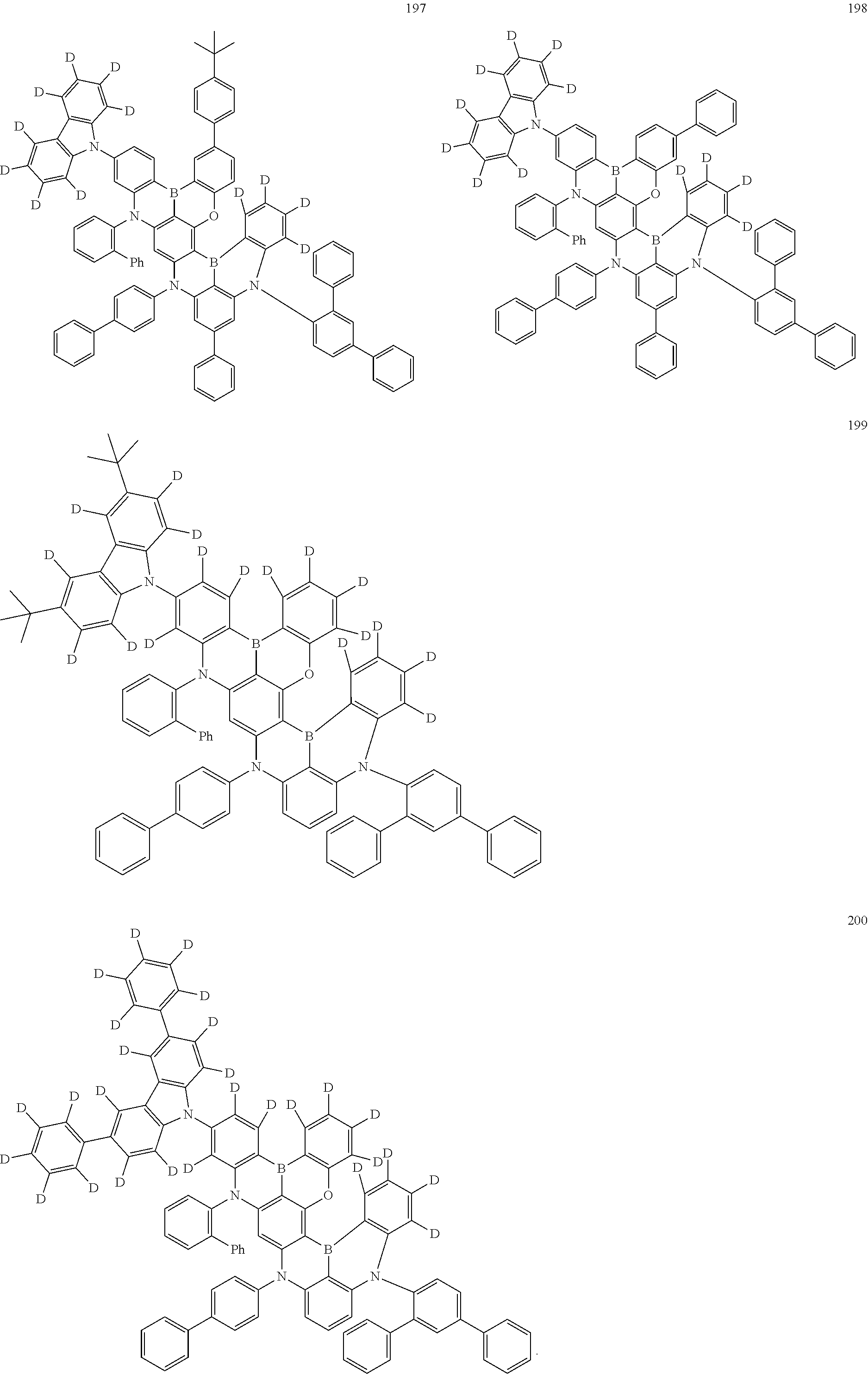

The fused polycyclic compound represented by Formula 1 has a structure in which two hydrocarbon rings are fused at specific positions through a boron atom and two heteroatoms in a fused polycyclic heterocycle and includes first substituents connected to the first benzene ring and a second substituent connected to the fifth benzene ring, thereby realizing high efficiency and long lifetime.

The fused polycyclic compound may include a fused polycyclic heterocycle in which first to third benzene rings are fused around the first boron atom, the first heteroatom, and the second heteroatom, and may have a structure in which the fourth and fifth benzene rings are connected to the fused polycyclic heterocycle through the second boron atom, the third heteroatom, and the fourth heteroatom. In addition, the fused polycyclic compound may include four first substituents connected to the first benzene ring and a second substituent connected to the fifth benzene ring. The first substituent is a deuterium atom, and the second substituent may include a carbazole moiety. The polycyclic compound may have improved emission efficiency and lifetime characteristics because the second boron atom, the third heteroatom, and the fourth heteroatom connecting two aromatic hydrocarbon rings and the fused polycyclic heterocycle are connected to specific positions of the fused polycyclic heterocycle, and the first and second substituents are included.

The fused polycyclic compound has a structure in which two hydrocarbon rings are fused at specific positions through the boron atom and two heteroatoms in the fused polycyclic heterocycle and may have high efficiency and long lifetime. In addition, the fused polycyclic compound may have a structure in which a conjugated structure is extended through the aromatic hydrocarbon ring, so that the multiple resonance effect is enhanced, and the emission efficiency may be further enhanced. Accordingly, the emission efficiency and device lifetime of a light emitting device including the fused polycyclic compound as an emitter may be significantly improved.

The fused polycyclic compound may exhibit the effect of expanding and strengthening multiple resonances within a molecule by introducing the first substituent and connecting the second boron atom, the third heteroatom, and the fourth heteroatom connecting two aromatic hydrocarbon rings and a fused polycyclic heterocycle to specific positions of the fused polycyclic heterocycle. The separation of the highest occupied molecular orbital (HOMO) and the lowest unoccupied molecular orbital (LUMO) may be promoted, thereby reducing ΔEST, and as a result, the reverse inter-system crossing (RISC) may be accelerated, thereby increasing the thermally activated delayed fluorescence phenomenon.

The fused polycyclic compound may appropriately control the singlet energy level and triplet energy level of the overall compound by controlling the specific position where two aromatic hydrocarbon rings are connected, the first and second substituents, or the like. Through this, the fused polycyclic compound according to an embodiment may exhibit improved thermally activated delayed fluorescence characteristics.

The fused polycyclic compound may exhibit the effect of improving structural stability by introducing the second substituent. Specifically, since the second substituent of the fused polycyclic compound becomes the origin of excitation energy or charge transfer from an adjacent molecule, the effect of improving stability may be achieved.

The emission spectrum of the fused polycyclic compound represented by Formula 1 has a full width at half maximum of about 10 nm to 50 nm, preferably, about 20 nm to 40 nm. Since the emission spectrum of the fused polycyclic compound represented by Formula 1 has the above-described range of the full width at half maximum, if applied to a device, emission efficiency may be improved. In addition, if used as a material for a blue light emitting device, device lifetime may be improved.

In an embodiment, the fused polycyclic compound represented by Formula 1 may be a material for emitting thermally activated delayed fluorescence. In addition, the fused polycyclic compound represented by Formula 1 may be a thermally activated delayed fluorescence dopant having a difference (ΔE_{ST}) between the lowest triplet excitation energy level (T1 level) and the lowest singlet excitation energy level (Si level) of about 0.6 eV or less. The fused polycyclic compound represented by Formula 1 may be a thermally activated delayed fluorescence dopant having a difference (ΔE_{ST}) between the lowest triplet excitation energy level (T1 level) and the lowest singlet excitation energy level (Si level) of about 0.4 eV or less, however, is not limited thereto.

The fused polycyclic compound represented by Formula 1 may be a light emitting material having a light emitting central wavelength in a wavelength range of about 430 nm to about 490 nm. For example, the fused polycyclic compound represented by Formula 1 may be a blue thermally activated delayed fluorescence (TADF) dopant. If the fused polycyclic compound is used as a light emitting material, the first dopant may be used as a dopant material emitting light in various wavelength ranges such as a red emitting dopant or green emitting dopant.

In the light emitting device ED of an embodiment, the emission layer EML may emit delayed fluorescence. For example, the emission layer EML may emit thermally activated delayed fluorescence (TADF).

In addition, the emission layer EML of the light emitting device ED may emit blue light. For example, the emission layer EML of an organic electroluminescence light emitting device ED may emit blue light in a wavelength range of about 490 nm or less. However, an embodiment is not limited thereto, and the emission layer EML may emit green light or red light.

The fused polycyclic compound may be included in an emission layer EML. The fused polycyclic compound may be included in an emission layer EML as a dopant material. The fused polycyclic compound may be a thermally activated delayed fluorescence emitting material. The fused polycyclic compound may be used as a thermally activated delayed fluorescence dopant. For example, in the light emitting device ED of an embodiment, the emission layer EML may include at least one among the fused polycyclic compounds represented in Compound Group 1 as a thermally delayed fluorescence dopant. However, the use of the fused polycyclic compound is not limited thereto.

In an embodiment, the emission layer EML may include multiple compounds. The emission layer EML may include the fused polycyclic compound represented by Formula 1, that is, the first compound, and at least one among a second compound represented by Formula HT-1, a third compound represented by Formula ET-1 and a fourth compound represented by Formula D-1 below.

In an embodiment, the emission layer EML may include the first compound represented by Formula 1 and further include at least one among a second compound represented by Formula HT-1 or a third compound represented by Formula ET-1 below.

In an embodiment, the emission layer EML may include a second compound represented by Formula HT-1. In an embodiment, the second compound may be used as a hole transport host material in an emission layer EML.

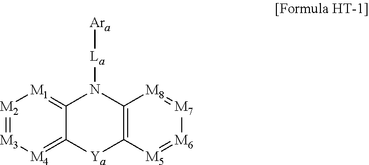

In Formula HT-1, M₁ to M₈ may be each independently N or CR₅₁. For example, all M₁ to M₈ may be CR₅₁. Otherwise, any one among M₁ to M₈ may be N, and the remainder may be CR₅₁.

In Formula HT-1, Lₐ may be a direct linkage, a substituted or unsubstituted arylene group of 6 to 30 ring-forming carbon atoms, or a substituted or unsubstituted heteroarylene group of 2 to 30 ring-forming carbon atoms. For example, Lₐ may be a direct linkage, a substituted or unsubstituted phenylene group, a substituted or unsubstituted divalent biphenyl group, a substituted or unsubstituted divalent carbazole group, or the like, but an embodiment of the inventive concept is not limited thereto.

In Formula HT-1, Yₐ may be a direct linkage, CR₅₂R₅₃, or SiR₅₄R₅₅. That is, as shown two benzene rings connected with the nitrogen atom of Formula HT-1 may be connected via a direct linkage,

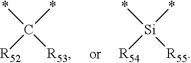

In Formula HT-1, if Yₐ is a direct linkage, the substituent represented by Formula HT-1 may include a carbazole moiety.

In Formula HT-1, Arₐ may be a substituted or unsubstituted aryl group of 6 to 30 ring-forming carbon atoms, or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but an embodiment is not limited thereto.

In Formula HT-1, R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 60 ring-forming carbon atoms. Otherwise, each of R₅₁ to R₅₅ may be combined with an adjacent group to form a ring. For example, R₅₁ to R₅₅ may be each independently a hydrogen atom or a deuterium atom. R₅₁ to R₅₅ may be each independently an unsubstituted methyl group or an unsubstituted phenyl group.

In an embodiment, the second compound represented by Formula HT-1 may be represented by any one among the compounds represented in Compound Group 2. An emission layer EML may include at least one among the compounds represented in Compound Group 2 as a hole transport host material.

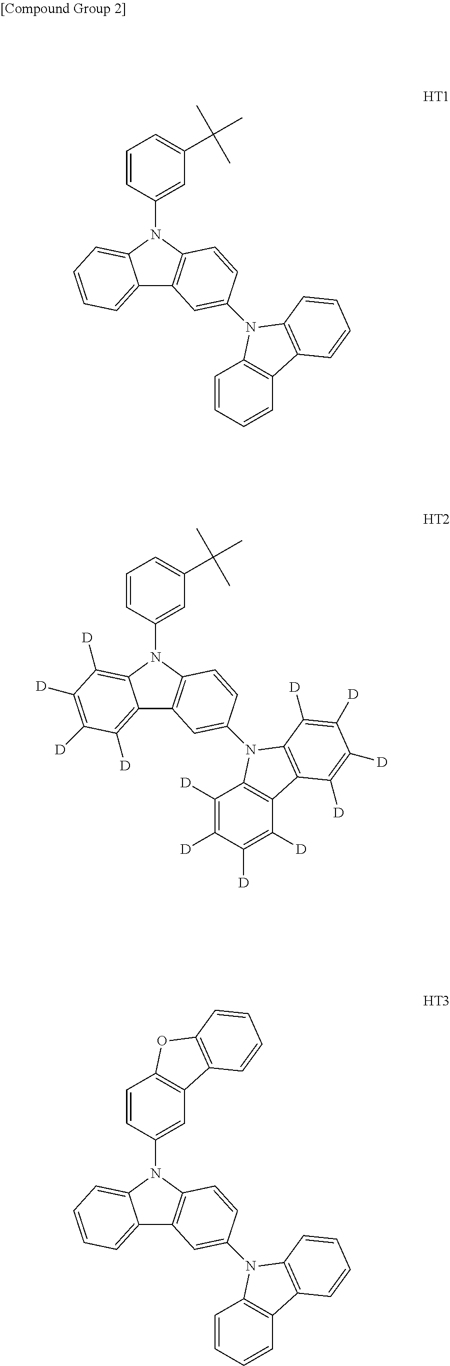 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

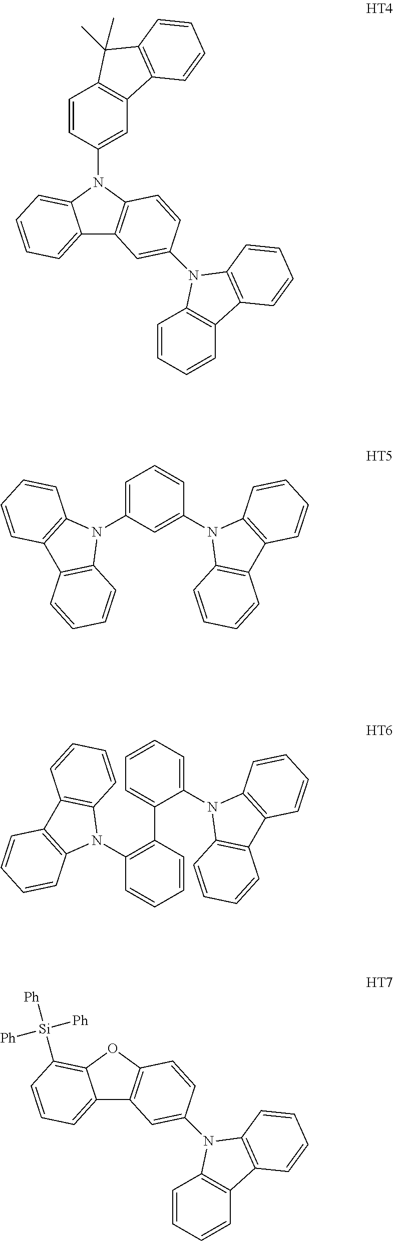 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

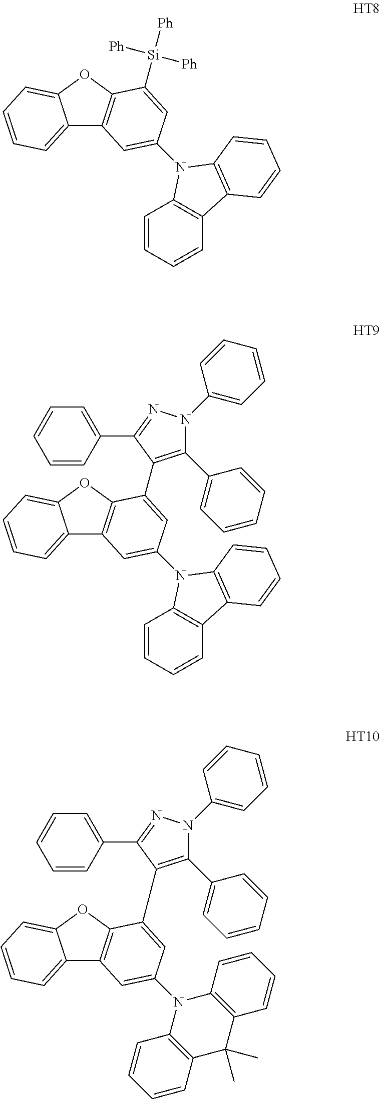 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

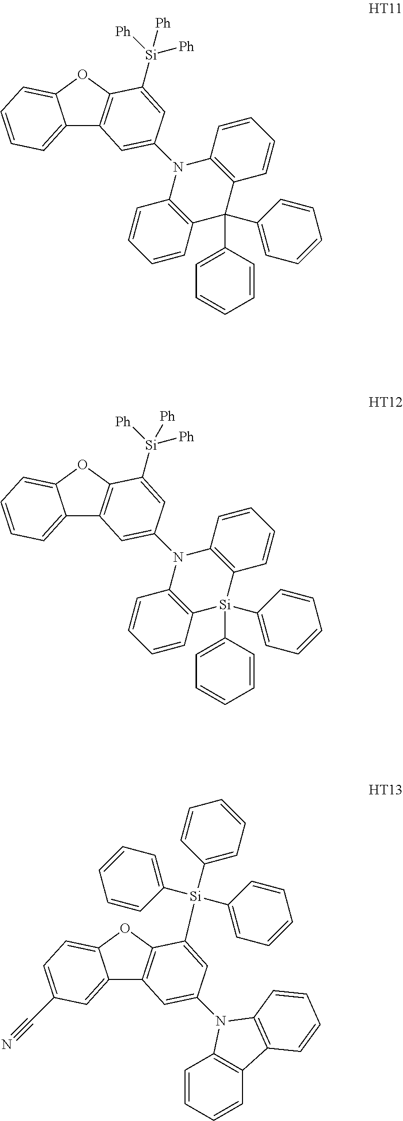 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

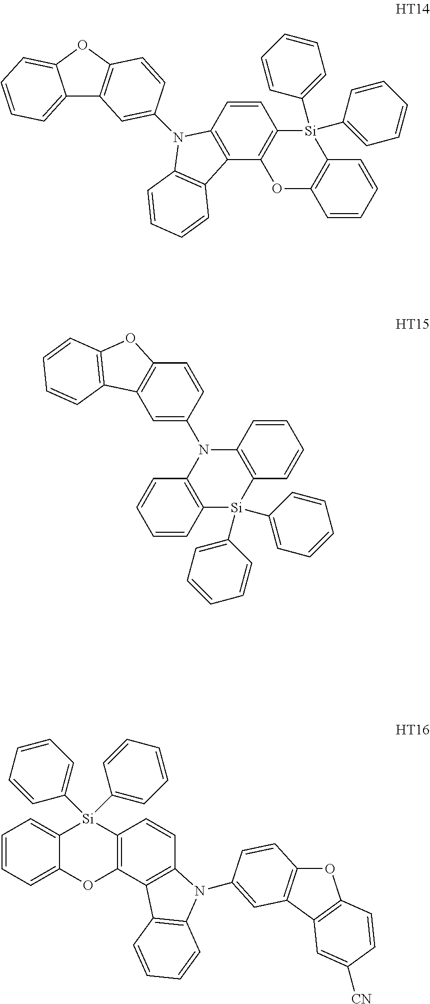 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

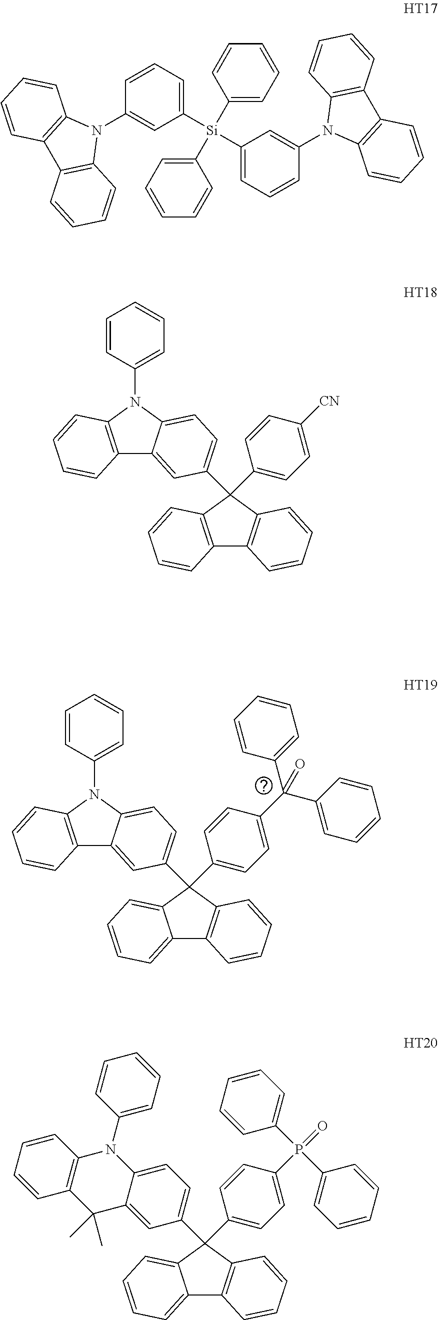

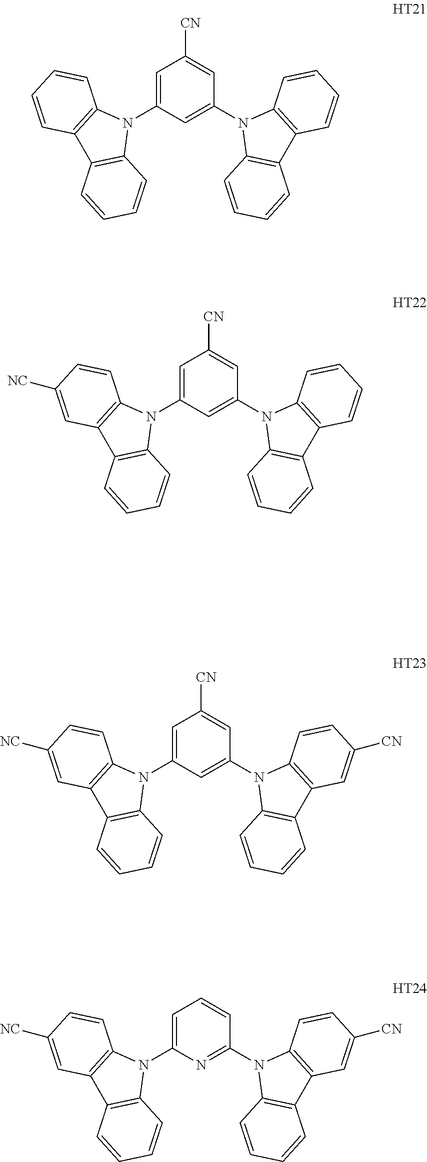 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

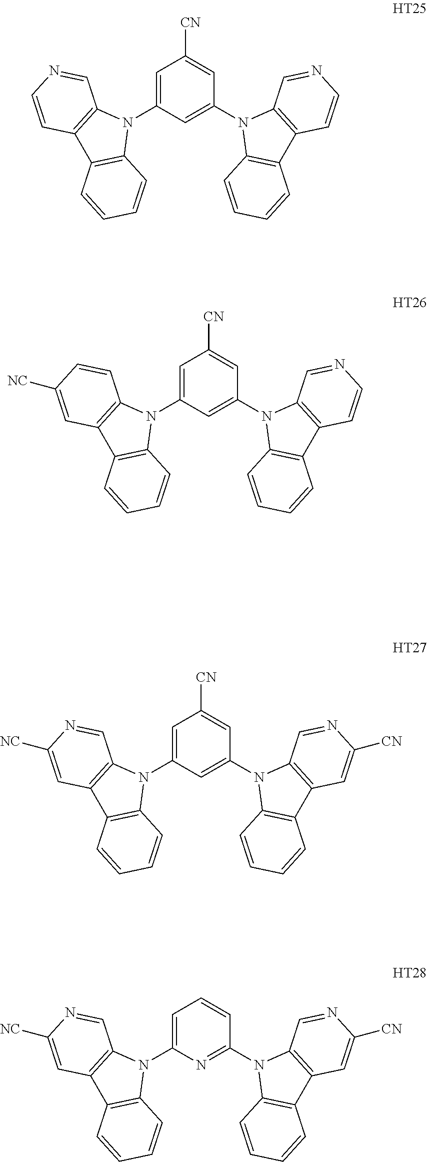 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

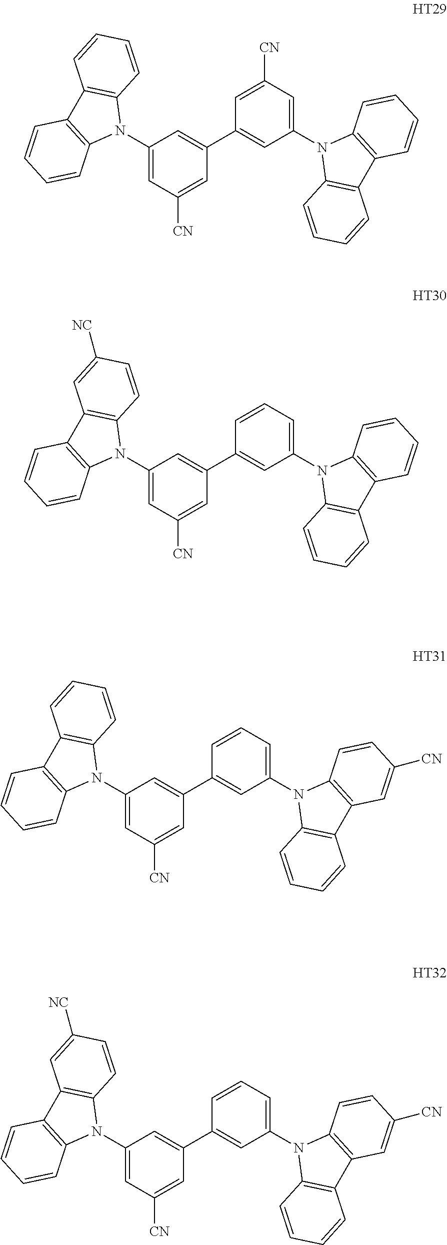 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

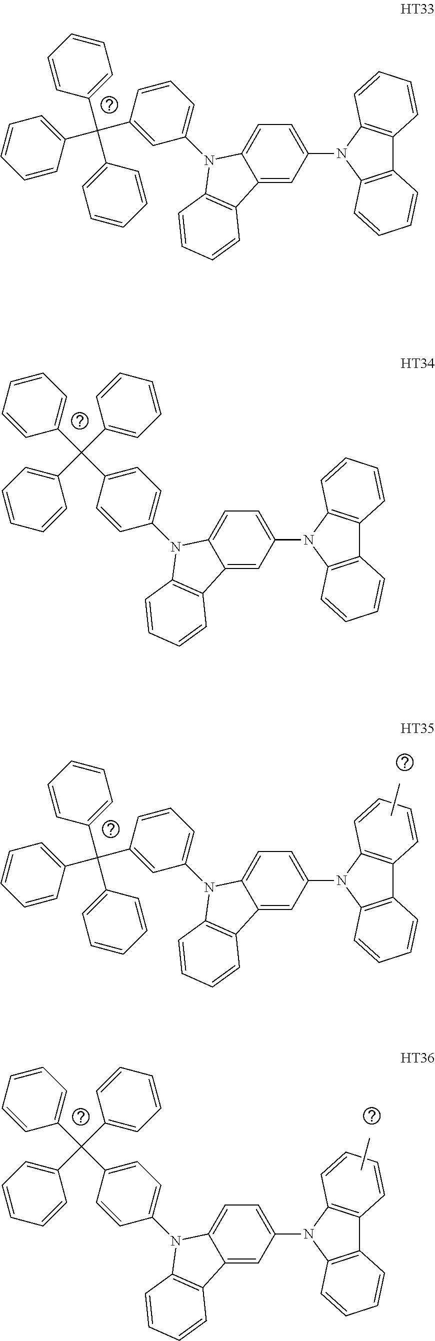

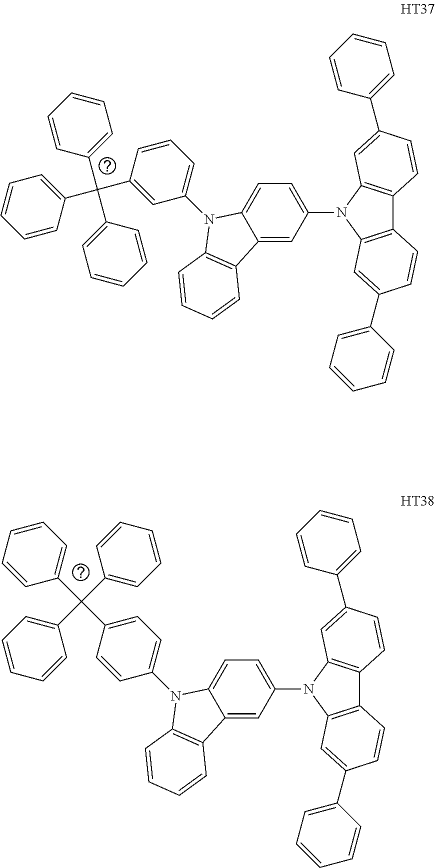 [SMILES: c1ccc(-c2ccc3c4ccc(-c5ccccc5)cc4n(-c4ccc5c(c4)c4ccccc4n5-c4cccc(C(c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc(C(c5ccccc5)(c5ccccc5)c5ccccc5)cc4)c3c2)cc1]

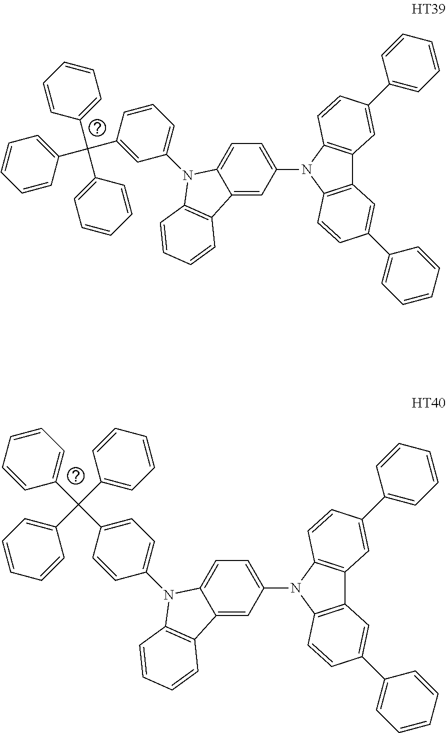 [SMILES: c1ccc(-c2ccc3c(c2)c2cc(-c4ccccc4)ccc2n3-c2ccc3c(c2)c2ccccc2n3-c2cccc(C(c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc(C(c3ccccc3)(c3ccccc3)c3ccccc3)cc2)cc1]

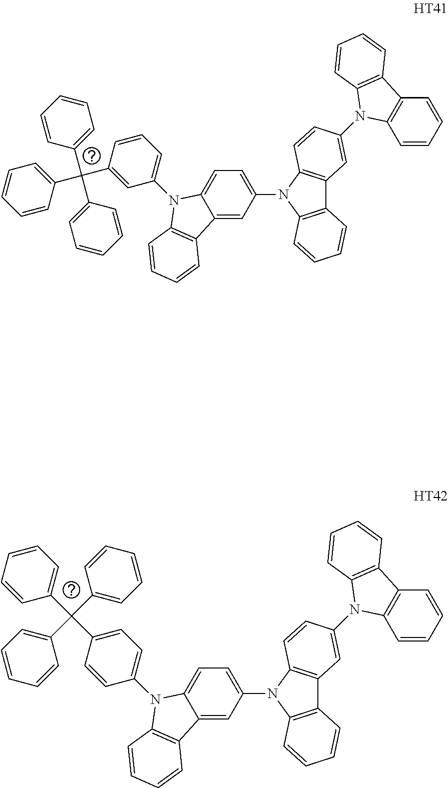 [SMILES: c1ccc(C(c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc(C(c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

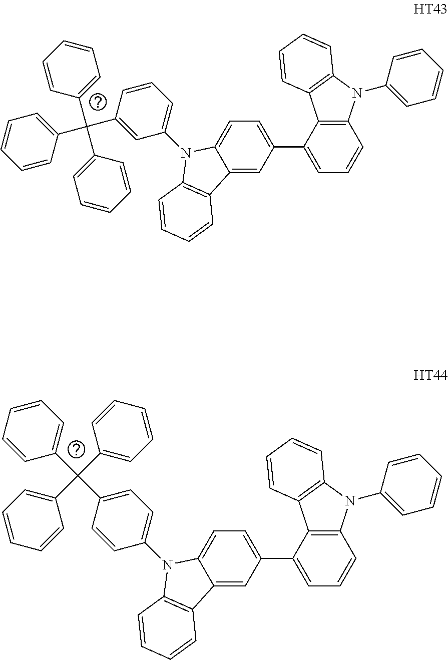 [SMILES: c1ccc(-n2c3ccccc3c3c(-c4ccc5c(c4)c4ccccc4n5-c4cccc(C(c5ccccc5)(c5ccccc5)c5ccccc5)c4)cccc32)cc1 ; c1ccc(-n2c3ccccc3c3c(-c4ccc5c(c4)c4ccccc4n5-c4ccc(C(c5ccccc5)(c5ccccc5)c5ccccc5)cc4)cccc32)cc1]

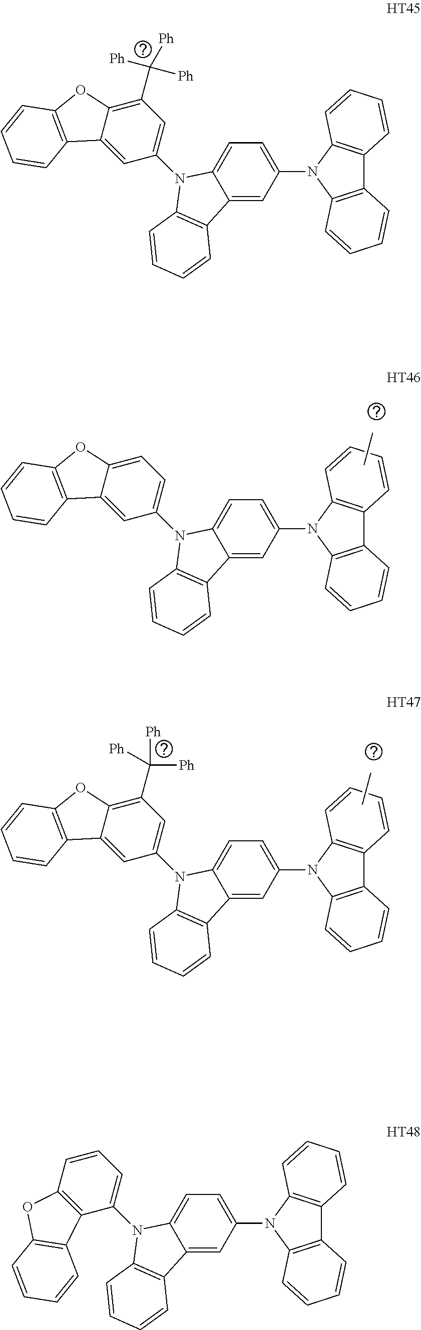

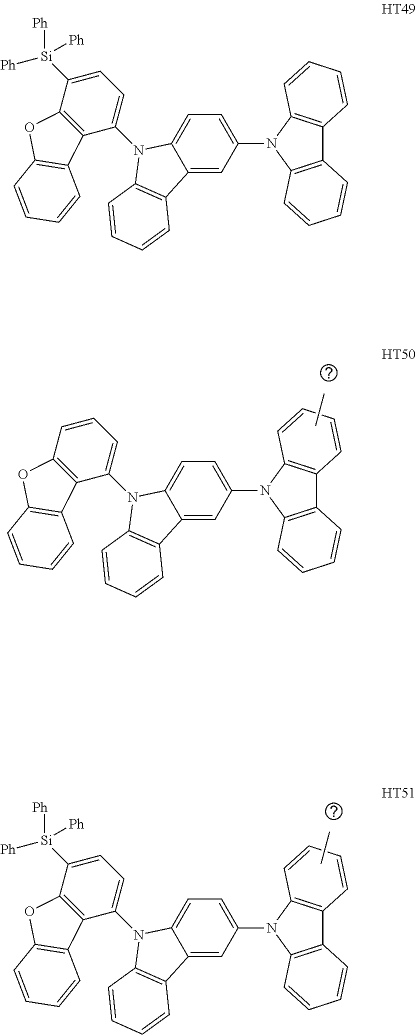

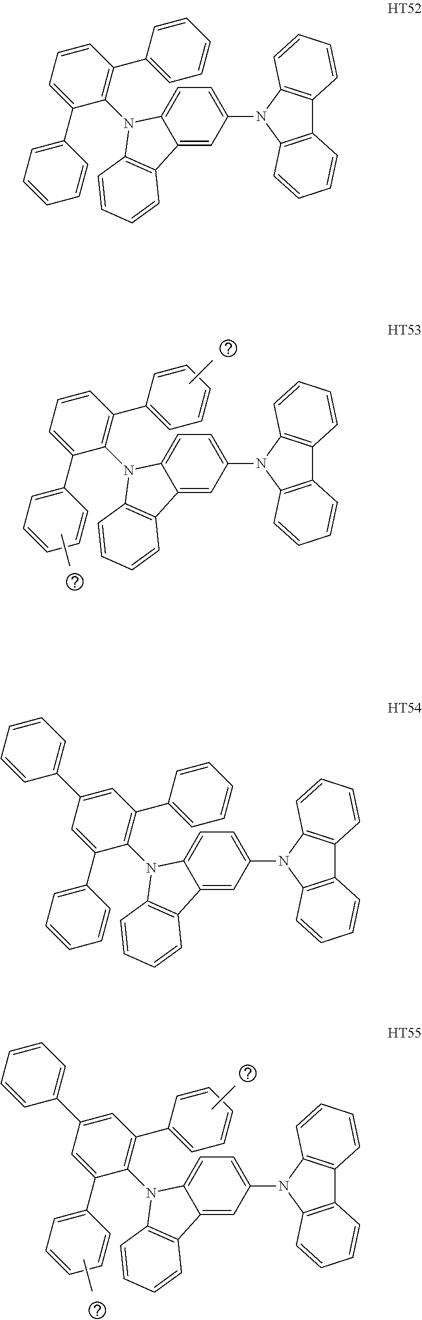

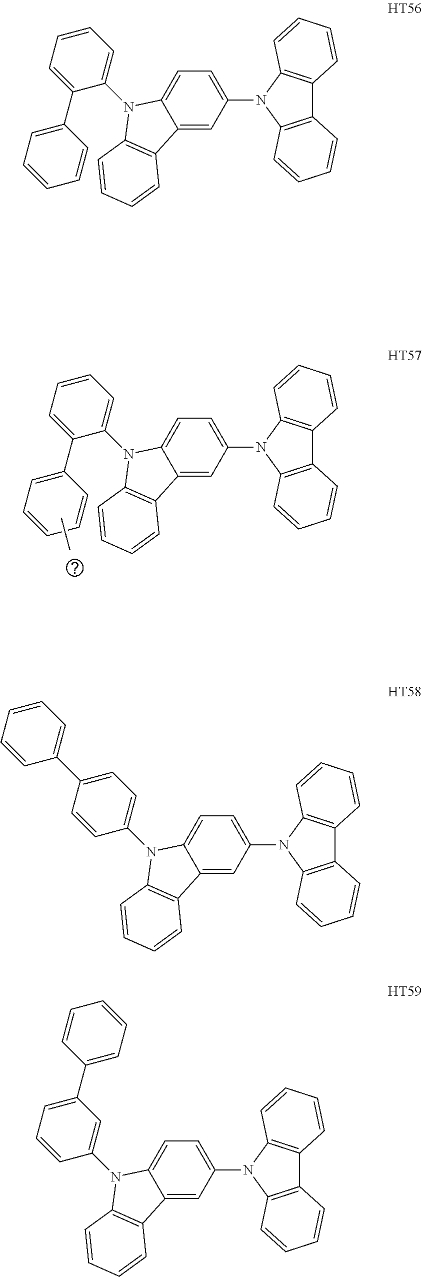

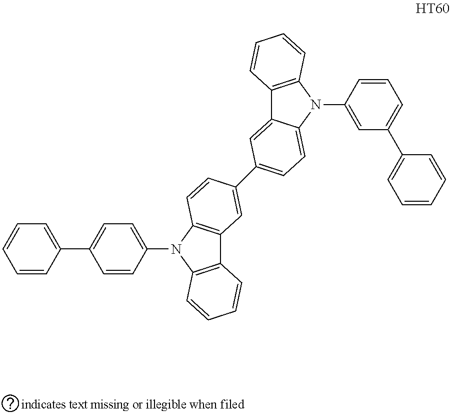 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In the particular compounds of Compound Group 2, “D” means a deuterium atom, and “Ph” may mean a substituted or unsubstituted phenyl group.

In an embodiment, the emission layer EML may include a third compound represented by Formula ET-1 below. For example, the third compound may be used as an electron transport host material in the emission layer EML.

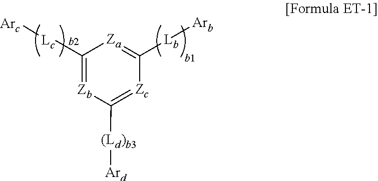

In Formula ET-1, at least one of Zₐ, Z_{b}, or Zₑ may be N, and the remainder may be CR₅₆. For example, at least one of Zₐ, Z_{b}, or Zₑ may be N, and the remainder two may be each independently CR₅₆. In this case, the third compound represented by Formula ET-1 may include a pyridine moiety. Otherwise, at least two of Zₐ, Z_{b}, or Z_{c} may be N, and the remainder may be CR₅₆. In this case, the third compound represented by Formula ET-1 may include a pyrimidine moiety. Otherwise, Zₐ, Z_{b}, or Z_{c} may be all N. In this case, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1, b2, and b3 may be each independently an integer of 0 to 10.

In Formula ET-1, Ar_{b} to Ar_{d} may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may be substituted or unsubstituted phenyl groups or substituted or unsubstituted carbazole groups.

In Formula ET-1, L_{b} to L_{d} may be each independently a direct linkage, a substituted or unsubstituted arylene group of 6 to 30 ring-forming carbon atoms, or a substituted or unsubstituted heteroarylene group of 2 to 30 ring-forming carbon atoms. If each of b1, b2, or b3 is an integer of 2 or more, L_{b} to L_{d} may be each independently a substituted or unsubstituted arylene group of 6 to 30 ring-forming carbon atoms, or a substituted or unsubstituted heteroarylene group of 2 to 30 ring-forming carbon atoms.

In an embodiment, the third compound may be represented by any one among the compounds in Compound Group 3. The light emitting device ED of an embodiment may include any one among the compounds in Compound Group 3.

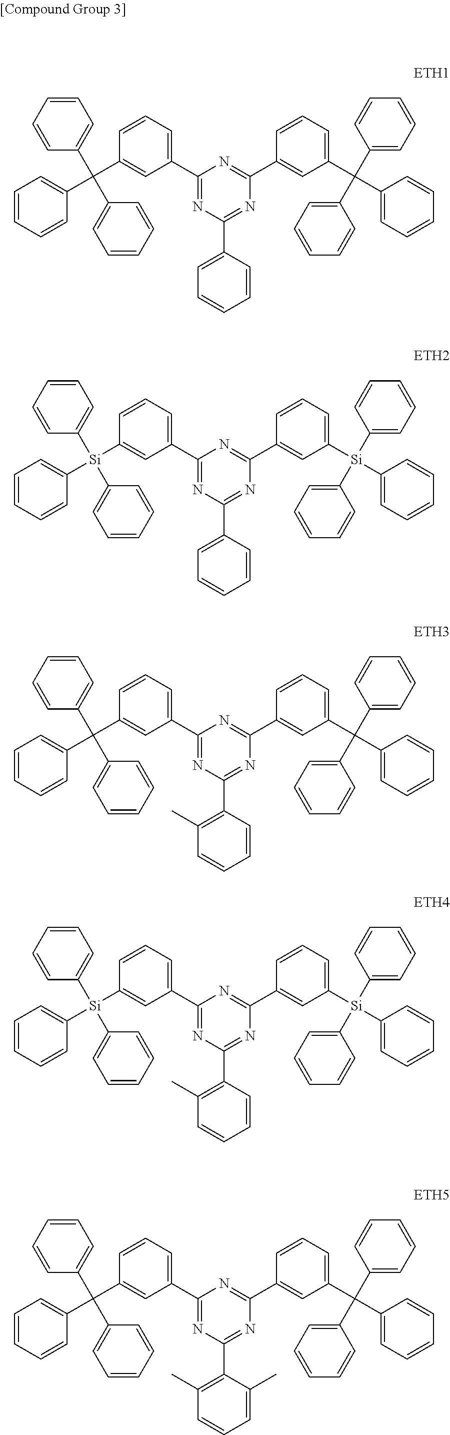

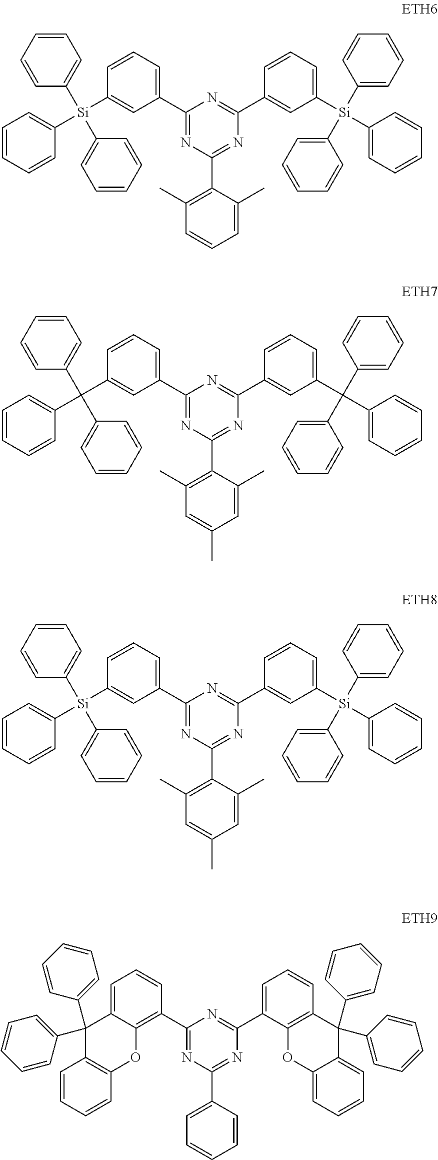 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

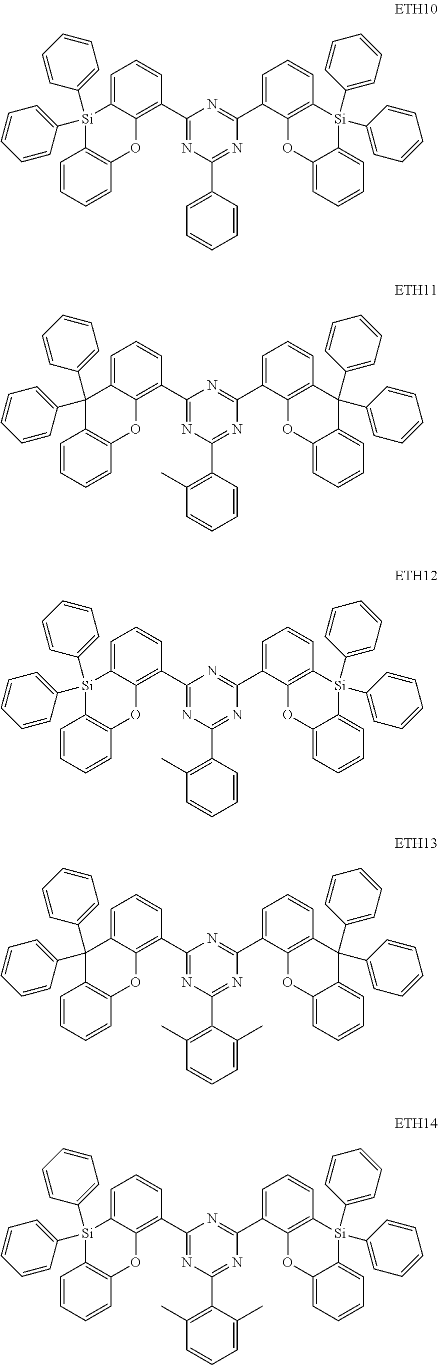

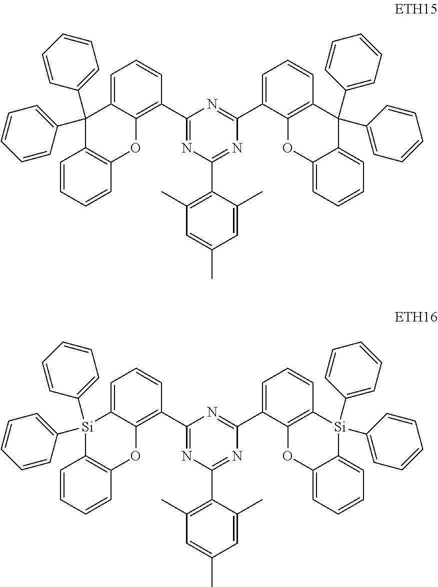 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

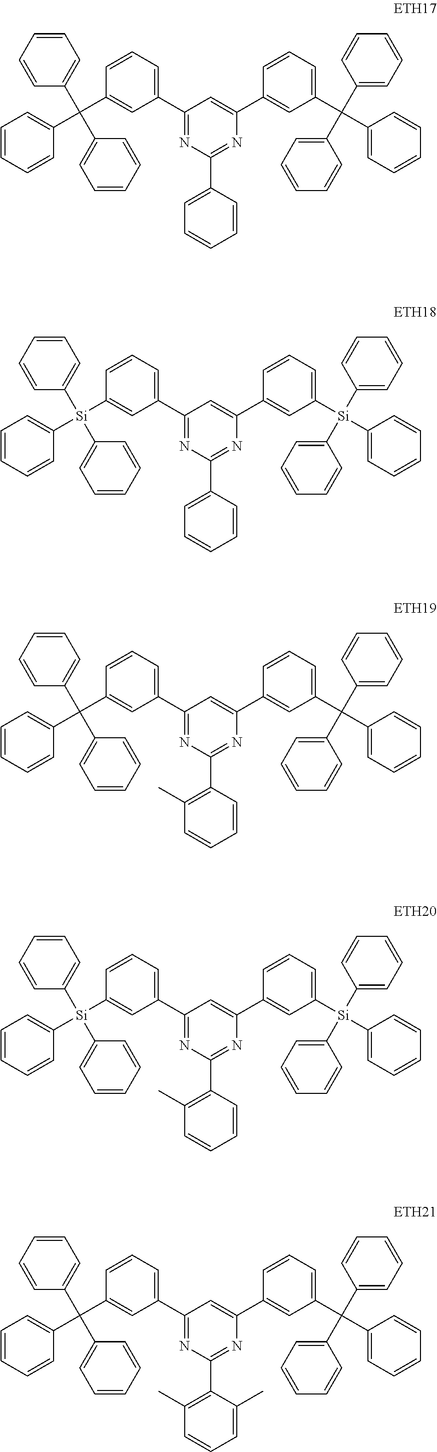

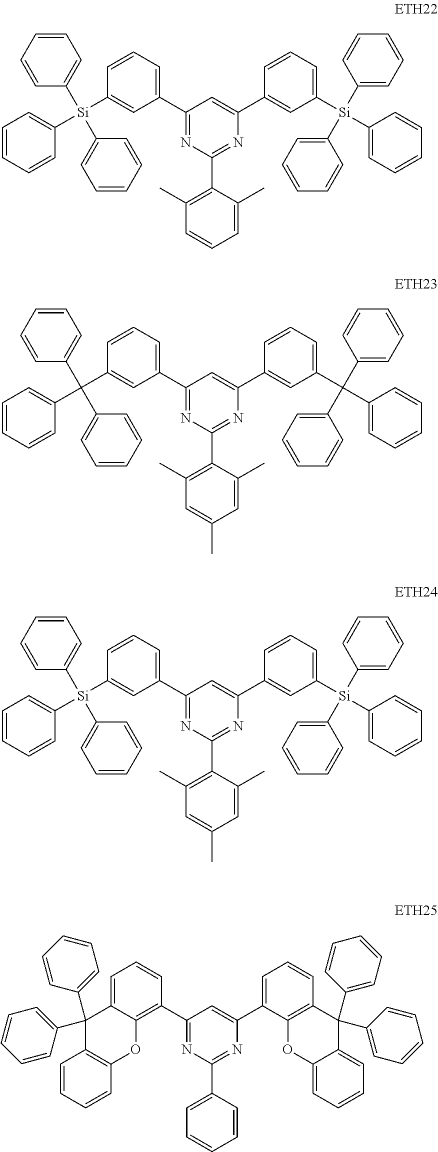 [SMILES: Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1]

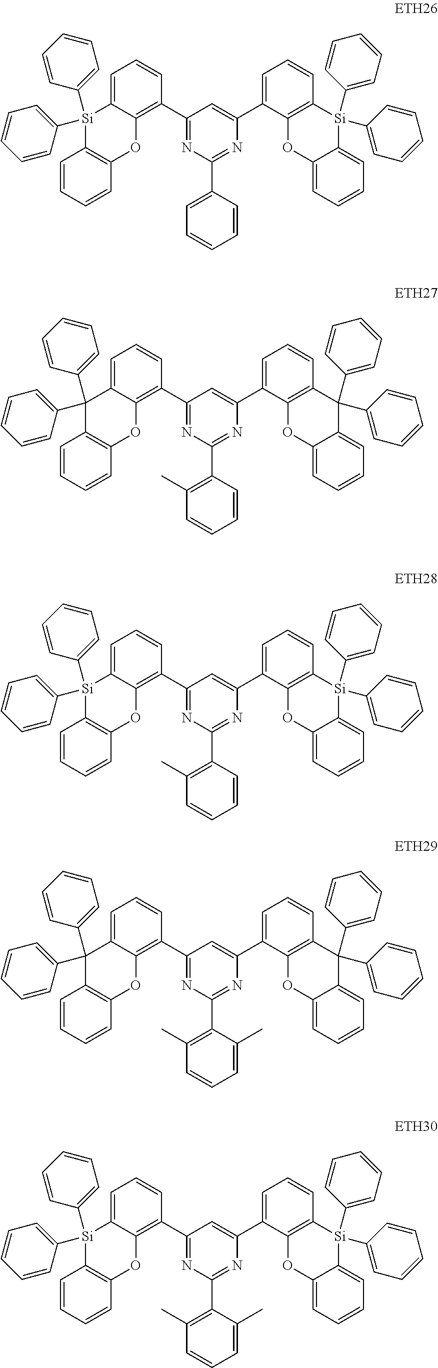

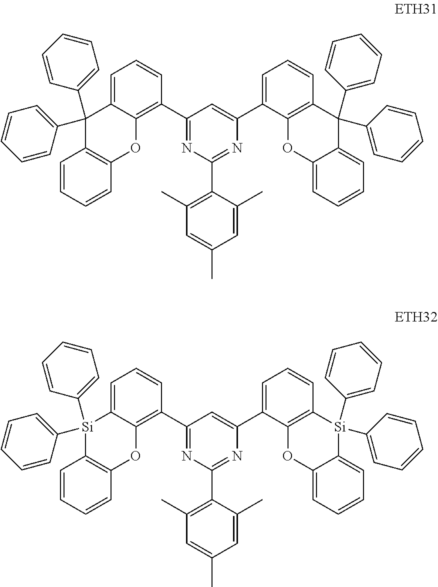 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

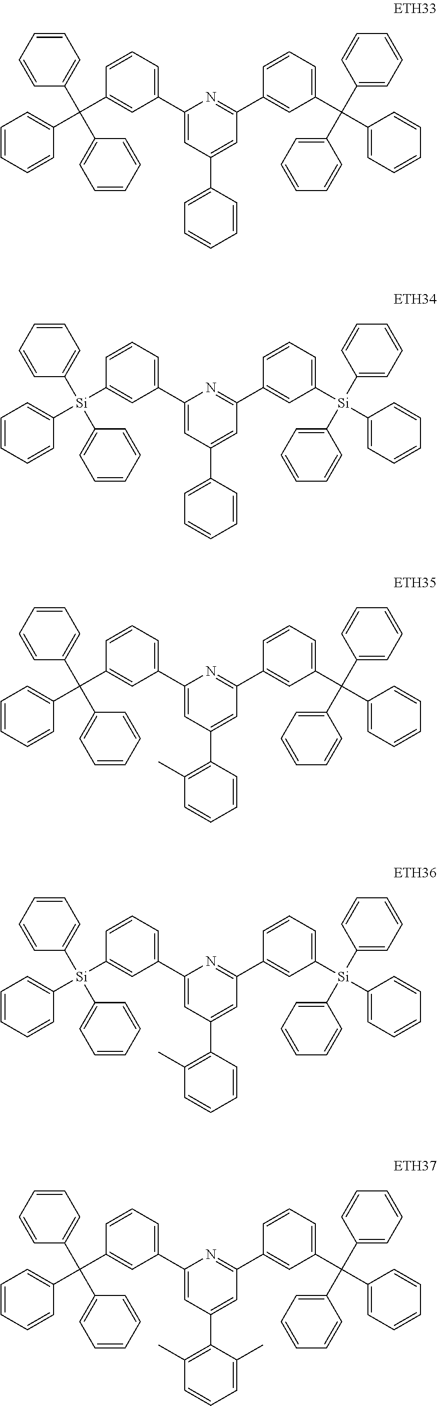

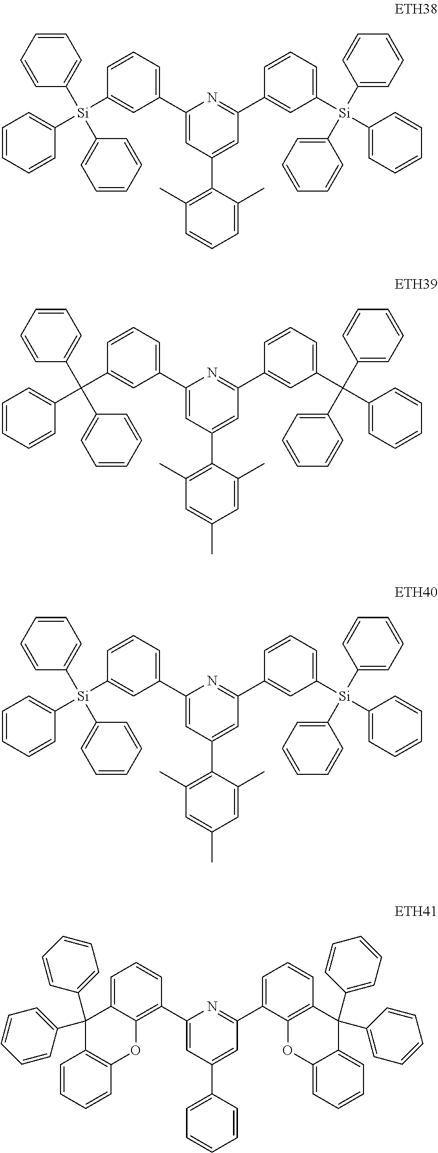 [SMILES: Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1]

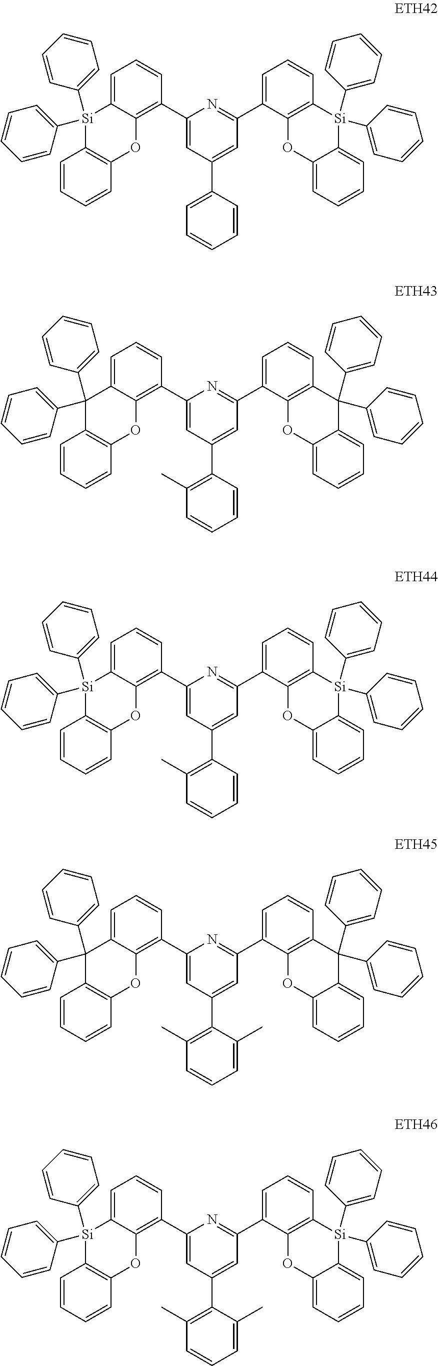

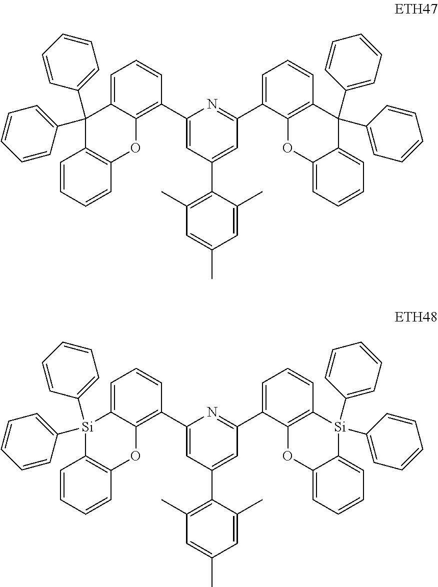 [SMILES: Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

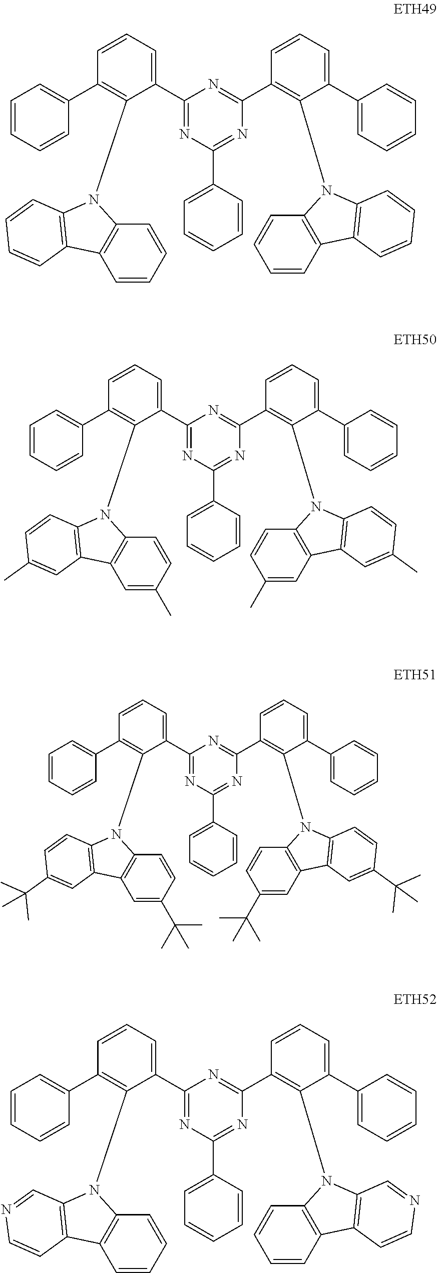

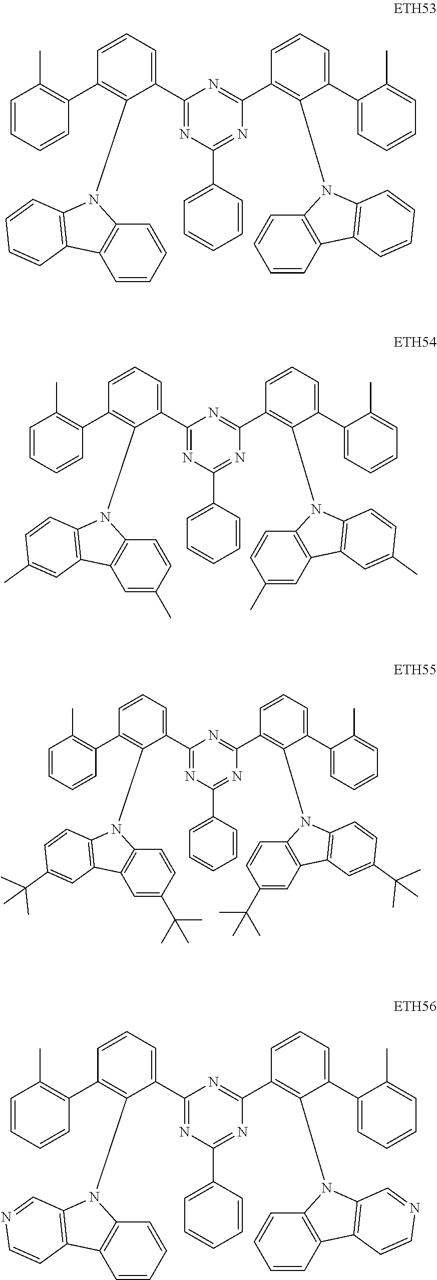

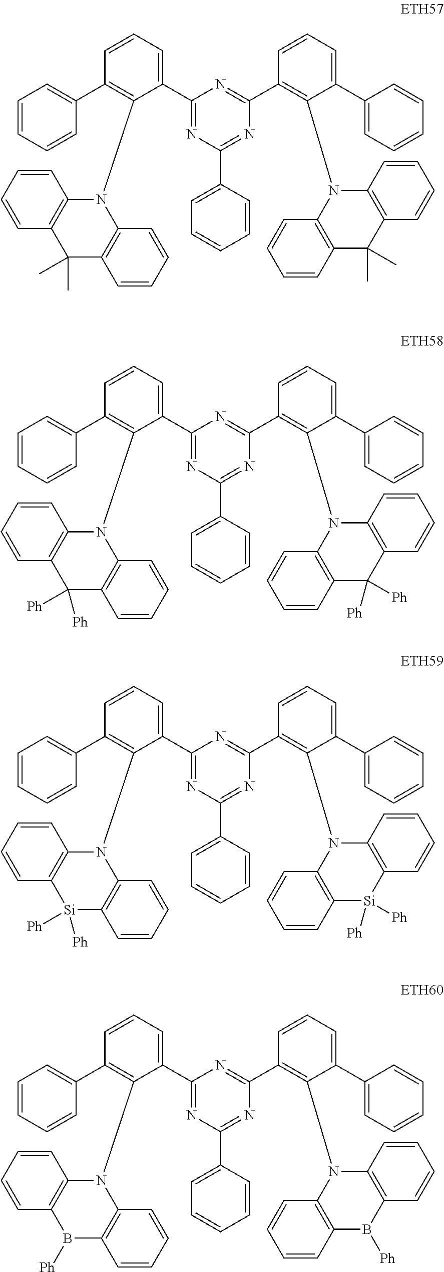

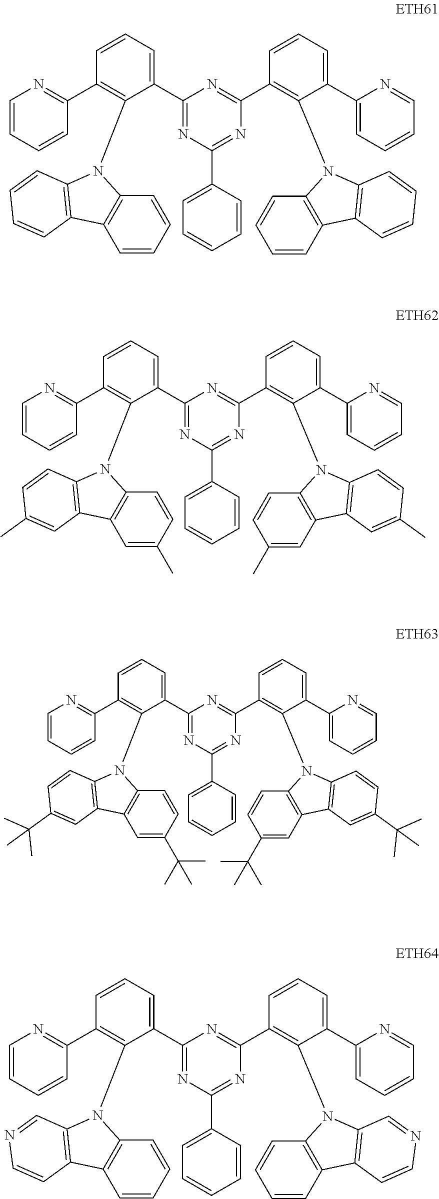

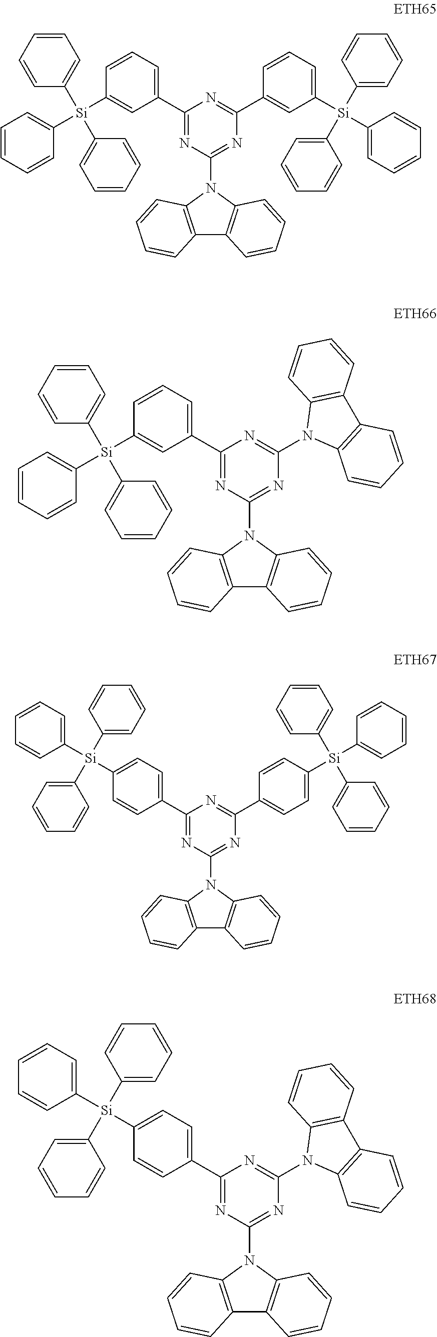 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

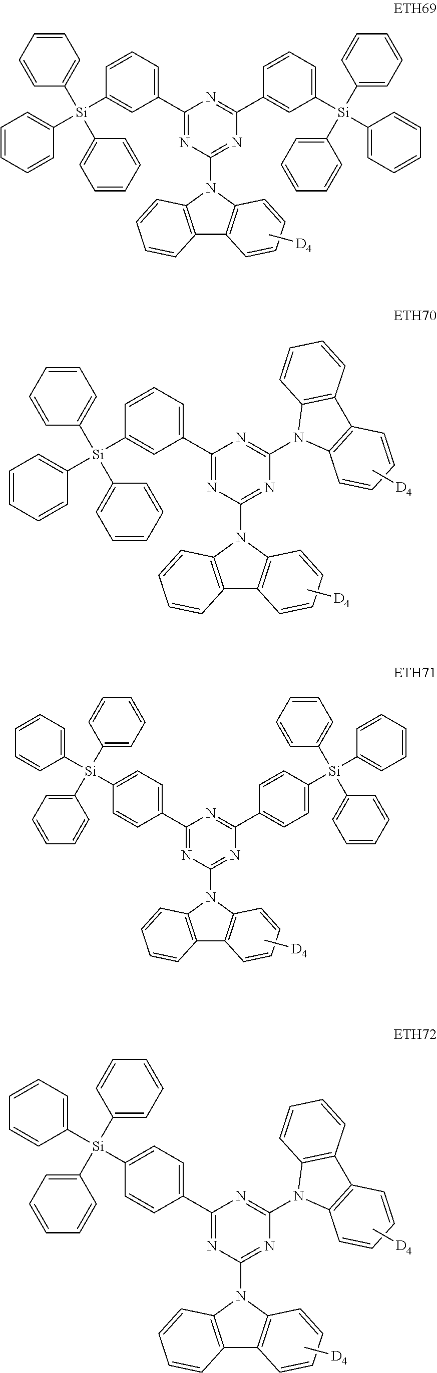

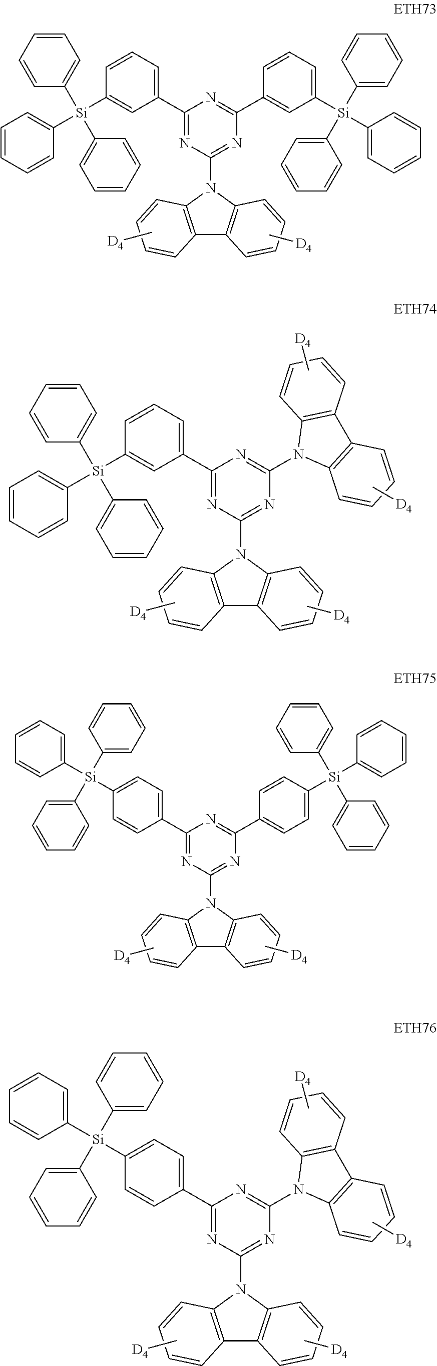

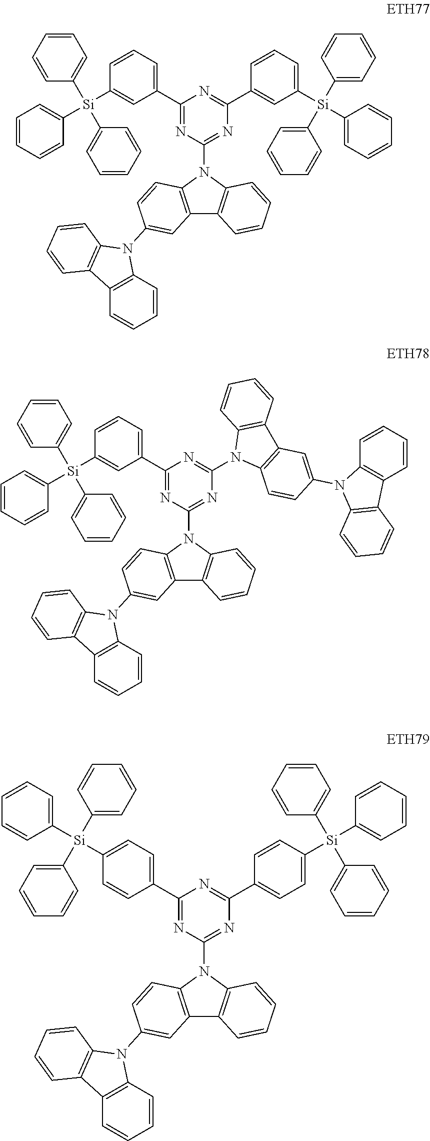 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

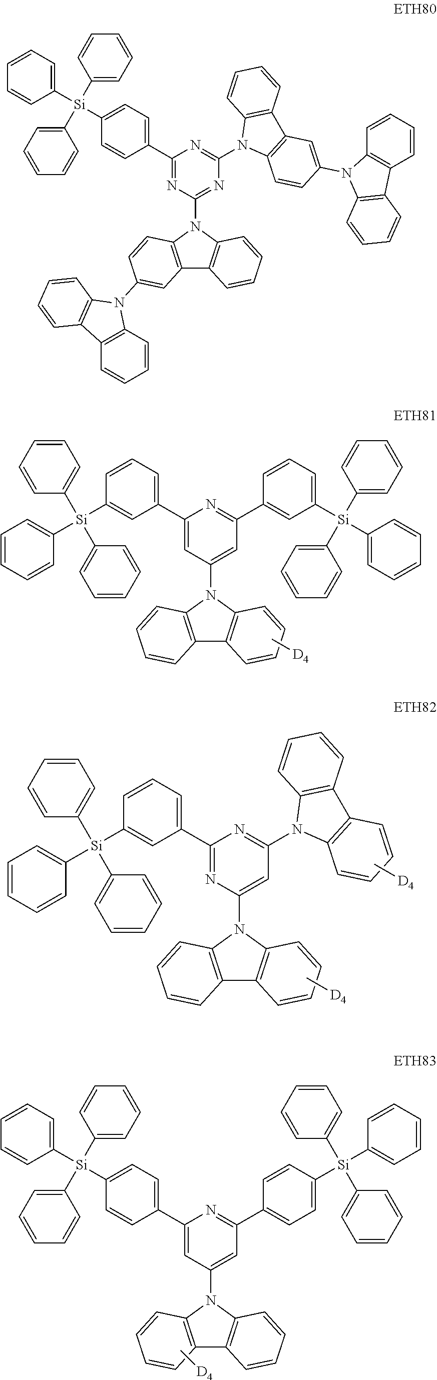

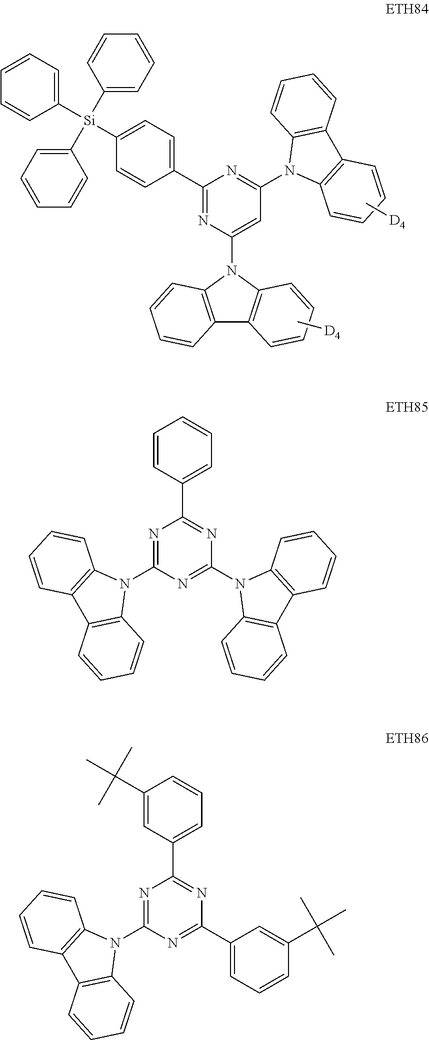

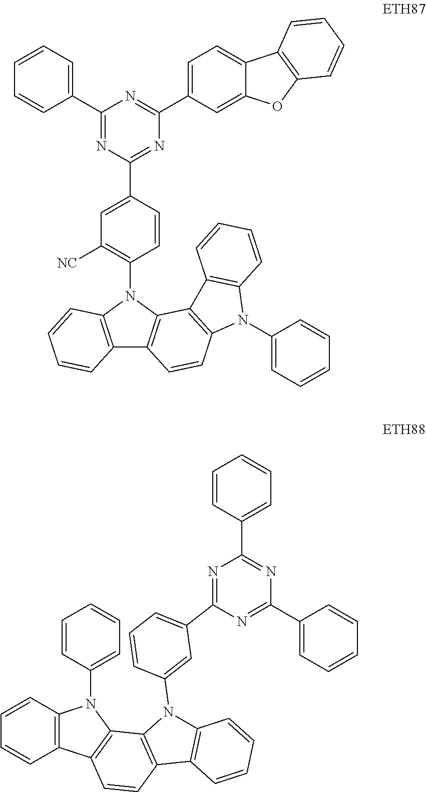 [SMILES: N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In the particular compounds suggested in Compound Group 3, “D” means a deuterium atom, and “Ph” means an unsubstituted phenyl group.

The emission layer EML may include the second compound and the third compound, and the second compound and the third compound may form an exciplex. In the emission layer EML, an exciplex may be formed by a hole transport host and an electron transport host. In this case, the triplet energy of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 eV to about 3.0 eV. In addition, the triplet energy of the exciplex may be a smaller value than the energy gap of each host material. The exciplex may have a triplet energy of about 3.0 eV or less, that is the energy gap between the hole transport host and the electron transport host.

In an embodiment, the emission layer EML may include a fourth compound in addition to the first compound to the third compound. The fourth compound may be used as a phosphorescence sensitizer of an emission layer EML. Since energy may transfer from the fourth compound to the first compound, light emission may arise.

For example, the emission layer EML may include an organometallic complex including platinum (Pt) as a central metal atom and ligands bonded to the central metal atom, as the fourth compound. In the light emitting device ED of an embodiment, the emission layer EML may include a compound represented by Formula D-1 as the fourth compound.

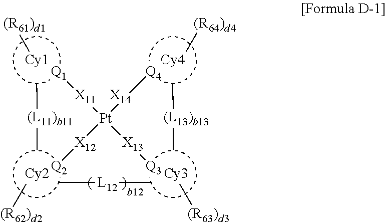

In Formula D-1, QC to Q 4 may be each independently C or N.

In Formula D-1, Q₁ or Q₃ may be C and the other N. Similarly, Q₂ or Q₄ may be C and the other N.

In Formula D-1, Cy1 to Cy4 may be each independently a substituted or unsubstituted hydrocarbon ring of 5 to 30 ring-forming carbon atoms, or a substituted or unsubstituted heterocycle of 2 to 30 ring-forming carbon atoms.

X₁₁ to X₁₄ may be each independently a direct linkage or

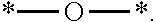

For example, any one of X₁ to X₁₄ may be

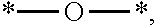

and the remainder may be direct linkages.

In Formula D-1, L₁₁, L₁₂, and L₁₃ may be each independently a direct linkage,

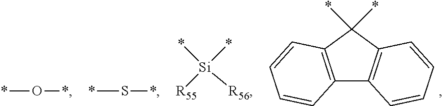

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁, L₁₂, and L₁₃, “ [symbol] ” means a part connected with Cy1 to Cy4.

In Formula D-1, b11 to b1e3 may be each independently 0 or 1. If b11 is 0, Cy1 and Cy2 may be unconnected. If b12 is 0, Cy2 and Cy3 may be unconnected. If b3 is 0, Cy3 and Cy4 may be unconnected.

In Formula D-1, R₆₁ to R₆₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. Otherwise, each of R₆₁ to R₆₆ may be combined with an adjacent group to form a ring. R₆₁ to R₆₆ may be each independently a substituted or unsubstituted methyl group, or a substituted or unsubstituted t-butyl group.

In Formula D-1, d1 to d4 are each independently an integer of 0 to 4. In Formula D-1, if d1 to d4 are 0, the fourth compound may be unsubstituted with R₆₁ to R₆₄, respectively. A case where d1 to d4 are 4, and R₆₁ to R₆₄ are hydrogen atoms, may be the same as a case where d1 to d4 are 0. If d1 to d4 are integers of 2 or more, each of multiple R₆₁ to R₆₄ may be all the same, or at least one among multiple R₆₁ to R₆₄ may be different.

In Formula D-1, Cy1 to Cy4 may be each independently a substituted or unsubstituted hydrocarbon ring or a substituted or unsubstituted heterocycle, represented by any one among C-1 to C-4 below.

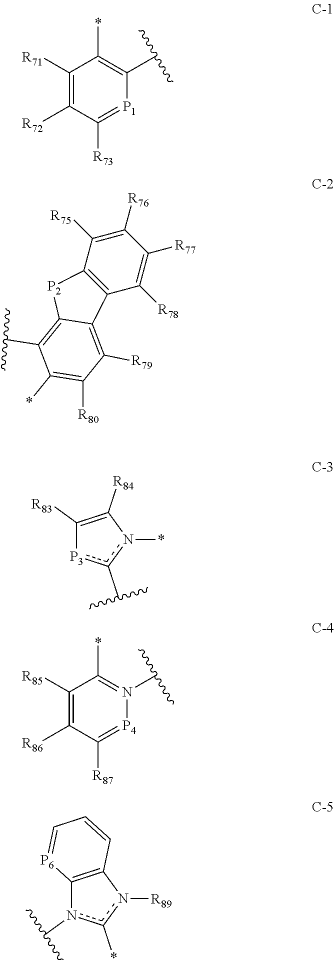

In C-1 to C-4, P₁ may be

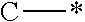 [SMILES: *C]

or CR₇₄, P₂ may be

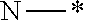 [SMILES: *N]

or NR₈₁, P₃ may be

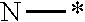 [SMILES: *N]

or NR₈₂, P₄ may be

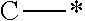 [SMILES: *C]

or CR₈₈, and P₆ may be

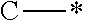 [SMILES: *C]

or CR₉₀. R₇₁ to R₉₀ may be each independently a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In addition, in C-1 to C-4,

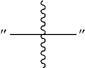

is a part connected with a central metal atom of Pt, and “ [symbol] ” corresponds to a part connected with an adjacent ring group (Cy1 to Cy4) or linker (L₁₁ to L₁₃).

The emission layer EML of an embodiment may include the first compound that is a fused polycyclic compound, and at least one among the second to fourth compounds. For example, the emission layer EML may include the first compound, the second compound and the third compound. In the emission layer EML, the second compound and the third compound may form exciplex, and in the exciplex, energy transfer to the first compound may arise, and light emission may arise.

In addition, the emission layer EML may include the first compound, the second compound, the third compound and the fourth compound. In the emission layer EML, the second compound and the third compound may form exciplex, and in the exciplex, energy transfer to the fourth compound and the first compound may arise, and light emission may arise. In an embodiment, the fourth compound may be a sensitizer. In the light emitting device ED of an embodiment, the fourth compound included in the emission layer EML may act as a sensitizer and may play the role of transferring energy from a host to the first compound that is a light emitting dopant. That is, the fourth compound that plays the role of an auxiliary dopant may accelerate energy transfer to the first compound that is a light emitting dopant and increase the light emitting ratio of the first compound. Accordingly, the emission efficiency of the emission layer EML of an embodiment may be improved. In addition, if the energy transfer to the first compound increases, excitons formed in the emission layer EML may not be accumulated but rapidly emit light, and the deterioration of a device may be reduced. Accordingly, the lifetime of the light emitting device ED of an embodiment may increase.

The light emitting device ED of an embodiment includes all of the first compound, the second compound, the third compound and the fourth compound, and the emission layer EML may include the combination of two host materials and two dopant materials. In the light emitting device ED of an embodiment, the emission layer EML may include the second compound and the third compound, which are two different hosts, the first compound which emits delayed fluorescence, and the fourth compound including an organometallic complex, simultaneously, and may show excellent emission efficiency properties.

In an embodiment, the fourth compound represented by Formula D-1 may be represented by at least one of the compounds represented in Compound Group 4. The emission layer EML may include at least one of the compounds represented in Compound Group 4 as a sensitizer material.

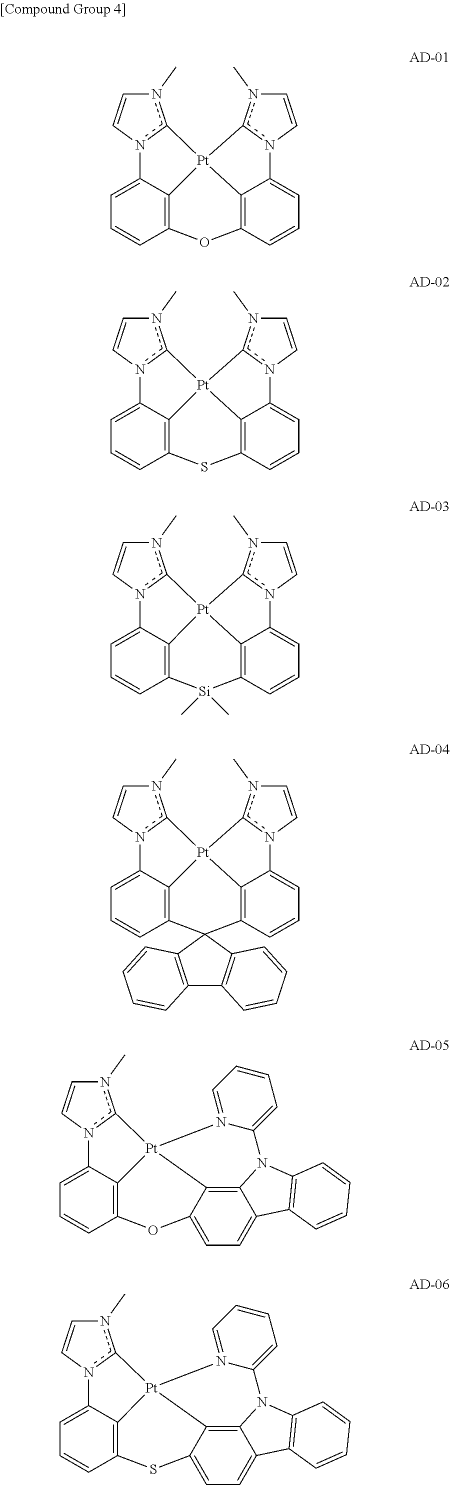

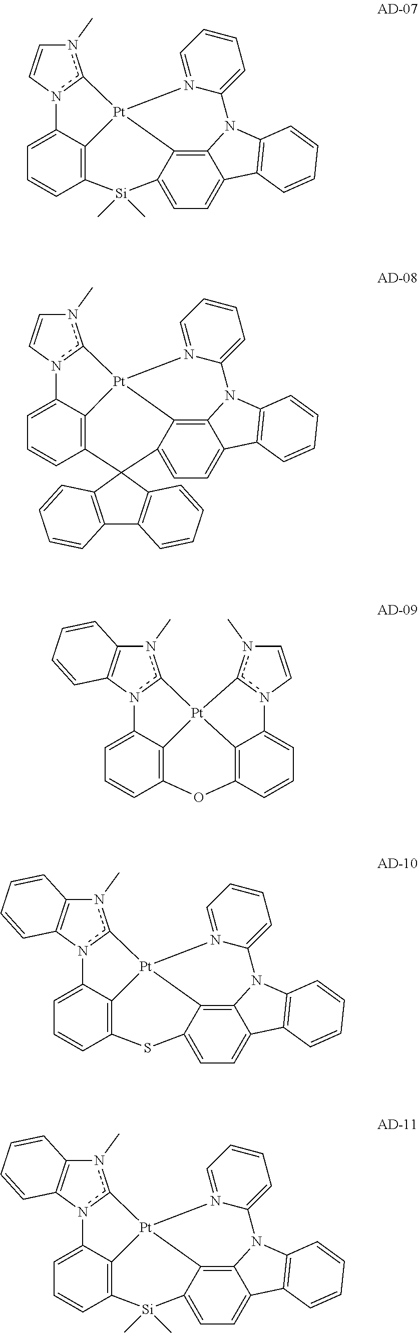

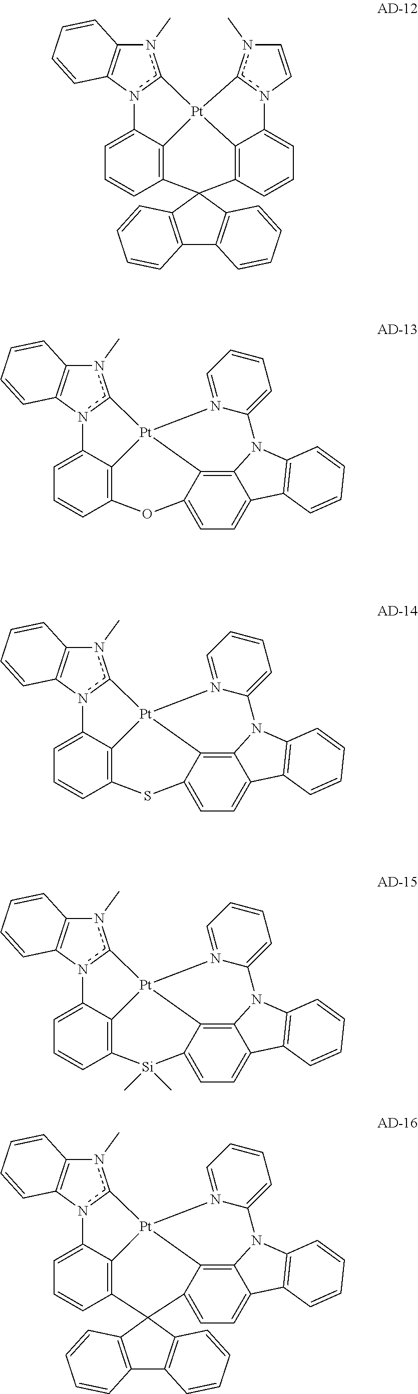

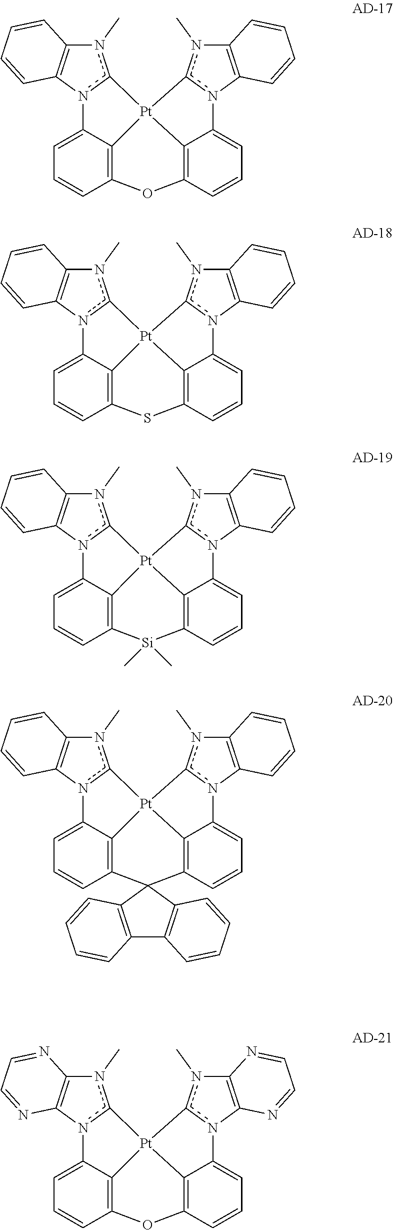

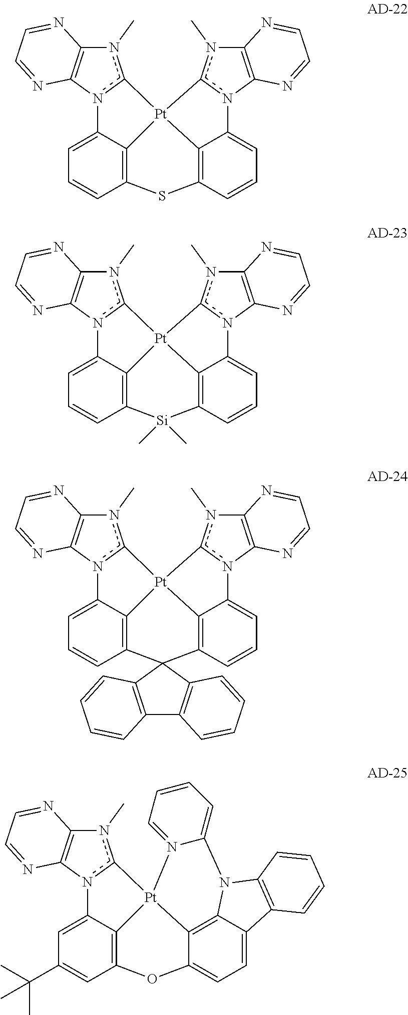

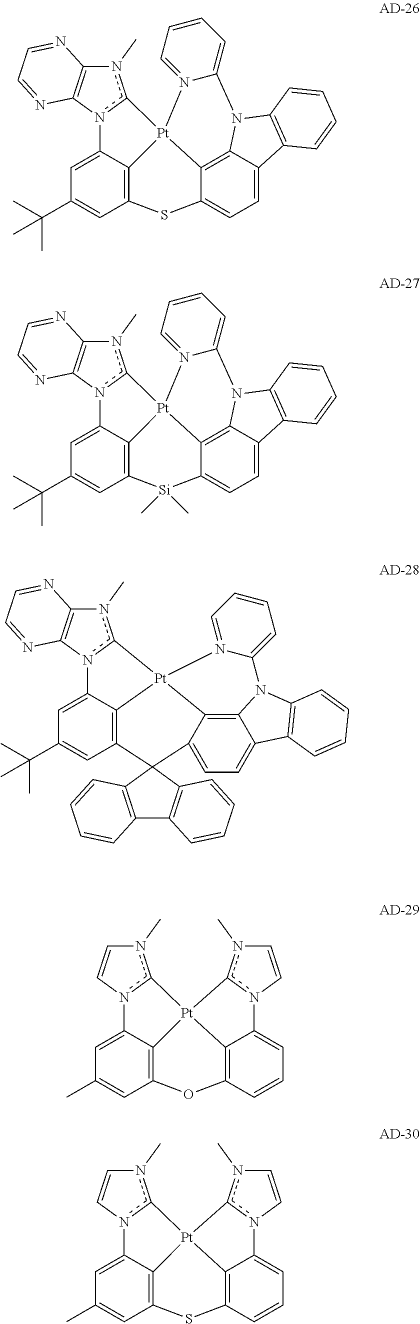

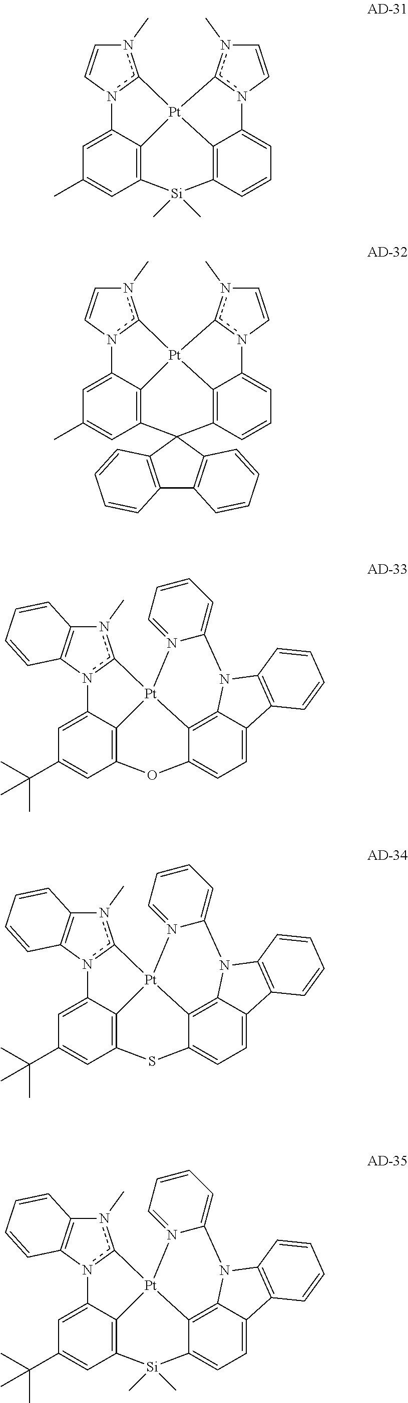

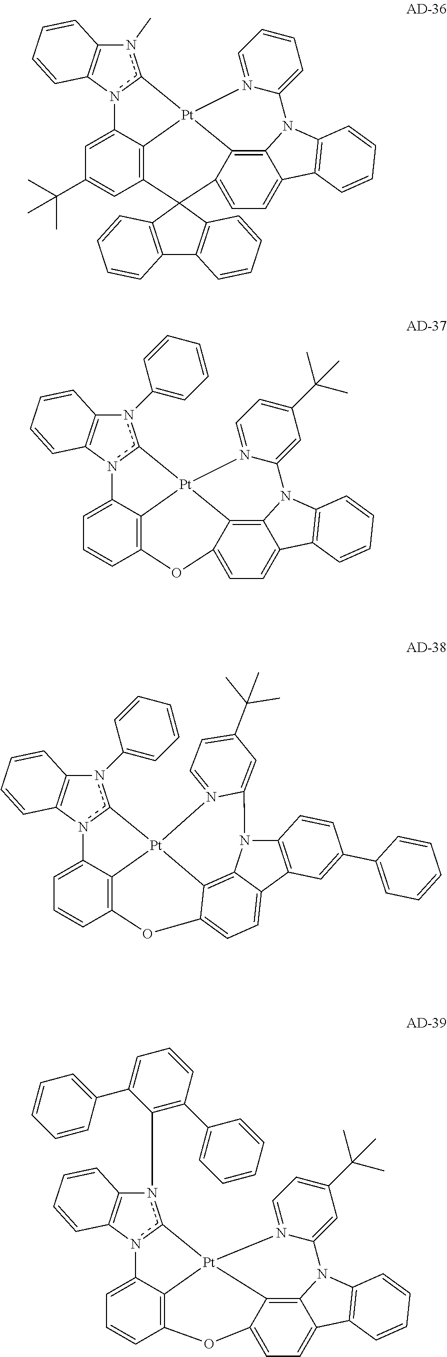

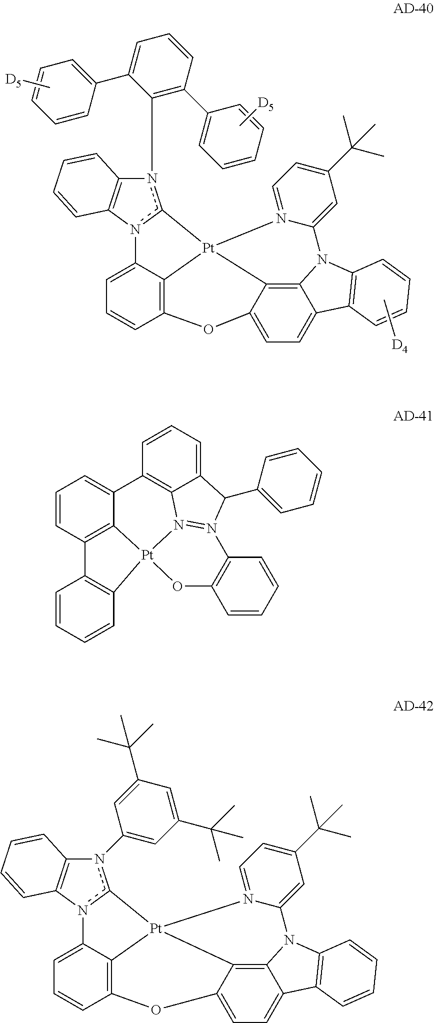

In the particular compounds suggested in Compound Group 4, “D” means a deuterium atom.

The light emitting device ED of an embodiment may include multiple emission layers. Multiple emission layers may be stacked in order and provided, and for example, a light emitting device ED including multiple emission layers may emit white light. The light emitting device including multiple emission layers may be a light emitting device of a tandem structure. If the light emitting device ED includes multiple emission layers, at least one emission layer EML may include the first compound represented by Formula 1 of an embodiment. In addition, if the light emitting device ED includes multiple emission layers, at least one emission layer EML may include all the first, second, third and fourth compounds as described above.

In the light emitting device ED of an embodiment, if the emission layer EML includes all the first, second, and third compounds, the amount of the first compound may be about 0.1 wt % to about 5 wt % based on the total weight of the first, second, and third compounds. However, an embodiment is not limited thereto. If the amount of the first compound satisfies the above-described ratio, energy transfer from the second compound and the third compound to the first compound may increase, and accordingly, the emission efficiency and device lifetime may increase.

In the emission layer EML, the total amount of the second compound and the third compound may be the remaining amount excluding the amount of the first compound. For example, the total amount of the second compound and the third compound may be about 65 wt % to about 95 wt % based on the total weight of the first compound, the second compound and the third compound.

In regard to an amount of the second compound and the third compound, a weight ratio of the second compound and the third compound may be about 3:7 to about 7:3.

If the total amount of the second compound and the third compound satisfies the above weight ratio, charge balance properties in the emission layer EML may be improved, and emission efficiency and device lifetime may be improved. If the total amount of the second compound and the third compound deviates from the above weight ratio, charge balance in the emission layer EML may decrease, emission efficiency may be degraded, and the device may be easily deteriorated.

If the emission layer EML includes the fourth compound, the amount of the fourth compound may be about 4 wt % to 30 wt % based on the total weight of the first compound, the second compound, the third compound and the fourth compound in the emission layer EML. However, an embodiment is not limited thereto. If the amount of the fourth compound satisfies the above weight percent range, energy transfer from a host to the first compound that is a light emitting dopant may increase, and emission ratio may be improved. Accordingly, the emission efficiency of the emission layer EML may be improved. If the relative amounts of the first compound, the second compound, the third compound and the fourth compound, included in the emission layer EML satisfies the above-described weight percent range, excellent emission efficiency and/or long lifetime may be achieved.

In the light emitting device ED of an embodiment, the emission layer EML may further include anthracene derivatives, pyrene derivatives, fluoranthene derivatives, chrysene derivatives, dihydrobenzanthracene derivatives, or triphenylene derivatives. Particularly, the emission layer EML may include anthracene derivatives or pyrene derivatives.

In the light emitting devices ED of embodiments, for example, light emitting devices shown in FIG. 3 to FIG. 6, the emission layer EML may further include known hosts and dopants in addition to the above-described host and dopant. For example, the emission layer EML may include a compound represented by Formula E-1 below. The compound represented by Formula E-1 below may be used as a fluorescence host material.

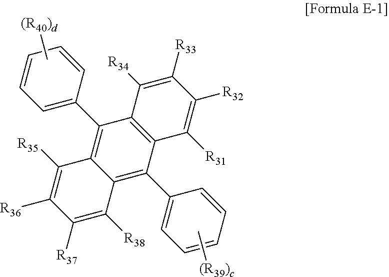

In Formula E-1, R₃₁ to R₄₃ may be each independently a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. Meanwhile, R₃₁ to R₄₀ may be combined with an adjacent group to form a saturated hydrocarbon ring, an unsaturated hydrocarbon ring, a saturated heterocycle or an unsaturated heterocycle. “c” and “d” may be each independently an integer of 0 to 5.

Formula E-1 may be represented by a compound of Compound E1 to Compound E19 below.

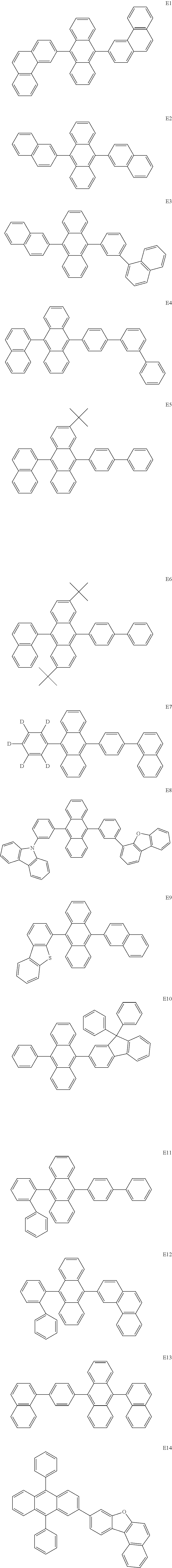

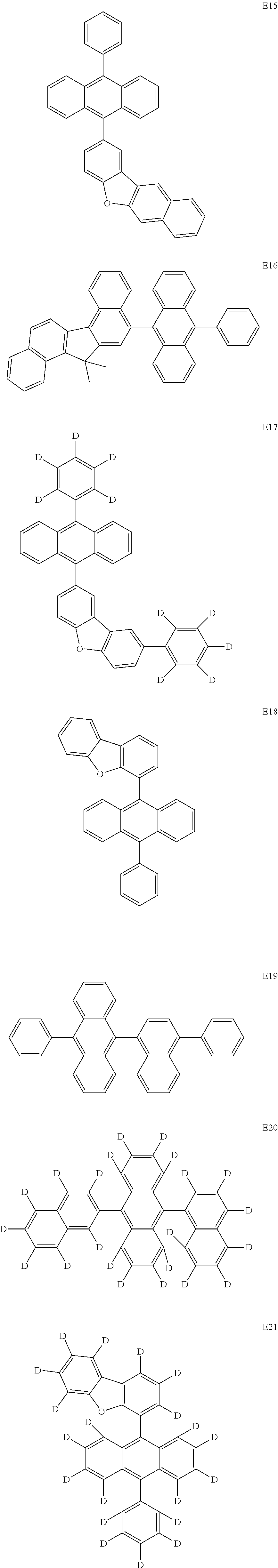

In an embodiment, the emission layer EML may include a compound represented by Formula E-2a or Formula E-2b below. The compound represented by Formula E-2a or Formula E-2b may be used as a host material in a phosphorescence emission layer.

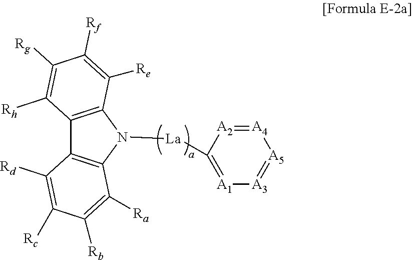

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. Meanwhile, if “a” is an integer of 2 or more, multiple Lₐ may be each independently a substituted or unsubstituted arylene group of 6 to 30 ring-forming carbon atoms, or a substituted or unsubstituted heteroarylene group of 2 to 30 ring-forming carbon atoms.

In addition, in Formula E-2a, A₁ to A₅ may be each independently N or CRi. Rₐ to Rᵢ may be each independently a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, or the like as a ring-forming atom.

In an embodiment, for example, in the compounds of Formula E-2a, two or three selected from A₁ to A₅ may be N, and the remainder may be CRᵢ.

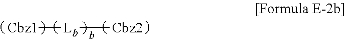

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, multiple L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one among the compounds in Compound Group E-2 below. However, the compounds shown in Compound Group E-2 are only illustrations, and the compound represented by Formula E-2a or Formula E-2b is not limited to the compounds represented in Compound Group E-2.

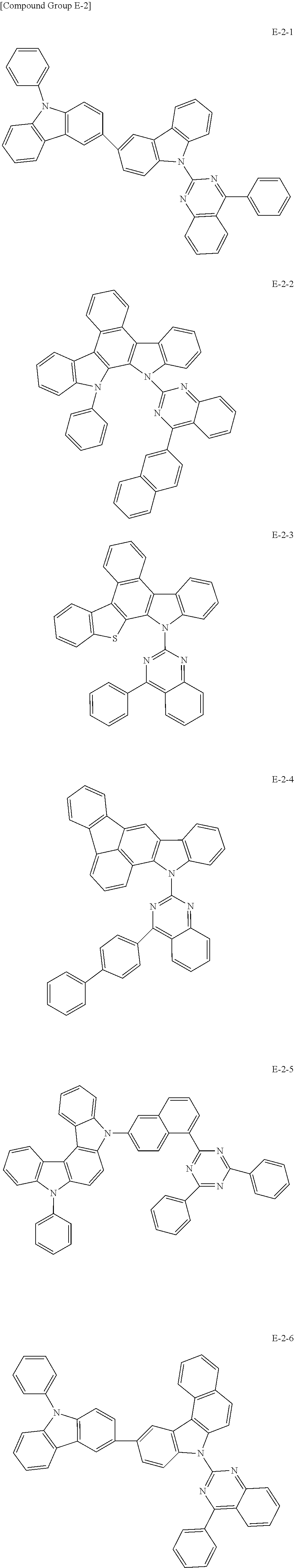

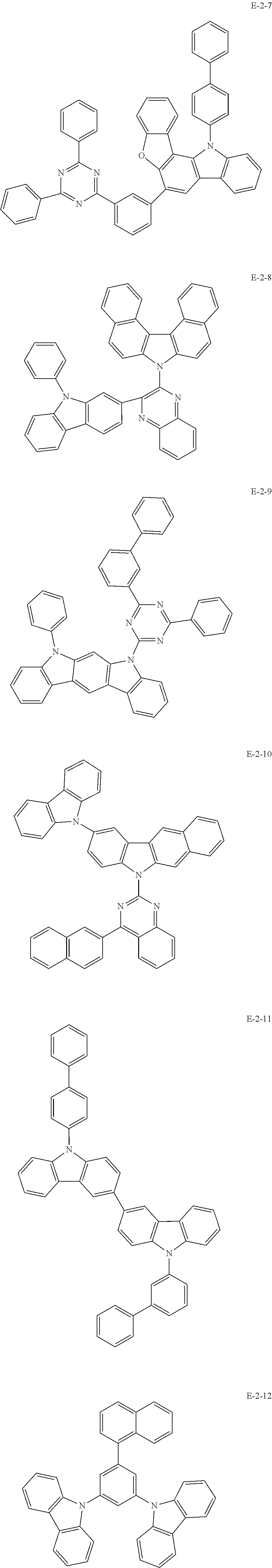

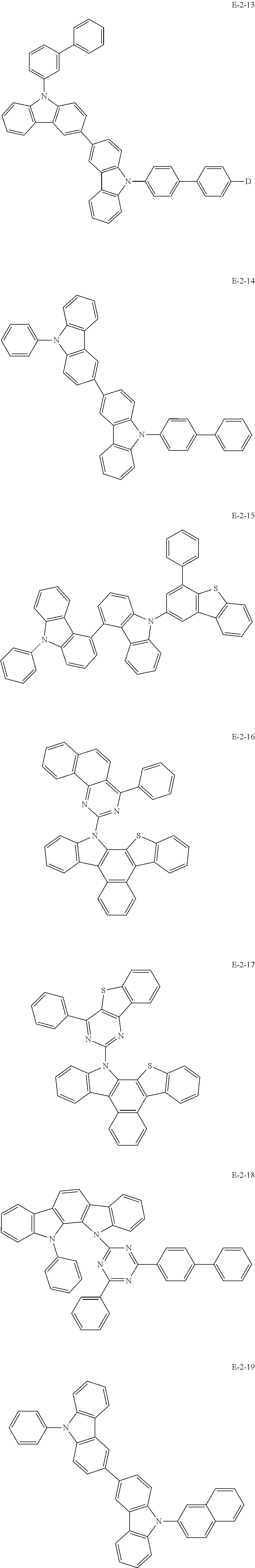

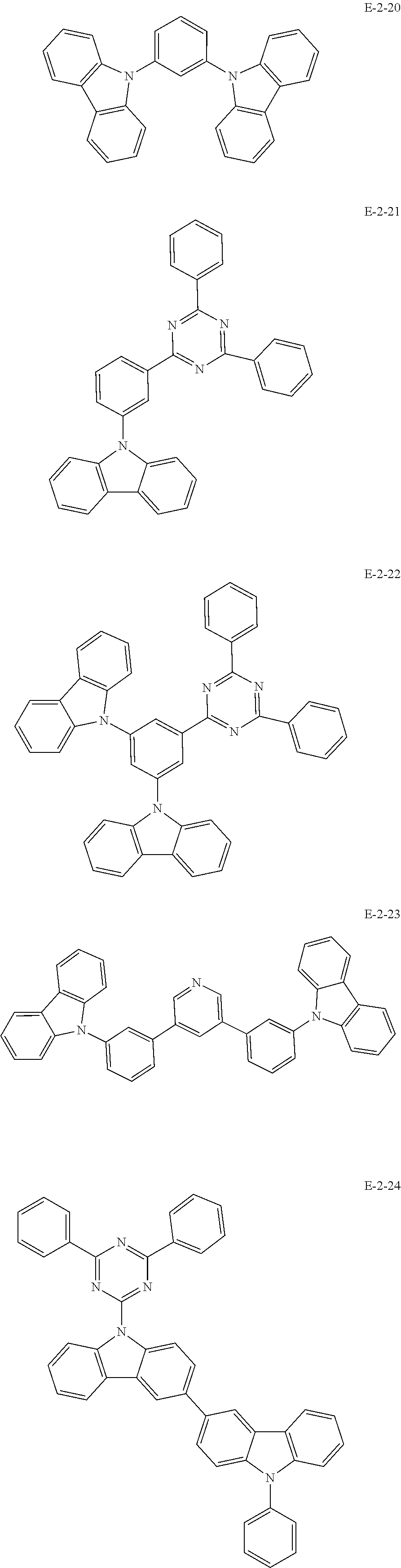 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material well-known in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the inventive concept is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), or the like may be used as the host material.

The emission layer EML may include a compound represented by Formula M-a below. The compound represented by Formula M-a may be used as a phosphorescence dopant material.

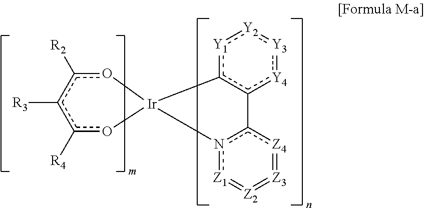

In Formula M-a, Y₁ to Y₄, and Zi to Z₄ may be each independently CR₁ or N, and R₁ to R₄ may be each independently a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, if “m” is 0, “n” is 3, and if “m” is 1, “n” is 2.

The compound represented by Formula M-a may be used as a phosphorescence dopant.

The compound represented by Formula M-a may be represented by any one among Compounds M-a1 to M-a25 below. However, Compounds M-a1 to M-a25 are illustrations, and the compound represented by Formula M-a is not limited to the compounds represented by Compounds M-a1 to M-a25 below.

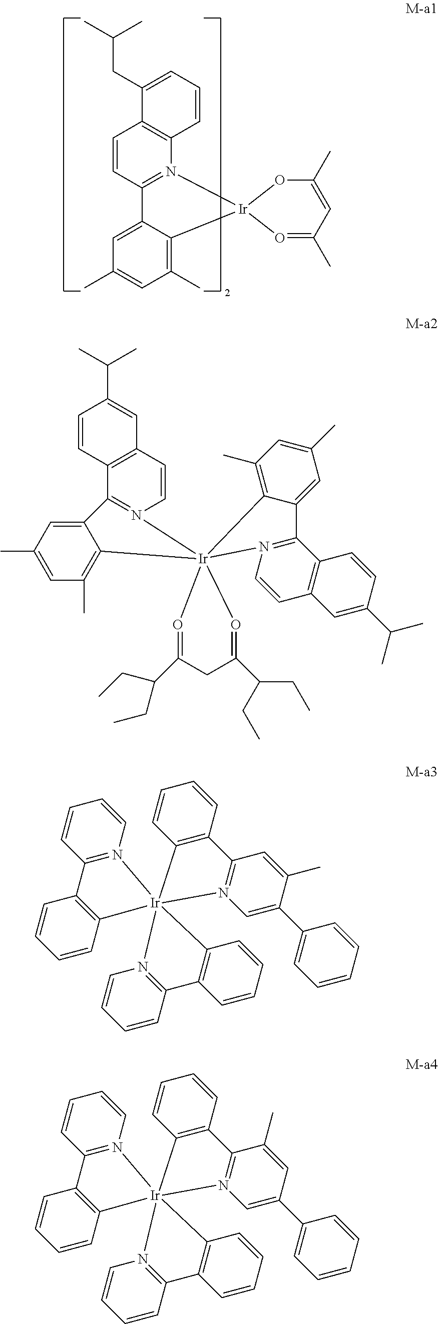

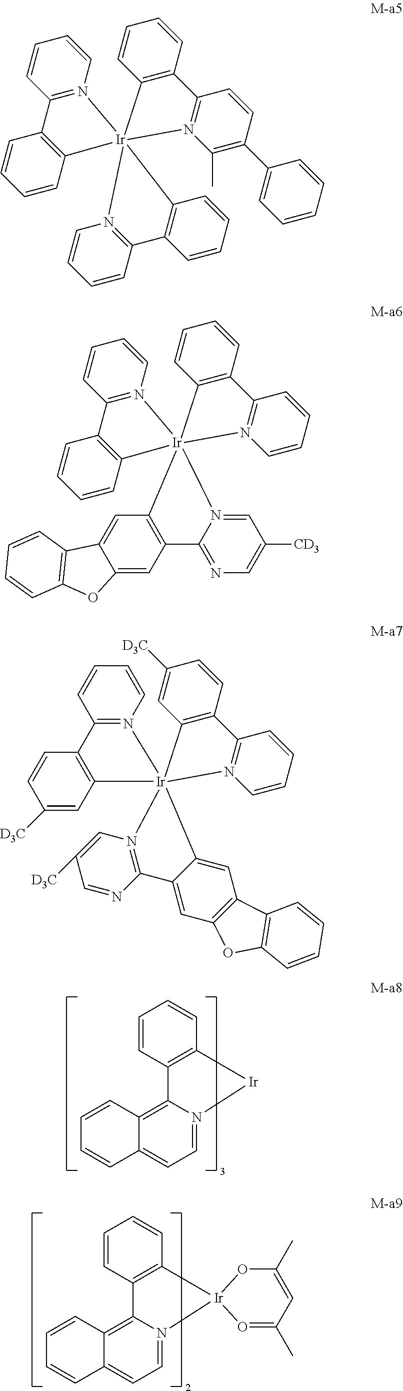

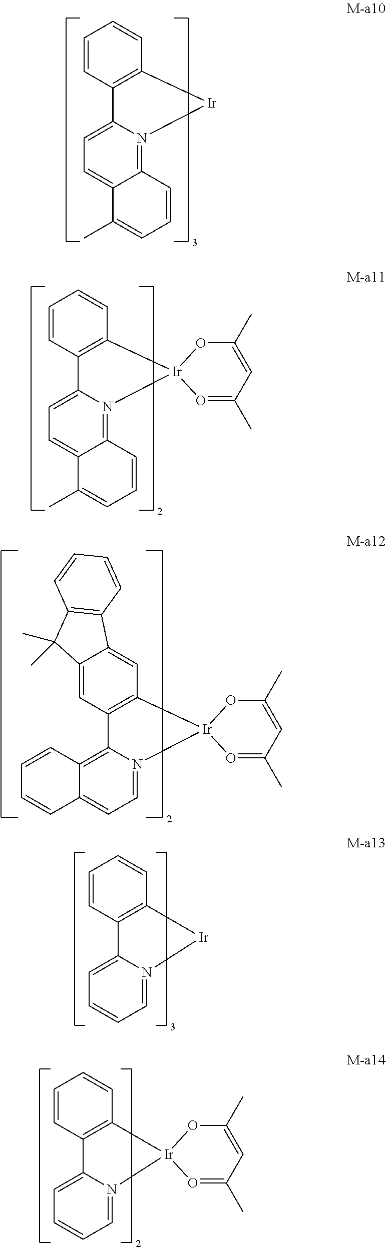

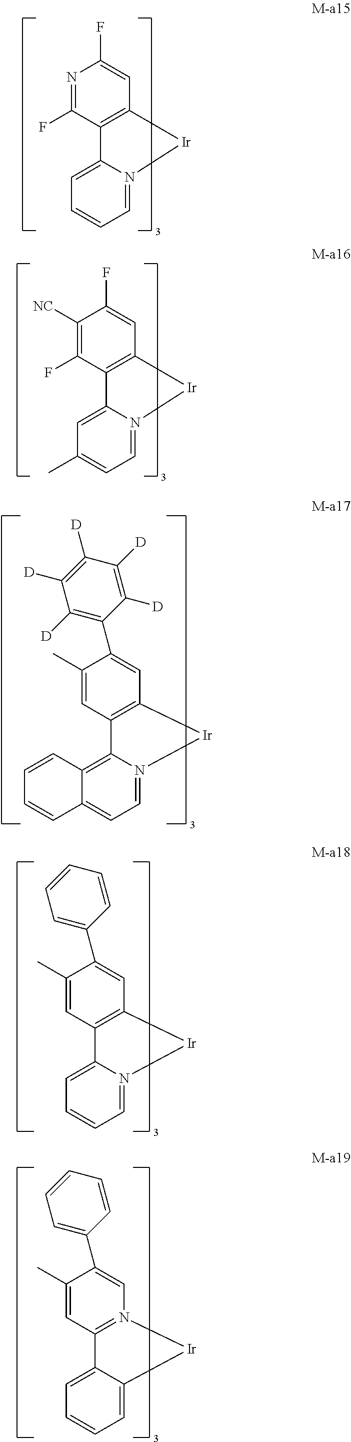

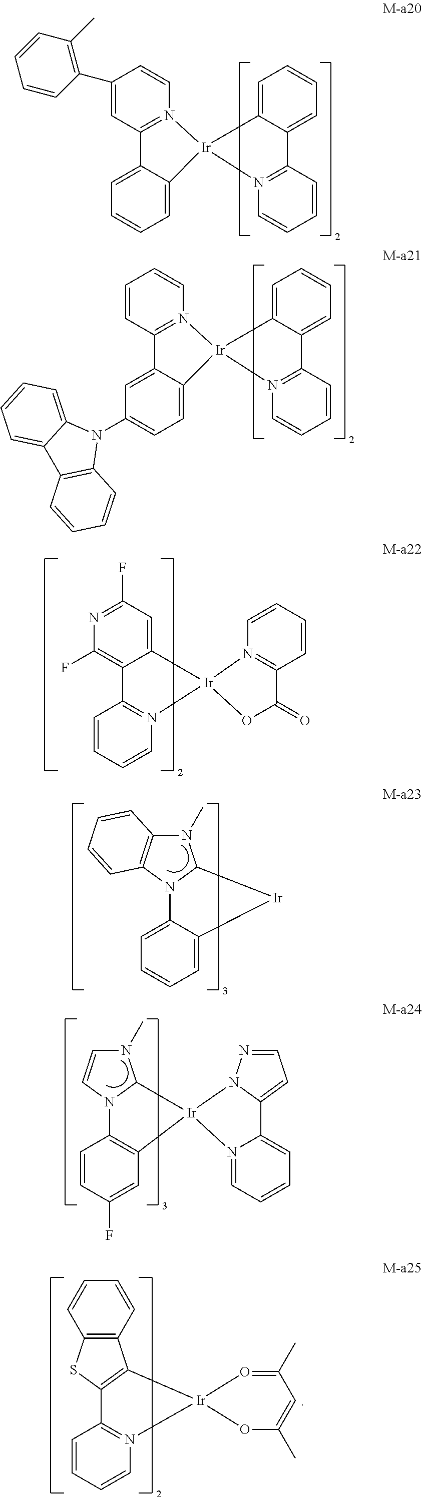

The emission layer EML may further include any one among Formula F-a to Formula F-c below. The compounds represented by Formula F-a to Formula F-c may be used as fluorescence dopant materials.

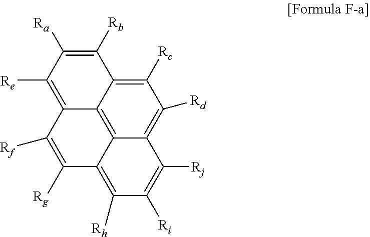

In Formula F-a, two selected from Rₐ to Rⱼ may be each independently substituted with

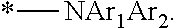

The remainder not substituted with

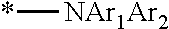

among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In

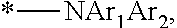

Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

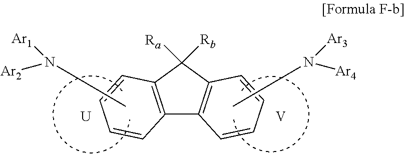

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms. At least one among Ar₁ to Ar₄ may be a heteroaryl group including O or S as a ring-forming atom.

In Formula F-b, the number of rings represented by U and V may be each independently 0 or 1. For example, in Formula F-b, if the number of U or V is 1, one ring forms a fused ring at the designated part by U or V, and if the number of U or V is 0, a ring is not present at the designated part by U or V. Particularly, if the number of U is 0, and the number of V is 1, or if the number of U is 1, and the number of V is 0, a fused ring having the fluorene core of Formula F-b may be a ring compound with four rings. In addition, if the number of both U and V is 0, the fused ring of Formula F-b may be a ring compound with three rings. In addition, if the number of both U and V is 1, a fused ring having the fluorene core of Formula F-b may be a ring compound with five rings.

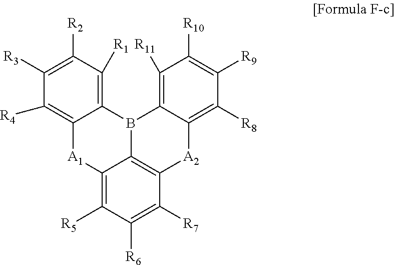

In Formula F-c, A₁ and A₂ may be each independently O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may be each independently combined with the substituents of an adjacent ring to form a fused ring. For example, if A₁ and A₂ may be each independently NRₘ, A₁ may be combined with R₄ or R₅ to form a ring. In addition, A₂ may be combined with R₇ or R₈ to form a ring.

In an embodiment, the emission layer EML may include as a known dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), or the like.

The emission layer EML may include a known phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). Particularly, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, an embodiment of the inventive concept is not limited thereto.

The emission layer may include a quantum dot.

In the description, a quantum dot means a crystal of a semiconductor compound. The quantum dot may emit light of various emission wavelengths depending on the size of the crystal. The quantum dot may also emit light of various emission wavelengths by controlling the element ratio in the quantum dot compound.

The diameter of the quantum dot may be, for example, about 1 nm to 10 nm.

The quantum dot may be synthesized by a wet chemical process, an organic metal chemical vapor deposition process, a molecular beam epitaxy process, or a similar process.

The wet chemical process is a method of growing a quantum dot particle crystal after mixing an organic solvent and a precursor material. When the crystal grows, the organic solvent naturally acts as a dispersant coordinated to the surface of the quantum dot crystal and may control the growth of the crystal. Therefore, the wet chemical processes may control the growth of quantum dot particles through easier and less costly processes than vapor deposition methods such as metal organic chemical vapor deposition (MOCVD) or molecular beam epitaxy (MBE).

The emission layer EML of the inventive concept may include a quantum dot material. The core of the quantum dot may be selected from a II-VI group compound, a III-V group compound, a III-VI group compound, a I-III-VI group compound, a IV-VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. Meanwhile, the II-VI group semiconductor compound may further include a I group metal and/or a IV group element. The I-II-VI group compound may be selected from CuSnS or CuZnS, and the II-IV-VI group compound may be selected from ZnSnS, or the like. The I-II-IV-VI group compound may be selected from a quaternary compound selected from the group consisting of Cu₂ZnSnS₂, Cu₂ZnSnS₄, Cu₂ZnSnSe₄, Ag₂ZnSnS₂, and mixtures thereof.

The III-VI group compound may include a binary compound such as In₂S₃, and In₂Se₃, a ternary compound such as InGaS₃, and InGaSe₃, or arbitrary combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, or a quaternary compound such as AgInGaS₂, and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. Meanwhile, the III-V group compound may further include a II group metal. For example, InZnP, or the like may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

Examples of the II-IV-V group semiconductor compound may be a ternary compound selected from the group consisting of ZnSnP, ZnSnP₂, ZnSnAs₂, ZnGeP₂, ZnGeAs₂, CdSnP₂, CdGeP₂, and mixtures thereof.

The IV group element may be selected from the group consisting of Si, Ge, and mixtures thereof. The IV group compound may be a binary compound selected from the group consisting of SiC, SiGe, and mixtures thereof.

Each element included in the multi-element compound such as the binary compound, ternary compound, and quaternary compound may exist in the particle at a uniform concentration or a non-uniform concentration. That is, the chemical formula indicates the type of element included in the compound, and the element ratio in the compound may be different. For example, AgInGaS₂ may indicate AgInxGai-xS₂ (x is a real number between 0 and 1).

In this case, the binary compound, the ternary compound or the quaternary compound may be present at uniform concentration in a particle or may be present at a partially different concentration distribution state in the same particle. In addition, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a ternary compound such as MgAl₂O₄, CoFe₂O₄, NiFe₂O₄ and CoMn₂O₄, but an embodiment of the inventive concept is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but an embodiment of the inventive concept is not limited thereto.

The quantum dot may have a full width of half maximum (FWHM) of emission wavelength spectrum of about 45 nm or less, preferably, about 40 nm or less, more preferably, about 30 nm or less. Within this range, color purity or color reproducibility may be improved. In addition, light emitted via such quantum dot is emitted in all directions, and light view angle properties may be improved.

In addition, the shape of the quantum dot may be generally used shapes in the art, without specific limitation. More particularly, the shape of spherical, pyramidal, multi-arm, or cubic nanoparticle, nanotube, nanowire, nanofiber, nanoplate particle, or the like may be used.

Since the energy band gap of the quantum dots may be controlled by controlling the size of the quantum dots or the element ratio in the quantum dot compound, light of various wavelengths may be obtained from the quantum dot emission layer. Therefore, by using the quantum dots as described above (using quantum dots of different sizes or having different element ratios in the quantum dot compound), a light emitting device that emits light of various wavelengths may be achieved. Specifically, the size of the quantum dots or the element ratio in the quantum dot compound may be selected so that red, green, and/or blue light is emitted. In addition, the quantum dots may be configured to emit white light by combining light of various colors.

In the light emitting devices ED of embodiments, as shown in FIG. 3 to FIG. 6, the electron transport region ETR is provided on the emission layer EML. The electron transport region ETR may include at least one of a hole blocking layer HBL, an electron transport layer ETL or an electron injection layer EIL. However, an embodiment of the inventive concept is not limited thereto.

The electron transport region ETR may have a single layer formed using a single material, a single layer formed using multiple different materials, or a multilayer structure having multiple layers formed using multiple different materials.

For example, the electron transport region ETR may have a single layer structure of an electron injection layer EIL or an electron transport layer ETL, or a single layer structure formed using an electron injection material and an electron transport material. Further, the electron transport region ETR may have a single layer structure formed using multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2 below.

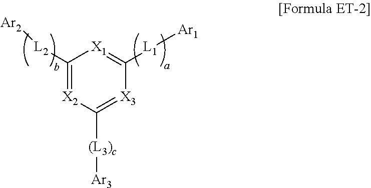

In Formula ET-2, at least one among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may be each independently an integer of 0 to 10. In Formula ET-2, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. Meanwhile, if “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the inventive concept is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), 4′-(4-(4-(4,6-diphenyl-1,3,5-triazin-2-yl)phenyl)naphthalen-1-yl)-[1,1′-biphenyl]-4-carbonitrile (CNNPTRZ), and mixtures thereof, without limitation.

In an embodiment, the electron transport region ETR may include any one among the compounds in Compound Group 3.

The electron transport region ETR may include at least one among Compounds ET1 to ET36 below.

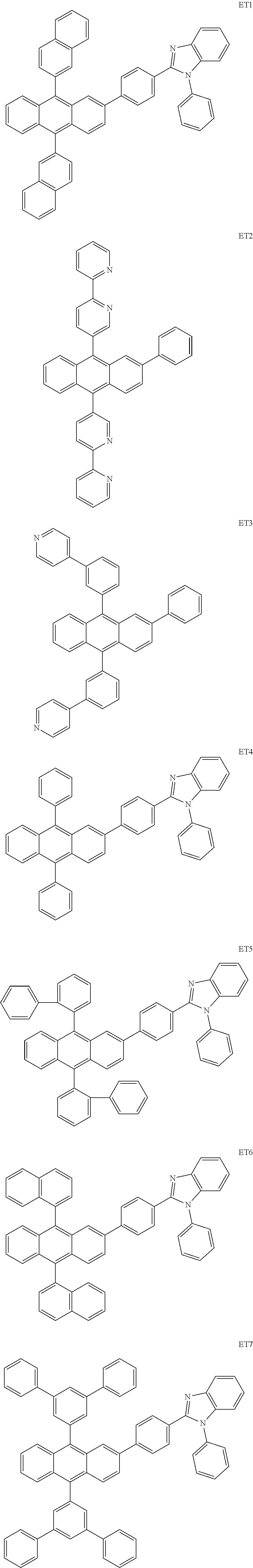

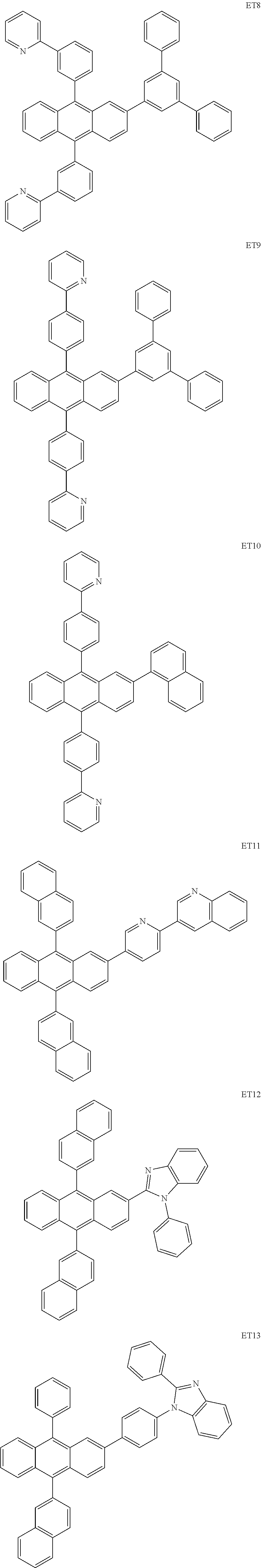

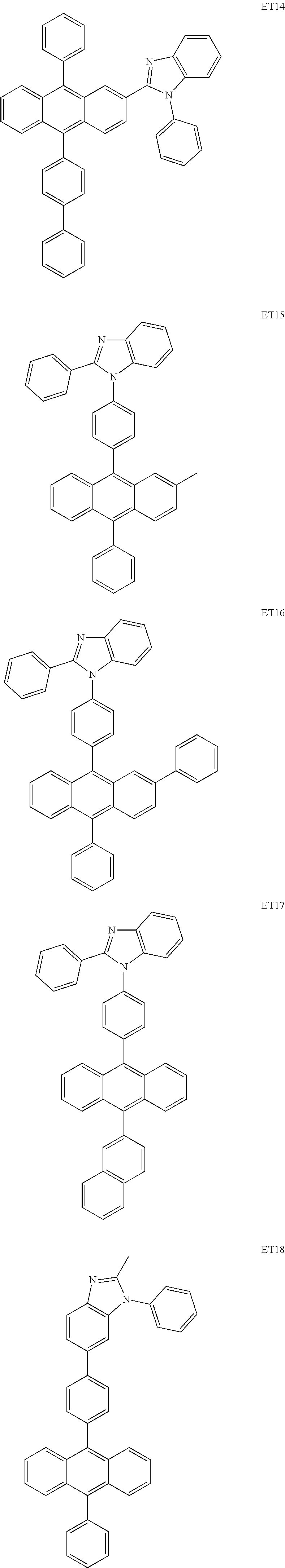

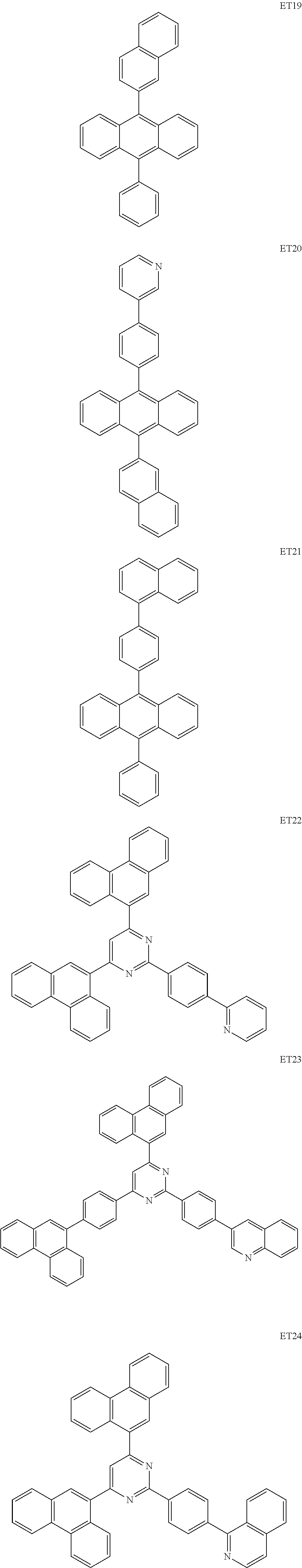

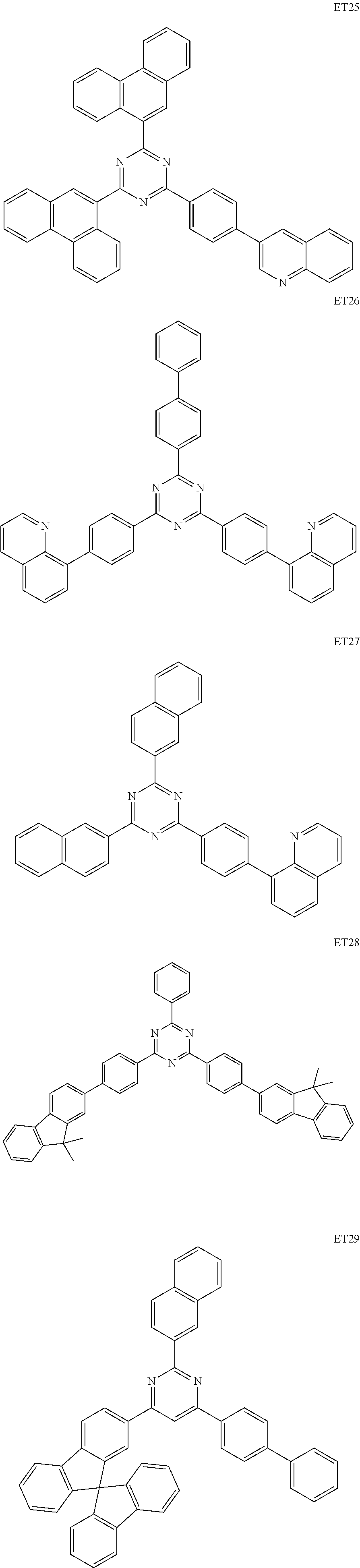 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

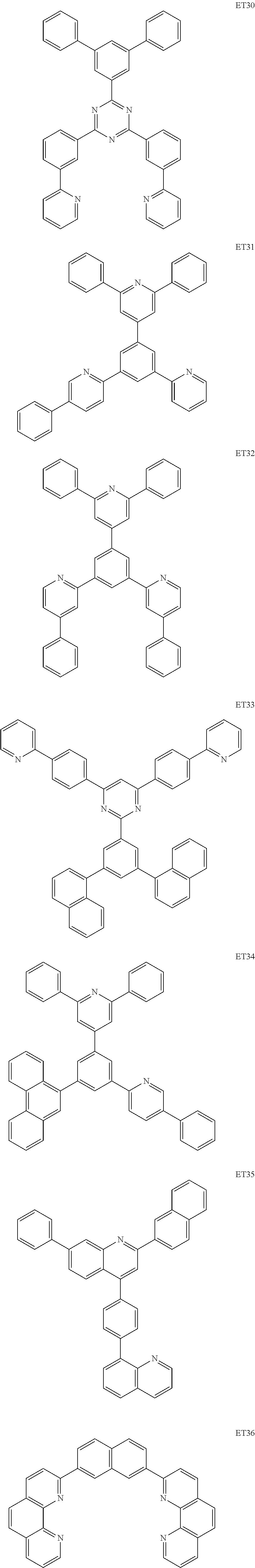

In addition, the electron transport region ETR may include a metal halide such as LiF, NaCl, CsF, RbCl, RbI, CuI and KI, a metal in lanthanoides such as Yb, or a co-depositing material of the metal halide and the metal in lanthanoides. For example, the electron transport region ETR may include KI:Yb, RbI:Yb, LiF:Yb, or the like, as the co-depositing material. Meanwhile, the electron transport region ETR may use a metal oxide such as Li₂O and BaO, or 8-hydroxy-lithium quinolate (Liq). However, an embodiment of the inventive concept is not limited thereto. The electron transport region ETR also may be formed using a mixture material of an electron transport material and an insulating organometal salt. The organometal salt may be a material having an energy band gap of about 4 eV or more. Particularly, the organometal salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the inventive concept is not limited thereto.

The electron transport region ETR may include the compounds of the electron transport region in at least one among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If the thickness of the electron transport layer ETL satisfies the above-described range, satisfactory electron transport properties may be obtained without substantial increase of a driving voltage. If the electron transport region ETR includes the electron injection layer EIL, the thickness of the electron injection layer EIL may be from about 1 Å to about 100 Å, and from about 3 Å to about 90 Å. If the thickness of the electron injection layer EIL satisfies the above described range, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but an embodiment of the inventive concept is not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is the transmissive electrode, the second electrode EL2 may include a transparent metal oxide, for example, ITO (indium tin oxide), IZO (indium zinc oxide), ZnO (zinc oxide), ITZO (indium tin zinc oxide), or the like.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, or MgYb). Otherwise, the second electrode EL2 may have a multilayered structure including a reflective layer or a transflective layer formed using the above-described materials and a transparent conductive layer formed using ITO, IZO, ZnO, ITZO, or the like. For example, the second electrode EL2 may include the aforementioned metal materials, combinations of two or more metal materials selected from the aforementioned metal materials, or oxides of the aforementioned metal materials.

Though not shown, the second electrode EL2 may be connected with an auxiliary electrode. If the second electrode EL2 is connected with the auxiliary electrode, the resistance of the second electrode EL2 may decrease.

Meanwhile, on the second electrode EL2 in the light emitting device ED of an embodiment, a capping layer CPL may be further disposed. The capping layer CPL may include a multilayer or a single layer.

In an embodiment, the capping layer CPL may be an organic layer or an inorganic layer. For example, if the capping layer CPL includes an inorganic material, the inorganic material may include an alkali metal compound such as LiF, an alkaline earth metal compound such as MgF₂, SiON, SiNx, SiOy, or the like.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), or the like, or includes an epoxy resin, or acrylate such as methacrylate. In addition, a capping layer CPL may include at least one among Compounds P1 to P5 below, but an embodiment of the inventive concept is not limited thereto.

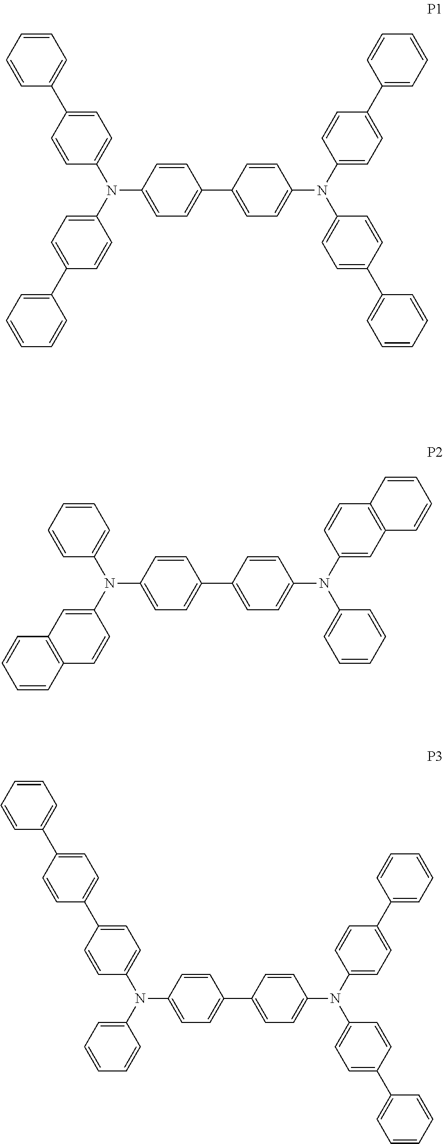 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

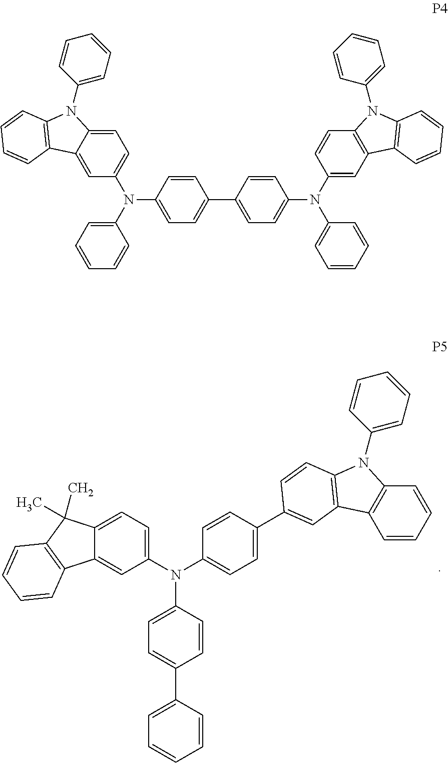 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

Meanwhile, the refractive index of the capping layer CPL may be about 1.6 or more. Particularly, the refractive index of the capping layer CPL with respect to light in a wavelength range of about 550 nm to about 660 nm may be about 1.6 or more.

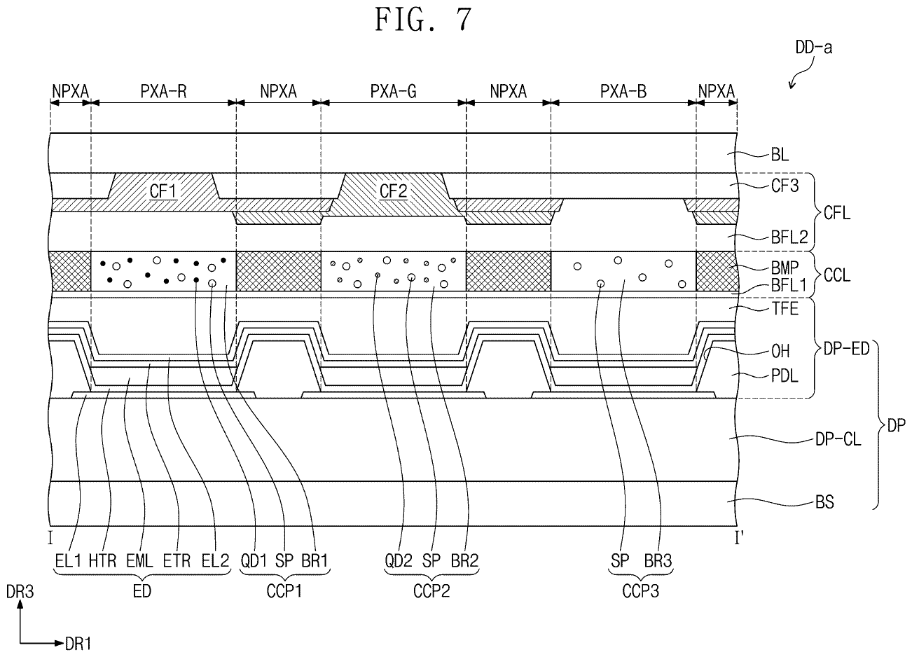

FIG. 7 to FIG. 10 are cross-sectional views of display devices according to embodiments. In the explanation on the display devices of embodiments referring to FIG. 7 to FIG. 10, the overlapping parts with the explanation on FIG. 1 to FIG. 6 will not be explained again, and instead, the different features will be explained chiefly.

Referring to FIG. 7, a display device DD-a according to an embodiment may include a display panel DP including a display device layer DP-ED, a light control layer CCL disposed on the display panel DP and a color filter layer CFL. In an embodiment shown in FIG. 7, the display panel DP includes a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The same structures as the light emitting devices of FIG. 3 to FIG. 6 may be applied to the structure of the light emitting device ED shown in FIG. 7.

In the display device DD-a according to an embodiment, the emission layer EML of the light emitting device ED included may include the fused polycyclic compound of an embodiment.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may emit light in the same wavelength range. In the display device DD-a of an embodiment, the emission layer EML may emit blue light. Meanwhile, different from the drawing, in an embodiment, the emission layer EML may be provided as a common layer for all luminous areas PXA-R, PXA-G and PXA-B.

The light control layer CCL may be disposed on the display panel DP. The light control layer CCL may include a light converter. The light converter may be a quantum dot or a phosphor. The light converter may transform the wavelength of light provided and then emit. That is, the light control layer CCL may be a layer including a quantum dot or a layer including a phosphor.

The light control layer CCL may include multiple light control parts CCP1, CCP2 and CCP3. The light control parts CCP1, CCP2 and CCP3 may be separated from one another.

Referring to FIG. 7, a partition pattern BMP may be disposed between the separated light control parts CCP1, CCP2 and CCP3, but an embodiment of the inventive concept is not limited thereto. In FIG. 7, the partition pattern BMP is shown not to be overlapped with the light control parts CCP1, CCP2 and CCP3, but at least a portion of the edge of the light control parts CCP1, CCP2 and CCP3 may be overlapped with the partition pattern BMP.

The light control layer CCL may include a first light control part CCP1 including a first quantum dot QD1 converting first color light provided from the light emitting device ED into second color light, a second light control part CCP2 including a second quantum dot QD2 converting the first color light into third color light, and a third light control part CCP3 transmitting the first color light. In an embodiment, the first light control part CCP1 may provide red light which is the second color light, and the second light control part CCP2 may provide green light which is the third color light. The third color control part CCP3 may transmit and provide blue light which is the first color light provided from the light emitting device ED. For example, the first quantum dot QD1 may be a red quantum dot, and the second quantum dot QD2 may be a green quantum dot. On the quantum dots QD1 and QD2, the same contents as those described above may be applied.

In addition, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but include the scatterer SP.

The scatterer SP may be an inorganic particle. For example, the scatterer SP may include at least one among TiO₂, ZnO, Al₂O₃, SiO₂, and hollow silica. The scatterer SP may include at least one among TiO₂, ZnO, Al₂O₃, SiO₂, and hollow silica or may be a mixture of two or more materials selected among TiO₂, ZnO, Al₂O₃, SiO₂, and hollow silica.

Each of the first light control part CCP1, the second light control part CCP2, and the third light control part CCP3 may include base resins BR1, BR2 and BR3 dispersing the quantum dots QD1 and QD2 and the scatterer SP. In an embodiment, the first light control part CCP1 may include the first quantum dot QD1 and the scatterer SP dispersed in the first base resin BR1, the second light control part CCP2 may include the second quantum dot QD2 and the scatterer SP dispersed in the second base resin BR2, and the third light control part CCP3 may include the scatterer particle SP dispersed in the third base resin BR3.

The base resins BR1, BR2 and BR3 are mediums in which the quantum dots QD1 and QD2 and the scatterer SP are dispersed and may be composed of various resin compositions which may be generally referred to as a binder. For example, the base resins BR1, BR2 and BR3 may be acrylic resins, urethane-based resins, silicone-based resins, epoxy-based resins, or the like. The base resins BR1, BR2 and BR3 may be transparent resins. In an embodiment, the first base resin BR1, the second base resin BR2 and the third base resin BR3 may be the same or different from each other.

The light control layer CCL may include a barrier layer BFL1. The barrier layer BFL1 may play the role of blocking the penetration of moisture and/or oxygen (hereinafter, will be referred to as “humidity/oxygen”). The barrier layer BFL1 may block the exposure of the light control parts CCP1, CCP2 and CCP3 to humidity/oxygen. Meanwhile, the barrier layer BFL1 may cover the light control parts CCP1, CCP2 and CCP3. In addition, a color filter layer CFL, which will be explained later, may include a barrier layer BFL2 disposed on the light control parts CCP1, CCP2 and CCP3.

The barrier layers BFL1 and BFL2 may include at least one inorganic layer. That is, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. Meanwhile, the barrier layers BFL1 and BFL2 may further include an organic layer. The barrier layers BFL1 and BFL2 may be composed of a single layer of multiple layers.

In the display device DD-a of an embodiment, the color filter layer CFL may be disposed on the light control layer CCL. For example, the color filter layer CFL may be disposed directly on the light control layer CCL. In this case, the barrier layer BFL2 may be omitted.

The color filter layer CFL may include filters CF1, CF2 and CF3. Each of the first to third filters CF1, CF2 and CF3 may be disposed corresponding to a red luminous area PXA-R, a green luminous area PXA-G, and a blue luminous area PXA-B, respectively.

The color filter layer CFL may include a first filter CF1 transmitting the second color light, a second filter CF2 transmitting the third color light, and a third filter CF3 transmitting the first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye.

Meanwhile, an embodiment of the inventive concept is not limited thereto, and the third filter CF3 may not include the pigment or dye. The third filter CF3 may include a polymer photosensitive resin and not include a pigment or dye. The third filter CF3 may be transparent. The third filter CF3 may be formed using a transparent photosensitive resin.

In addition, in an embodiment, the first filter CF1 and the second filter CF2 may be yellow filters. The first filter CF1 and the second filter CF2 may be provided in one body without distinction.

Though not shown, the color filter layer CFL may further include a light blocking part (not shown). The light blocking part may be a black matrix. The light blocking part may be formed by including an organic light blocking material or an inorganic light blocking material including a black pigment or black dye. The light blocking part may prevent light leakage phenomenon and divide the boundaries among adjacent filters CF1, CF2 and CF3.

On the color filter layer CFL, a base substrate BL may be disposed. The base substrate BL may be a member providing a base surface on which the color filter layer CFL, the light control layer CCL, or the like are disposed. The base substrate BL may be a glass substrate, a metal substrate, a plastic substrate, or the like. However, an embodiment of the inventive concept is not limited thereto, and the base substrate BL may be an inorganic layer, an organic layer or a composite material layer. In addition, different from the drawing, the base substrate BL may be omitted in an embodiment.

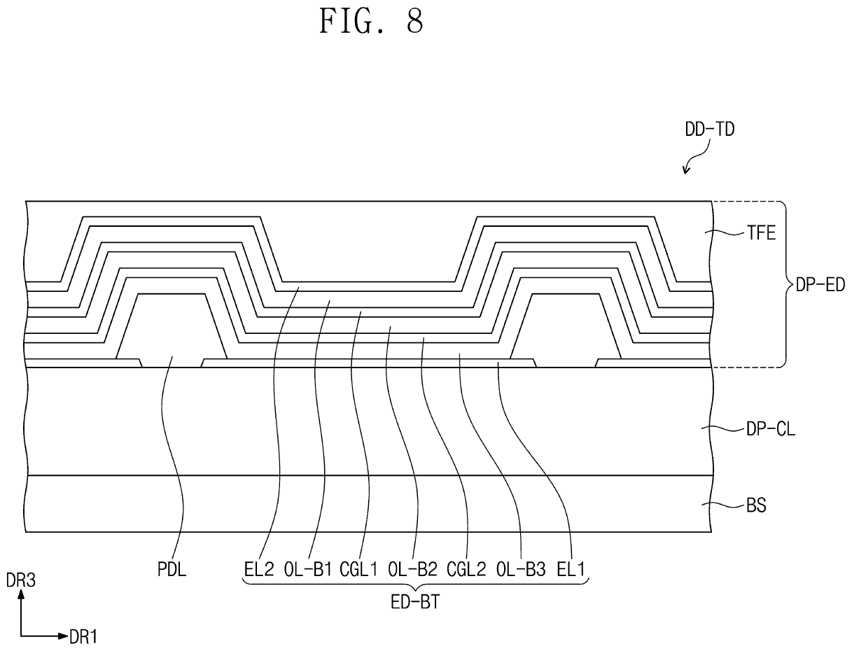

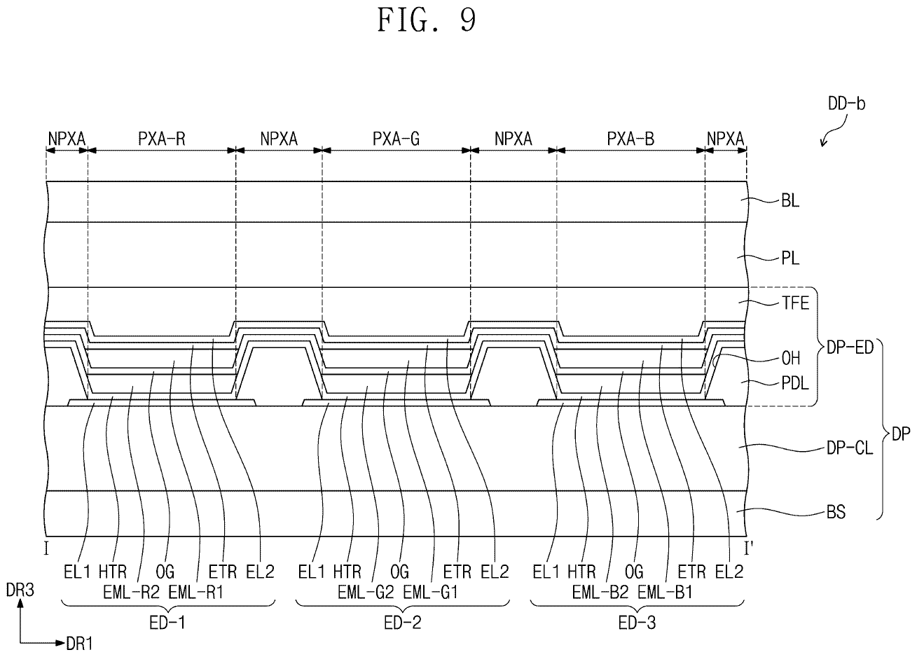

FIG. 8 is a cross-sectional view showing a portion of the display device according to an embodiment. In a display device DD-TD of an embodiment, a light emitting device ED-BT may include multiple light emitting structures OL-B1, OL-B2 and OL-B3. The light emitting device ED-BT may include oppositely disposed first electrode EL1 and second electrode EL2, and the multiple light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include an emission layer EML (FIG. 7), and a hole transport region HTR and an electron transport region ETR disposed with the emission layer EML (FIG. 7) therebetween.

That is, the light emitting device ED-BT included in the display device DD-TD of an embodiment may be a light emitting device of a tandem structure including multiple emission layers.

In an embodiment shown in FIG. 8, light emitted from the light emitting structures OL-B1, OL-B2 and OL-B3 may be all blue light. However, an embodiment of the inventive concept is not limited thereto, and the wavelength ranges of light emitted from the light emitting structures OL-B1, OL-B2 and OL-B3 may be different from each other. For example, the light emitting device ED-BT including the multiple light emitting structures OL-B1, OL-B2 and OL-B3 emitting light in different wavelength ranges may emit white light.

Between neighboring light emitting structures OL-B1, OL-B2 and OL-B3, charge generating layers CGL1 and CGL2 may be disposed. The charge generating layers CGL1 and CGL2 may include a p-type charge generating layer and/or an n-type charge generating layer.

In at least one among the light emitting structures OL-B1, OL-B2 and OL-B3, included in the display device DD-TD of an embodiment, the fused polycyclic compound of an embodiment may be included. That is, at least one among multiple emission layers included in the light emitting device ED-BT may include the fused polycyclic compound of an embodiment.

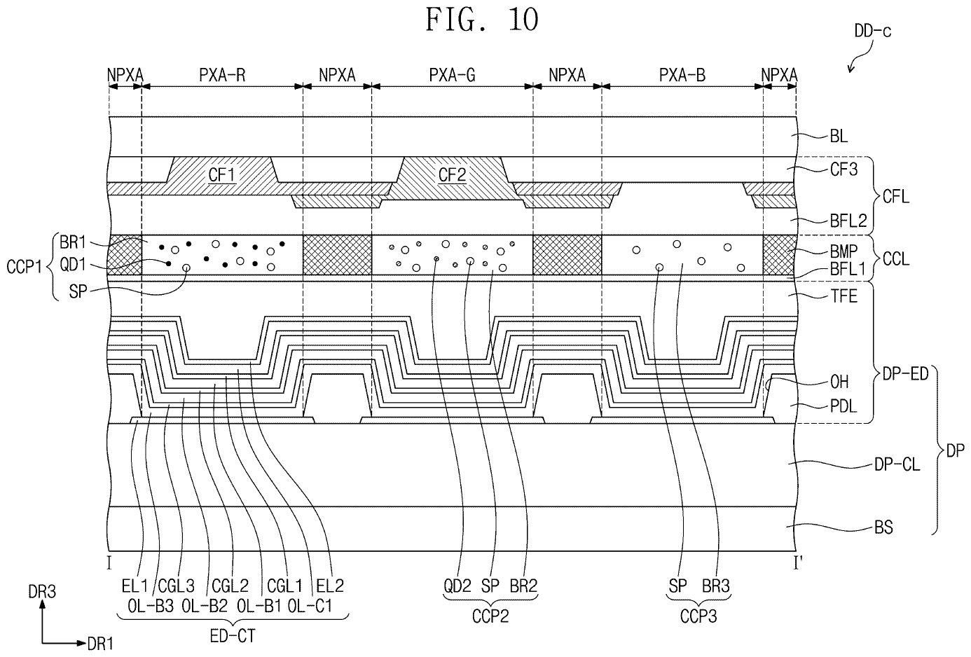

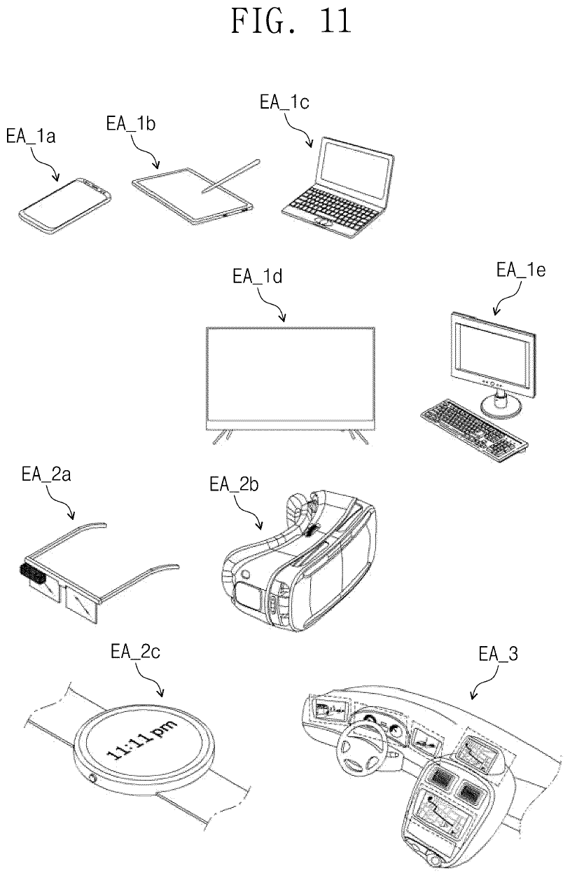

FIG. 9 is a cross-sectional view showing a display device according to an embodiment of the inventive concept. FIG. 10 is a cross-sectional view showing a display device according to an embodiment of the inventive concept.

Referring to FIG. 9, a display device DD-b according to an embodiment may include light emitting devices ED-1, ED-2 and ED-3, in which two emission layers are stacked. Compared to the display device DD of an embodiment, shown in FIG. 2, an embodiment shown in FIG. 9 is different in that the first to third light emitting devices ED-1, ED-2 and ED-3 include two emission layers stacked in a thickness direction, each. In the first to third light emitting devices ED-1, ED-2 and ED-3, two emission layers may emit light in the same wavelength range.

The first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generating layer. More particularly, the emission auxiliary part OG may include an electron transport region, a charge generating layer, and a hole transport region stacked in order. The emission auxiliary part OG may be provided as a common layer in all the first to third light emitting devices ED-1, ED-2 and ED-3. However, an embodiment of the inventive concept is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be disposed between the emission auxiliary part OG and the electron transport region ETR. The second red emission layer EML-R2, the second green emission layer EML-G2 and the second blue emission layer EML-B2 may be disposed between the hole transport region HTR and the emission auxiliary part OG.

That is, the first light emitting device ED-1 may include a first electrode EL1, a hole transport region HTR, a second red emission layer EML-R2, an emission auxiliary part OG, a first red emission layer EML-R1, an electron transport region ETR, and a second electrode EL2, stacked in order. The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order.

Meanwhile, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. Different from the drawing, the optical auxiliary layer PL may be omitted from the display device according to an embodiment.

At least one emission layer included in the display device DD-b of an embodiment, shown in FIG. 9 may include the fused polycyclic compound of an embodiment. For example, in an embodiment, at least one among a first blue emission layer EML-B1 and a second blue emission layer EML-B2 may include the fused polycyclic compound of an embodiment.

Different from FIG. 8 and FIG. 9, a display device DD-c in FIG. 10 is shown to include four light emitting structures OL-B1, OL-B2, OL-B3 and OL-C1. A light emitting device ED-CT may include oppositely disposed first electrode EL1 and second electrode EL2, and first to fourth light emitting structures OL-B1, OL-B2, OL-B3 and OL-C1 stacked in order in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be disposed. Among the four light emitting structures, the first to third light emitting structures OL-B1, OL-B2 and OL-B3 emit blue light, and the fourth light emitting structure OL-C1 may emit green light. However, an embodiment of the inventive concept is not limited thereto, and the first to fourth light emitting structures OL-B1, OL-B2, OL-B3 and OL-C1 may emit different wavelengths of light.

Charge generating layers CGL1, CGL2 and CGL3 disposed among neighboring light emitting structures OL-B1, OL-B2, OL-B3 and OL-C1 may include a p-type charge generating layer and/or an n-type charge generating layer.

In at least one among the light emitting structures OL-B1, OL-B2, OL-B3 and OL-C1, included in the display device DD-c of an embodiment, the fused polycyclic compound of an embodiment may be included. For example, in an embodiment, at least one among the first to third light emitting structures OL-B1, OL-B2, and OL-B3 may include the fused polycyclic compound of an embodiment.

The light emitting device ED according to an embodiment of the inventive concept may include the fused polycyclic compound of an embodiment, represented by Formula 1 in at least one functional layer disposed between a first electrode and a second electrode EL2 and may show excellent emission efficiency and improved lifetime characteristics. For example, the polycyclic compound according to an embodiment may be included in the emission layer EML of the light emitting device ED, and the light emitting device of an embodiment may show long lifetime characteristics.

In an embodiment, an electronic device may include a display device including multiple light emitting devices and a control part controlling the display device. The electronic device of an embodiment may be a device activated according to electrical signals. The electronic device may include display devices of various embodiments. For example, the electronic device may include large-size display devices such as televisions, monitors, and outside billboards, and medium- and small-size display devices such as personal computers, laptop computers, personal digital terminals, display devices for automobiles, game consoles, portable electronic devices, and cameras.

FIG. 11 is a diagram showing a vehicle AM in which first to fourth display devices DD-1, DD-2, DD-3 and DD-4 are disposed. At least one among the first to fourth display devices DD-1, DD-2, DD-3 and DD-4 may include the same configurations as the display devices DD, DD-TD, DD-a, DD-b and DD-c of embodiments, explained referring to FIGS. 1, 2, and 7 to 10.

In FIG. 11, an automobile is shown as a vehicle AM, but this is an illustration, and the first to fourth display devices DD-1, DD-2, DD-3 and DD-4 may be disposed on other transport means such as bicycles, motorcycles, trains, ships and airplanes. In addition, at least one among the first to fourth display devices DD-1, DD-2, DD-3 and DD-4 including the same configurations as the display devices DD, DD-TD, DD-a, DD-b and DD-c may be introduced in personal computers, laptop computers, personal digital terminals, game consoles, portable electronic devices, televisions, monitors, external billboards, or the like. In addition, these are suggested as examples, and the display device may be introduced in other electronic devices as long as not deviated from the inventive concept.

At least one among the first to fourth display devices DD-1, DD-2, DD-3 and DD-4 may include the light emitting device ED of an embodiment, explained referring to FIG. 3 to FIG. 6. The light emitting device ED of an embodiment may include the heterocyclic compound of an embodiment. At least one among the first to fourth display devices DD-1, DD-2, DD-3 and DD-4 may include the light emitting device ED including the heterocyclic compound of an embodiment and may show improved display lifetime.

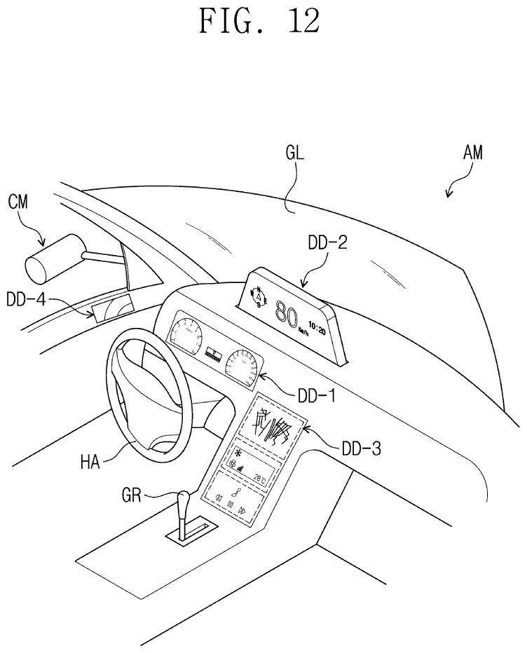

Referring to FIG. 12, a vehicle AM may include a steering wheel HA for the operation of the vehicle AM and a gear GR. In addition, the vehicle AM may include a front window GL disposed to face a driver.

A first display device DD-1 may be disposed in a first region overlapping with the steering wheel HA. For example, the first display device DD-1 may be a digital cluster displaying the first information of the vehicle AM. The first information may include a first graduation showing the running speed of the vehicle AM, a second graduation showing the number of revolution of an engine (that is, revolutions per minute (RPM)), and images showing a fuel state. First graduation and second graduation may be represented by digital images.

A second display device DD-2 may be disposed in a second region facing a driver's seat and overlapping with the front window GL. The driver's seat may be a seat where the steering wheel HA is disposed. For example, the second display device DD-2 may be a head up display (HUD) showing the second information of the vehicle AM. The second display device DD-2 may be optically clear. The second information may include digital numbers showing the running speed of the vehicle AM and may further include information including the current time. Different from the drawing, the second information of the second display device DD-2 may be projected and displayed on the front window GL.

A third display device DD-3 may be disposed in a third region adjacent to the gear GR. For example, the third display device DD-3 may be a center information display (CID) for a vehicle, disposed between a driver's seat and a passenger seat and showing third information. The passenger seat may be a seat separated from the driver's seat with the gear GR therebetween. The third information may include information on road conditions (for example, navigation information), on playing music or radio, on playing a dynamic image (or image), on the temperature in the vehicle AM, or the like.

A fourth display device DD-4 may be disposed in a fourth region separated from the steering wheel HA and the gear GR and adjacent to the side of the vehicle AM. For example, the fourth display device DD-4 may be a digital wing mirror displaying fourth information. The fourth display device DD-4 may display the external image of the vehicle AM, taken by a camera module CM disposed at the outside of the vehicle AM. The fourth information may include the external image of the vehicle AM.

The above-described first to fourth information is for illustration, and the first to fourth display devices DD-1, DD-2, DD-3 and DD-4 may further display information on the inside and outside of the vehicle AM. The first to fourth information may include different information from each other. However, an embodiment of the inventive concept is not limited thereto, and a portion of the first to fourth information may include the same information.

Hereinafter, the fused polycyclic compound according to an embodiment of the inventive concept and the light emitting device according to an embodiment will be particularly explained referring to embodiments and comparative embodiments. In addition, the embodiments below are only illustrations to assist the understanding of the inventive concept, and the scope of the inventive concept is not limited thereto.

### EXAMPLES

### 1. Synthesis of Fused Polycyclic Compound

First, the synthetic method of the fused polycyclic compound according to an embodiment will be explained in particular, illustrating the synthetic methods of Compounds 113, 127, 134, 142, 173, 177 and 184. In addition, the synthetic methods of the fused polycyclic compounds explained hereinafter are embodiments, and the synthetic method of the fused polycyclic compound according to an embodiment of the inventive concept is not limited to the examples that follow.

### (1) Synthesis of Compound 113

Fused Polycyclic Compound 113 according to an embodiment may be synthesized by the reactions below.

### Synthesis of Intermediate 113-A

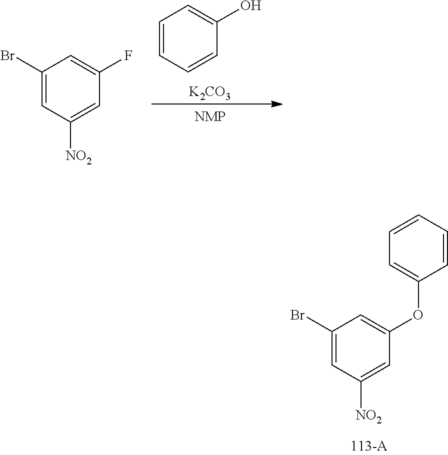

To three 1 L reaction vessels, 20 g of 1-bromo-3-fluoro-5-nitrobenzene, 17 g of phenol, 25 g of K₂CO₃, and 300 mL of NMP were added and stirred and heated at about 180° C. for about 6 hours. The obtained reaction solution was filtered through celite, concentrated, and purified by column chromatography (eluent: hexane) to obtain 23 g of a colorless liquid (yield: 87%). The product was confirmed by FAB-MS as Intermediate 113-A based on m/z=294.

### Synthesis of Intermediate 113-B

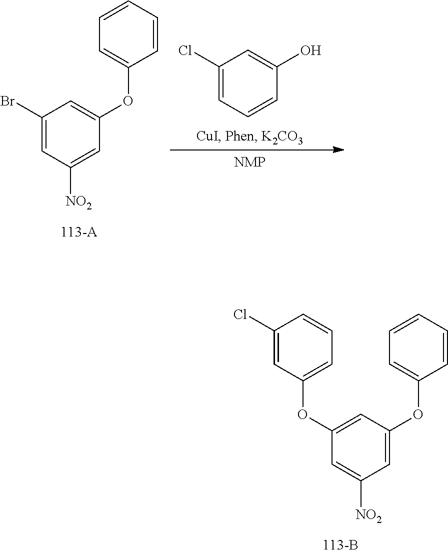

To three 1 L reaction vessels, 23 g of 113-A, 23 g of 3-chlorophenol, 24 g of K₂CO₃, 1.7 g of CuI, 1.6 g of phenanthroline, and 300 mL of NVIP were added and stirred and heated at about 180° C. for about 6 hours. The obtained reaction solution was filtered through celite, concentrated, and purified by column chromatography (eluent: hexane) to obtain 23 g of a colorless liquid (yield: 76%). The product was confirmed by FAB-MS as Intermediate 113-B based on m/z=342.

### Synthesis of Intermediate 113-C

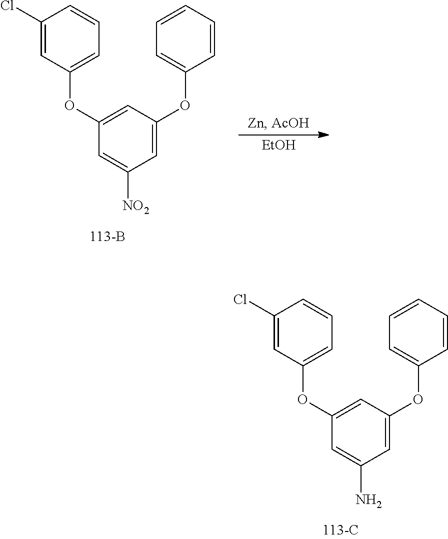

To three 500 mL reaction vessels, 23 g of 113-B, 22 g of powdered Zn, and 60 mL of ethanol were added, the mixture was stirred while cooling in an ice bath, and a mixture of 23 mL of acetic acid and 60 mL of ethanol was slowly added thereto using a dropping funnel. The mixture was stirred at room temperature overnight, the obtained reaction solution was filtered and collected, an organic layer was extracted three times with toluene, and the collected organic layer was washed with brine and water. After drying the product over MgSO₄, the liquid was filtered, collected, concentrated, and purified by column chromatography (eluent: EtOAc/hexane=1/8) to obtain 12 g (yield: 61%) of a brown liquid. The product was confirmed by FAB-MS as Intermediate 113-C based on m/z=312.

### Synthesis of Intermediate 113-D

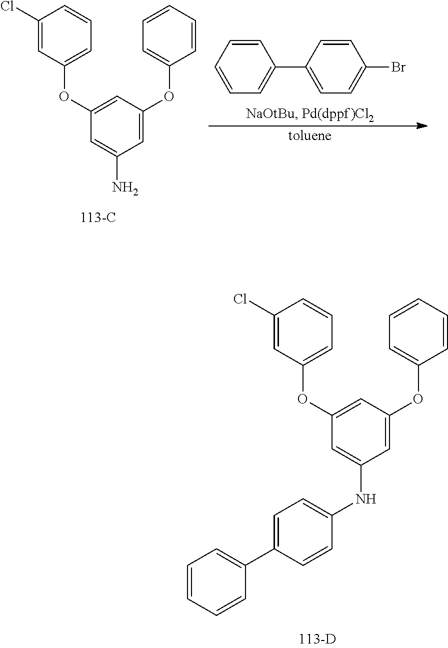

To three 500 mL reaction vessels, 13 g of 113-C, 11 g of 4-bromo-1,1′-biphenyl, 1.8 g of Pd(dppf)Cl₂, 5.9 g of NaOtBu, and 200 mL of toluene were added, and the mixture was heated and stirred at about 120° C. for about 3 hours. The obtained reaction solution was filtered through celite, concentrated, and purified by column chromatography (eluent: toluene/hexane=1:3) to obtain 18 g (yield: 93%) of a white solid. The product was confirmed by FAB-MS as Intermediate 113-D based on m/z=464.

### Synthesis of Intermediate 113-E

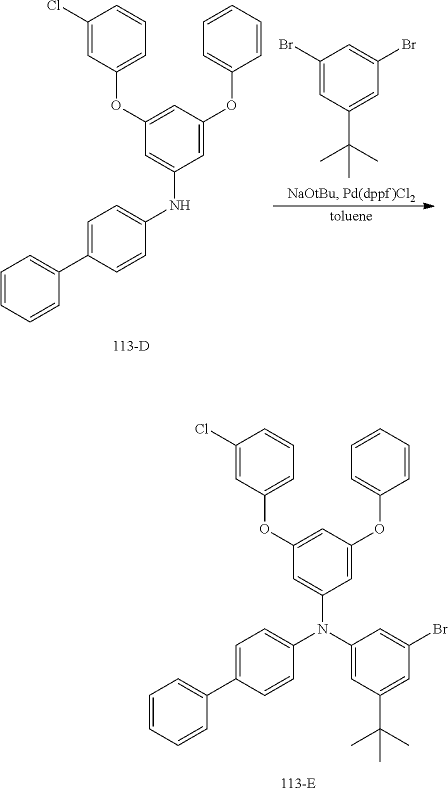

To three 500 mL reaction vessels, 18 g of 113-D, 11 g of 1,3-dibromo-5-tert-butylbenzene, 1.4 g of Pd(dppf)Cl₂, 3.8 g of NaOtBu, and 200 mL of toluene were added, and the mixture was heated and stirred at about 120° C. for about 5 hours. The obtained reaction solution was filtered through celite, concentrated, and purified by column chromatography (eluent: toluene/hexane=1:2) to obtain 21 g (yield: 82%) of a white solid. The product was confirmed by FAB-MS as Intermediate 113-E based on m/z=675.

### Synthesis of Intermediate 113-F

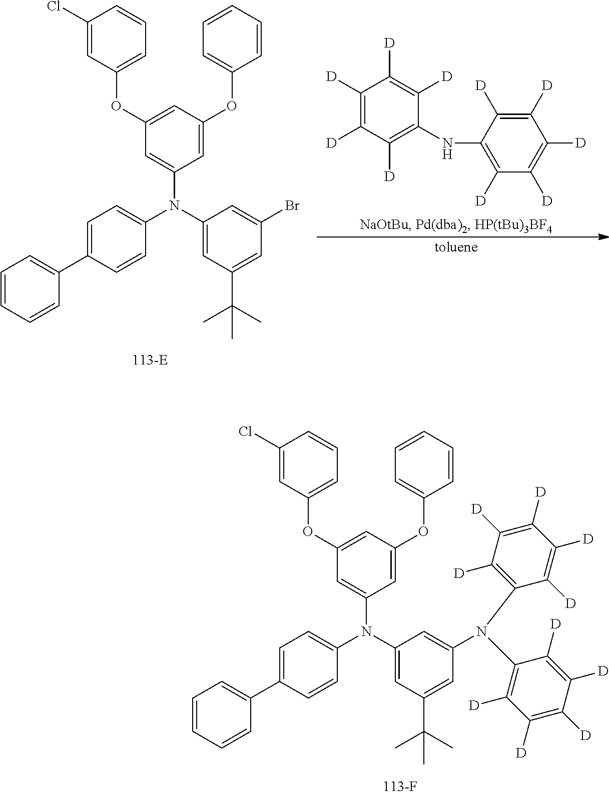 [SMILES: CC(C)(C)c1cc(Br)cc(N(c2ccc(-c3ccccc3)cc2)c2cc(Oc3ccccc3)cc(Oc3cccc(Cl)c3)c2)c1 ; [2H]c1c([2H])c([2H])c(Nc2c([2H])c([2H])c([2H])c([2H])c2[2H])c([2H])c1[2H] ; "NaOtBu, Pd(dba)2, HP(tBu)3BF4" ; "toluene" ; [2H]c1c([2H])c([2H])c(N(c2cc(N(c3ccc(-c4ccccc4)cc3)c3cc(Oc4ccccc4)cc(Oc4cccc(Cl)c4)c3)cc(C(C)(C)C)c2)c2c([2H])c([2H])c([2H])c([2H])c2[2H])c([2H])c1[2H]]

To three 500 mL reaction vessels, 21 g of 113-E, 6.7 g of bis(phenyl-d₅)amine, 1.7 g of Pd(dba)₂, 1.7 g of HP(tBu)₃BF₄, 4.5 g of NaOtBu, and 150 mL of toluene were added, and the mixture was heated and stirred at about 120° C. for about 5 hours. The obtained reaction solution was filtered through celite, concentrated, and purified by column chromatography (eluent: toluene/hexane=1:1) to obtain 21 g (yield: 89%) of a white solid. The product was confirmed by FAB-MS as Intermediate 113-F based on m/z=773.

### Synthesis of Intermediate 113-G

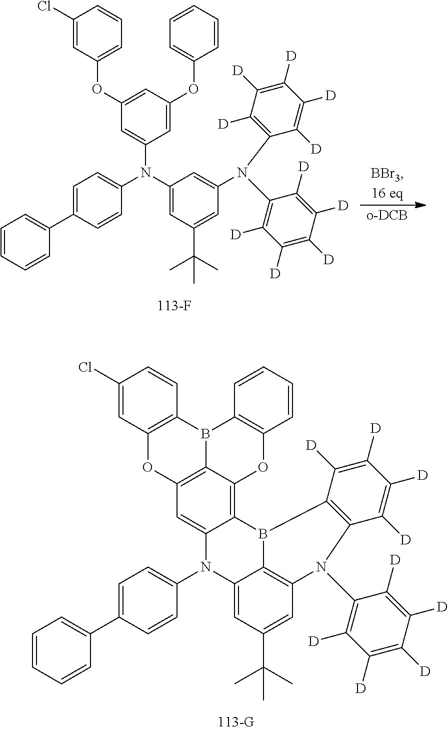

To three 1 L reaction vessels, 21 g of 113-F and 180 mL of o-dichlorobenzene were added, 111 g of BBr₃ was slowly added thereto while stirring at room temperature, and the mixture was heated and stirred at about 180° C. for about 24 hours. To the obtained reaction solution, 310 mL of N,N-diisopropylethylamine was added while cooling in an ice bath, and the mixture was stirred at room temperature for about 1 hour. Water was added to the reaction solution, and an organic layer was extracted with toluene and washed with brine and water. The organic layer was dried over MgSO₄, the liquid was filtered, collected, concentrated, and purified by column chromatography (eluent: dichloromethane/hexane=1/3), and a molecular weight was confirmed by FAB-MS. 3.0 g (yield: 14%) of a yellow solid was obtained. FAB-MS measurement showed m/z=788, and Intermediate 113-G was confirmed.

### Synthesis of Compound 113

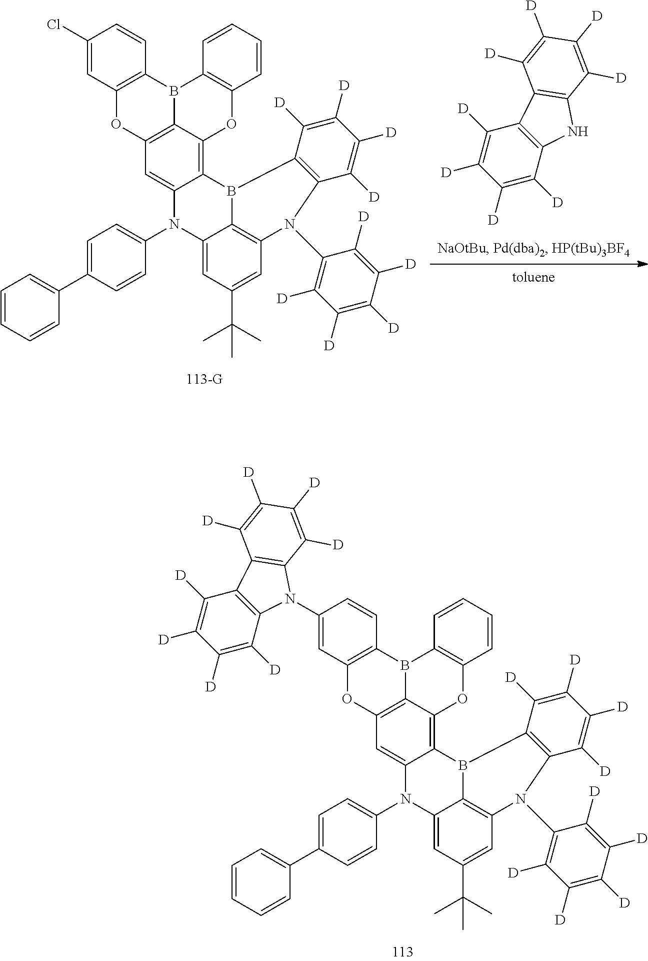 [SMILES: [2H]c1c([2H])c([2H])c(N2c3cc(C(C)(C)C)cc4c3B(c3c(cc5c6c3Oc3ccccc3B6c3ccc(Cl)cc3O5)N4c3ccc(-c4ccccc4)cc3)c3c([2H])c([2H])c([2H])c([2H])c32)c([2H])c1[2H] ; [2H]c1c([2H])c([2H])c2c([nH]c3c([2H])c([2H])c([2H])c([2H])c32)c1[2H] ; [2H]c1c([2H])c([2H])c(N2c3cc(C(C)(C)C)cc4c3B(c3c(cc5c6c3Oc3ccccc3B6c3ccc(-n6c7c([2H])c([2H])c([2H])c([2H])c7c7c([2H])c([2H])c([2H])c([2H])c76)cc3O5)N4c3ccc(-c4ccccc4)cc3)c3c([2H])c([2H])c([2H])c([2H])c32)c([2H])c1[2H]]

To three 100 mL reaction vessels, 3.0 g of 113-G, 1.0 g of carbazole-d₈, 0.27 g of Pd(dba)₂, 0.27 g of HP(tBu)₃BF₄, 0.56 g of NaOtBu, and 20 mL of toluene were added, and the mixture was heated and stirred at about 120° C. for about 24 hours. The obtained reaction solution was filtered through celite, concentrated, and purified by column chromatography (eluent: dichloromethane/hexane=1/3) to obtain 2.3 g (yield: 64%) of a yellow solid. The product was confirmed by FAB-MS as Compound 113 based on m/z=927.

### (2) Synthesis of Compounds 127, 134, 142, 173, 177 and 184

Fused Polycyclic Compounds 127, 134, 142, 173, 177 and 184 were synthesized by the same manner as the Fused Polycyclic Compound 113, except that some of the materials used in the synthesis of Intermediate n-A to Intermediate n-G and the structures of each of Intermediate n-A to Intermediate n-G were different. Hereinafter, Intermediate n-A to Intermediate n-G, n refer to the number of the fused polycyclic compounds according to embodiments.

Compounds 127, 134, 142, 173, 177 and 184 may be synthesized by the reactions below, and the types of substituents R_{A}, R_{B}, R_{C}, R_{D}, and Z in the materials or Intermediate n-A to Intermediate n-G, used in the synthesis are as shown in Table 1, and the quantities, yields, and the m/z results of FAB-MS of Intermediate n-A to Intermediate n-G are listed in Tables 2 and 3.

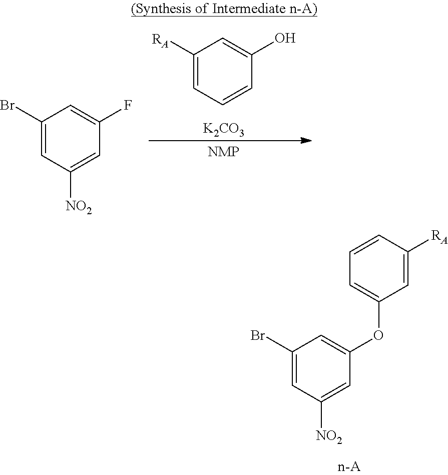

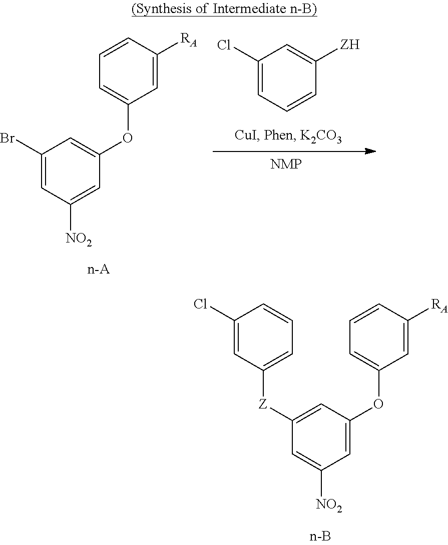

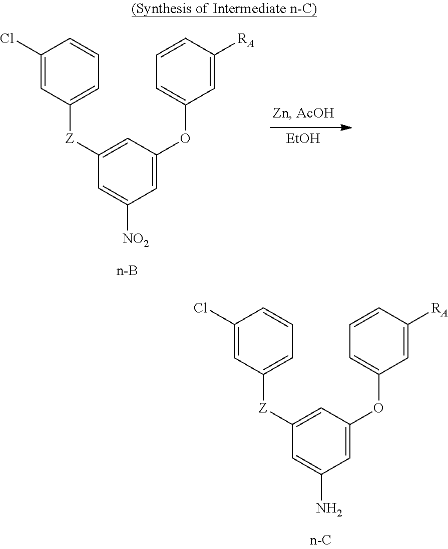

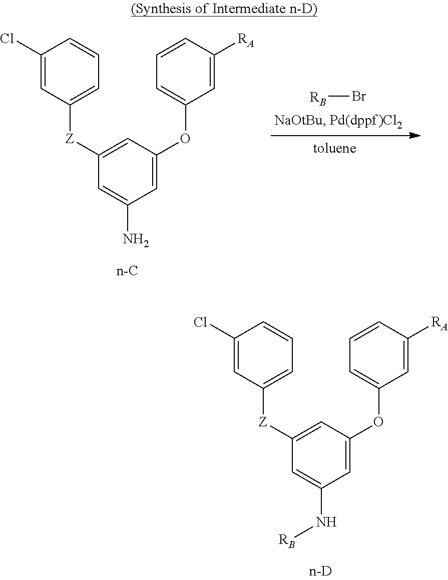

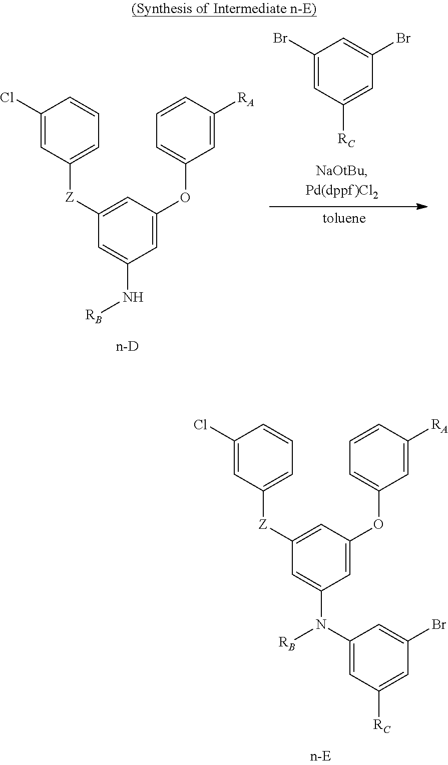

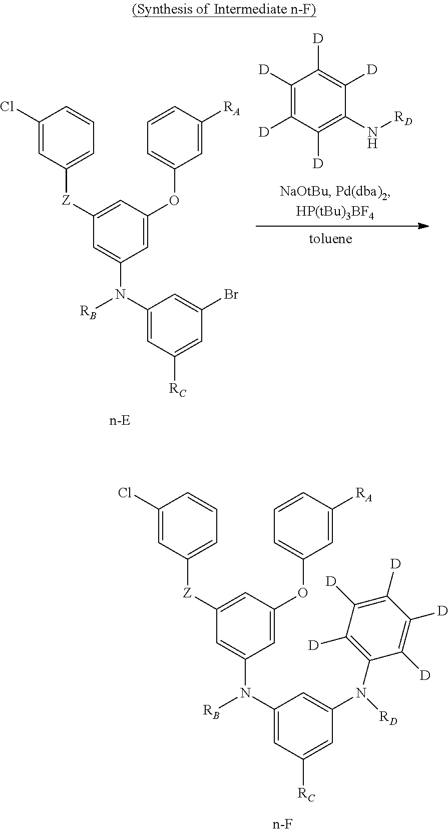

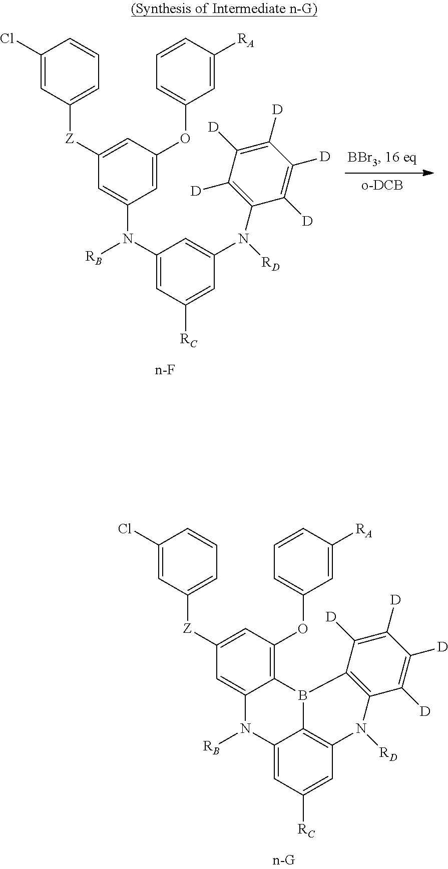

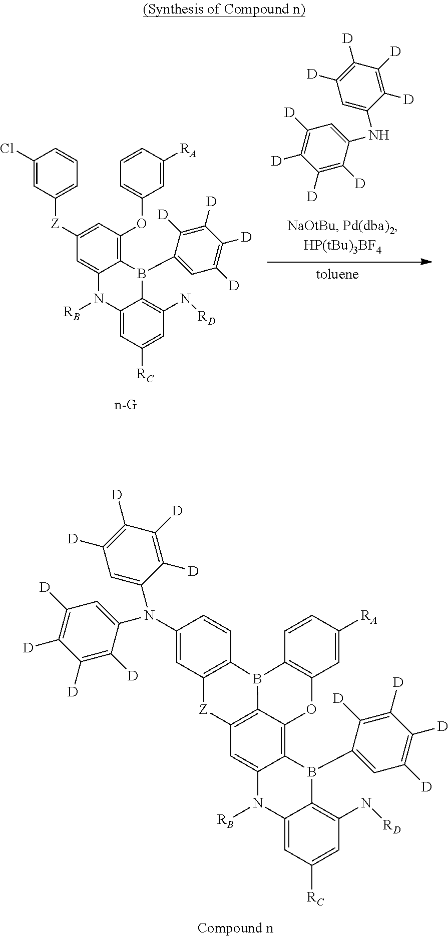

TABLE 1

| Comp. | | | | | |
|---|---|---|---|---|---|
| No. (n) | R_{A} | Z | R_{B} | R_{C} | R_{D} |
| 113 | H | —O— | p-BiPh | tBu | Ph-d₅ |
| 127 | Ph | —O— | p-BiPh | tBu | o-BiPh |
| 134 | Cbz-d₈ | —O— | p-BiPh | tBu | o-BiPh |
| 142 | Cbz-d₈ | —O— | o-BiPh | Ph | o-BiPh |
| 173 | H | —N(o-BiPh)— | TerPh | tBu | Ph-d₅ |
| 177 | Ph | —N(o-BiPh)— | p-BiPh | tBu | o-BiPh |
| 184 | Cbz-d₈ | —N(o-BiPh)— | p-BiPh | tBu | o-BiPh |

In Table 1 above, “H” means a hydrogen atom, “Ph” means an unsubstituted phenyl group, “Cbz-d8” means a carbazole group in which 8 deuterium atoms are substituted, “p-BiPh” means an unsubstituted p-biphenyl group, “o-BiPh” means an unsubstituted o-biphenyl group, “tBu” means an unsubstituted t-butyl group, and “Ph-d5” means a phenyl group in which 5 deuterium atoms are substituted.

TABLE 2

| | Amount (yield, %) | | | | | | | |
|---|---|---|---|---|---|---|---|---|
| Comp No. | Inter. | Inter. | Inter. | Inter. | Inter. | Inter. | Inter | Comp. |
| (n) | n-A | n-B | n-C | n-D | n-E | n-F | n-G | n |
| 113 | 23 g | 23 g | 13 g | 18 g | 21 g | 21 g | 3.1 g | 2.3 g |
| | (87%) | (76%) | (61%) | (93%) | (82%) | (89%) | (14%) | (64%) |
| 127 | 27 g | 24 g | 12 g | 16 g | 19 g | 19 g | 3.3 g | 2.0 g |
| | (79%) | (81%) | (54%) | (94%) | (87%) | (82%) | (17%) | (52%) |
| 134 | 37 g | 35 g | 16 g | 17 g | 21 g | 20 g | 2.1 g | 1.5 g |
| | (87%) | (85%) | (49%) | (81%) | (89%) | (82%) | (10%) | (67%) |
| 142 | 37 g | 35 g | 16 g | 16 g | 18 g | 19 g | 2.3 g | 1.9 g |
| | (87%) | (85%) | (49%) | (76%) | (81%) | (89%) | (12%) | (72%) |
| 173 | 23 g | 32 g | 13 g | 19 g | 21 g | 18 g | 3.8 g | 2.8 g |
| | (87%) | (83%) | (43%) | (97%) | (85%) | (77%) | (21%) | (64%) |
| 177 | 27 g | 31 g | 11 g | 12 g | 13 g | 13 g | 3.4 g | 2.9 g |
| | (79%) | (76%) | (38%) | (85%) | (82%) | (84%) | (26%) | (74%) |
| 184 | 37 g | 41 g | 15 g | 16 g | 19 g | 19 g | 4.5 g | 3.4 g |
| | (87%) | (78%) | (38%) | (87%) | (92%) | (83%) | (24%) | (67%) |

TABLE 3

| | m/z value of FAB-MS | | | | | | | |
|---|---|---|---|---|---|---|---|---|
| Comp. | Inter. | Inter. | Inter. | Inte. | Inter. | Inter. | Inter. | Comp. |
| No. (n) | n-A | n-B | n-C | n-D | n-E | n-F | n-G | n |
| 113 | 294 | 342 | 312 | 464 | 675 | 773 | 785 | 927 |
| 127 | 370 | 418 | 388 | 540 | 751 | 921 | 935 | 1074 |
| 134 | 467 | 515 | 485 | 637 | 848 | 1018 | 1032 | 1171 |
| 142 | 467 | 515 | 485 | 637 | 868 | 1037 | 1052 | 1191 |
| 173 | 294 | 493 | 463 | 691 | 902 | 1001 | 1015 | 1154 |
| 177 | 370 | 569 | 539 | 691 | 902 | 1072 | 1086 | 1225 |
| 184 | 467 | 666 | 636 | 788 | 1000 | 1169 | 1184 | 1322 |

### 2. Manufacture and Evaluation of Light Emitting Devices

A light emitting device of an embodiment including a fused polycyclic compound of an embodiment in an emission layer was manufactured by a method below. The fused polycyclic compounds of Compounds 113, 127, 134, 142, 173, 177 and 184, as the Example Compounds were used as emission layer dopant materials to manufacture light emitting devices of Examples 1 to 7. Comparative Examples 1 to 7 correspond to light emitting devices manufactured using Comparative Compound X1 to Comparative Compound X7 as emission layer dopant materials.

### Example Compound

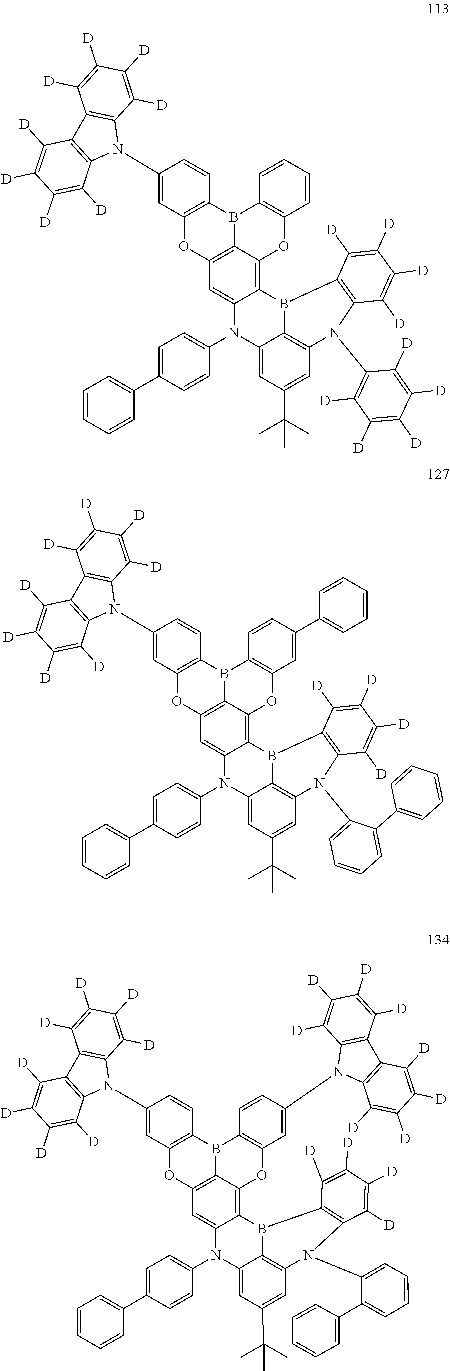

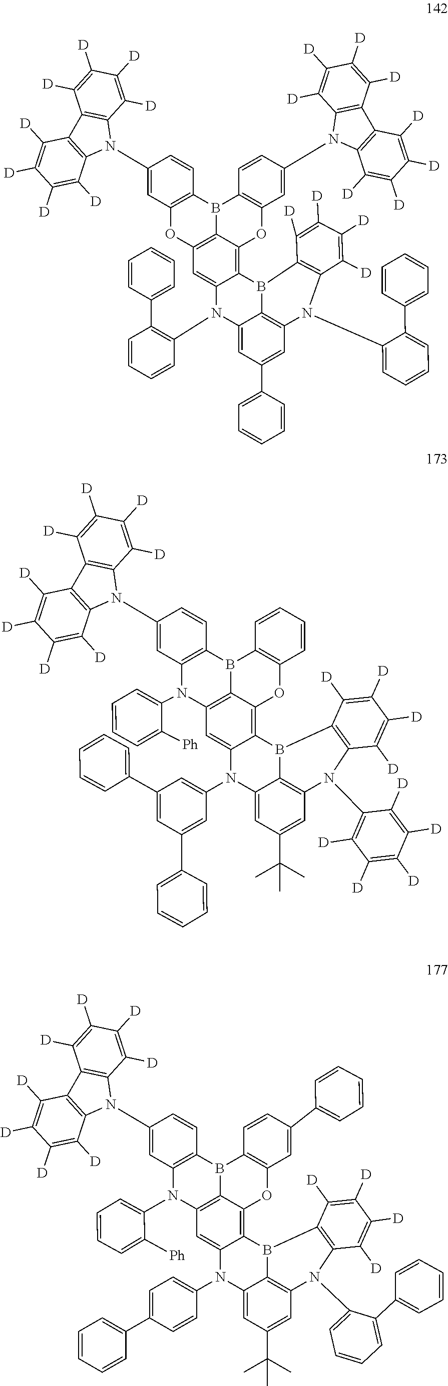

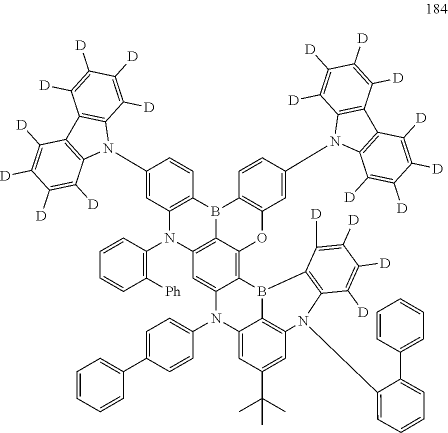

### [Comparative Compound]

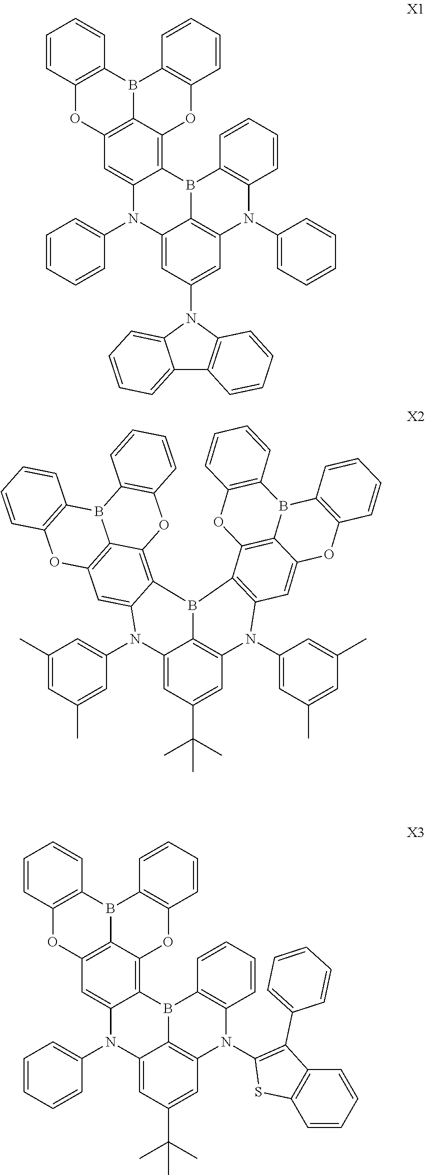

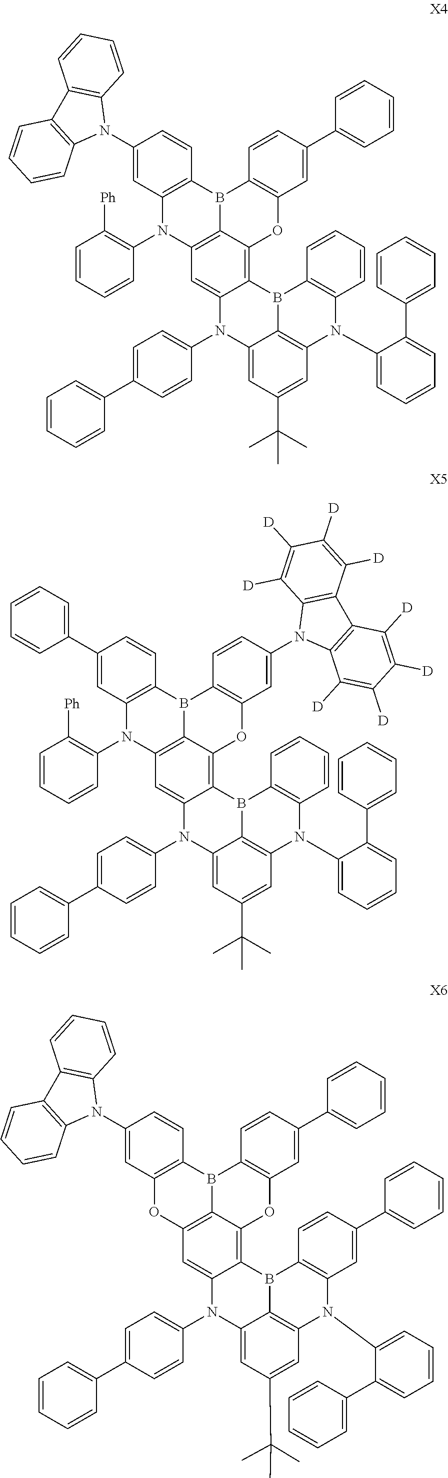

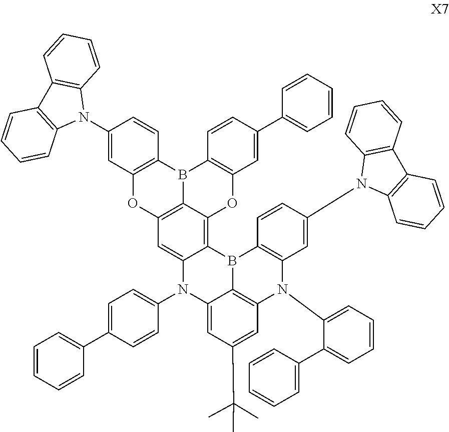 [SMILES: CC(C)(C)c1cc2c3c(c1)N(c1ccccc1-c1ccccc1)c1cc(-n4c5ccccc5c5ccccc54)ccc1B3c1c(cc3c4c1Oc1cc(-c5ccccc5)ccc1B4c1ccc(-n4c5ccccc5c5ccccc54)cc1O3)N2c1ccc(-c2ccccc2)cc1]

### Manufacture of Light Emitting Devices

The light emitting devices of the Examples and Comparative Examples were ultrasonically cleaned for about 5 minutes using isopropyl alcohol and pure water each on a glass substrate on which ITO was patterned as a first electrode. After the ultrasonic cleaning, UV irradiation was performed for about 30 minutes and ozone treatment was performed. Afterward, HAT-CN was deposited at a thickness of about 10 nm, TrisPCz at a thickness of about 30 nm, and mCBP at a thickness of about 5 nm to form a hole transport region.

Next, the Example Compound or the Comparative Compound and mCBP were co-deposited to form an emission layer at a thickness of about 30 nm. The Example Compound or the Comparative Compound and mCBP were co-deposited at a weight ratio of about 2:98. In the manufacture of the light emitting device, the Example Compound or the Comparative Compound was used as an emission layer dopant material.

SF3-TRZ at a thickness of about 10 nm, SF3-TRZ:Liq at a weight ratio of about 50:50 at a thickness of about 20 nm, and Liq at a thickness of about 2 nm were sequentially deposited on the emission layer to form an electron transport region.

Al was deposited to a thickness of about 100 nm to form a second electrode.

The compounds used in the manufacture of light emitting devices of the Examples and Comparative Examples are indicated below.

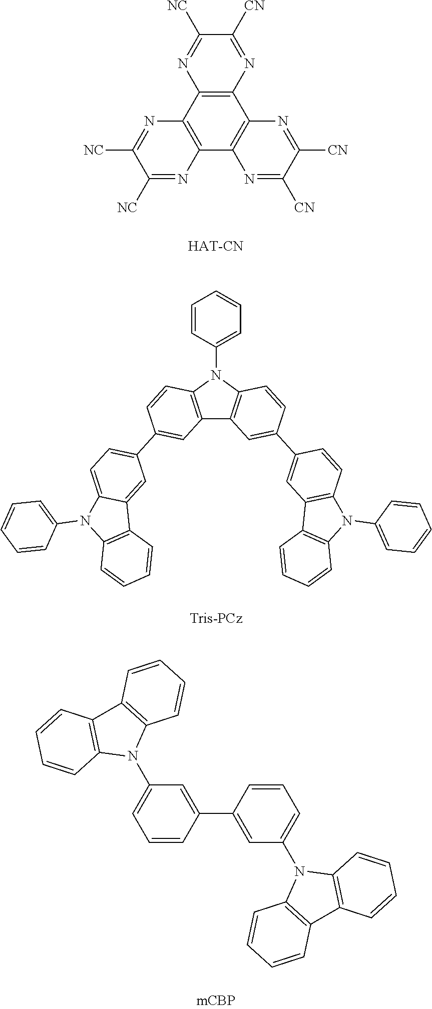 [SMILES: N#Cc1nc2c3nc(C#N)c(C#N)nc3c3nc(C#N)c(C#N)nc3c2nc1C#N ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1cc(-c2cccc(-n3c4ccccc4c4ccccc43)c2)cc(-n2c3ccccc3c3ccccc32)c1]

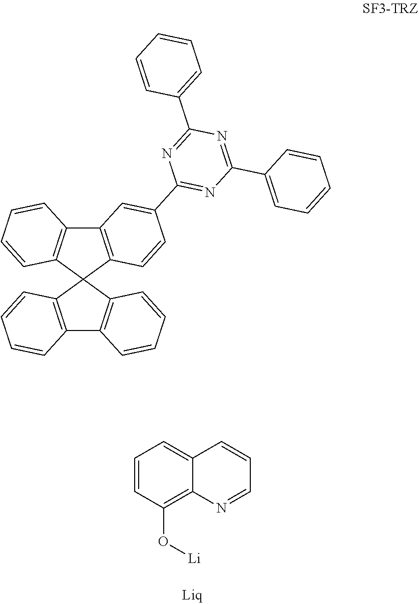

### (Evaluation of Properties of Light Emitting Devices)

The maximum emission wavelength (λmax), external quantum yield (EQE), and relative device lifespan of the light emitting devices manufactured with the Examples Compounds 113, 127, 134, 142, 173, 177 and 184 and Comparative Compounds X₁ to X₇ were evaluated. Table 4 below shows the evaluation results of the light emitting devices for Examples 1 to 7 and Comparative Examples 1 to 7. The maximum emission wavelength (λmax) and external quantum yield (EQE) represent the values measured at a luminance of about 1000 candela per square meter (cd/m²), and the relative device lifespan is expressed as the relative device lifespan, where the time taken for the luminance to decrease from initial luminance value to 50% of the initial luminance value as the device was driven at about 0.75 mA of device Comparative Example 1 is set (normalized) at 100.

TABLE 4

| | | Max. emission | Ex. quantum | Rel. device |
|---|---|---|---|---|
| | Emission layer | wavelength | efficiency | lifespan |
| | dopant comp. | (λmax, nm) | (EQE, %) | (%) |
| Example 1 | Compound 113 | 463 | 18.3 | 153 |
| Example 2 | Compound 127 | 464 | 19.5 | 158 |
| Example 3 | Compound 134 | 465 | 19.2 | 164 |
| Example 4 | Compound 142 | 461 | 18.9 | 148 |
| Example 5 | Compound 173 | 461 | 18.4 | 159 |
| Example 6 | Compound 177 | 462 | 19.3 | 168 |
| Example 7 | Compound 184 | 463 | 18.1 | 172 |
| Comp. Ex. 1 | Comp. Cmpd. | 453 | 12.1 | 100 |
| | X1 | | | |
| Comp. Ex 2 | Comp. Cmpd. | 451 | 13.6 | 105 |
| | X2 | | | |
| Comp. Ex. 3 | Comp. Cmpd. | 451 | 12.4 | 93 |
| | X3 | | | |
| Comp. Ex. 4 | Comp. Cmpd. | 462 | 17.4 | 131 |
| | X4 | | | |
| Comp. Ex. 5 | Comp. Cmpd. | 463 | 14.3 | 124 |
| | X5 | | | |
| Comp. Ex. 6 | Comp. Cmpd. | 467 | 13.4 | 113 |
| | X6 | | | |
| Comp. Ex. 7 | Comp. Cmpd. | 463 | 14.9 | 116 |
| | X7 | | | |

Referring to the results in Table 4, it is confirmed that the light emitting devices of the Examples emit blue light with a maximum emission wavelength of about 470 nm or less. In addition, the Examples showed superior results compared to the Comparative Examples in terms of external quantum yield (EQE) properties and relative device lifespan characteristics.

As demonstrated, in the cases of the polycyclic compounds of the Examples used in the light emitting devices of the Examples of the inventive concept, it is believed that because two aromatic hydrocarbon rings are connected to the specific positions of the fused polycyclic heterocycle, and first and second substituents are included, as compared to the Comparative Examples, the Examples may have characteristics such as excellent maximum quantum yield and material stability, and the light emitting devices including the same may also show excellent efficiency and lifetime characteristics.

Comparative Compounds X1 and X3 used in Comparative Examples 1 and 3 have a structure in which two aromatic hydrocarbon rings are connected to the specific positions of a fused polycyclic heterocycle, but do not include deuterium substitution which is a first substituent connected to a first benzene ring, and a carbazole moiety which is a second substituent connected to a fifth benzene ring, compared to the fused polycyclic compound of the inventive concept. Accordingly, it is understood that Comparative Examples 1 and 3 have lower external quantum efficiency and shorter device lifetime characteristics compared to the Examples.

Comparative Compound X2 used in Comparative Example 2 has a structure in which two aromatic hydrocarbon rings are connected to the specific positions of a fused polycyclic heterocycle, but do not include a deuterium substitution which is a first substituent connected to a first benzene ring, and a carbazole moiety which is a second substituent connected to a fifth benzene ring, compared to the fused polycyclic compound of the inventive concept. Comparative Compound X2 is judged to have a relatively high planar structure, and thus the frequency of accepting energy or charge in an excited state with adjacent molecules in an emission layer is high. Accordingly, the generation of hot excitons with high energy generated through triplet-triplet annihilation (TTA) is induced, thereby causing deterioration and exhausting the triplet excitons used for light emission. Accordingly, Comparative Example 2 is understood to have lower external quantum efficiency and shorter device lifetime characteristics compared to the Examples.

Comparative Compound X4 used in Comparative Example 4 has a structure in which two aromatic hydrocarbon rings are connected to the specific positions of a fused polycyclic heterocycle, and includes a carbazole moiety as a second substituent connected to a fifth benzene ring, but does not include a deuterium substitution as a first substituent connected to a first benzene ring, compared to the fused polycyclic compound of the inventive concept. Comparative Compound X4 is judged that the loss of non-luminescence activity was not suppressed in an excited state, since the first benzene ring is not deuterated by the first substituent compared to the fused polycyclic compound of an embodiment of the inventive concept. Accordingly, Comparative Example 4 is understood to have lower external quantum efficiency and shorter device lifetime characteristics compared to the Examples.

Comparative Compound X5 used in Comparative Example 5 has a structure in which two aromatic hydrocarbon rings are connected to the specific positions of the fused polycyclic heterocycle but does not include a deuterium substitution which is a first substituent connected to a first benzene ring and a carbazole moiety which is a second substituent connected to a fifth benzene ring, compared to the fused polycyclic compound of the Examples of the inventive concept. Comparative Compound X5 is understood to have lower external quantum efficiency and shorter device lifetime characteristics compared to the Examples, since a carbazole moiety is connected to a fourth benzene ring, not the fifth benzene ring.

Comparative Compounds X6 and X7 used in Comparative Examples 6 and 7 have a structure in which two aromatic hydrocarbon rings are connected to the specific positions of a fused polycyclic heterocycle and include a carbazole moiety as a second substituent connected to a fifth benzene ring but do not include a deuterium substitution as a first substituent connected to a first benzene ring, compared to the fused polycyclic compound of the inventive concept. In Comparative Compound X6, an unsubstituted phenyl group is connected to a first benzene ring instead of a deuterium atom as a first substituent, and In Comparative Compound X7, an unsubstituted carbazole group is connected instead of a deuterium atom as a first substituent. Accordingly, it is understood that Comparative Examples 6 and 7 have lower external quantum efficiency and shorter device lifetime characteristics compared to the Examples.

The fused polycyclic compound of an embodiment may exhibit excellent emission efficiency and excellent material stability characteristics. In addition, the fused polycyclic compound of an embodiment may be used as a thermally activated delayed fluorescent material. In addition, the light emitting device of an embodiment including the fused polycyclic compound of an embodiment in the emission layer exhibits excellent emission efficiency characteristics in a blue emission region and may exhibit long-life characteristics.

The light emitting device of an embodiment may show improved device properties of high efficiency and relatively longer lifetimes.

The fused polycyclic compound of an embodiment may be included in the emission layer of a light emitting device and may contribute to the increase of the efficiency and lifetime of the light emitting device.

The electronic device of an embodiment may show excellent display quality.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A light emitting device, comprising:
a first electrode;
a second electrode disposed on the first electrode; and
an emission layer disposed between the first electrode and the second electrode, and comprising a first compound represented by Formula 1: 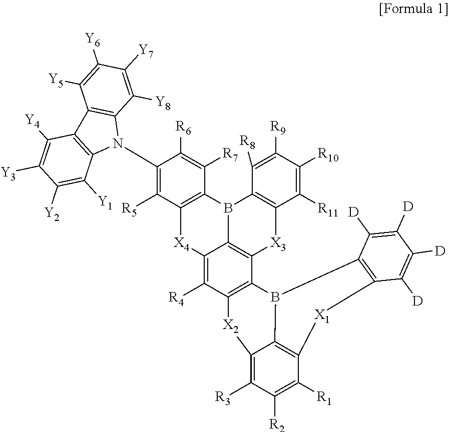
in Formula 1,
X₁ to X₄ are each independently O, S or NAr,
Ar is a substituted or unsubstituted aryl group of 6 to 30 ring-forming carbon atoms, or a substituted or unsubstituted heteroaryl group of 2 to 30 ring-forming carbon atoms,
R₁ to R₁₁ and Y₁ to Y₈ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
D is a deuterium atom.

2. The light emitting device of claim 1, wherein the first compound represented by Formula 1 is represented by a compound of Formula 2-1, Formula 2-2, or Formula 2-3: 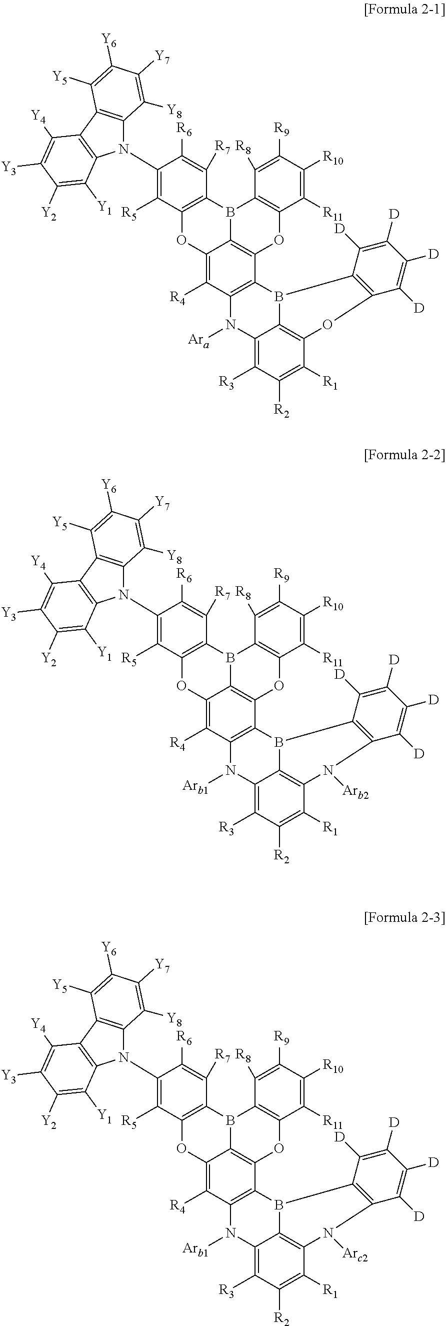
in Formula 2-1, Formula 2-2, and Formula 2-3,
Arₐ, Ar_{b1}, Ar_{b2}, Ar_{c1}, Ar_{c2}, and Ar_{c3} are each independently a substituted or unsubstituted aryl group of 6 to 30 ring-forming carbon atoms, or a substituted or unsubstituted heteroaryl group of 2 to 30 ring-forming carbon atoms, and
Formula 2-1, Formula 2-2, and Formula 2-3 comprise a structure in which an arbitrary hydrogen atom is substituted with a deuterium atom.

3. The light emitting device of claim 2, wherein, in Formula 2-1, Formula 2-2, and Formula 2-3, Arₐ, Ar_{b1}, Ar_{b2}, Ar_{c1}, Ar_{c2}, and Ar_{c3} are each independently a substituted or unsubstituted phenyl group, a substituted or unsubstituted divalent biphenyl group, or a substituted or unsubstituted terphenyl group.

4. The light emitting device of claim 1, wherein the first compound represented by Formula 1 is represented by a compound of Formula 2-4 to Formula 2-10: 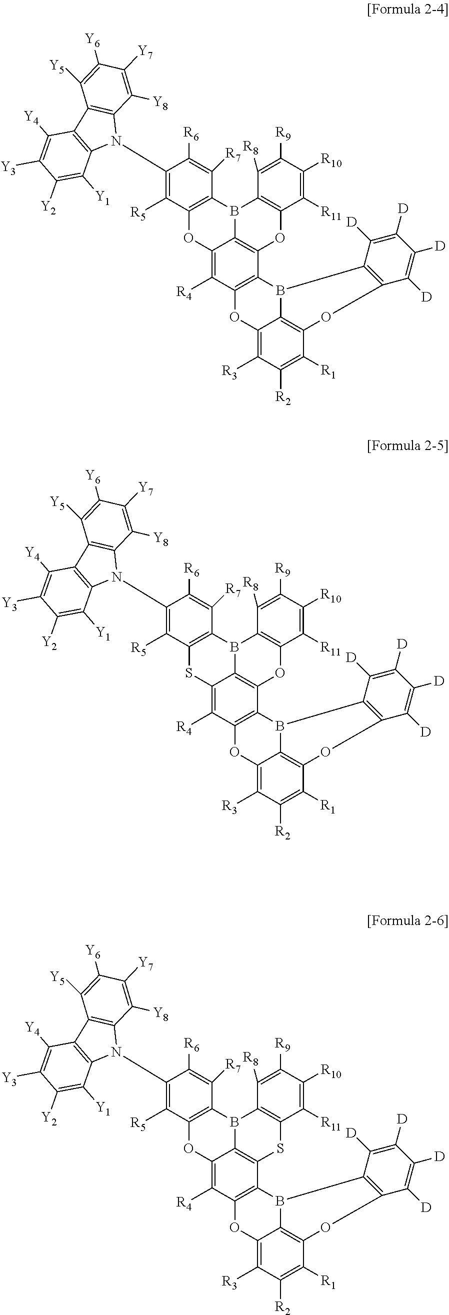 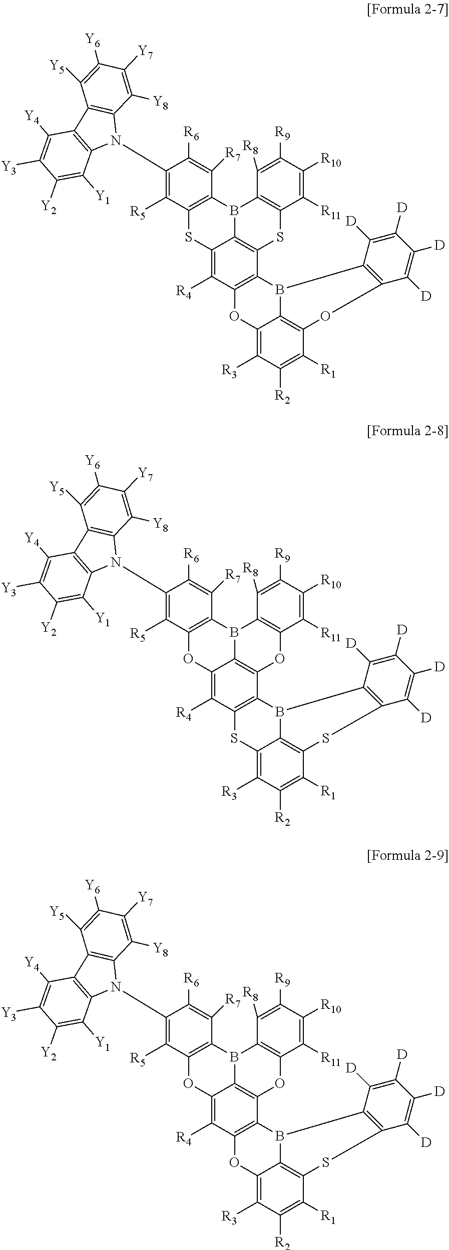 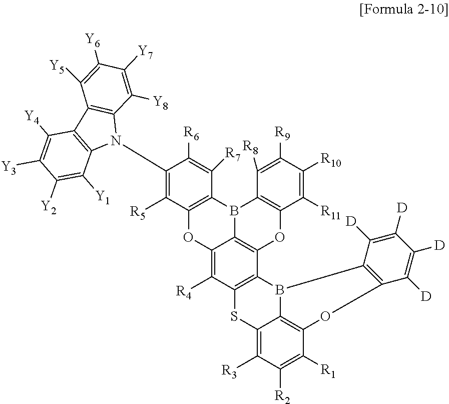
in Formula 2-4 to Formula 2-10,
Formula 2-4 to Formula 2-10 comprise a structure in which an arbitrary hydrogen atom is substituted with a deuterium atom.

5. The light emitting device of claim 1, wherein the first compound represented by Formula 1 is represented by a compound of Formula 3-1 or Formula 3-2: 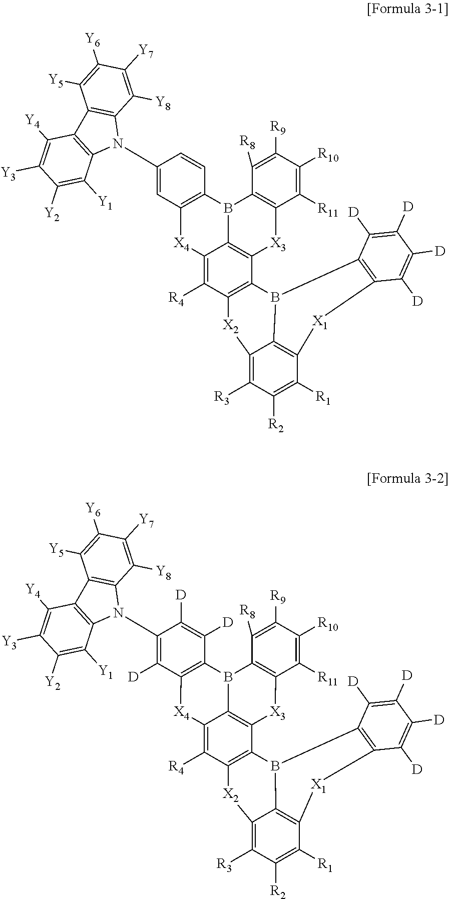
in Formula 3-1 and Formula 3-2,
R₁ to R₄, R₈ to R₁₁, and Y₁ to Y₈ are the same as defined in Formula 1.

6. The light emitting device of claim 1, wherein the first compound represented by Formula 1 is represented by a compound of Formula 4-1 to Formula 4-8: 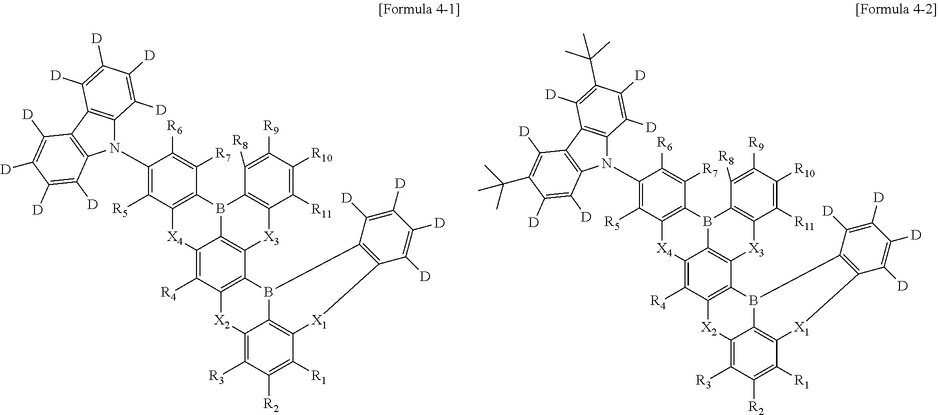 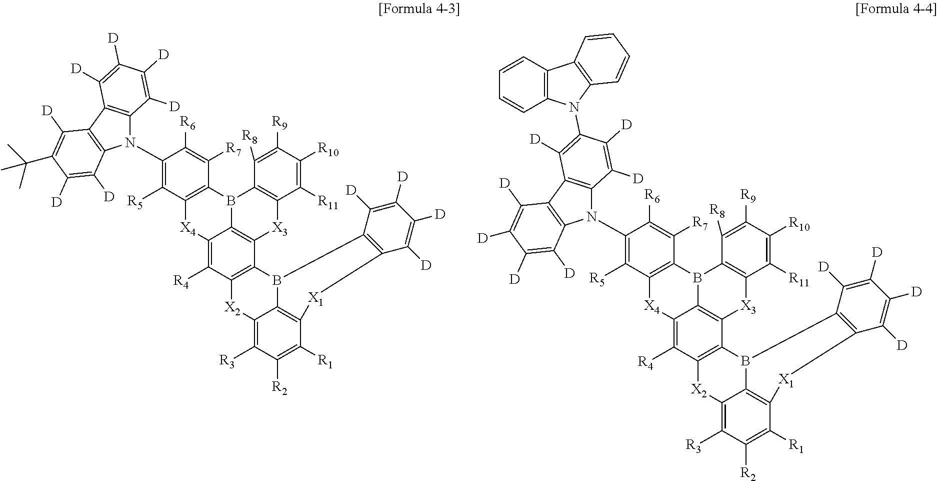 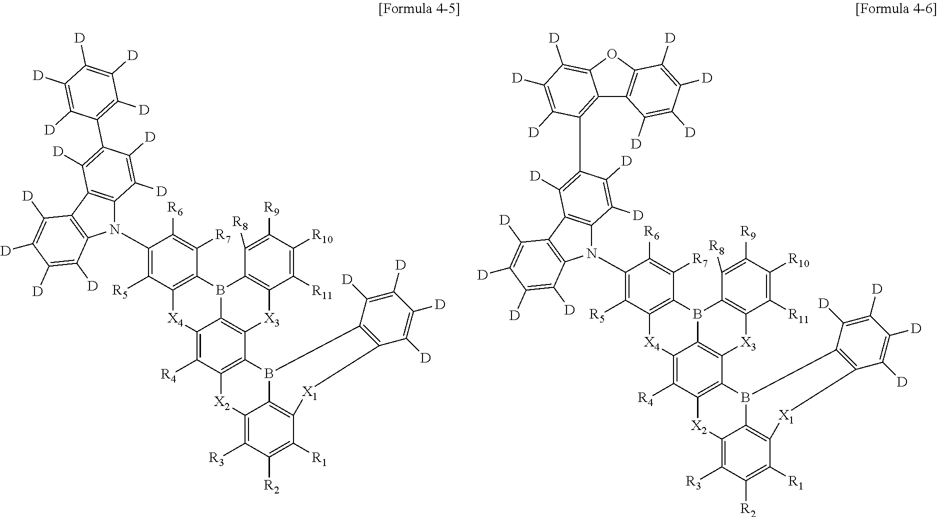 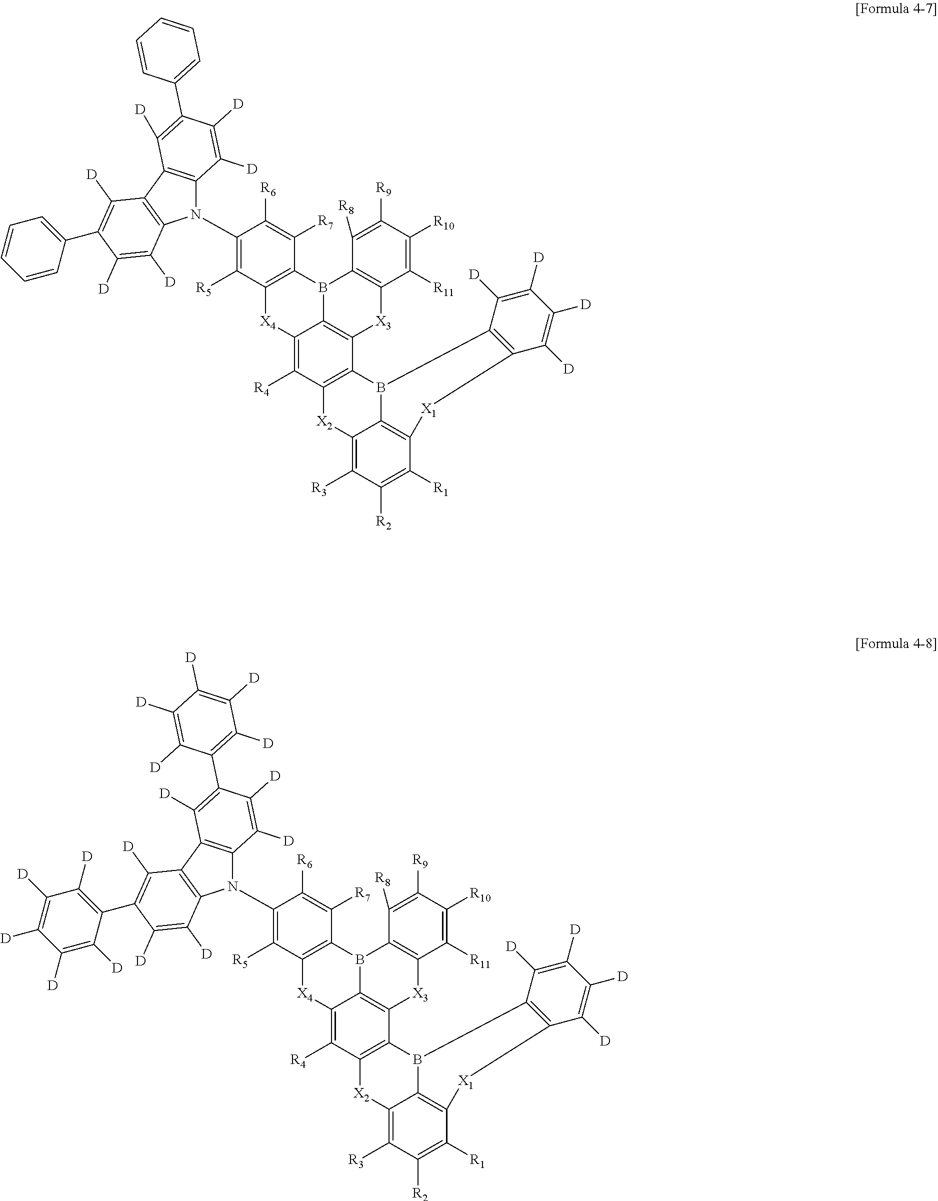
in Formula 4-1 to Formula 4-8,
Formula 4-1 to Formula 4-8 comprise a structure in which an arbitrary hydrogen atom is substituted with a deuterium atom.

7. The light emitting device of claim 1, wherein the first compound represented by Formula 1 is represented by a compound of Formula 5-1 to Formula 5-12: 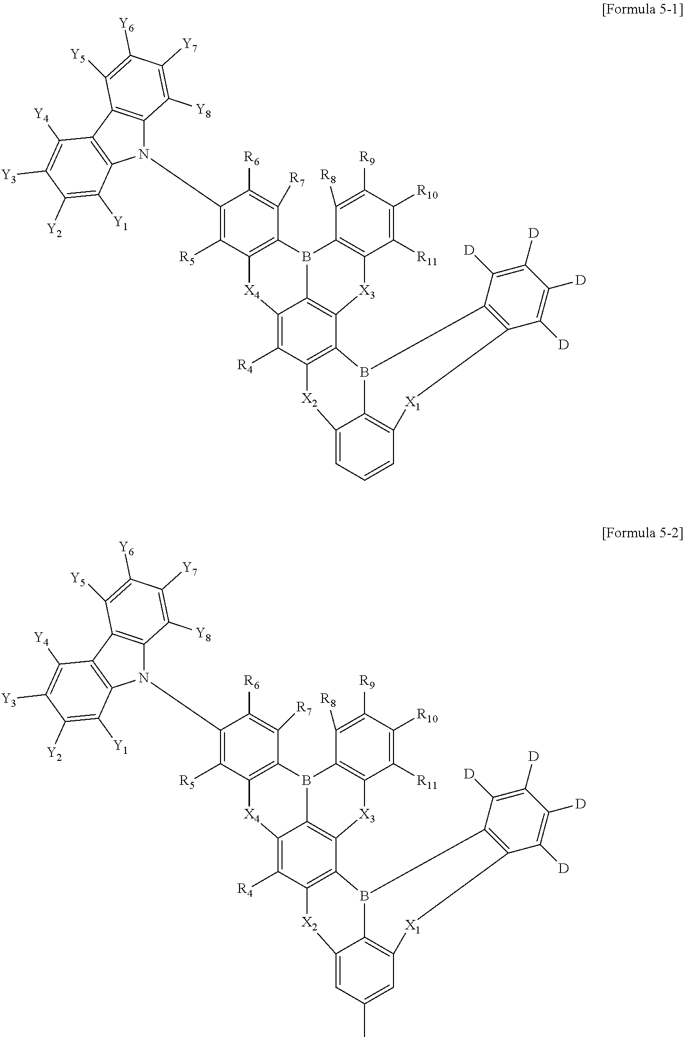 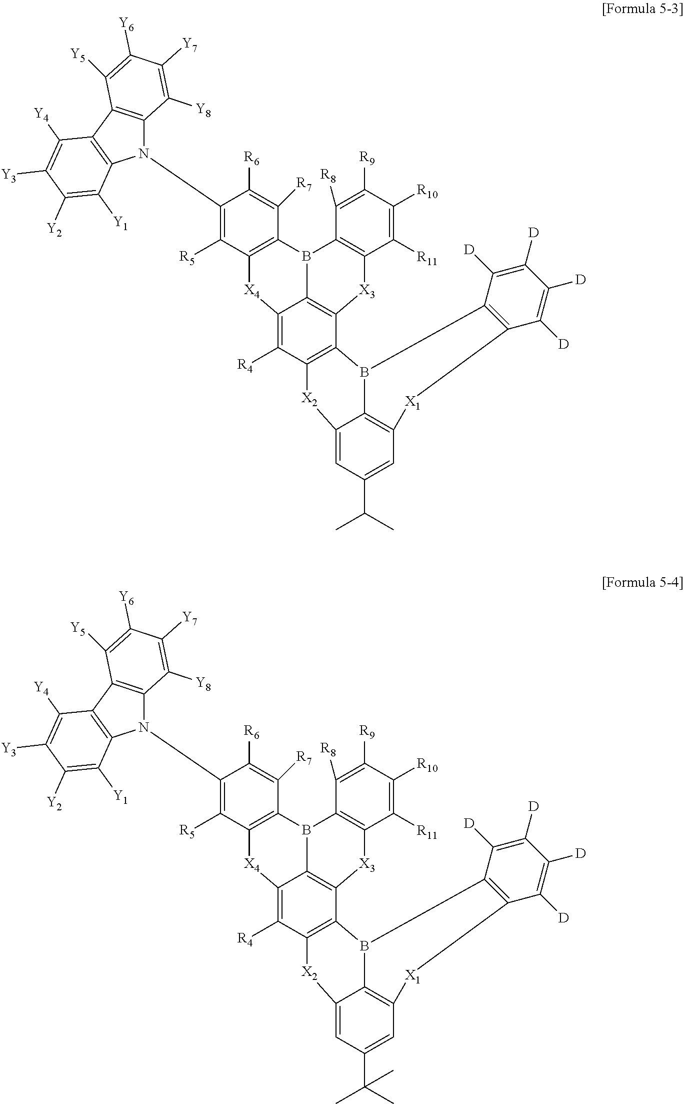 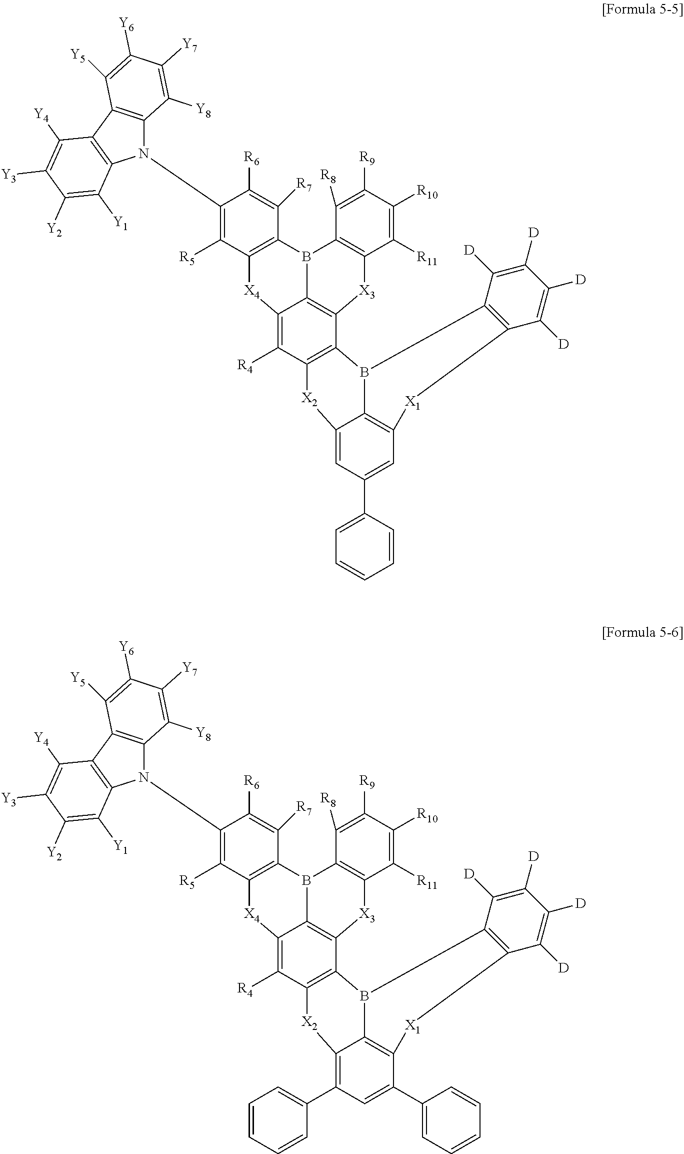 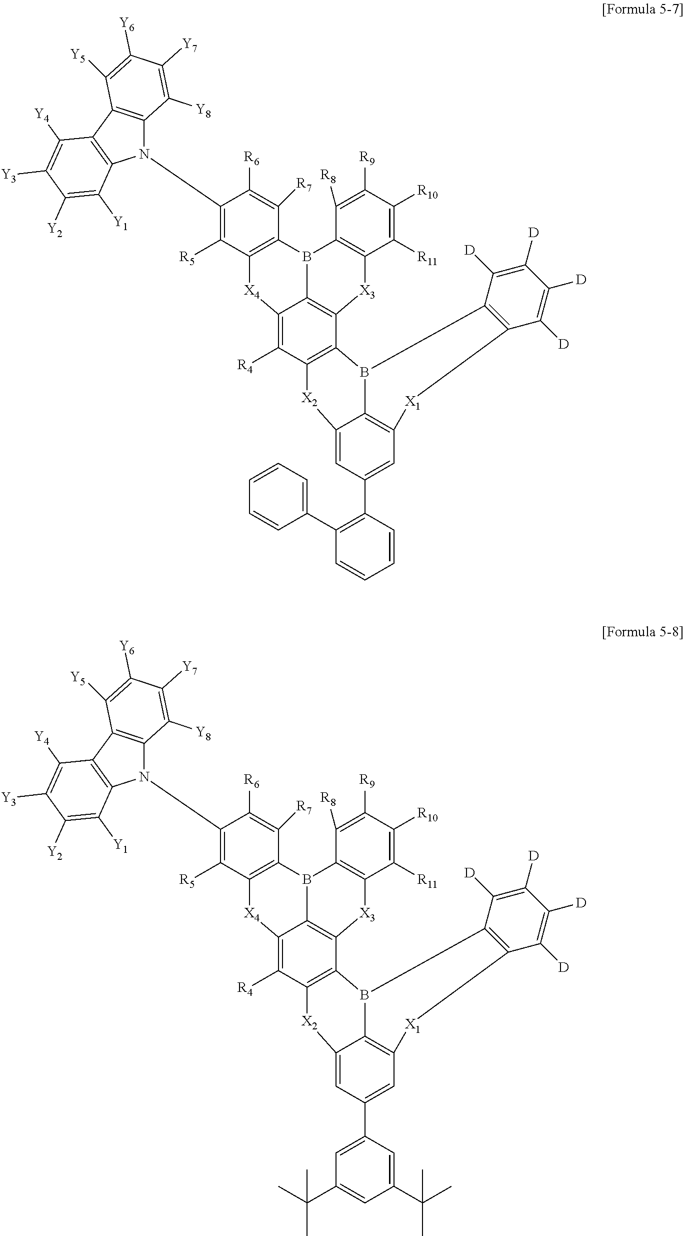 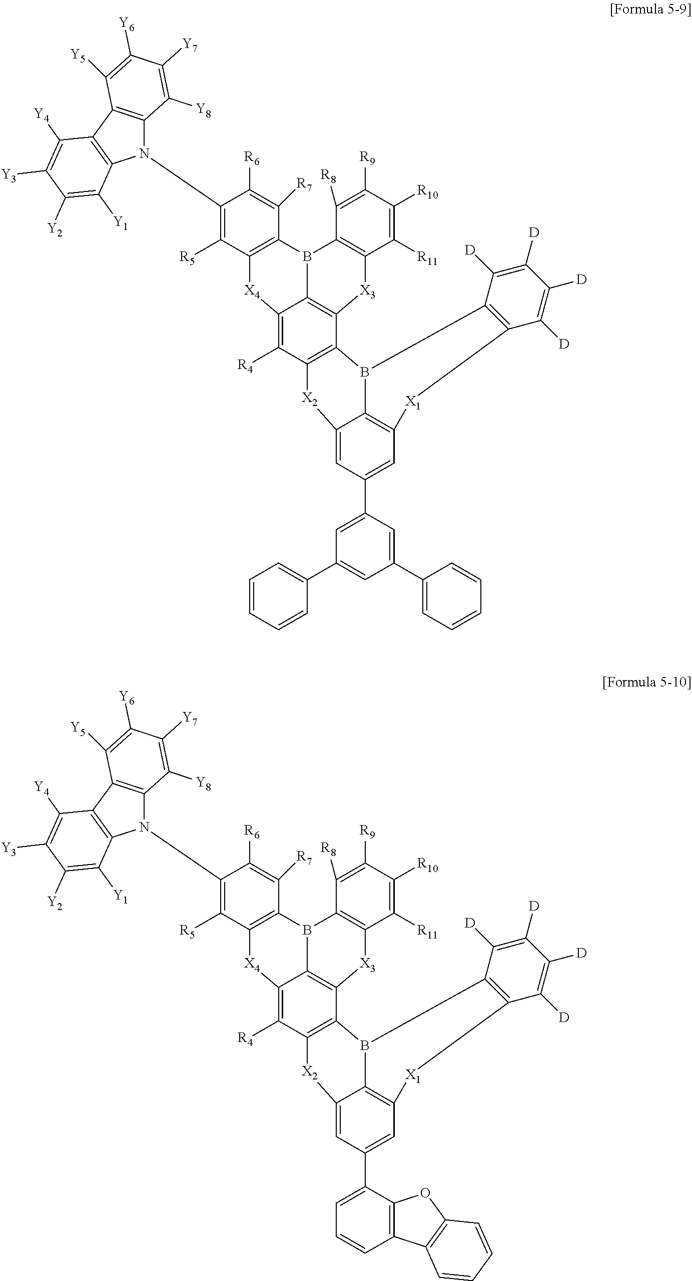 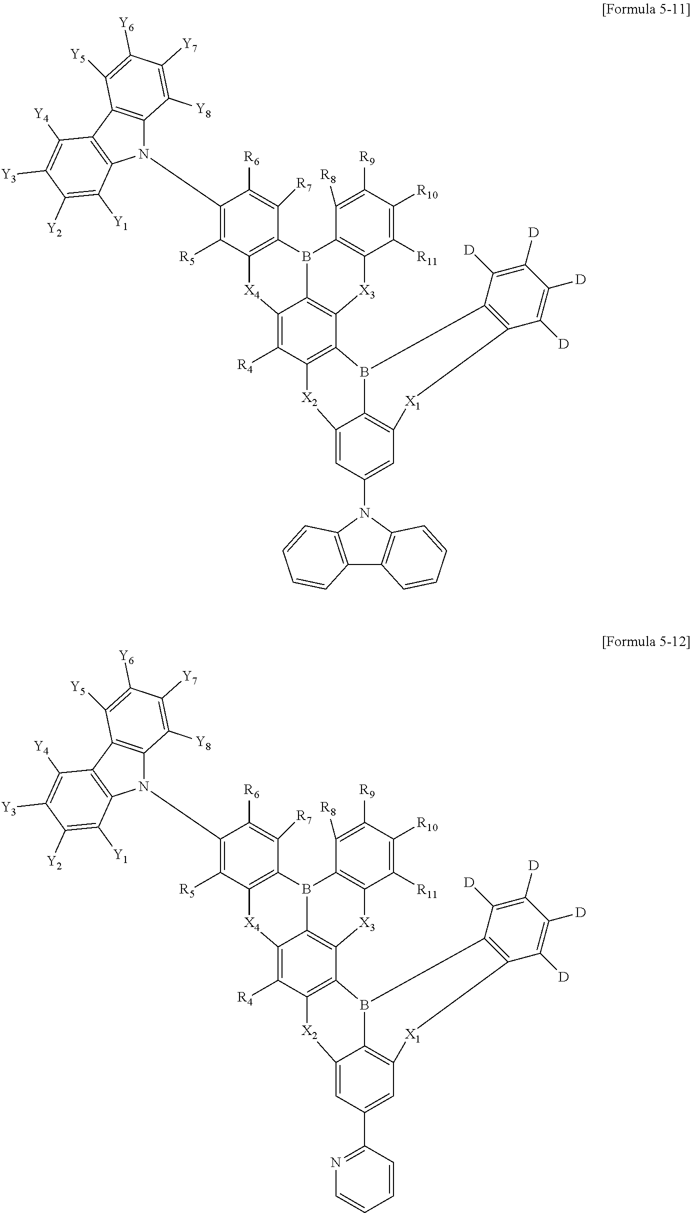
in Formula 5-1 to Formula 5-12,
Formula 5-1 to Formula 5-12 comprise a structure in which an arbitrary hydrogen atom is substituted with a deuterium atom.

8. The light emitting device of claim 1, wherein R₈ to R₁₁ are each independently a hydrogen atom, a deuterium atom, or any one group of Formula S-1 to Formula S-5: 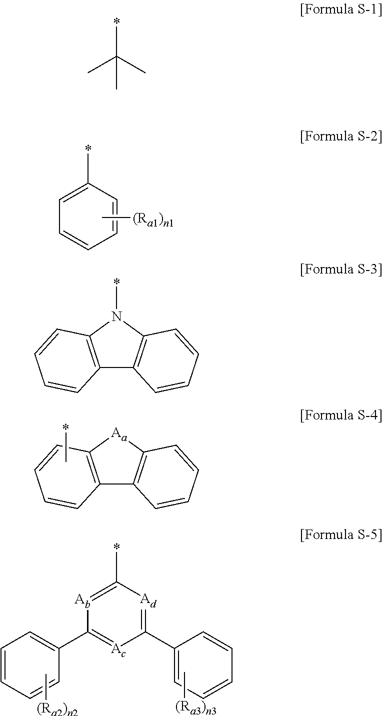
in Formula S-1 to Formula S-5,
Aₐ is O, S, or NAr_{d},
A_{b}, A_{c}, and A_{d} are each independently N or CH,
Ar_{d} is a substituted or unsubstituted aryl group of 6 to 30 ring-forming carbon atoms,
Rₐ₁, Rₐ₂, and Rₐ₃ are each independently a hydrogen atom, a deuterium atom, a substituted or unsubstituted alkyl group of 1 to 20 carbon atoms, or a substituted or unsubstituted aryl group of 6 to 30 ring-forming carbon atoms,
n1 is an integer of 0 to 5,
n2 and n3 are each independently an integer of 0 to 4, and [symbol]
represents a connection of the group Formula S-1 to Formula S-5 in the compound of Formula 1, and Formula S-1 to Formula S-5 comprise a structure in which an arbitrary hydrogen atom is substituted with a deuterium atom.

9. The light emitting device of claim 1, wherein, in Formula 1,
R₈, R₉ and R₁₁ are each independently a hydrogen atom or a deuterium atom, and
R₁₀ is represented by a group of Formula S-1 to Formula S-5.

10. The light emitting device of claim 1, wherein the first compound represented by Formula 1 comprises at least one compound in Compound Group 1: 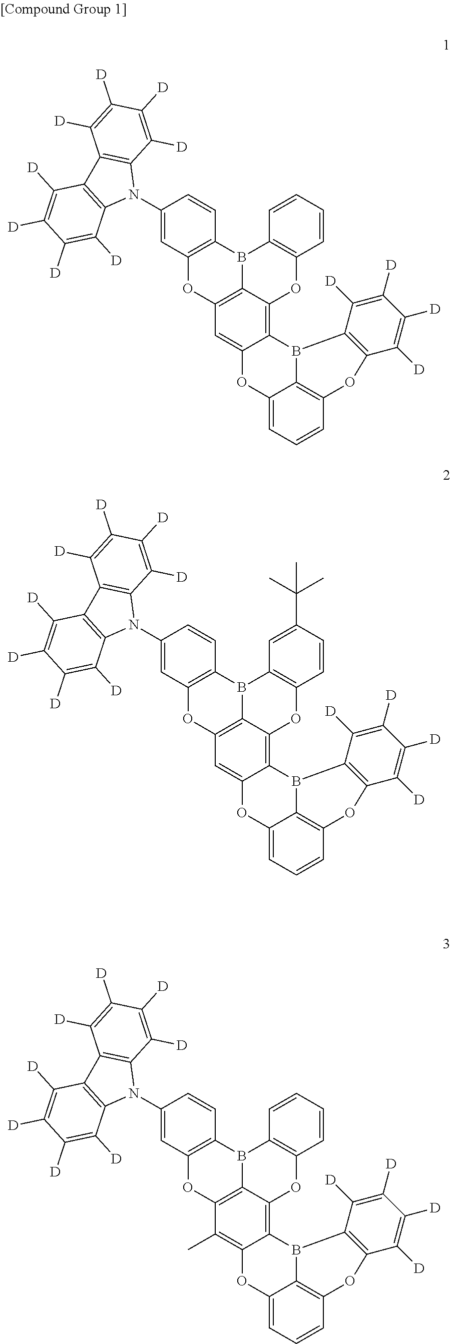 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1O2)O3] 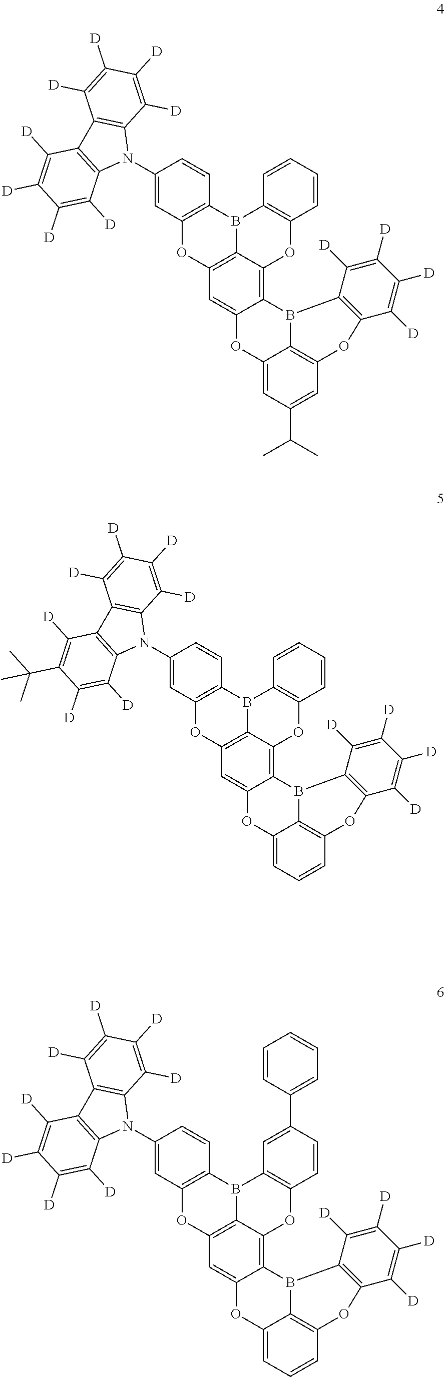 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3] 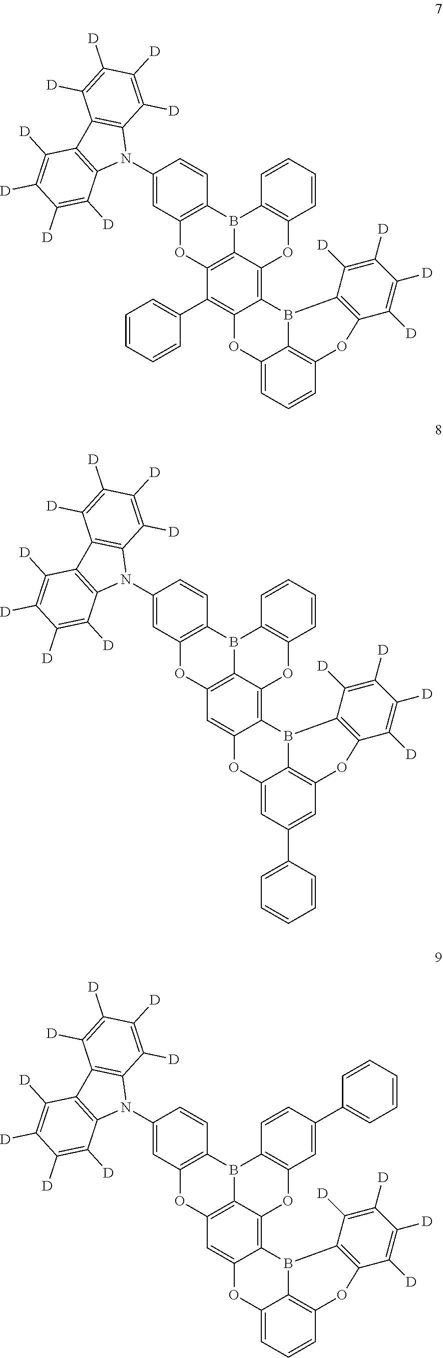 [SMILES: [2H]c1c([2H])c([2H])c2c(c1[2H])Oc1cccc3c1B2c1c2c4c(c(-c5ccccc5)c1O3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)O3] 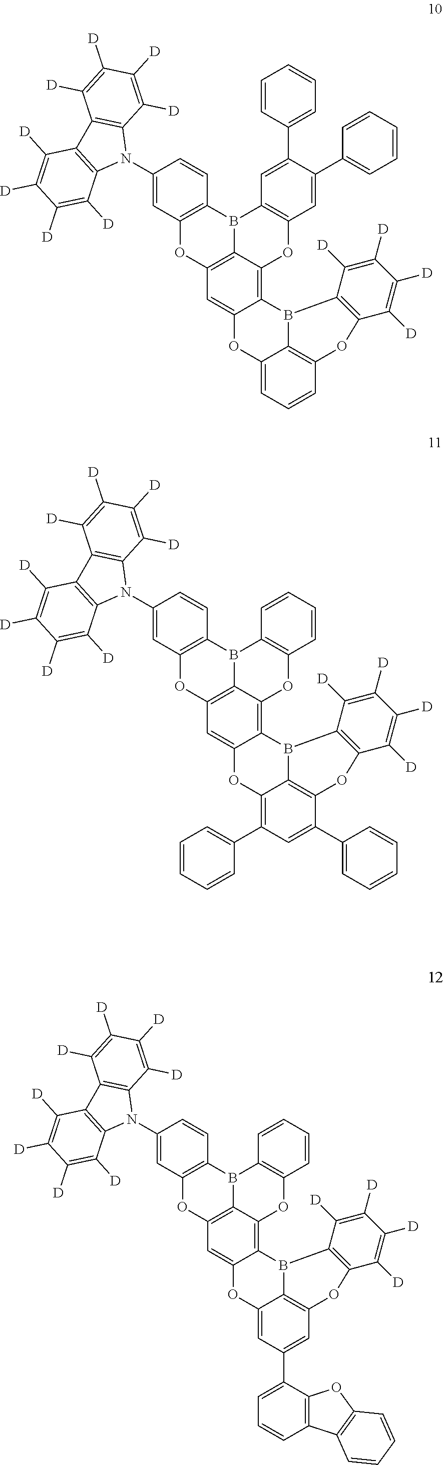 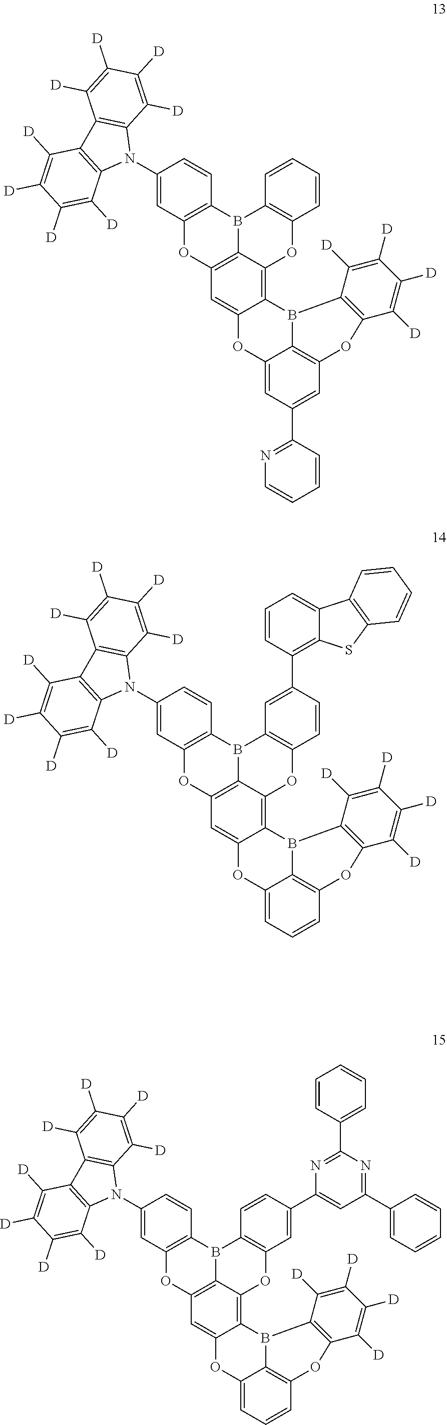 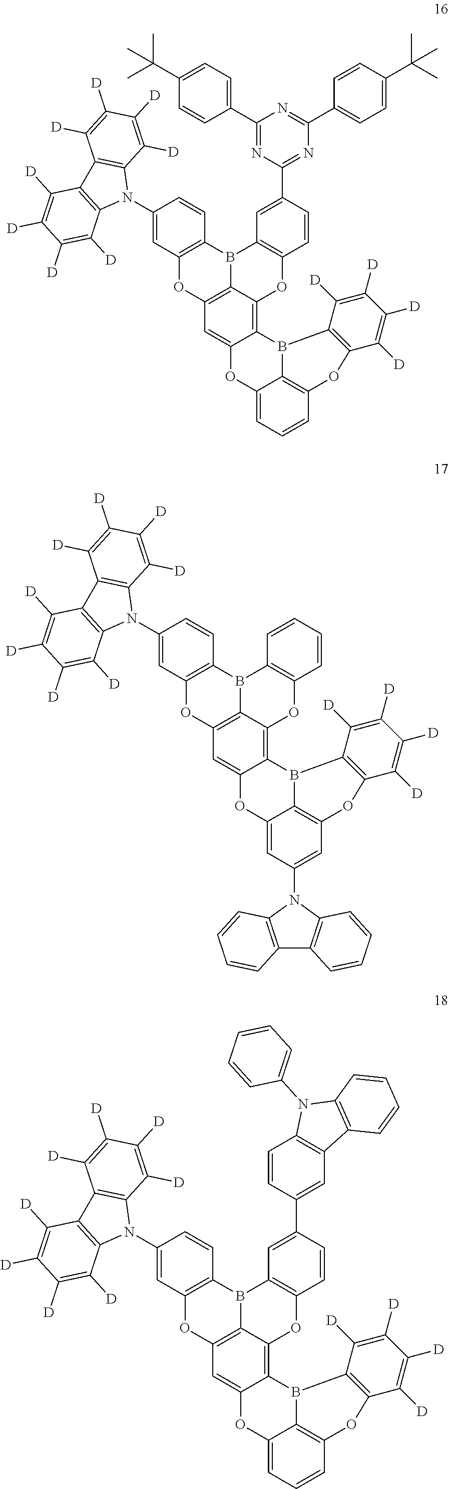 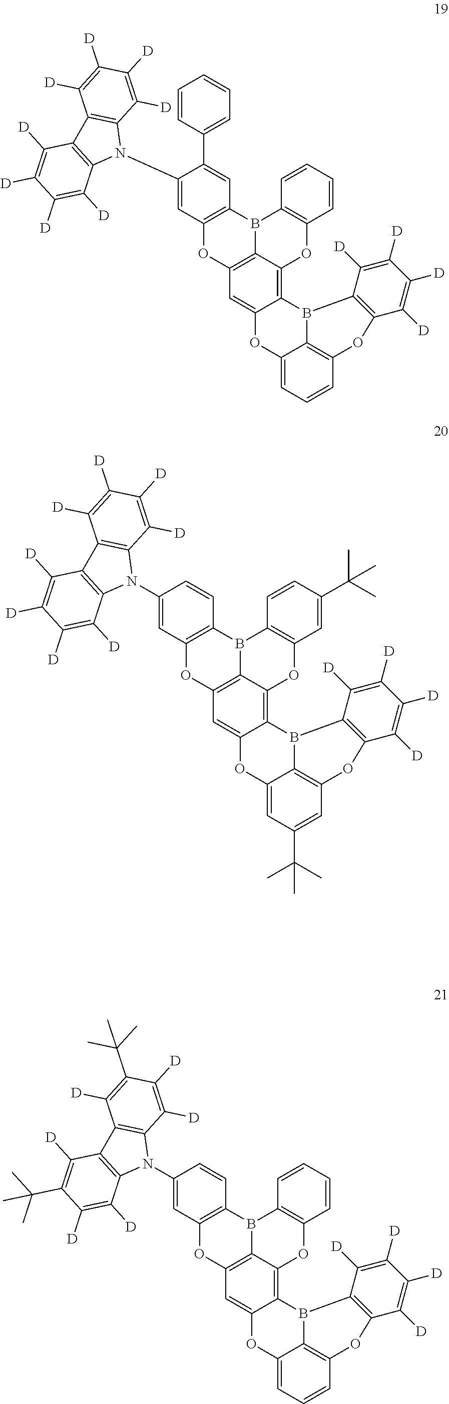 [SMILES: [2H]c1c([2H])c([2H])c2c(c1[2H])Oc1cccc3c1B2c1c(cc2c4c1Oc1ccccc1B4c1cc(-c4ccccc4)c(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(C(C)(C)C)cc3c1B2c1c(cc2c4c1Oc1cc(C(C)(C)C)ccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c(C(C)(C)C)c([2H])c5c5c([2H])c(C(C)(C)C)c([2H])c([2H])c54)cc1O2)O3] 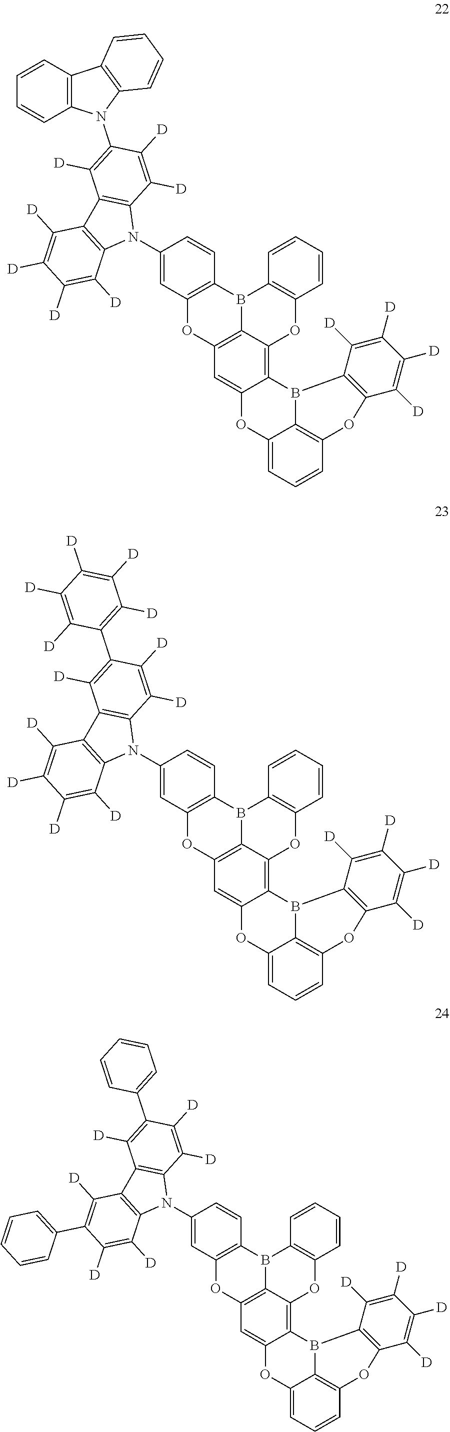 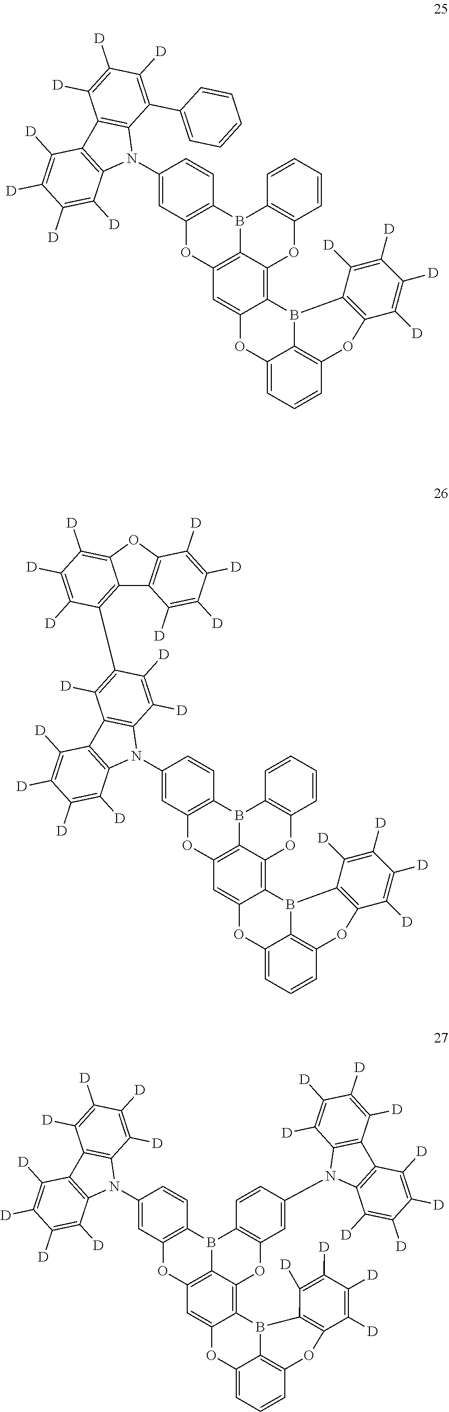 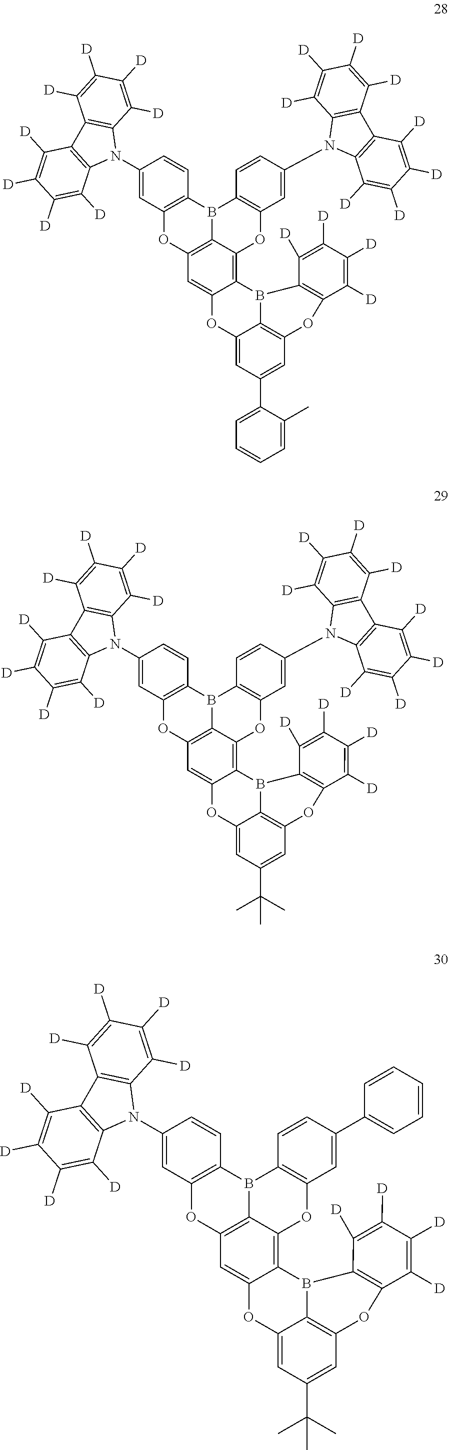 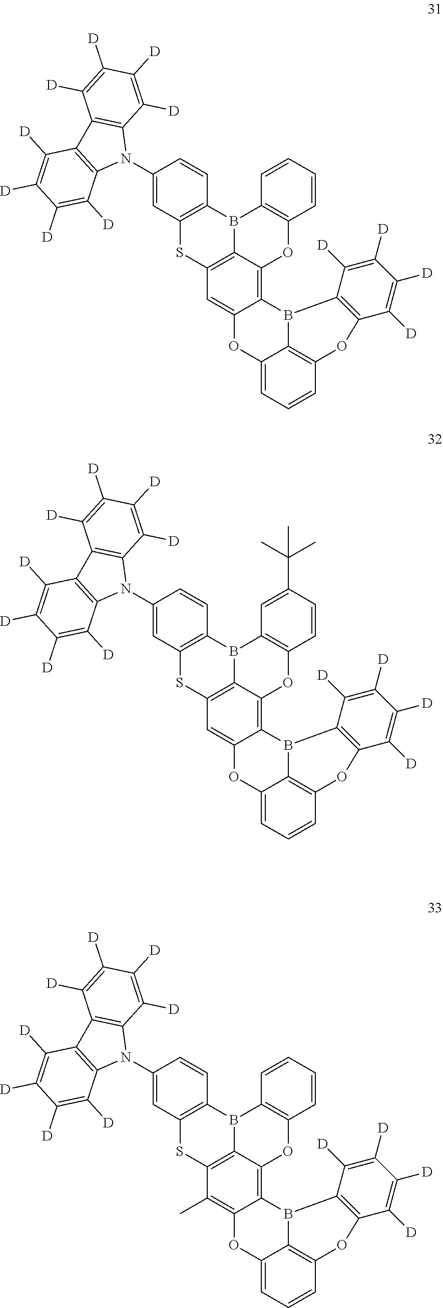 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1S2)O3] 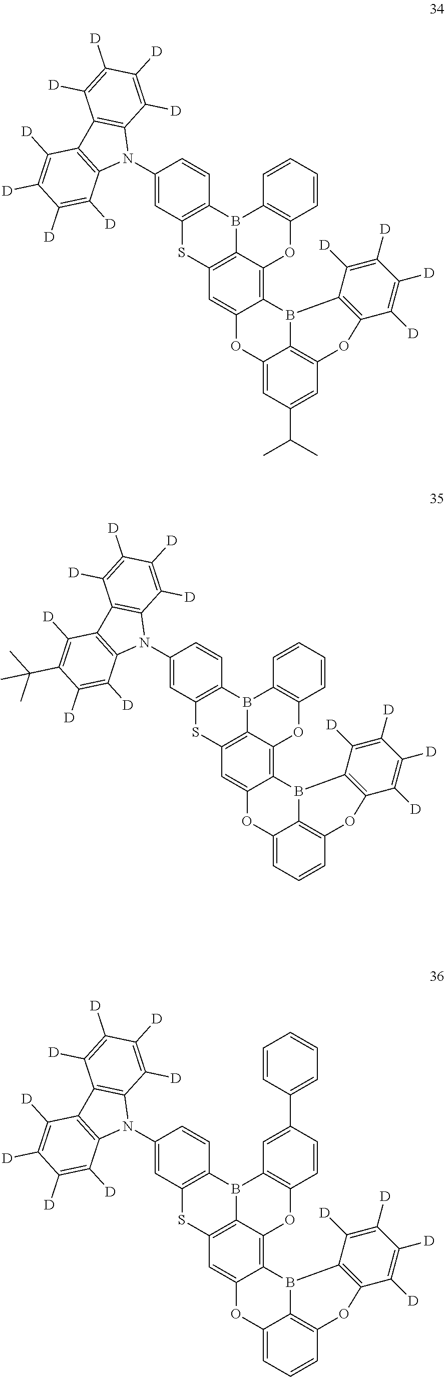 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1S2)O3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1S2)O3] 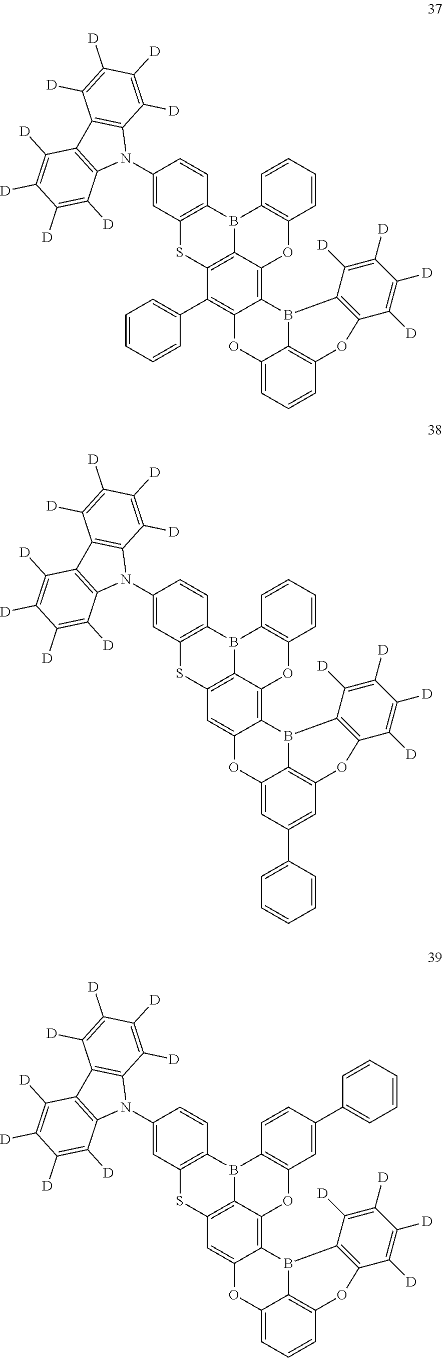 [SMILES: [2H]c1c([2H])c([2H])c2c(c1[2H])Oc1cccc3c1B2c1c2c4c(c(-c5ccccc5)c1O3)Sc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1S2)O3] 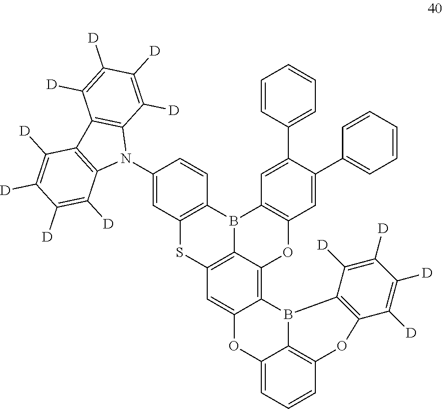 [SMILES: [2H]c1c([2H])c([2H])c2c(c1[2H])Oc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1S2)O3] 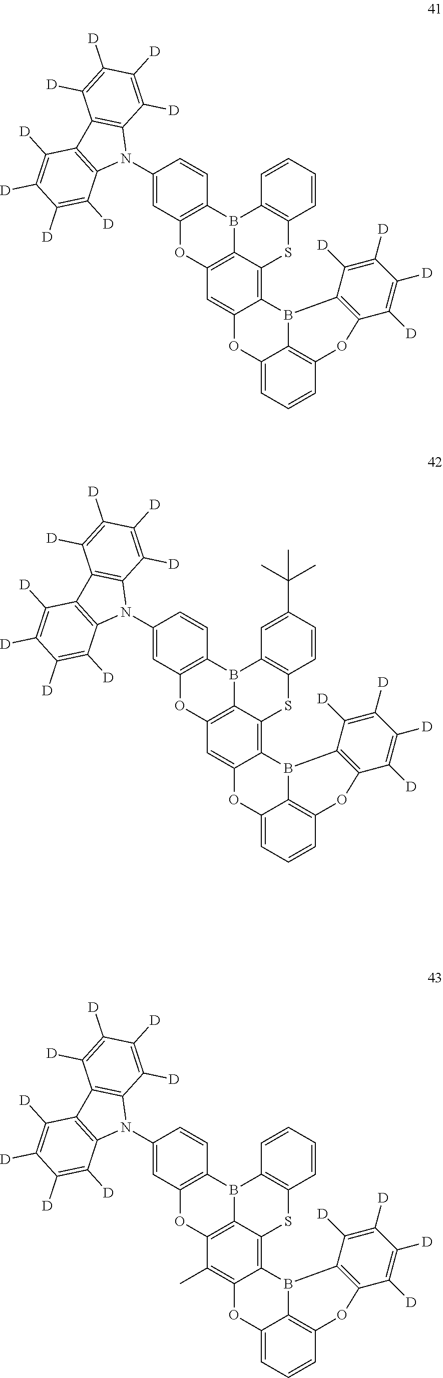 [SMILES: [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(c(C)c2c4c1Sc1ccccc1B4c1ccc(-n4c5c([2H])c([2H])c([2H])c([2H])c5c5c([2H])c([2H])c([2H])c([2H])c54)cc1O2)O3] 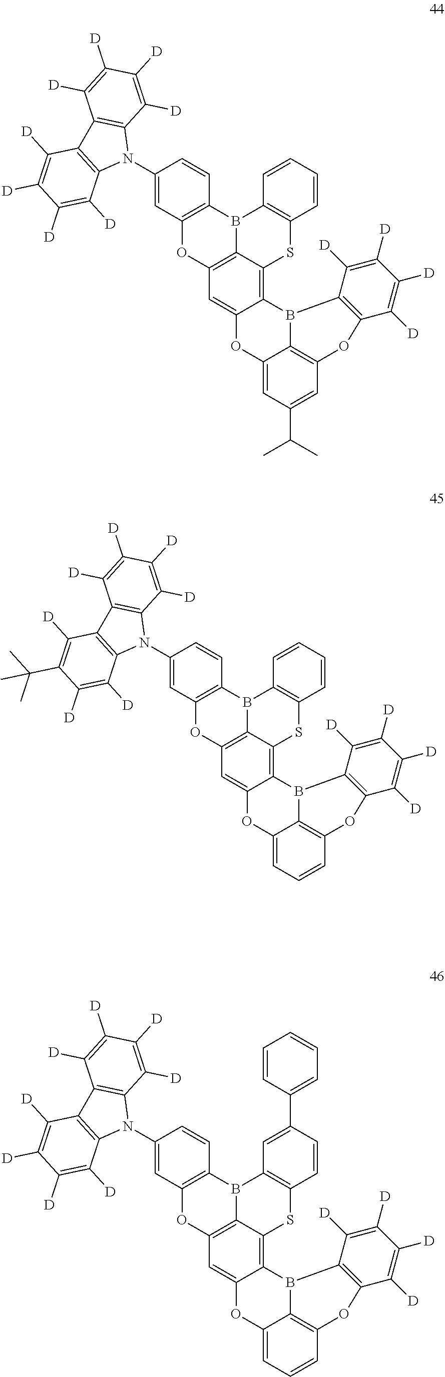 [SMILES: [2H]c1c([2H])c([2H])c2c(c1[2H])Oc1cc(C(C)C)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Oc1cccc3c1B2c1c(cc2c4c1Sc1ccc(-c5ccccc5)cc1B4c1ccc(-n4c5c([2H])c([2H])c([2H])c([2H])c5c5c([2H])c([2H])c([2H])c([2H])c54)cc1O2)O3] 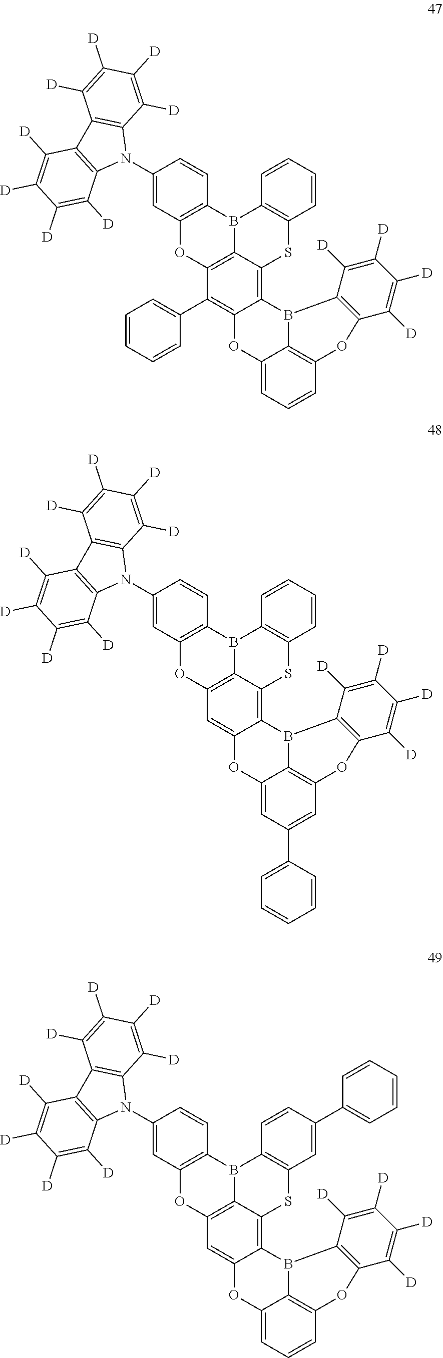 [SMILES: [2H]c1c([2H])c([2H])c2c(c1[2H])Oc1cccc3c1B2c1c(c(-c2ccccc2)c2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(-c3ccccc3)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1cc(-c5ccccc5)ccc1B4c1ccc(-n4c5c([2H])c([2H])c([2H])c([2H])c5c5c([2H])c([2H])c([2H])c([2H])c54)cc1O2)O3] 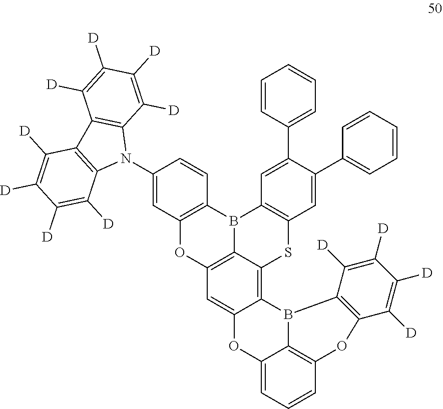 [SMILES: [2H]c1c([2H])c([2H])c2c(c1[2H])Oc1cccc3c1B2c1c(cc2c4c1Sc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)O3] 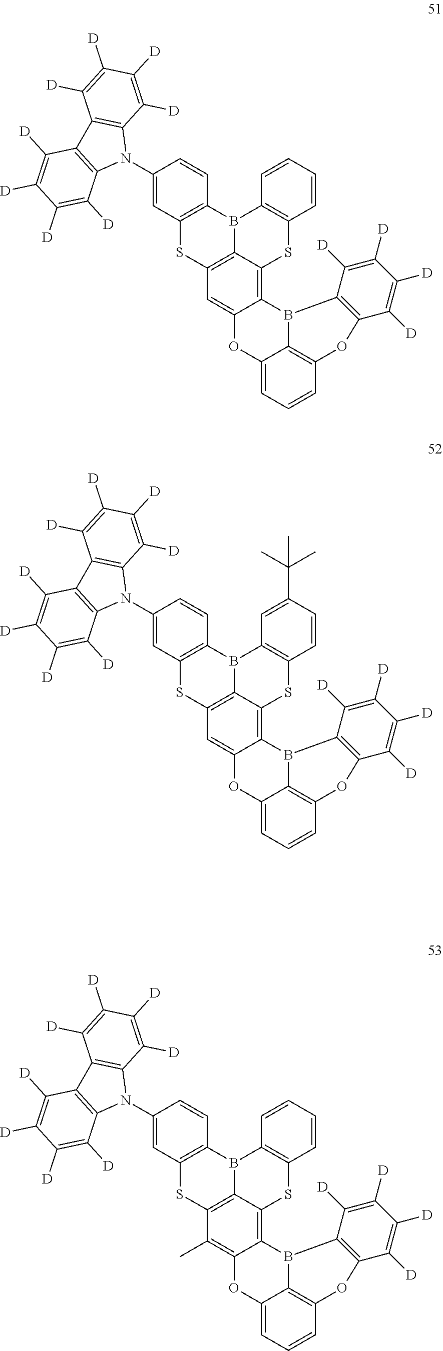 [SMILES: [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1ccc(C(C)(C)C)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(C)c2c4c1Sc1ccccc1B4c1ccc(-n4c5c([2H])c([2H])c([2H])c([2H])c5c5c([2H])c([2H])c([2H])c([2H])c54)cc1S2)O3] 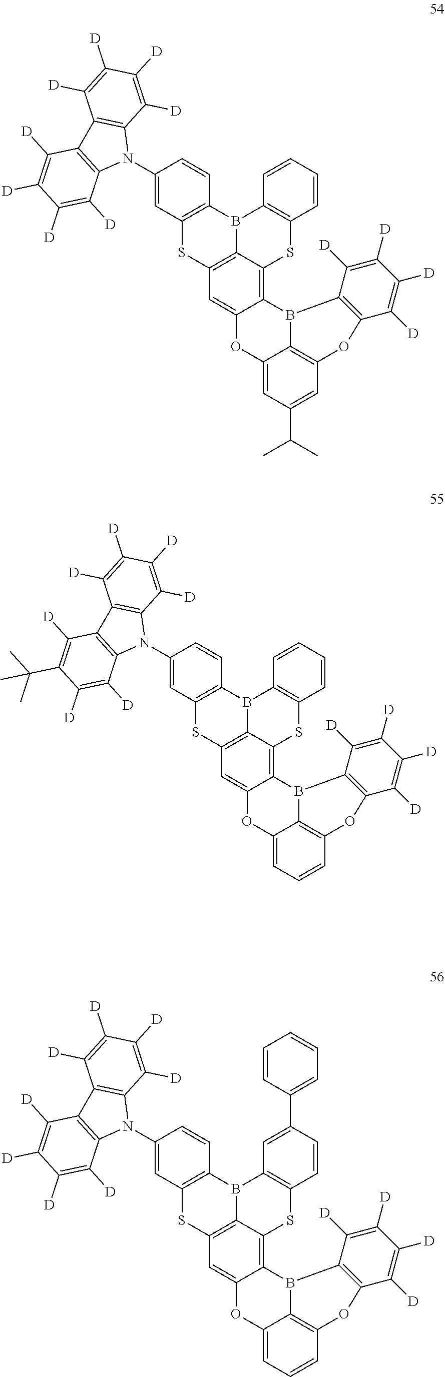 [SMILES: [2H]c1c([2H])c([2H])c2c(c1[2H])Oc1cc(C(C)C)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c(C(C)(C)C)c([2H])c([2H])c54)cc1S2)O3 ; [2H]c1c([2H])c([2H])c2c(c1[2H])Oc1cccc3c1B2c1c(cc2c4c1Sc1ccc(-c5ccccc5)cc1B4c1ccc(-n4c5c([2H])c([2H])c([2H])c([2H])c5c5c([2H])c([2H])c([2H])c([2H])c54)cc1S2)O3] 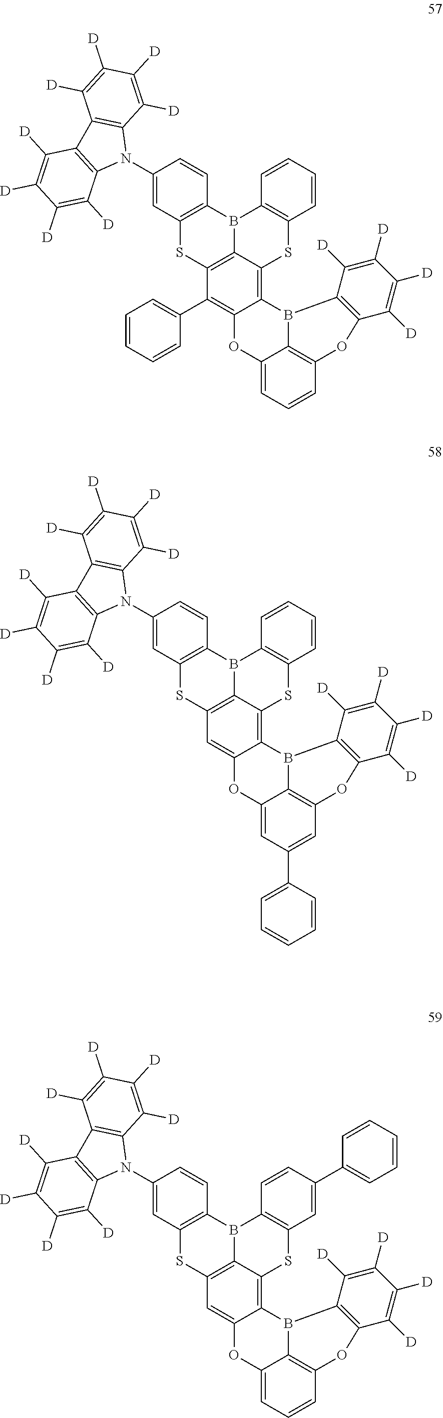 [SMILES: [2H]c1c([2H])c([2H])c2c(c1[2H])Oc1cccc3c1B2c1c(c(-c2ccccc2)c2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cc(-c3ccccc3)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1cc(-c5ccccc5)ccc1B4c1ccc(-n4c5c([2H])c([2H])c([2H])c([2H])c5c5c([2H])c([2H])c([2H])c([2H])c54)cc1S2)O3] 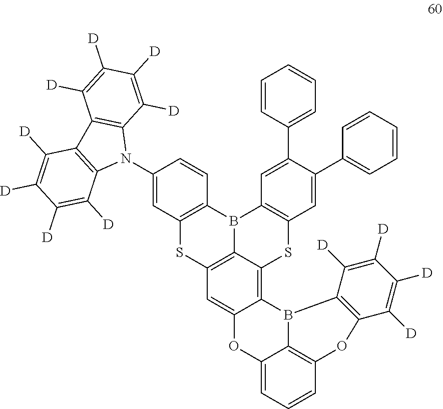 [SMILES: [2H]c1c([2H])c([2H])c2c(c1[2H])Oc1cccc3c1B2c1c(cc2c4c1Sc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1S2)O3] 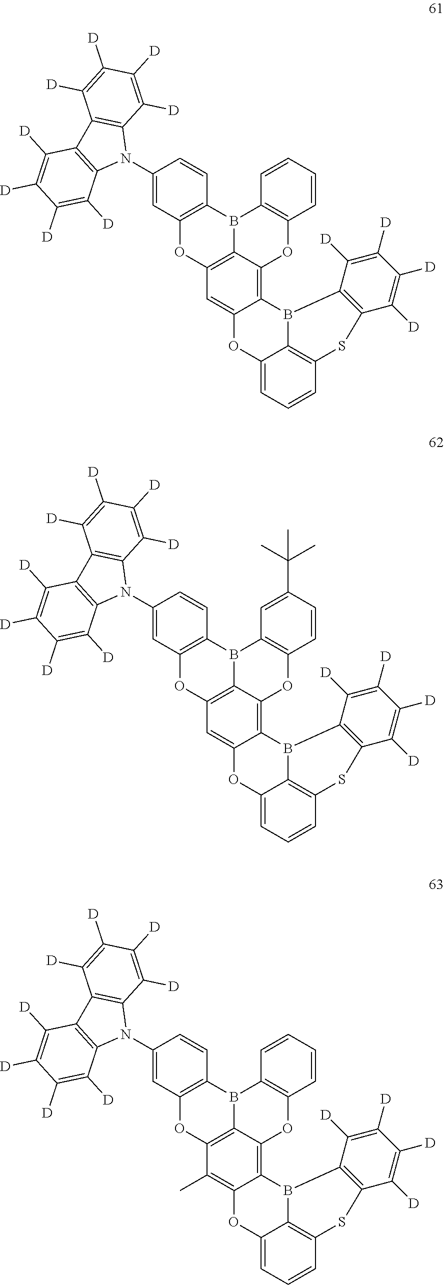 [SMILES: [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1O2)O3] 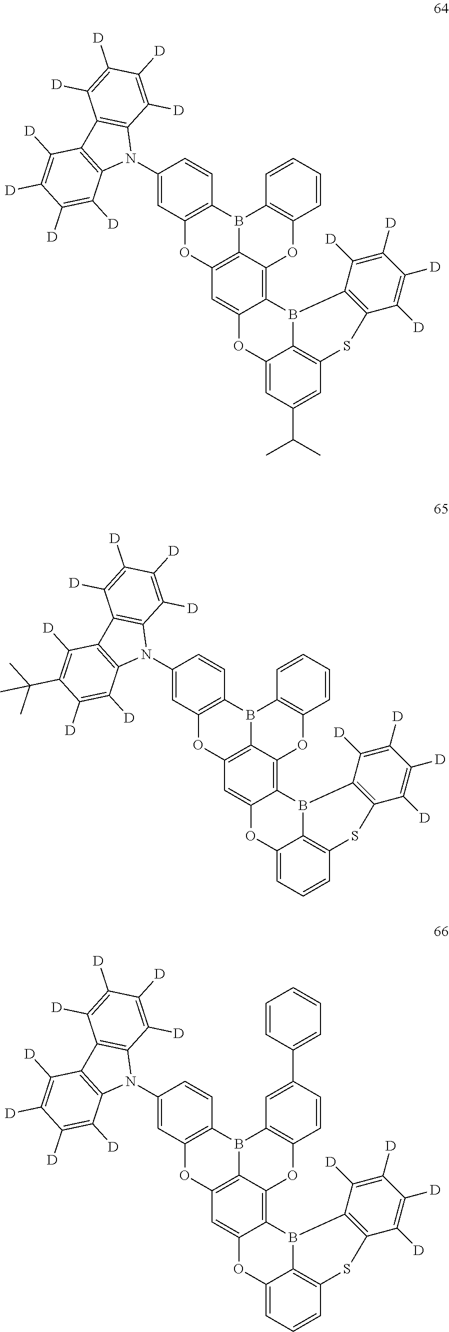 [SMILES: [2H]c1c([2H])c([2H])c2c(c1[2H])Sc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3] 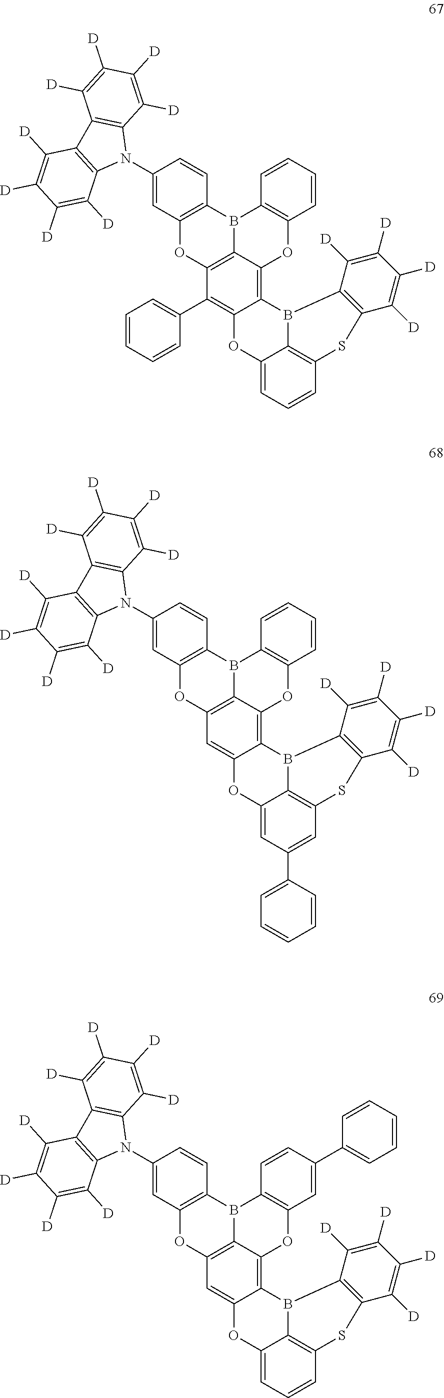 [SMILES: [2H]c1c([2H])c([2H])c2c(c1[2H])Sc1cccc3c1B2c1c2c4c(c(-c5ccccc5)c1O3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Sc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)O3] 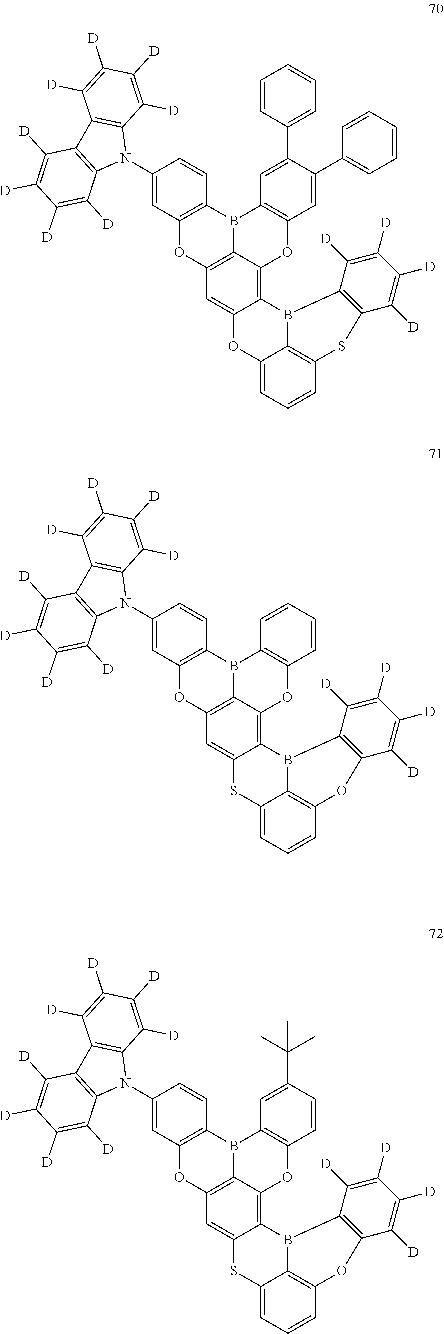 [SMILES: [2H]c1c([2H])c([2H])c2c(c1[2H])Sc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)S3] 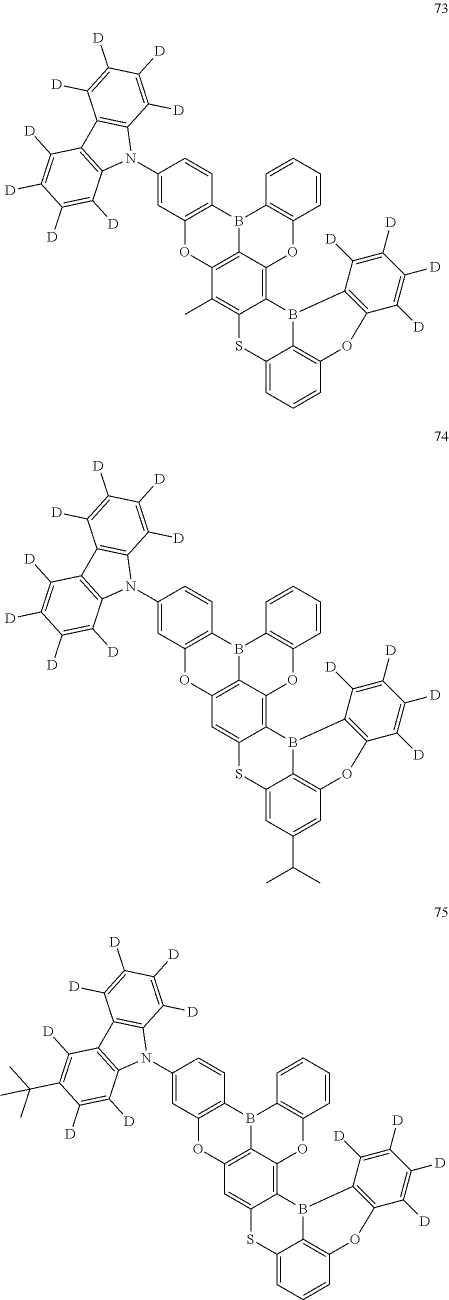 [SMILES: [2H]c1c([2H])c([2H])c2c(c1[2H])Oc1cccc3c1B2c1c2c4c(c(C)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)S3] 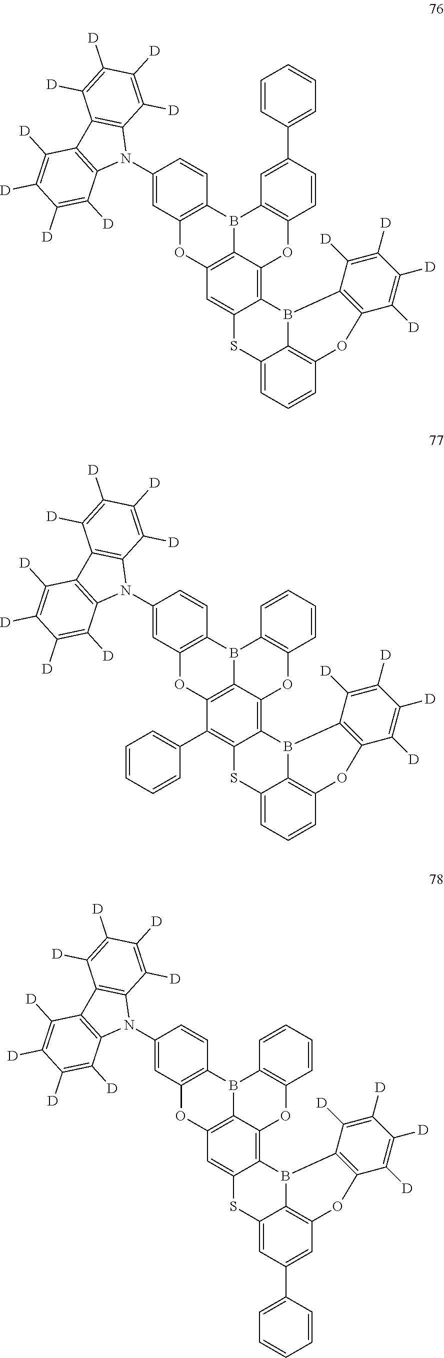 [SMILES: [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c2c4c(c(-c5ccccc5)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3] 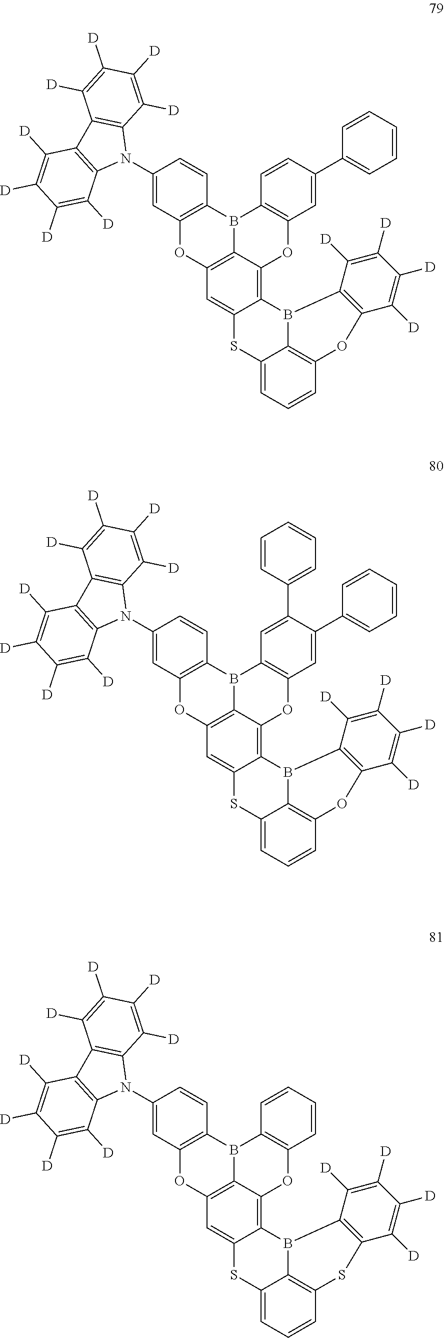 [SMILES: [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3] 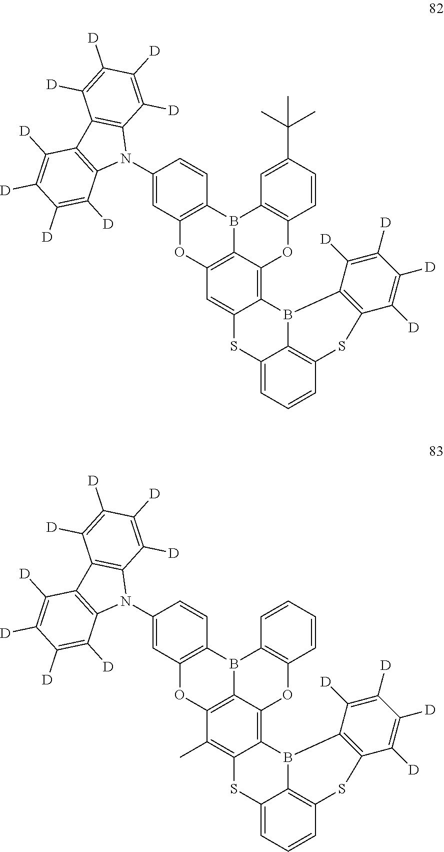 [SMILES: [2H]c1c([2H])c([2H])c2c(c1[2H])Sc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c2c4c(c(C)c1S3)Oc1cc(-n3c5c([2H])c([2H])c([2H])c([2H])c5c5c([2H])c([2H])c([2H])c([2H])c53)ccc1B4c1ccccc1O2] 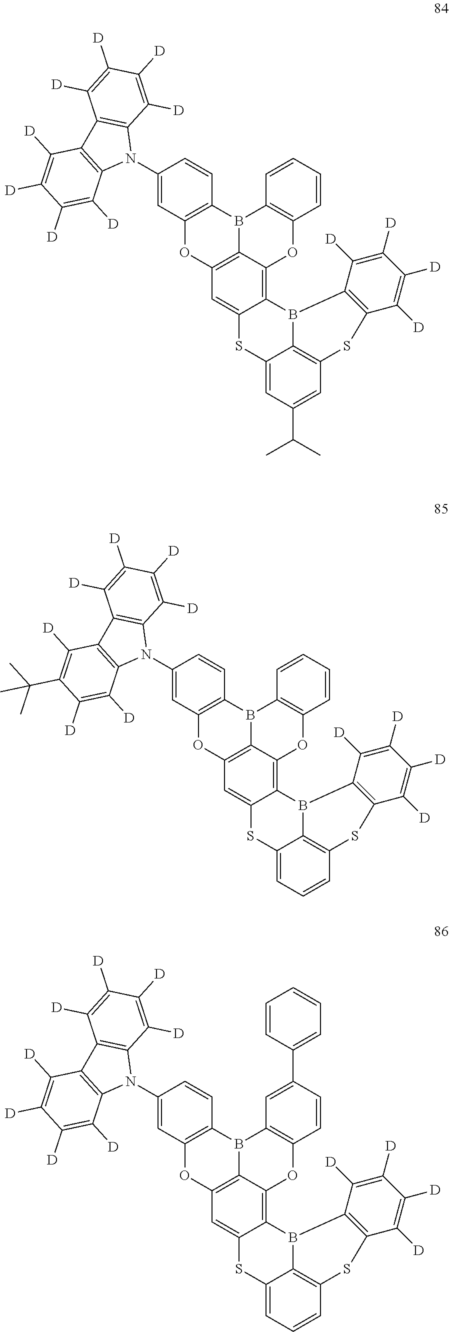 [SMILES: [2H]c1c([2H])c([2H])c2c(c1[2H])Sc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)S3 ; [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)S3] 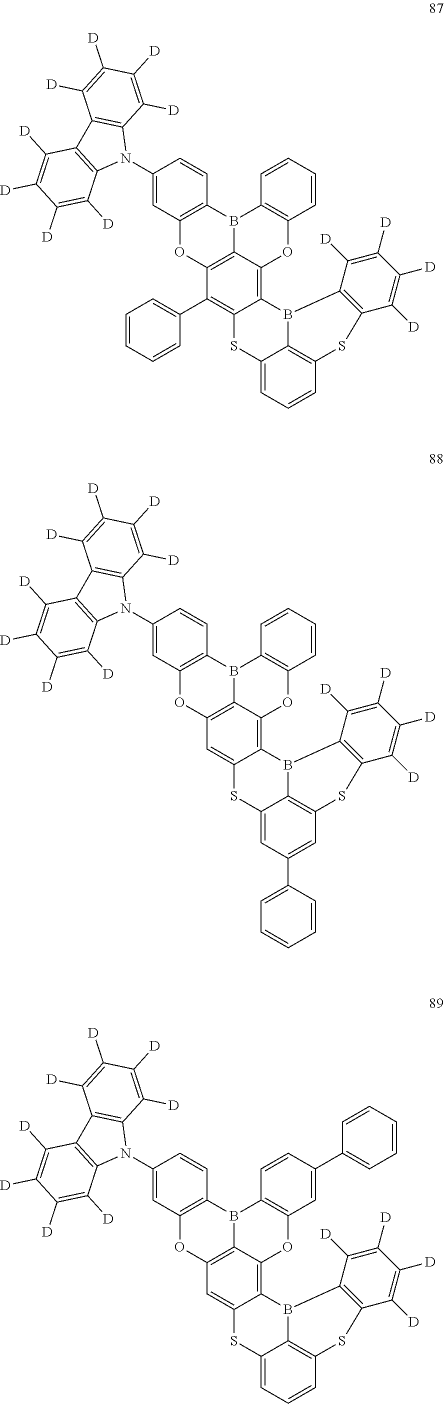 [SMILES: [2H]c1c([2H])c([2H])c2c(c1[2H])Sc1cccc3c1B2c1c2c4c(c(-c5ccccc5)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Sc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)S3] 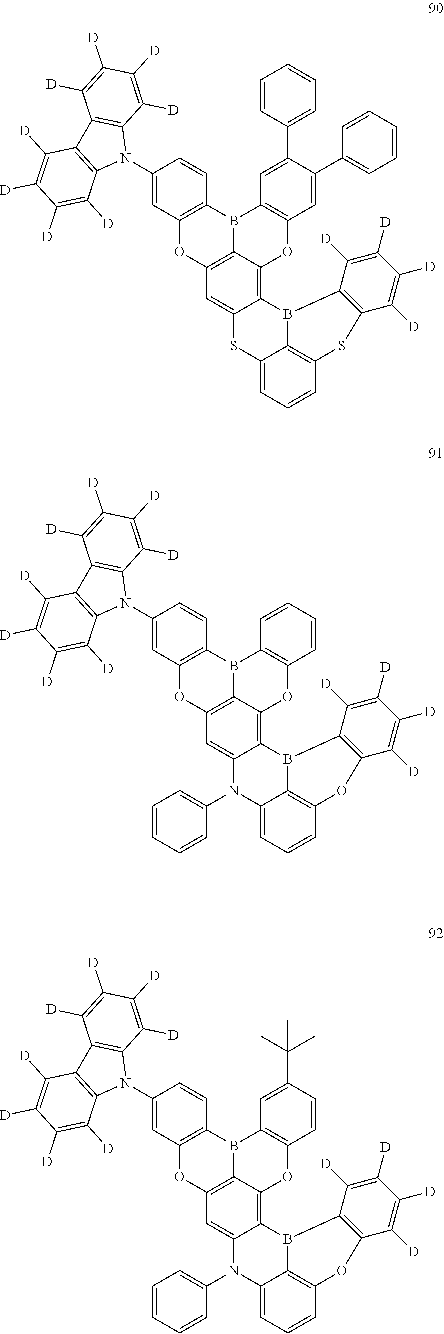 [SMILES: [2H]c1c([2H])c([2H])c2c(c1[2H])Sc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)N3c1ccccc1] 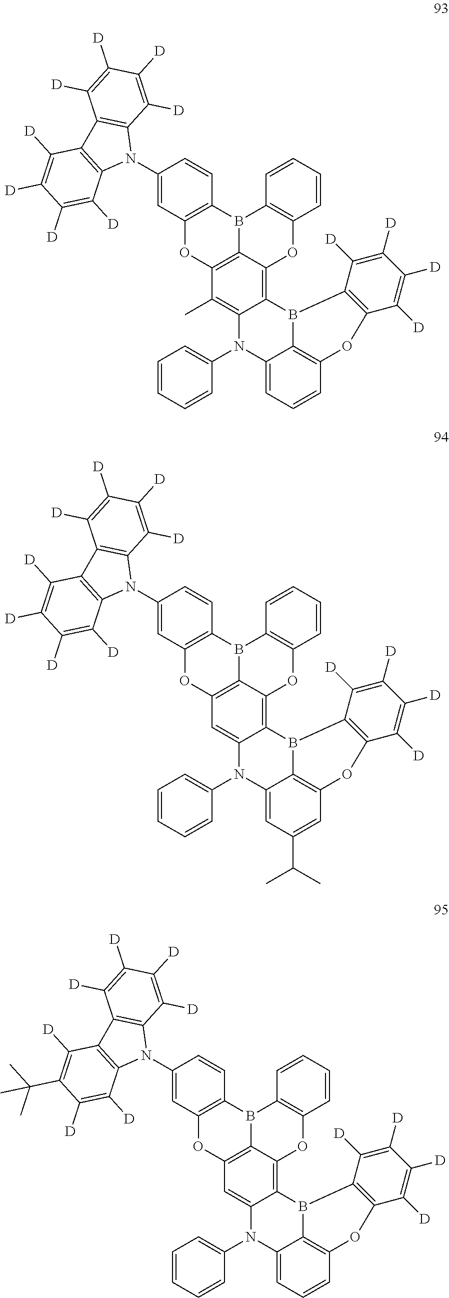 [SMILES: [2H]c1c([2H])c([2H])c2c(c1[2H])Oc1cccc3c1B2c1c2c4c(c(C)c1N3c1ccccc1)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)N3c1ccccc1] 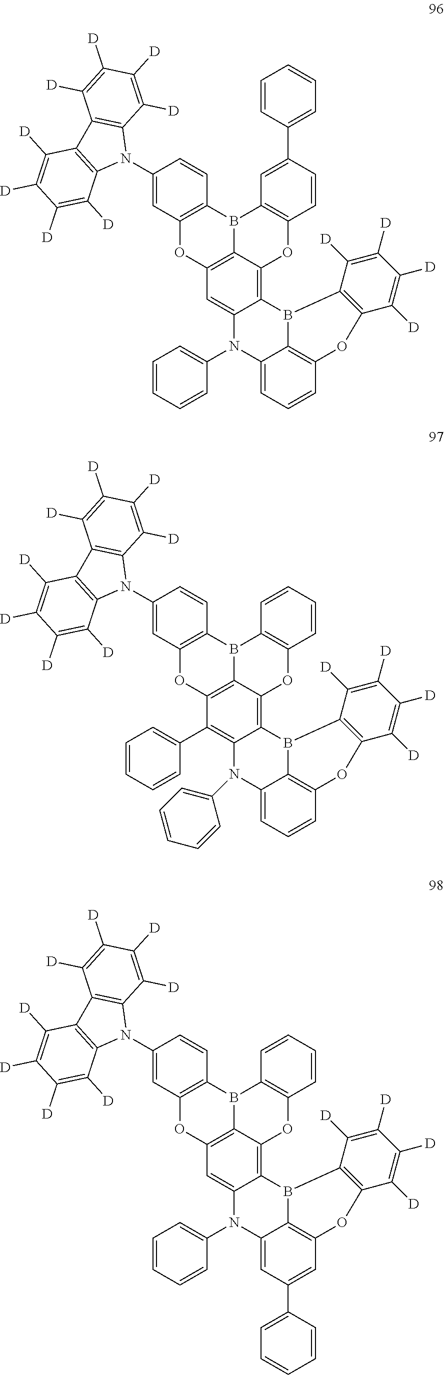 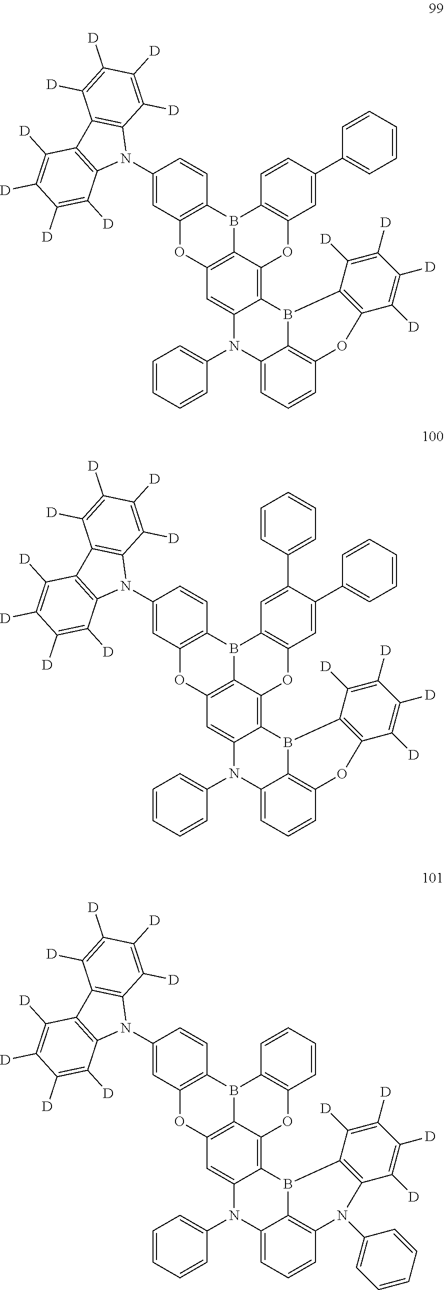 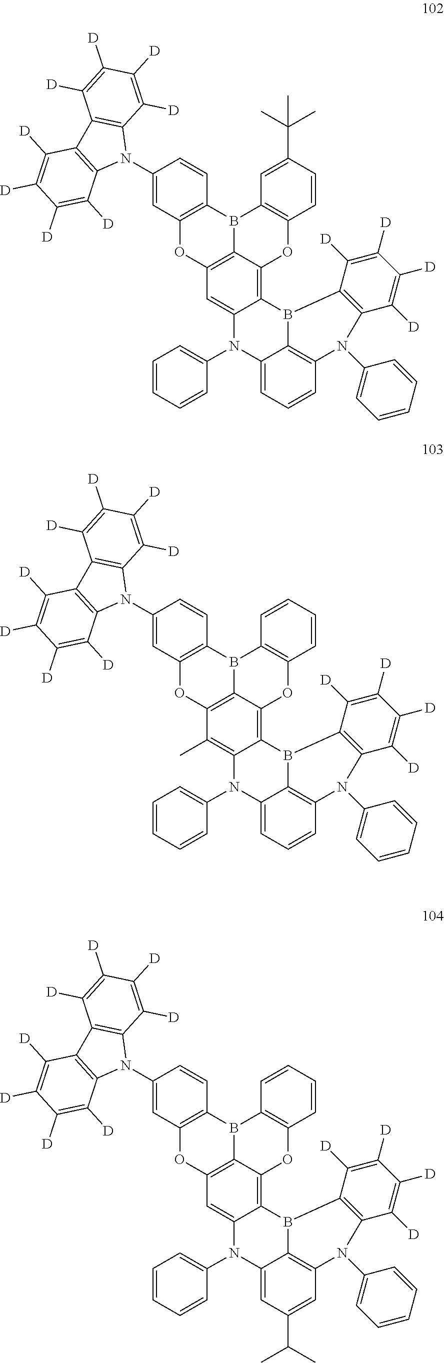 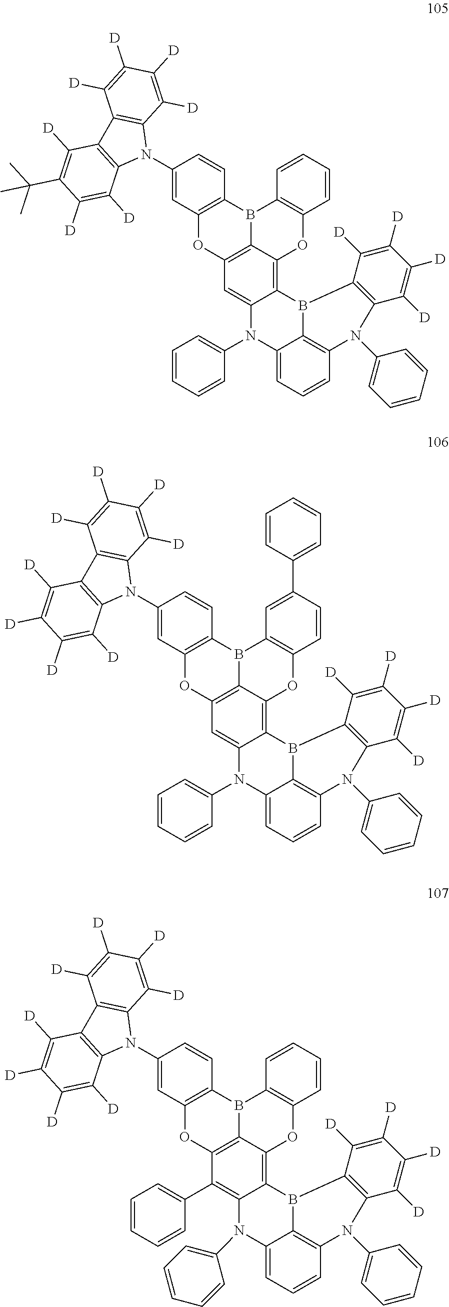 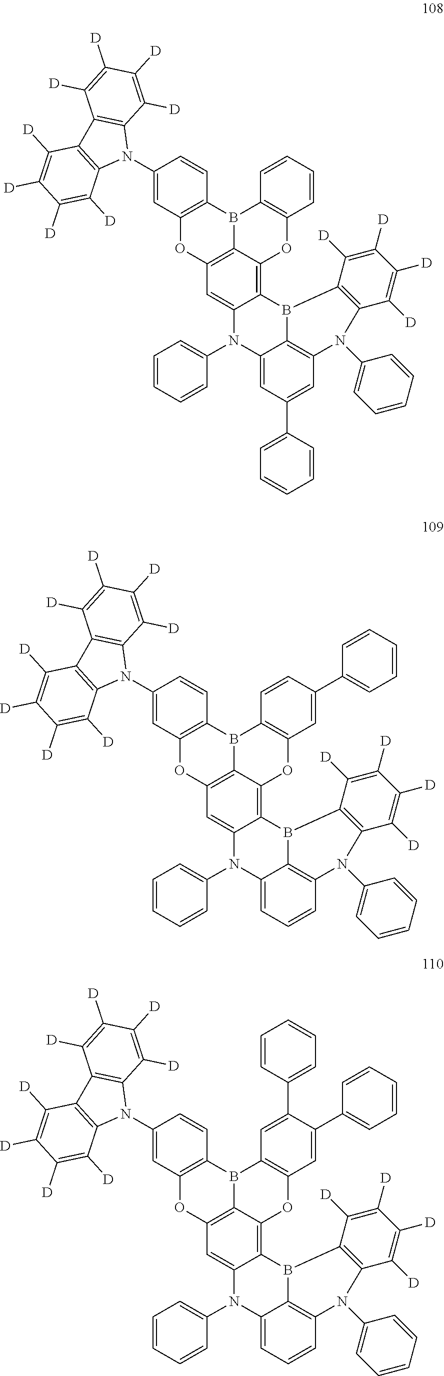 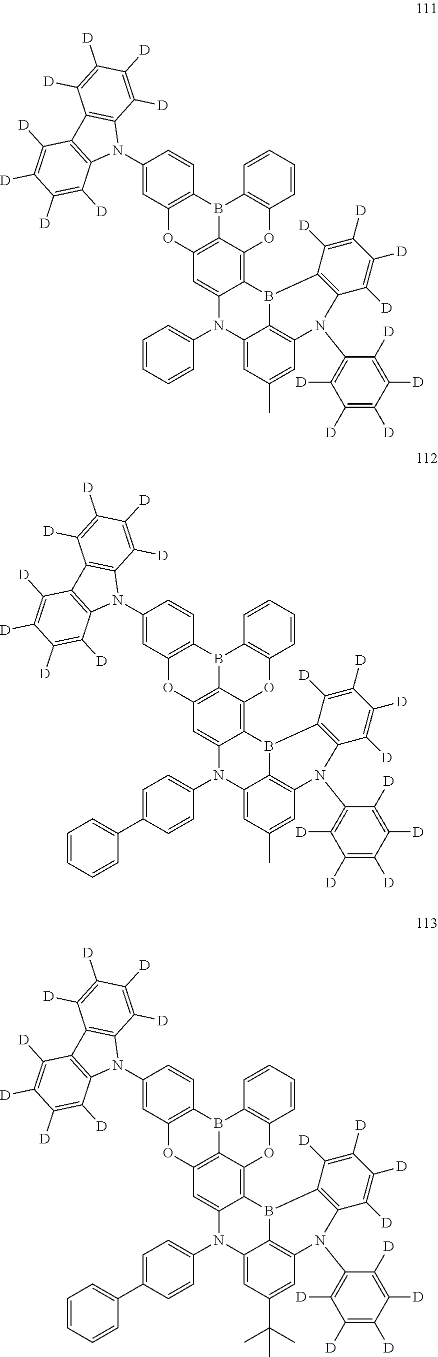 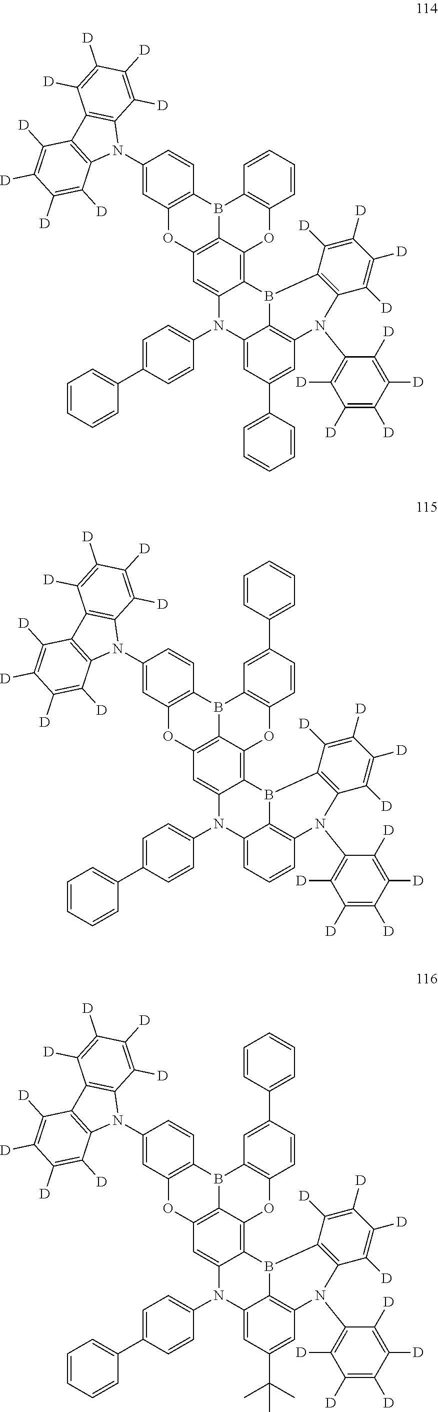 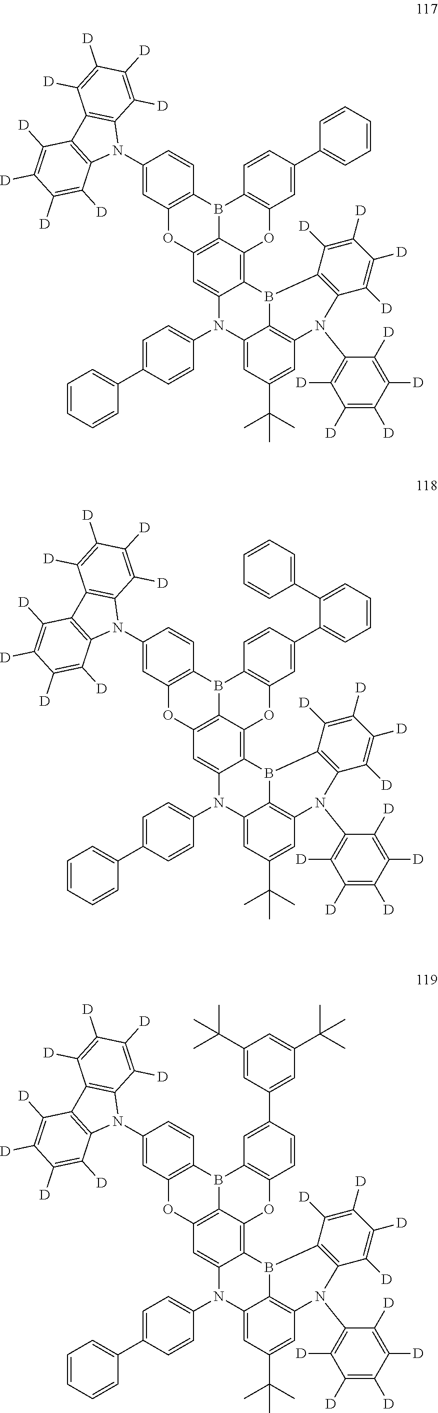 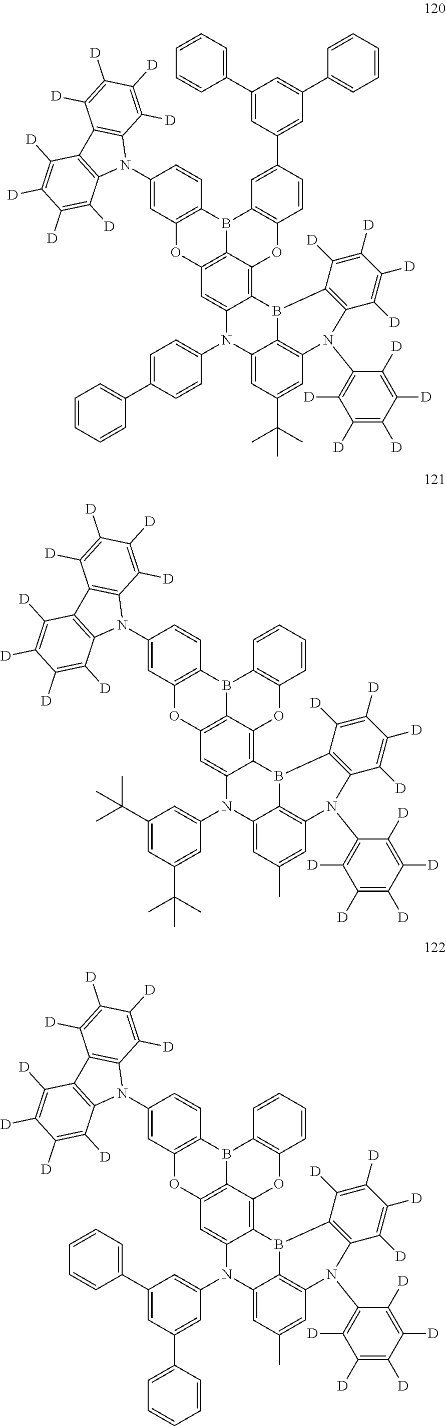 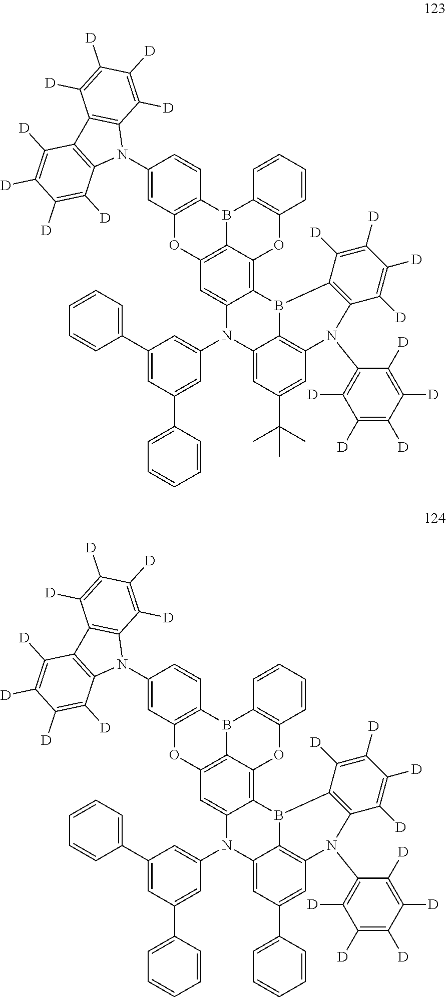 [SMILES: [2H]c1c([2H])c([2H])c(N2c3cc(C(C)(C)C)cc4c3B(c3c(cc5c6c3Oc3ccccc3B6c3ccc(-n6c7c([2H])c([2H])c([2H])c([2H])c7c7c([2H])c([2H])c([2H])c([2H])c76)cc3O5)N4c3cc(-c4ccccc4)cc(-c4ccccc4)c3)c3c([2H])c([2H])c([2H])c([2H])c32)c([2H])c1[2H] ; [2H]c1c([2H])c([2H])c(N2c3cc(-c4ccccc4)cc4c3B(c3c(cc5c6c3Oc3ccccc3B6c3ccc(-n6c7c([2H])c([2H])c([2H])c([2H])c7c7c([2H])c([2H])c([2H])c([2H])c76)cc3O5)N4c3cc(-c4ccccc4)cc(-c4ccccc4)c3)c3c([2H])c([2H])c([2H])c([2H])c32)c([2H])c1[2H]] 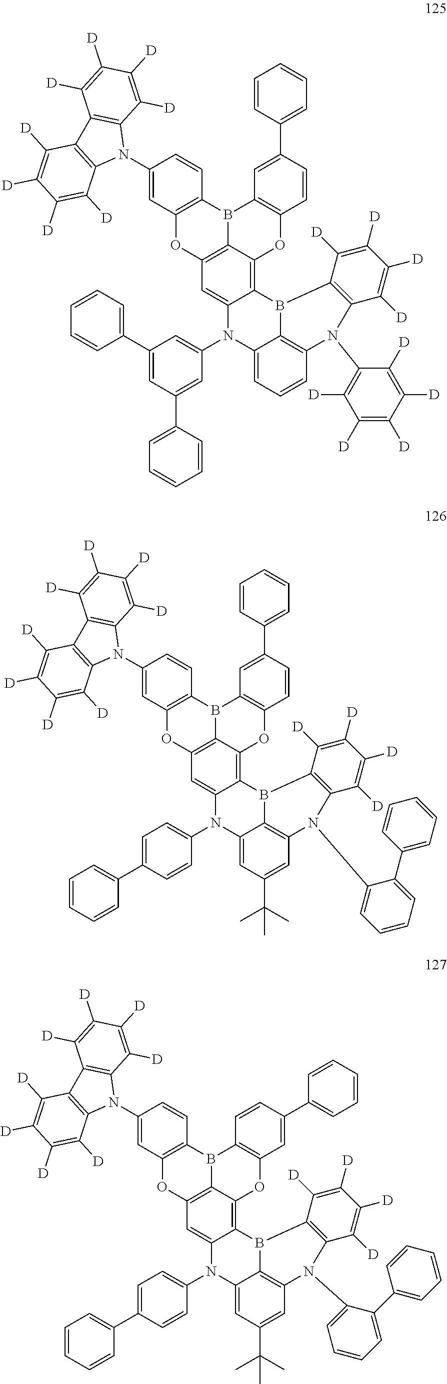 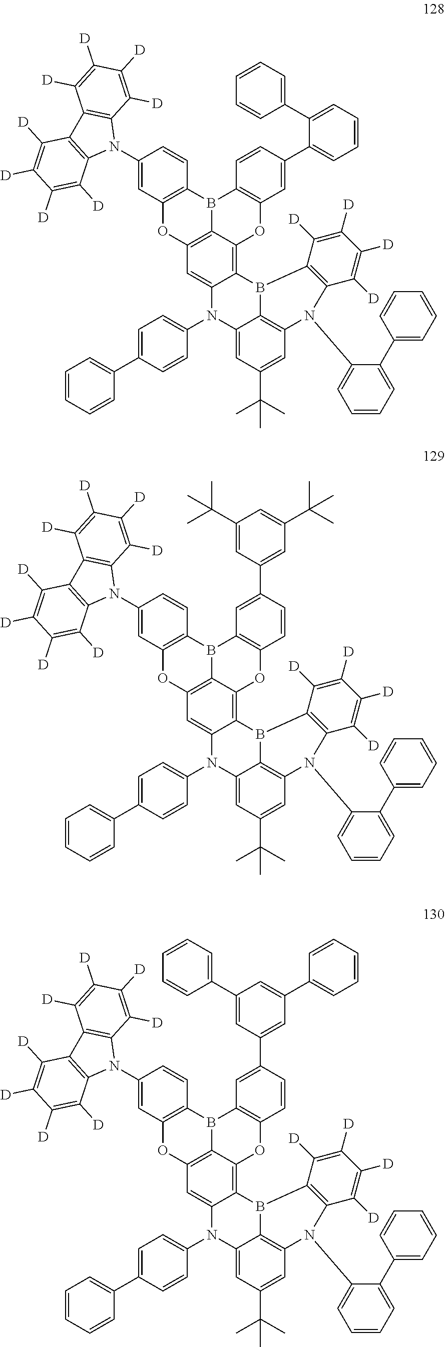 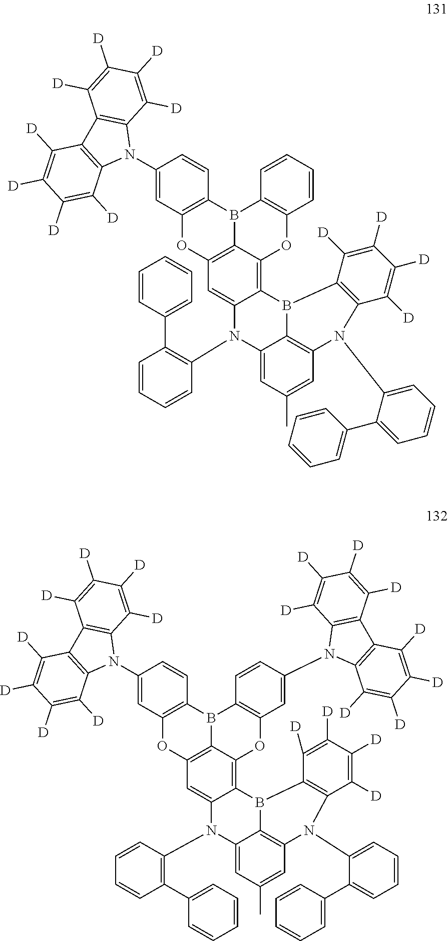 [SMILES: [2H]c1c([2H])c([2H])c2c(c1[2H])B1c3c(cc(C)cc3N2c2ccccc2-c2ccccc2)N(c2ccccc2-c2ccccc2)c2cc3c4c(c21)Oc1ccccc1B4c1ccc(-n2c4c([2H])c([2H])c([2H])c([2H])c4c4c([2H])c([2H])c([2H])c([2H])c42)cc1O3 ; [2H]c1c([2H])c([2H])c2c(c1[2H])B1c3c(cc(C)cc3N2c2ccccc2-c2ccccc2)N(c2ccccc2-c2ccccc2)c2cc3c4c(c21)Oc1cc(-n2c5c([2H])c([2H])c([2H])c([2H])c5c5c([2H])c([2H])c([2H])c([2H])c52)ccc1B4c1ccc(-n2c4c([2H])c([2H])c([2H])c([2H])c4c4c([2H])c([2H])c([2H])c([2H])c42)cc1O3] 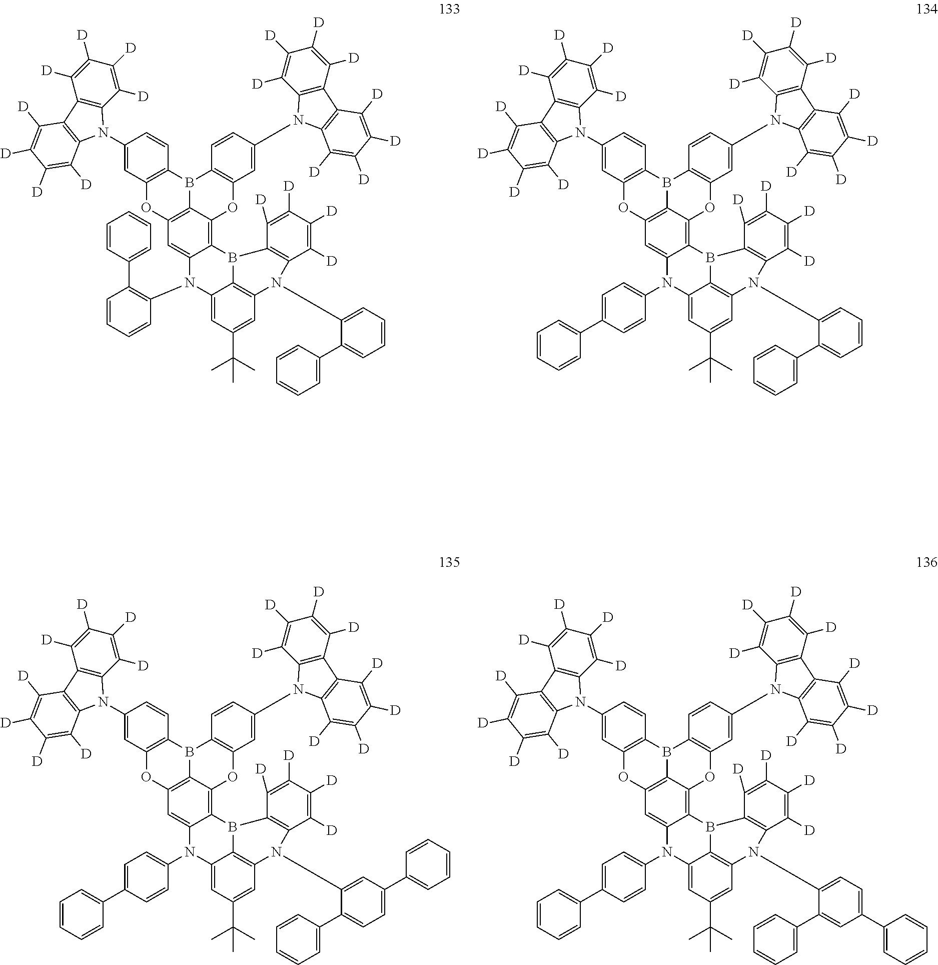 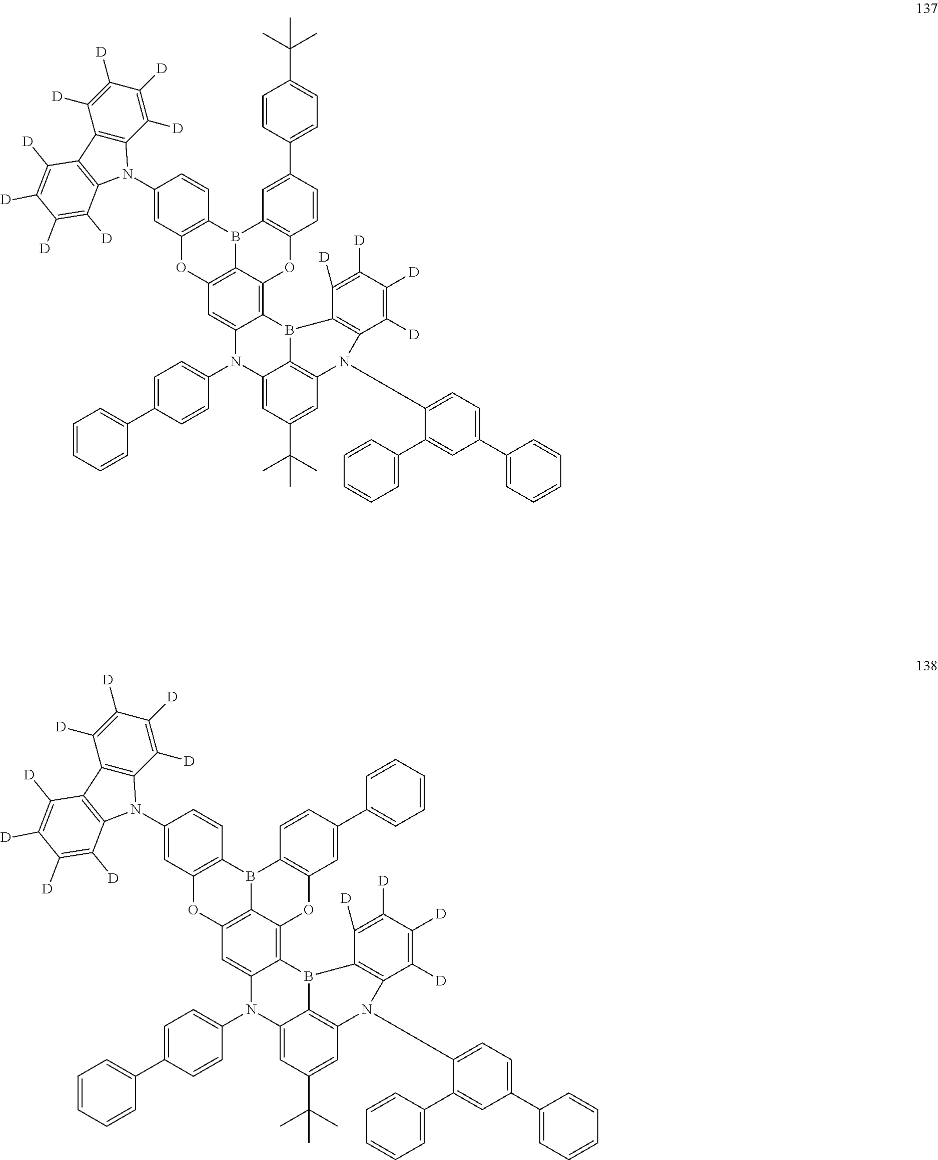 [SMILES: [2H]c1c([2H])c([2H])c2c(c1[2H])B1c3c(cc(C(C)(C)C)cc3N(c3ccc(-c4ccccc4)cc3)c3cc4c5c(c31)Oc1ccc(-c3ccc(C(C)(C)C)cc3)cc1B5c1ccc(-n3c5c([2H])c([2H])c([2H])c([2H])c5c5c([2H])c([2H])c([2H])c([2H])c53)cc1O4)N2CCc1ccc(-c2ccccc2)cc1-c1ccccc1 ; [2H]c1c([2H])c([2H])c2c(c1[2H])B1c3c(cc(C(C)(C)C)cc3N(c3ccc(-c4ccccc4)cc3)c3cc4c5c(c31)Oc1cc(-c3ccccc3)ccc1B5c1ccc(-n3c5c([2H])c([2H])c([2H])c([2H])c5c5c([2H])c([2H])c([2H])c([2H])c53)cc1O4)N2CCc1ccc(-c2ccccc2)cc1-c1ccccc1] 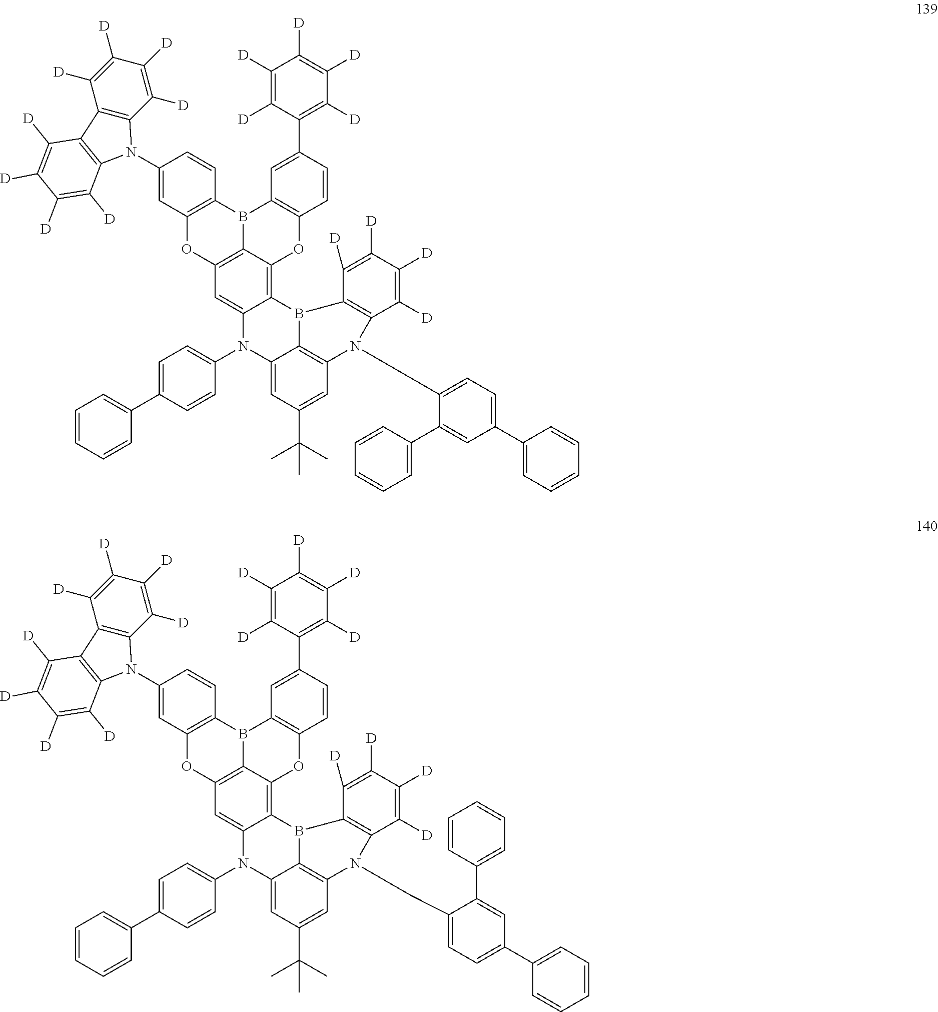 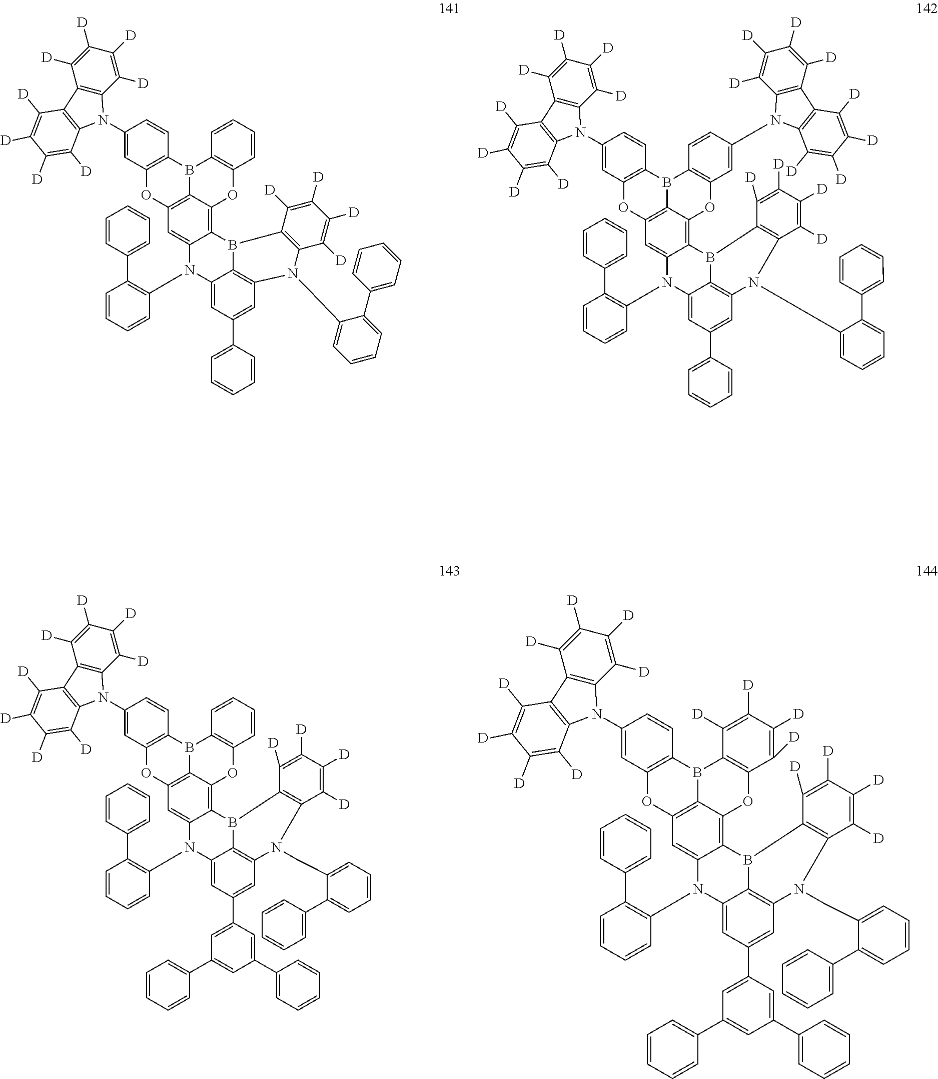 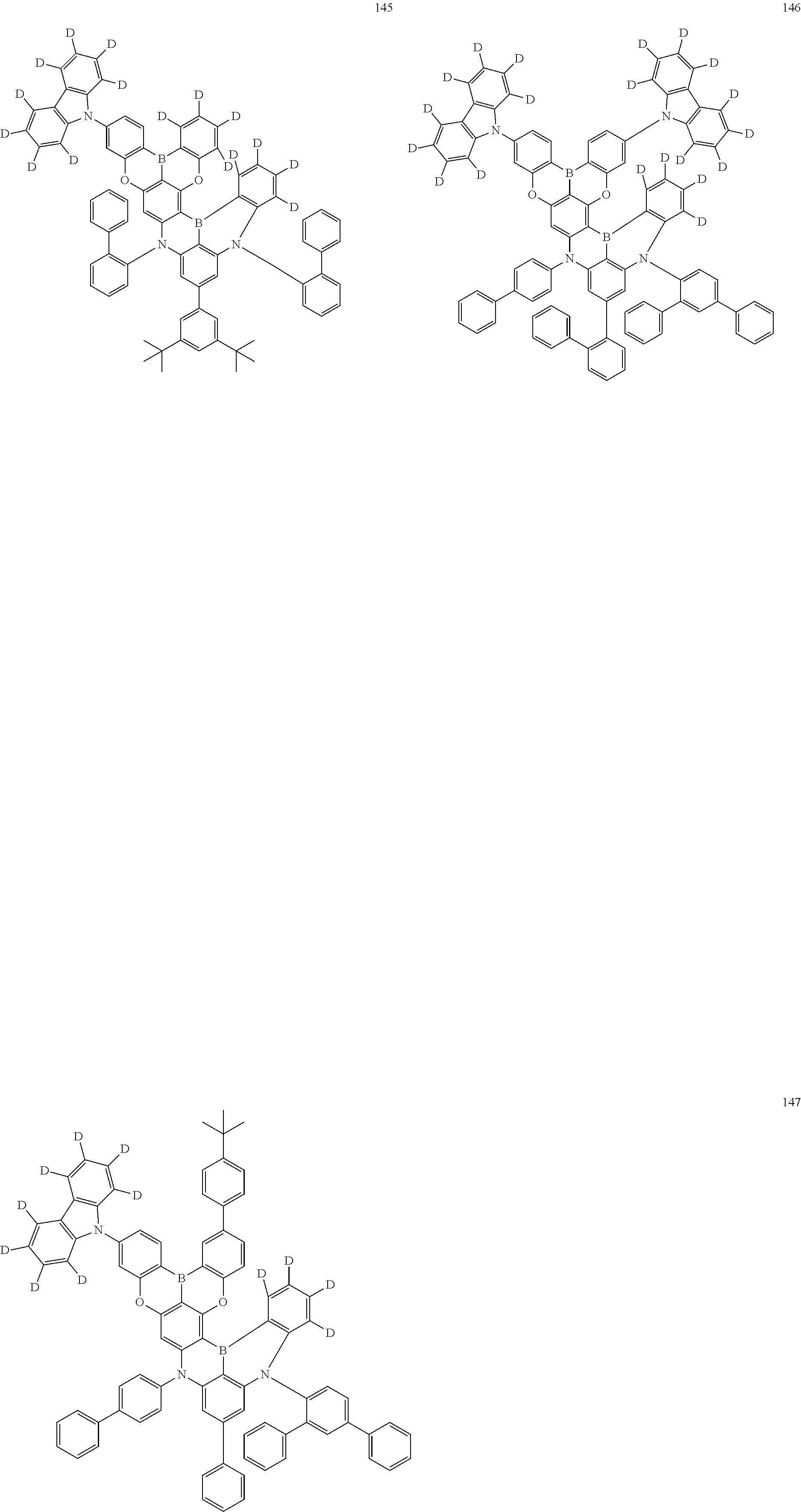 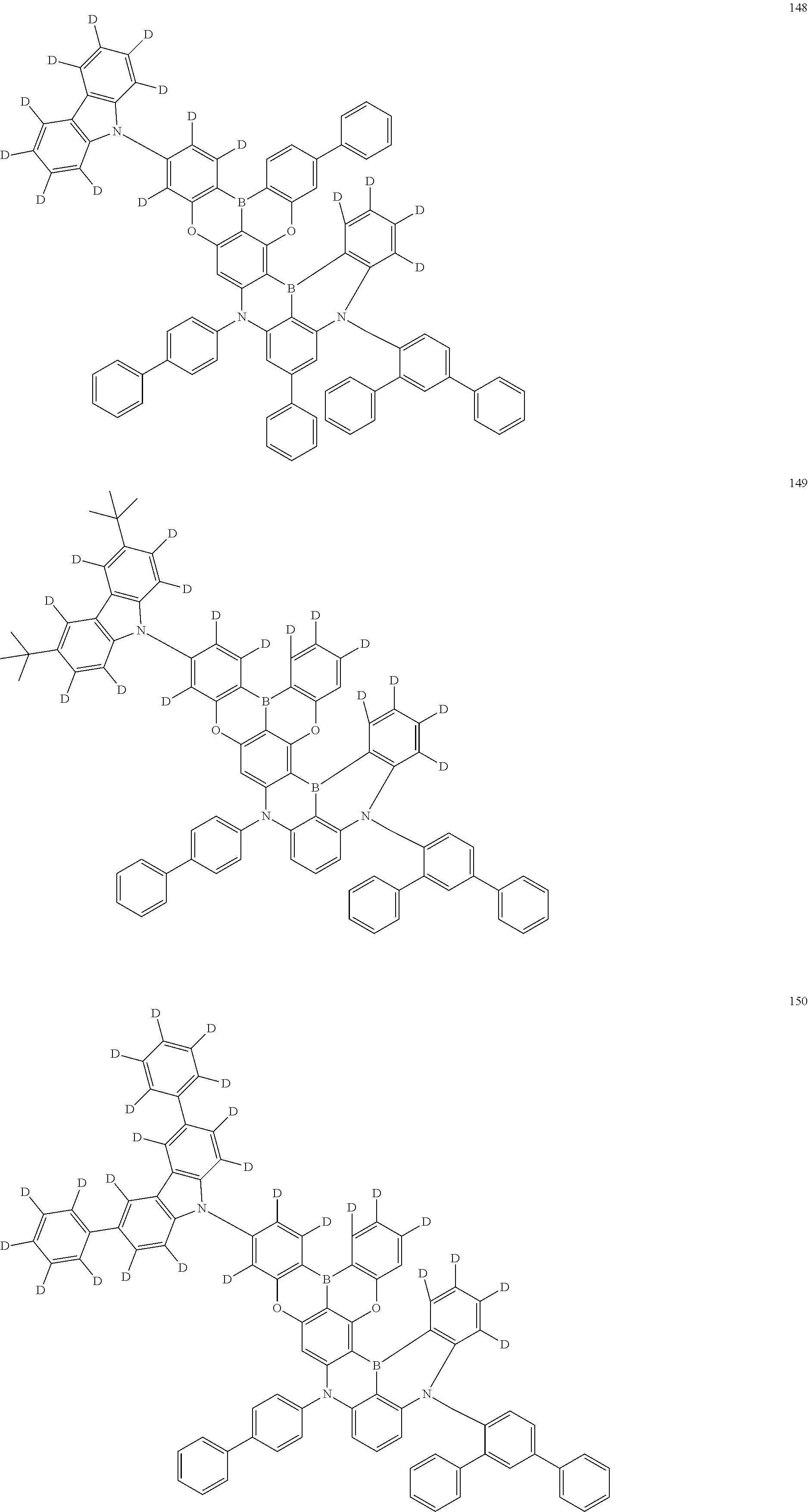 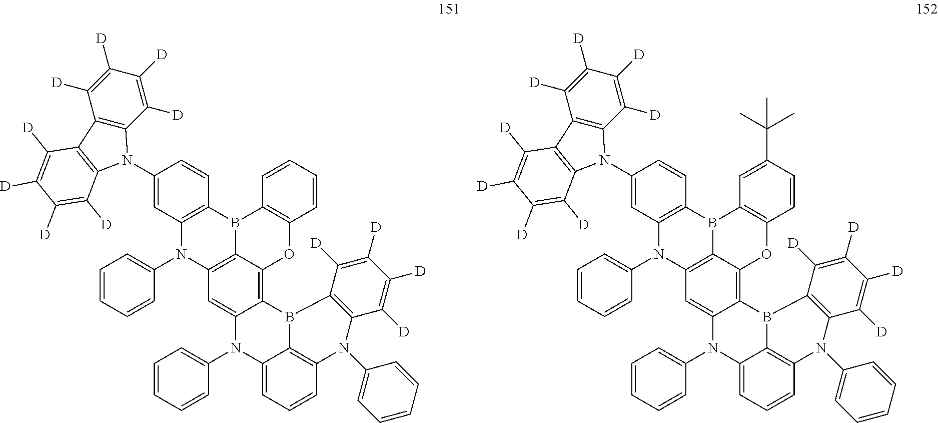 [SMILES: [2H]c1c([2H])c([2H])c2c(c1[2H])B1c3c(cccc3N2c2ccccc2)N(c2ccccc2)c2cc3c4c(c21)Oc1ccccc1B4c1ccc(-n2c4c([2H])c([2H])c([2H])c([2H])c4c4c([2H])c([2H])c([2H])c([2H])c42)cc1N3c1ccccc1 ; [2H]c1c([2H])c([2H])c2c(c1[2H])B1c3c(cccc3N2c2ccccc2)N(c2ccccc2)c2cc3c4c(c21)Oc1ccc(C(C)(C)C)cc1B4c1ccc(-n2c4c([2H])c([2H])c([2H])c([2H])c4c4c([2H])c([2H])c([2H])c([2H])c42)cc1N3c1ccccc1] 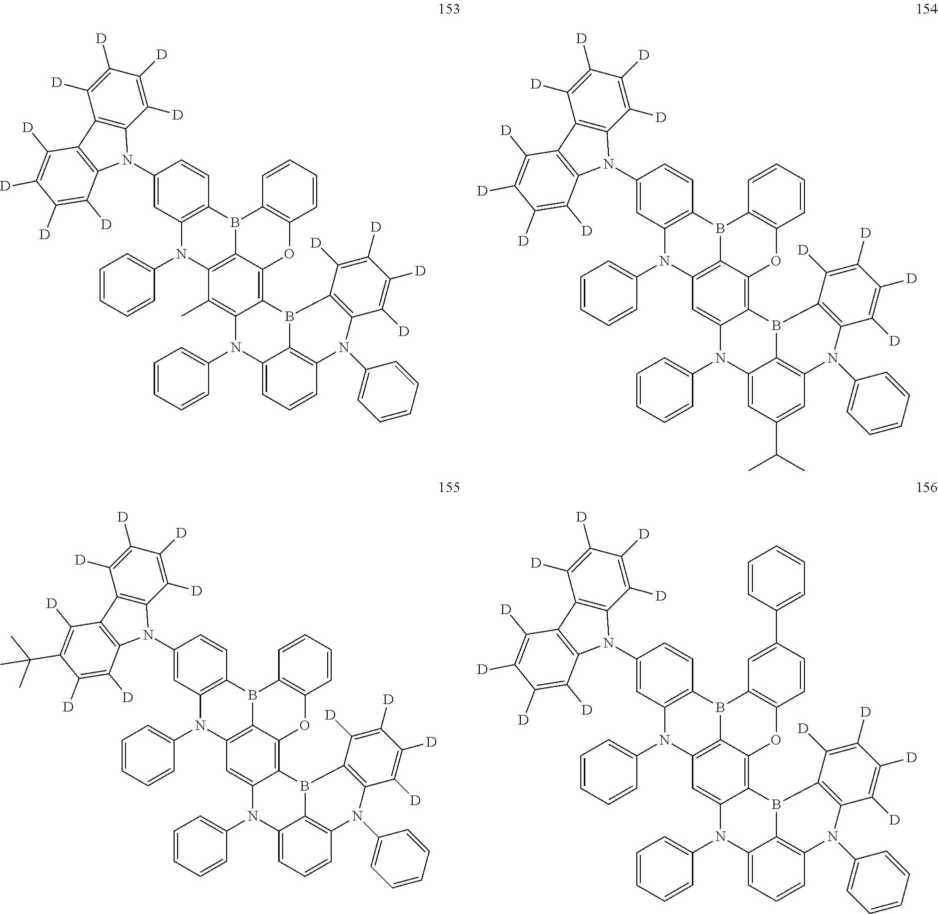 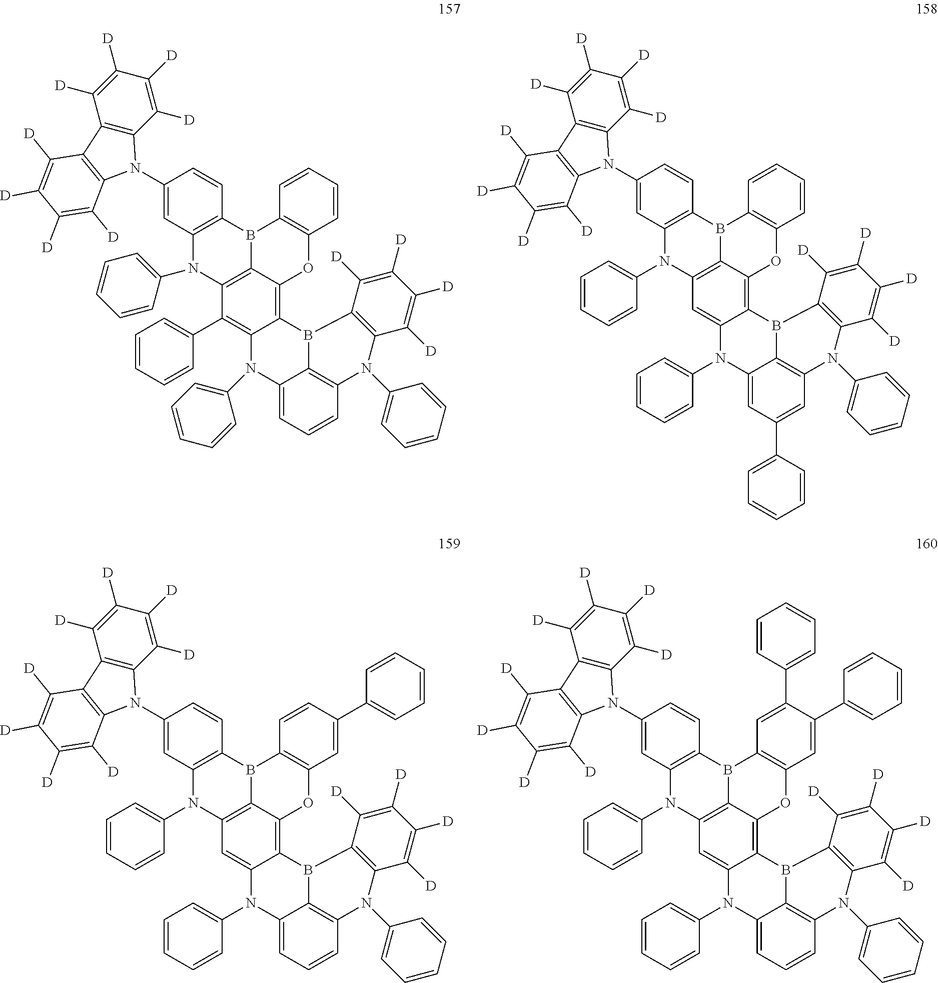 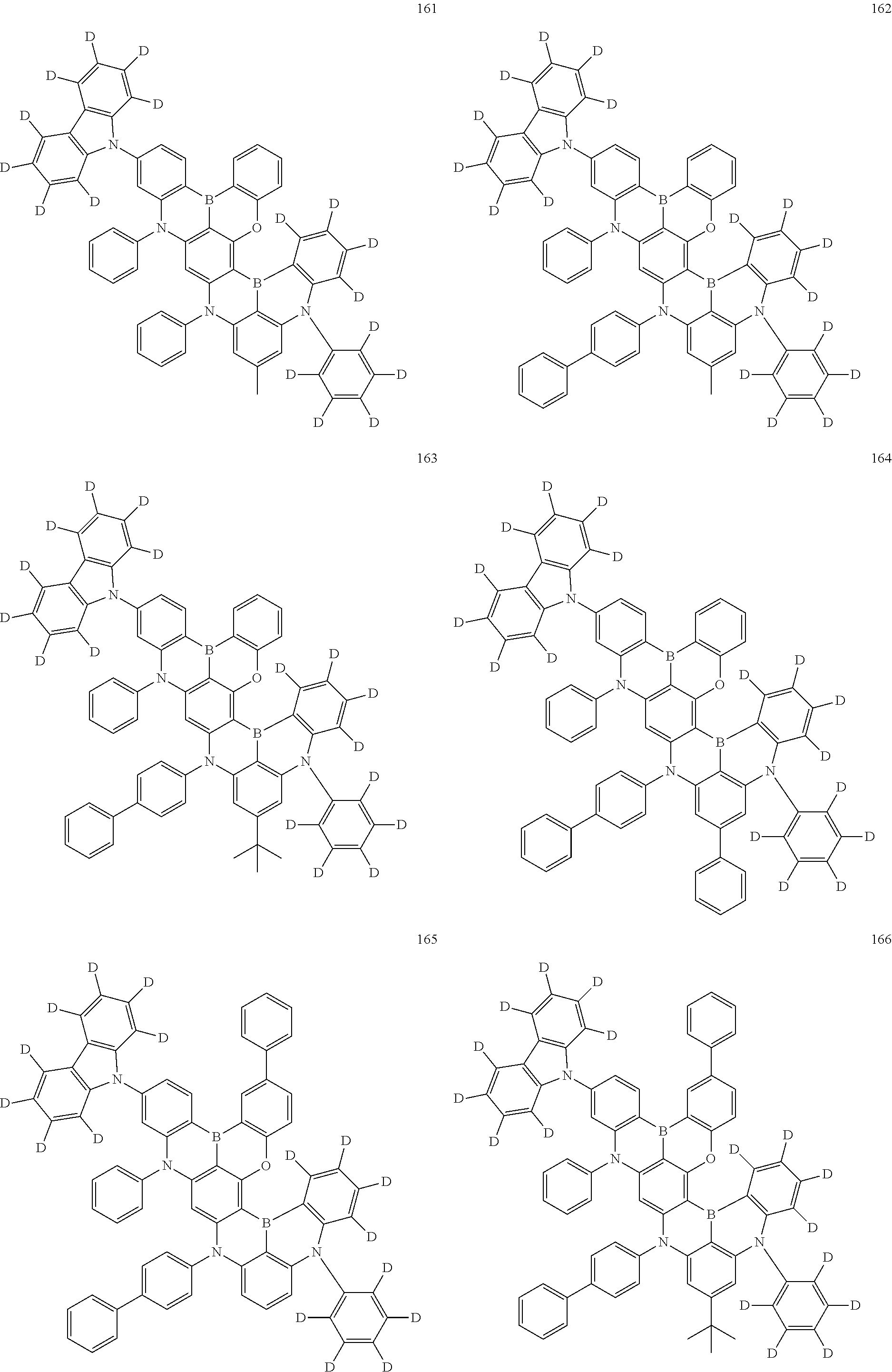 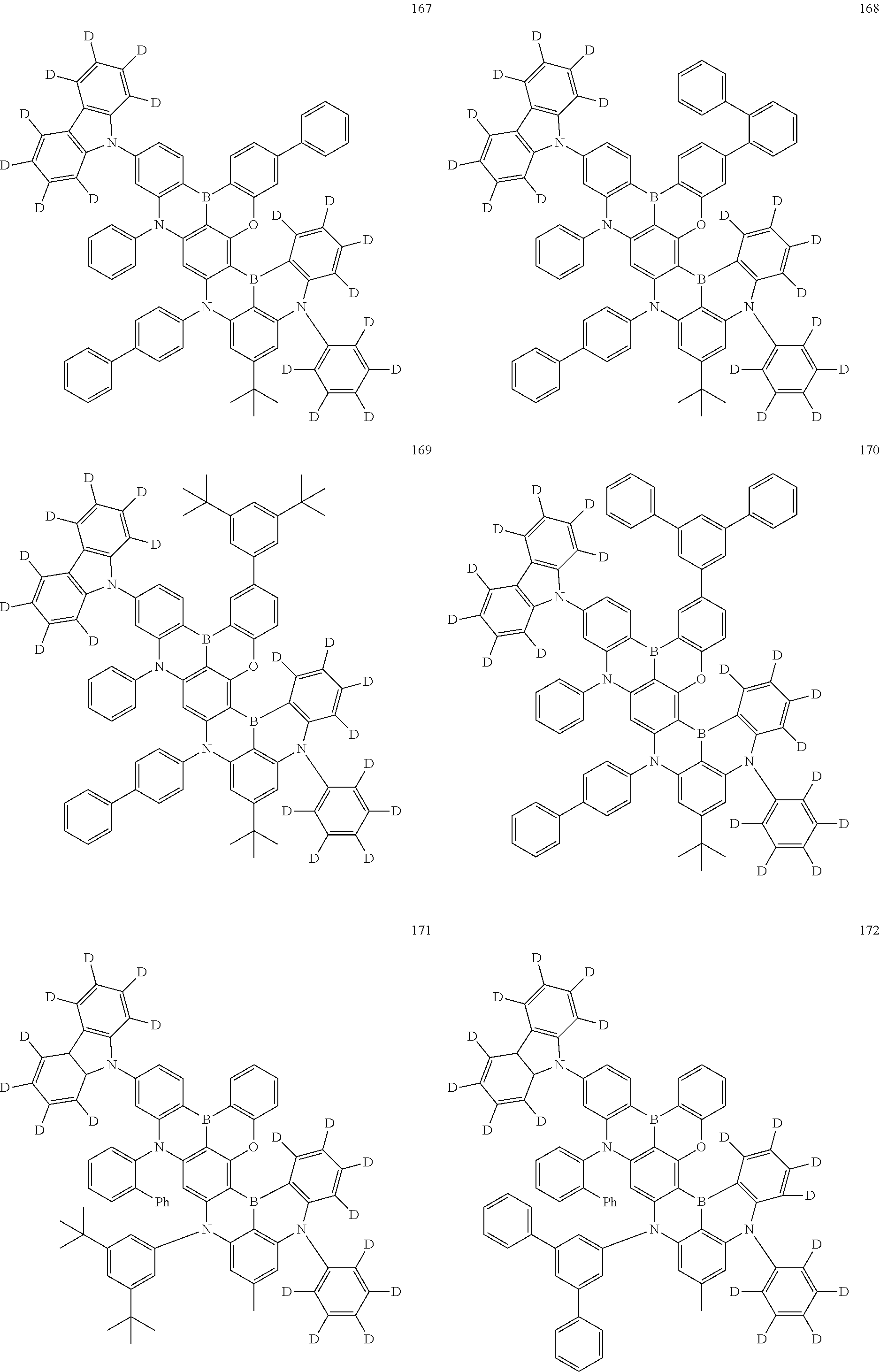 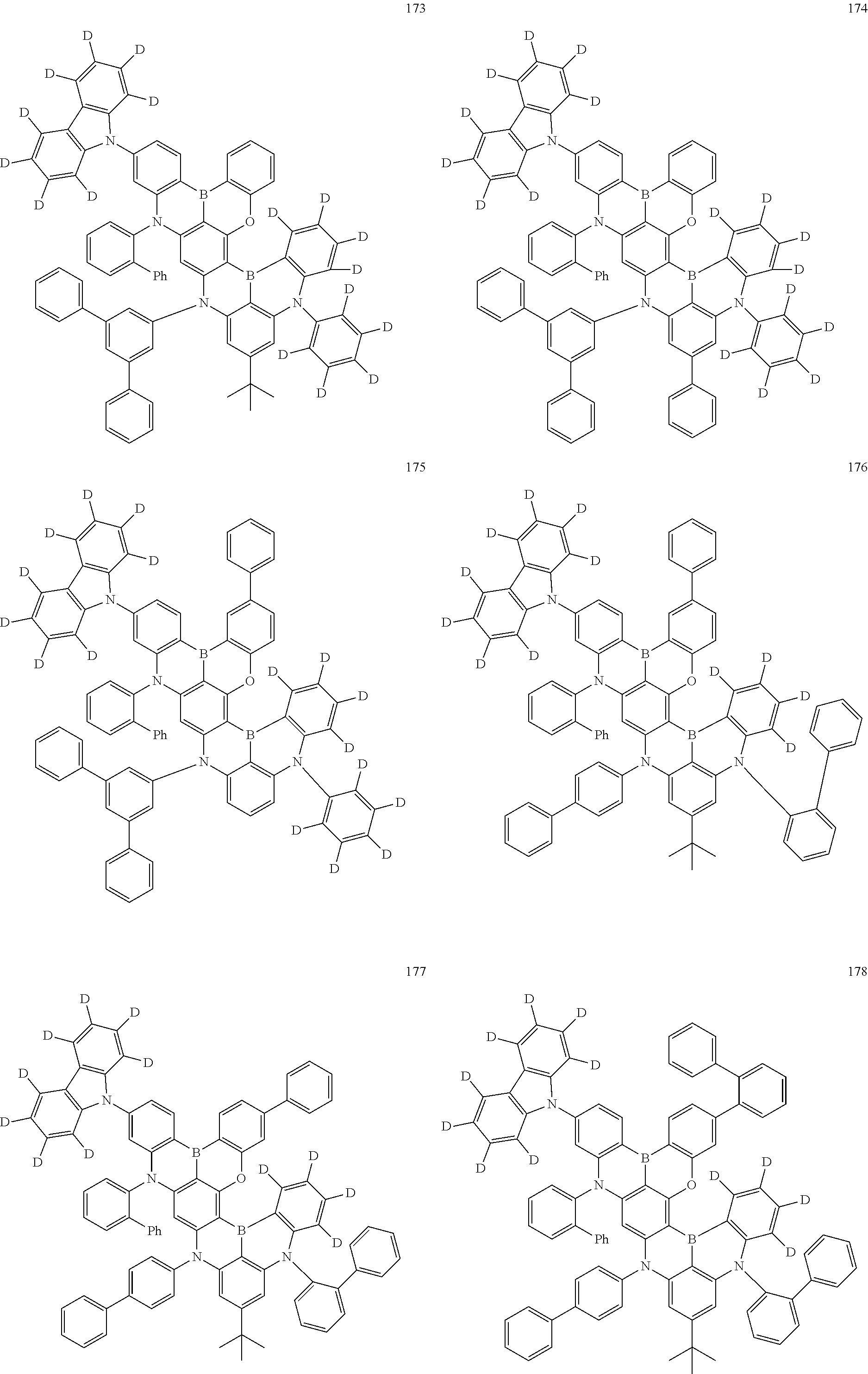 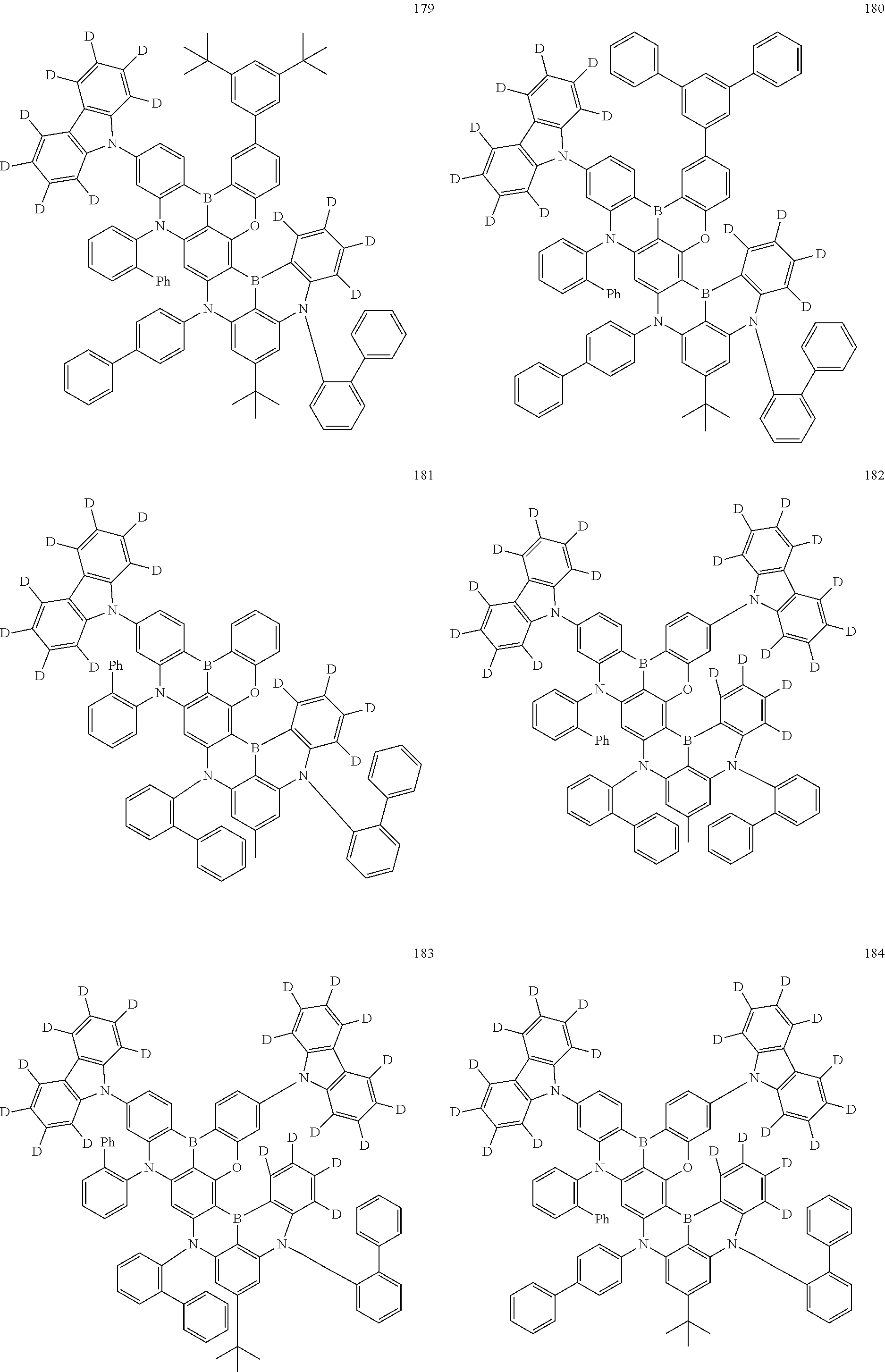 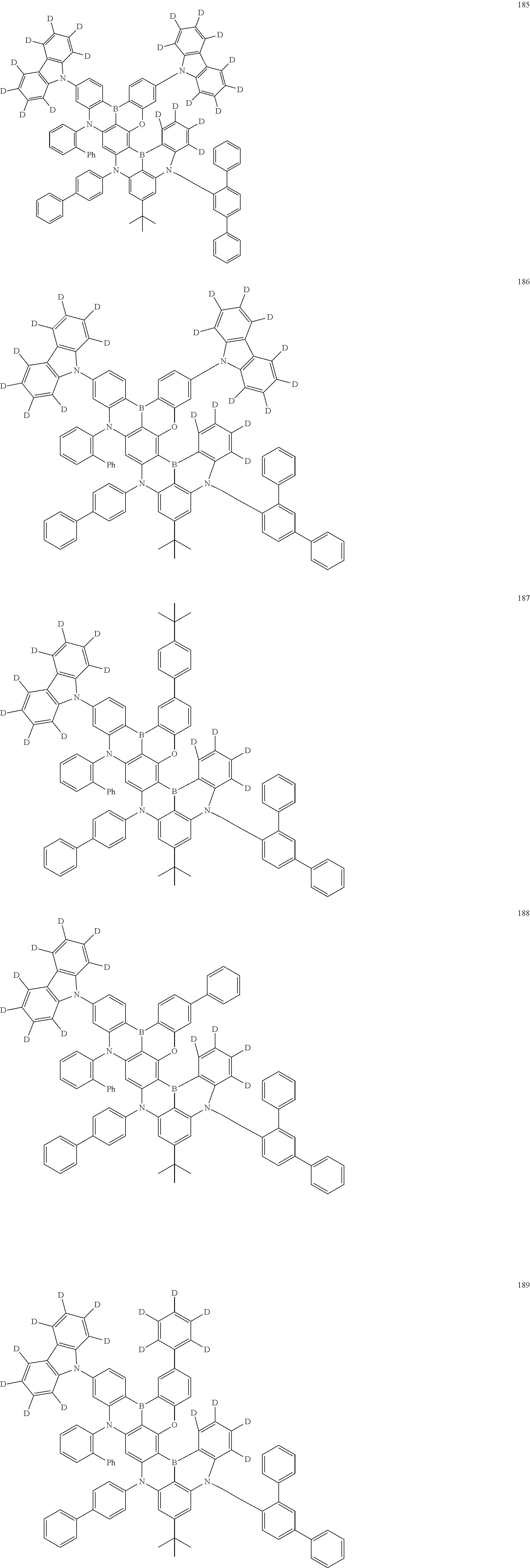 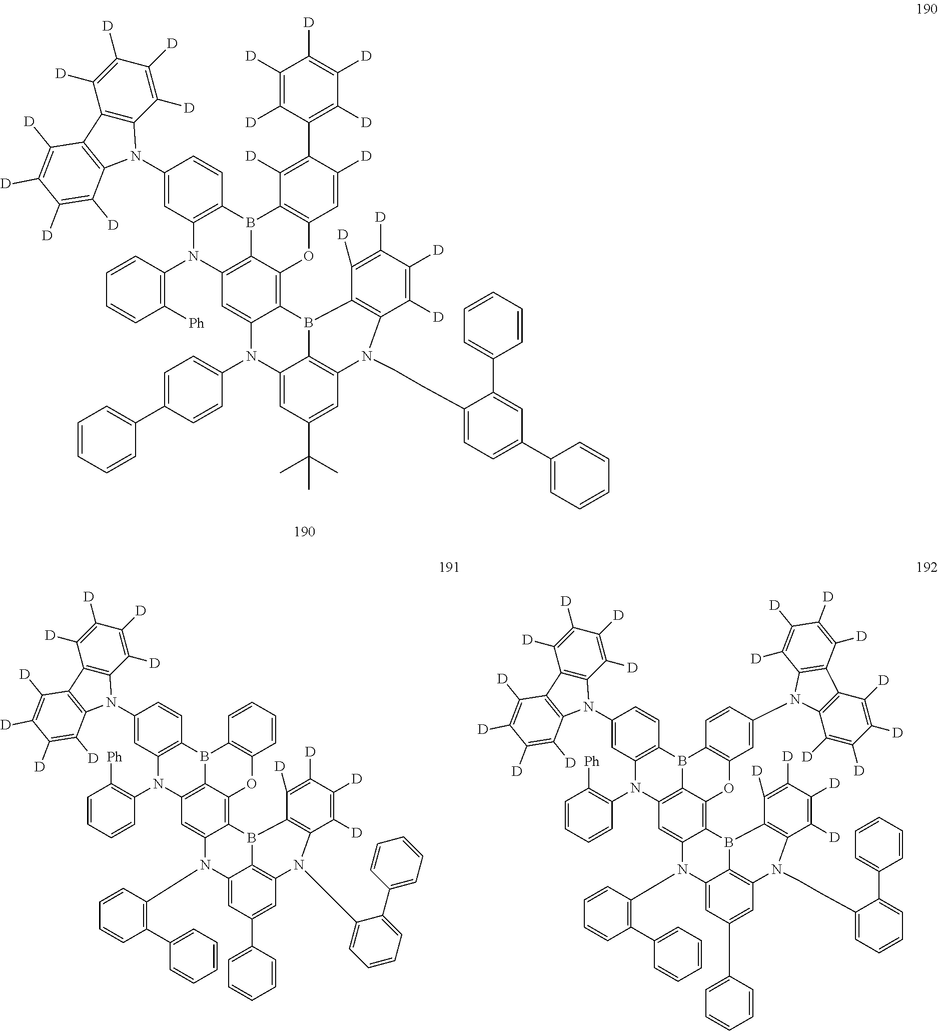 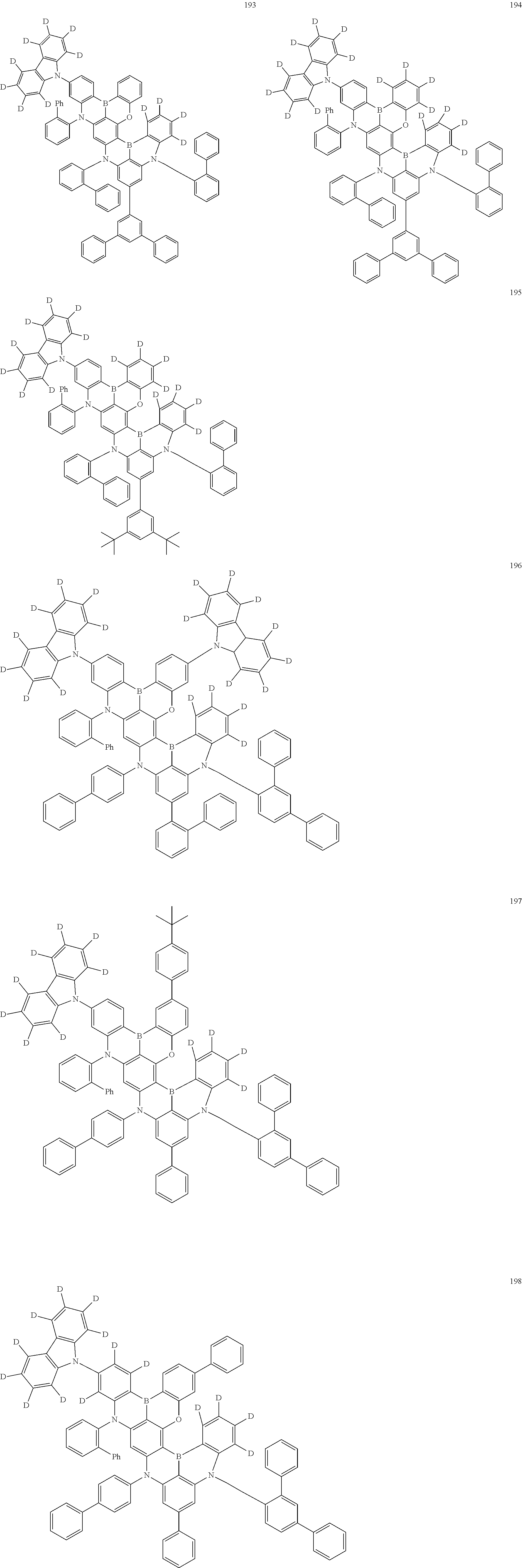 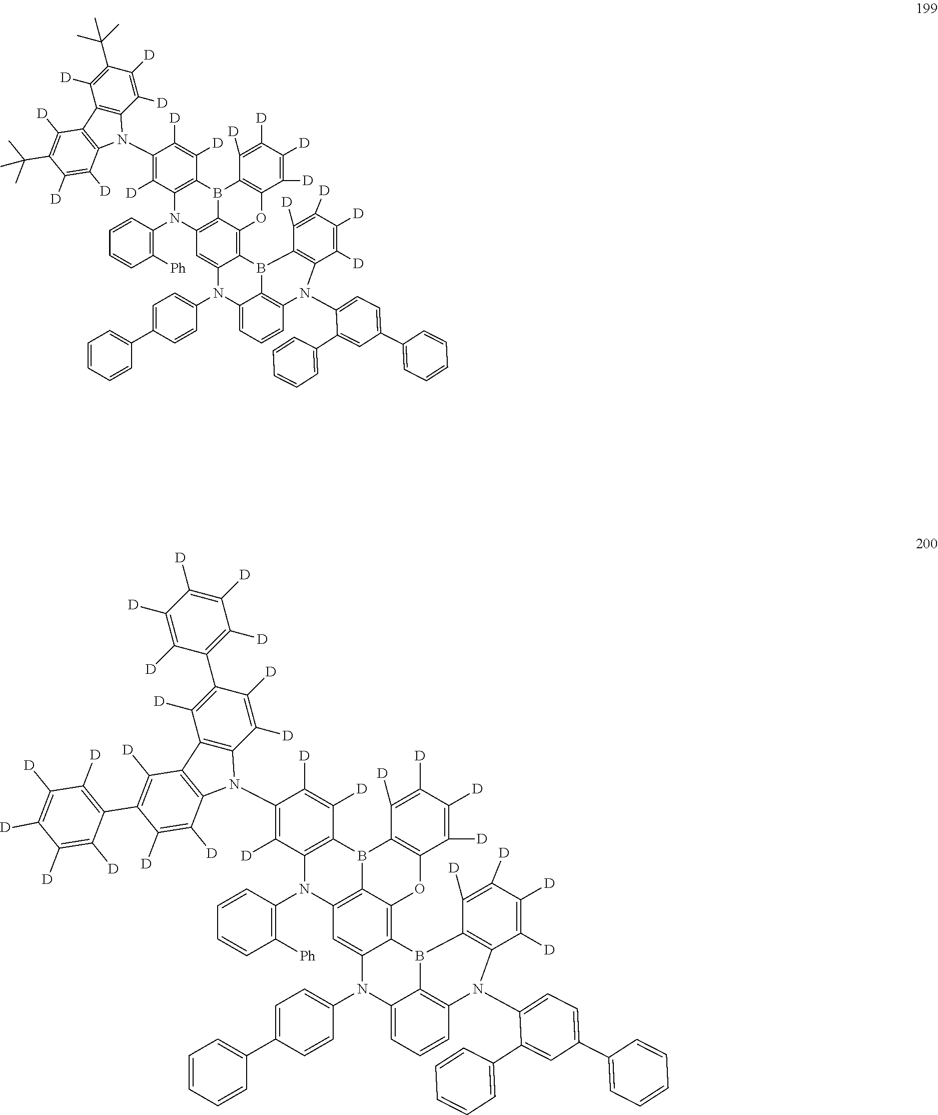
in Compound Group 1, D is a deuterium atom, and Ph is an unsubstituted phenyl group.

11. An electronic device, comprising:
a base layer;
a circuit layer disposed on the base layer; and
a display device layer disposed on the circuit layer and comprising a light emitting device,
wherein the light emitting device comprises a first electrode, a second electrode disposed on the first electrode, and an emission layer disposed between the first electrode and the second electrode, and comprising a first compound represented by Formula 1: 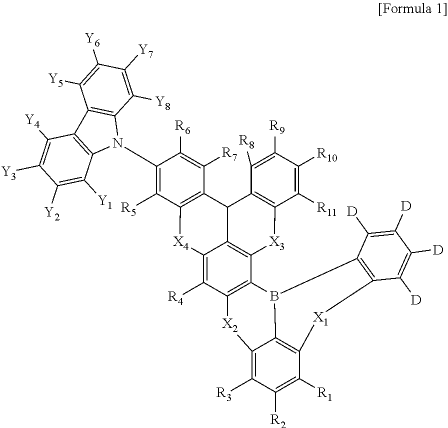
in Formula 1,
X₁ to X₄ are each independently O, S or NAr,
Ar is a substituted or unsubstituted aryl group of 6 to 30 ring-forming carbon atoms, or a substituted or unsubstituted heteroaryl group of 2 to 30 ring-forming carbon atoms,
R₁ to R₁₁ and Y₁ to Y₈ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
D is a deuterium atom.

12. The electronic device of claim 11, wherein
the light emitting device further comprises a capping layer disposed on the second electrode, and
a refractive index of the capping layer with respect to light in a wavelength range of about 550 nm to about 660 nm is about 1.6 or more.

13. The electronic device of claim 11, wherein
the electronic device further comprises a light control layer disposed on the display device layer and comprising a quantum dot,
the light emitting device emits a first color light, and
the light control layer comprises:
a first light control part comprising a first quantum dot converting the first color light into a second color light with a wavelength greater than the first color light;
a second light control part comprising a second quantum dot converting the first color light into a third color light with a wavelength greater than the first color light and the second color light; and
a third light control part transmitting the first color light.

14. The electronic device of claim 11, wherein the electronic device is selected from large-sized display devices such as televisions, monitors, and outdoor billboards, and small and medium-sized display devices such as personal computers, notebook computers, personal digital terminals, vehicle display devices, game consoles, portable electronic devices or cameras.

15. A fused polycyclic compound represented by the following Formula 1: 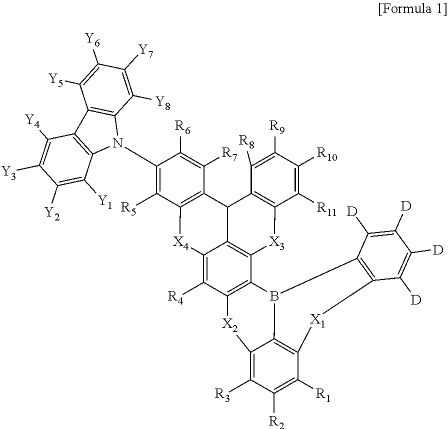
in Formula 1,
X₁ to X₄ are each independently O, S or NAr,
Ar is a substituted or unsubstituted aryl group of 6 to 30 ring-forming carbon atoms, or a substituted or unsubstituted heteroaryl group of 2 to 30 ring-forming carbon atoms,
R₁ to R₁₁ and Y₁ to Y₈ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
D is a deuterium atom.

16. The fused polycyclic compound of claim 15, wherein the fused polycyclic compound represented by Formula 1 is represented by a compound of Formula 2-1, Formula 2-2, or Formula 2-3: 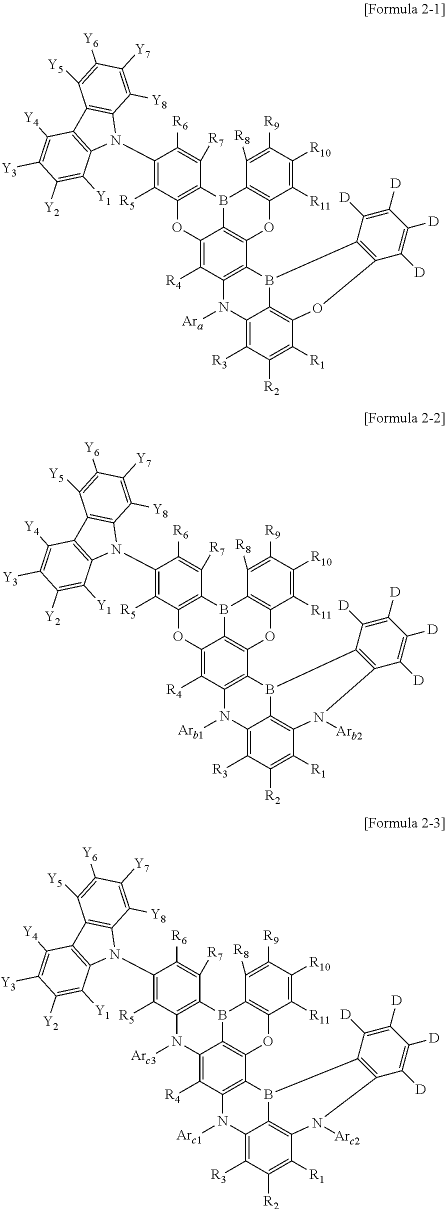
in Formula 2-1, Formula 2-2, and Formula 2-3,
Arₐ, Ar_{b1}, Ar_{b2}, Ar_{c1}, Ar_{c2}, and Ar_{c3} are each independently a substituted or unsubstituted aryl group of 6 to 30 ring-forming carbon atoms, or a substituted or unsubstituted heteroaryl group of 2 to 30 ring-forming carbon atoms, and
Formula 2-1, Formula 2-2, and Formula 2-3 comprise a structure in which an arbitrary hydrogen atom is substituted with a deuterium atom.

17. The fused polycyclic compound of claim 15, wherein the fused polycyclic compound represented by Formula 1 is represented by a compound of Formula 4-1 to Formula 4-8: 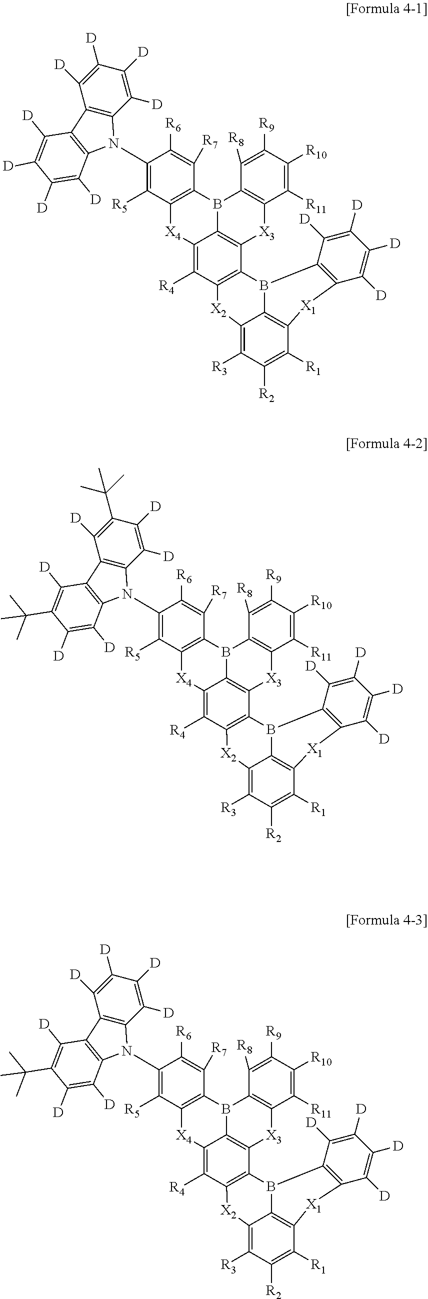 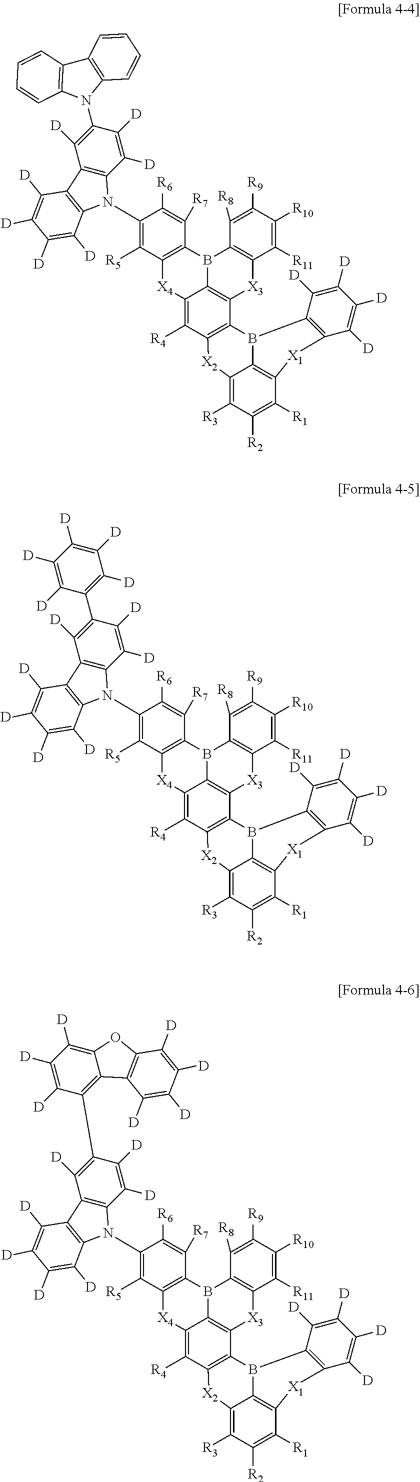 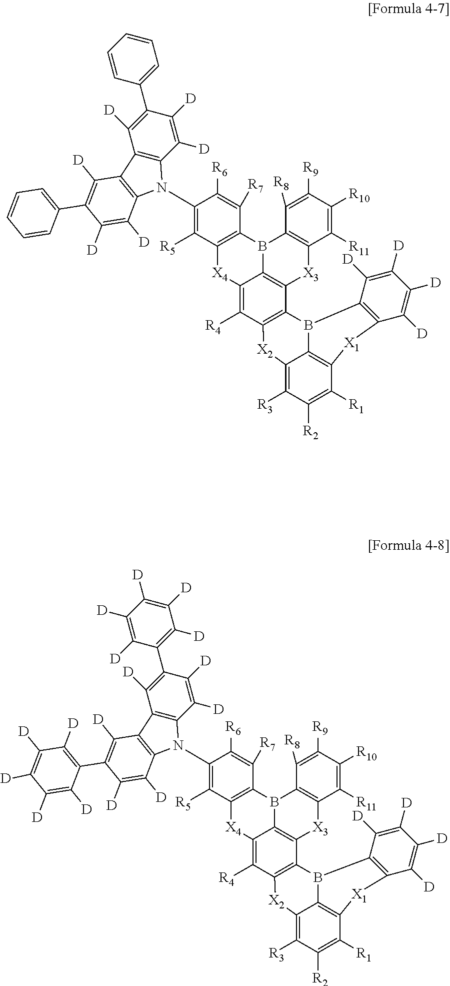
in Formula 4-1 to Formula 4-8,
Formula 4-1 to Formula 4-8 comprise a structure in which an arbitrary hydrogen atom is substituted with a deuterium atom.

18. The fused polycyclic compound of claim 15, wherein the fused polycyclic compound represented by Formula 1 is represented by a compound of Formula 5-1 to Formula 5-12: 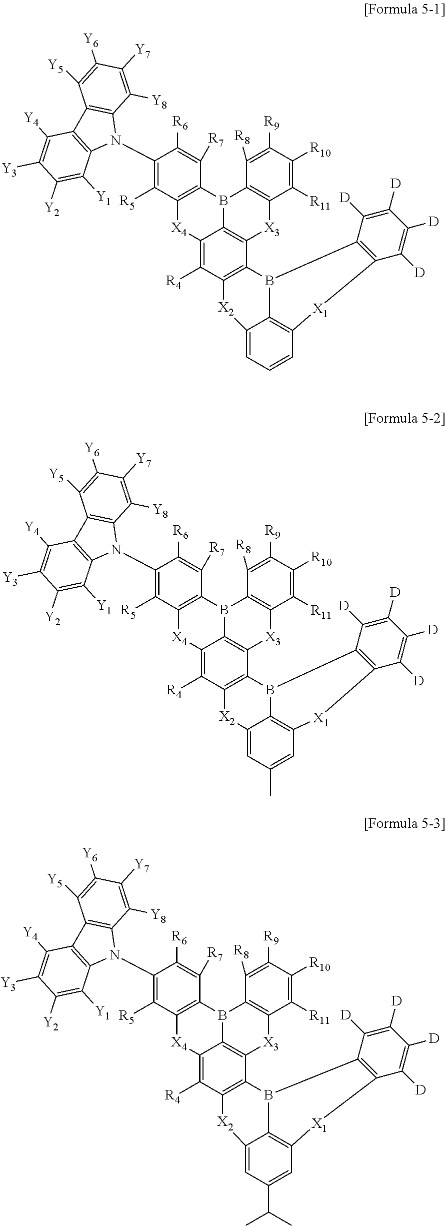 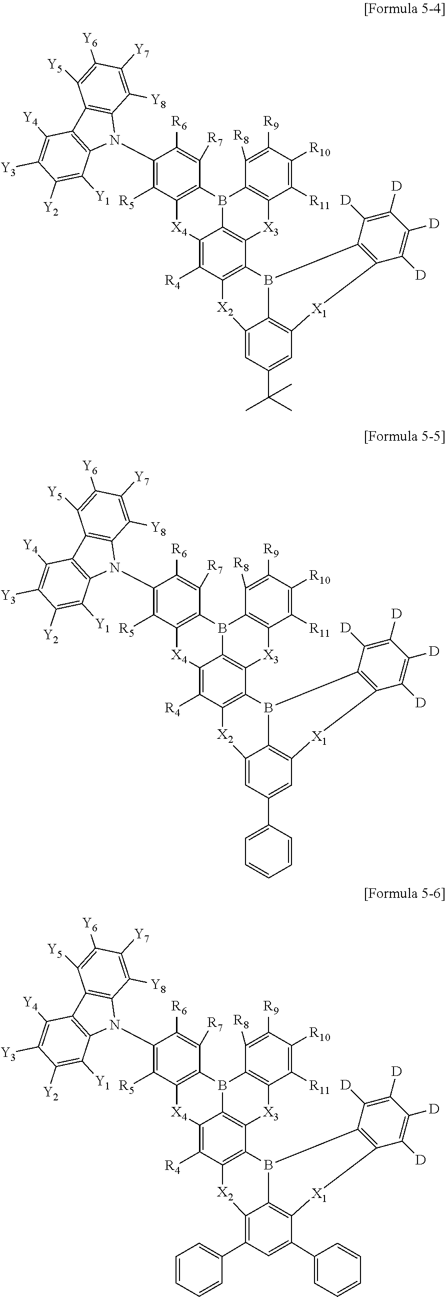 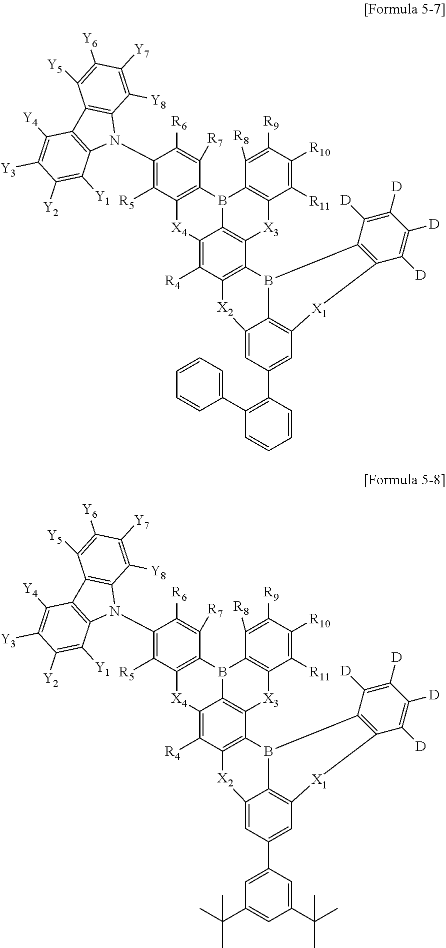 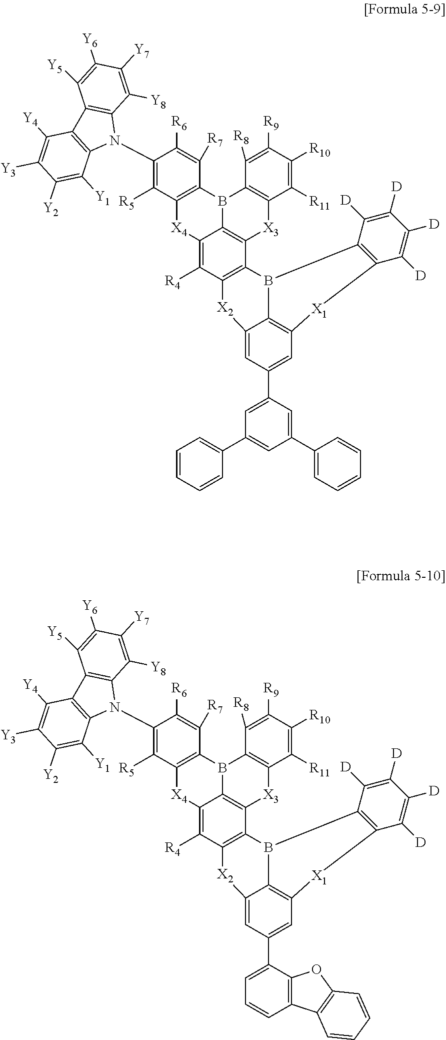 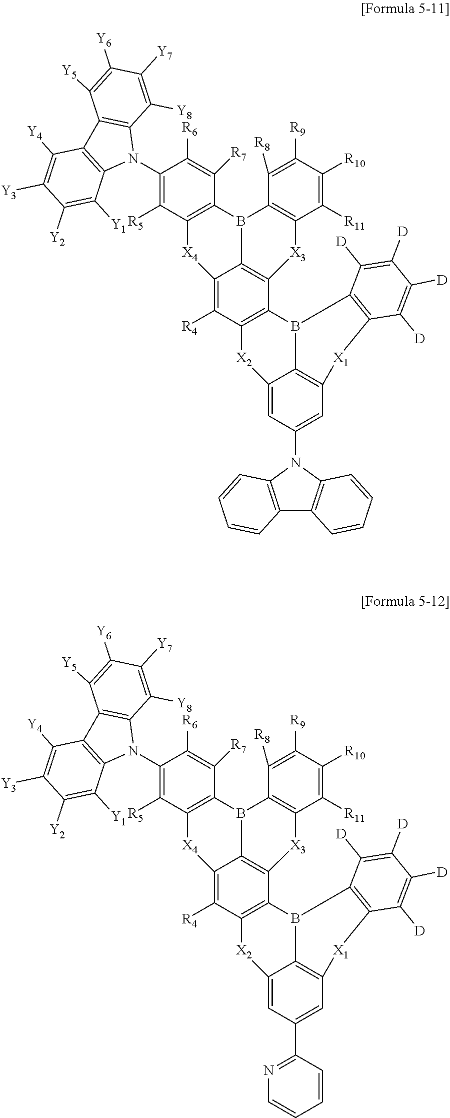
in Formula 5-1 to Formula 5-12,
Formula 5-1 to Formula 5-12 comprise a structure in which an arbitrary hydrogen atom is substituted with a deuterium atom.

19. The fused polycyclic compound of claim 15, wherein R₈ to R₁₁ are each independently a hydrogen atom, a deuterium atom, or a group of Formula S-1 to Formula S-5: 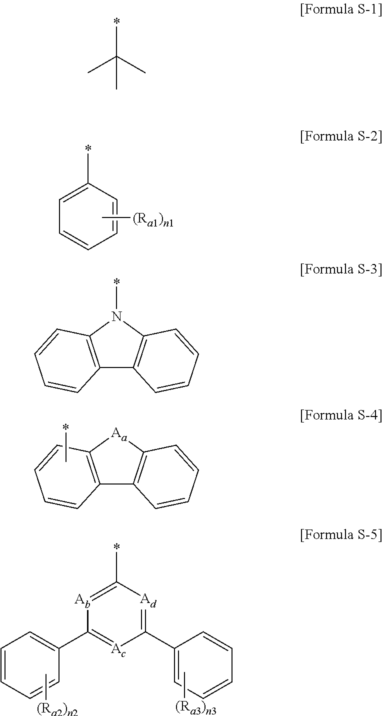
in Formula S-1 to Formula S-5,
Aₐ is O, S, or NAr_{d},
A_{b}, A_{c}, and A_{d} are each independently N or CH,
Ar_{d} is a substituted or unsubstituted aryl group of 6 to 30 ring-forming carbon atoms,
Rₐ₁, Rₐ₂, and Rₐ₃ are each independently a hydrogen atom, a deuterium atom, a substituted or unsubstituted alkyl group of 1 to 20 carbon atoms, or a substituted or unsubstituted aryl group of 6 to 30 ring-forming carbon atoms,
n1 is an integer of 0 to 5,
n2 and n3 are each independently an integer of 0 to 4, and [symbol]
represents a connection of the group Formula S-1 to Formula S-5 in the compound of Formula 1, and Formula S-1 to Formula S-5 comprise a structure in which an arbitrary hydrogen atom is substituted with a deuterium atom.

20. The fused polycyclic compound of claim 15, wherein the fused polycyclic compound represented by Formula 1 comprises at least one compound of the Compound Group 1: 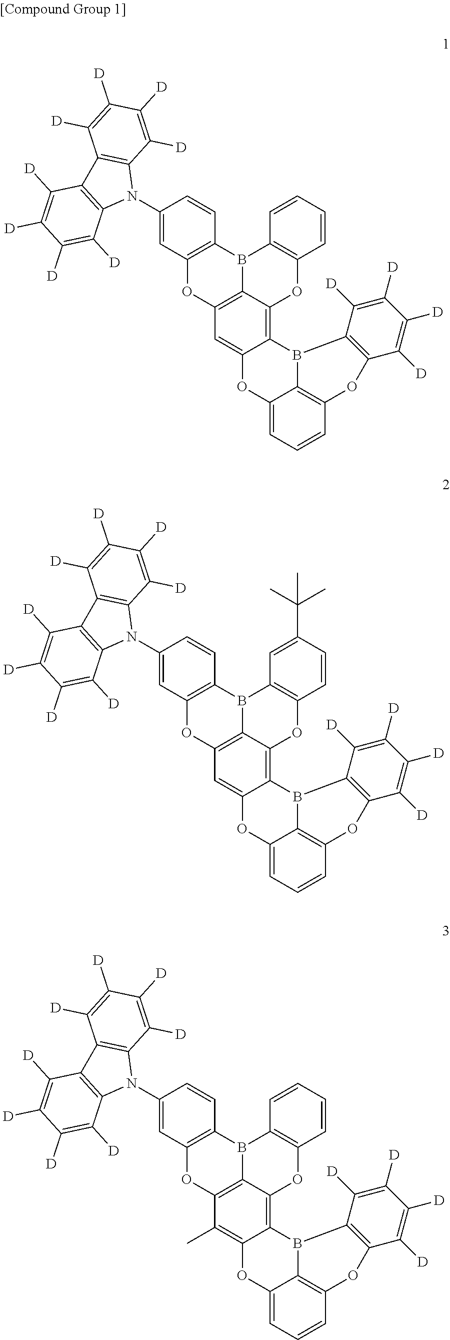 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1O2)O3] 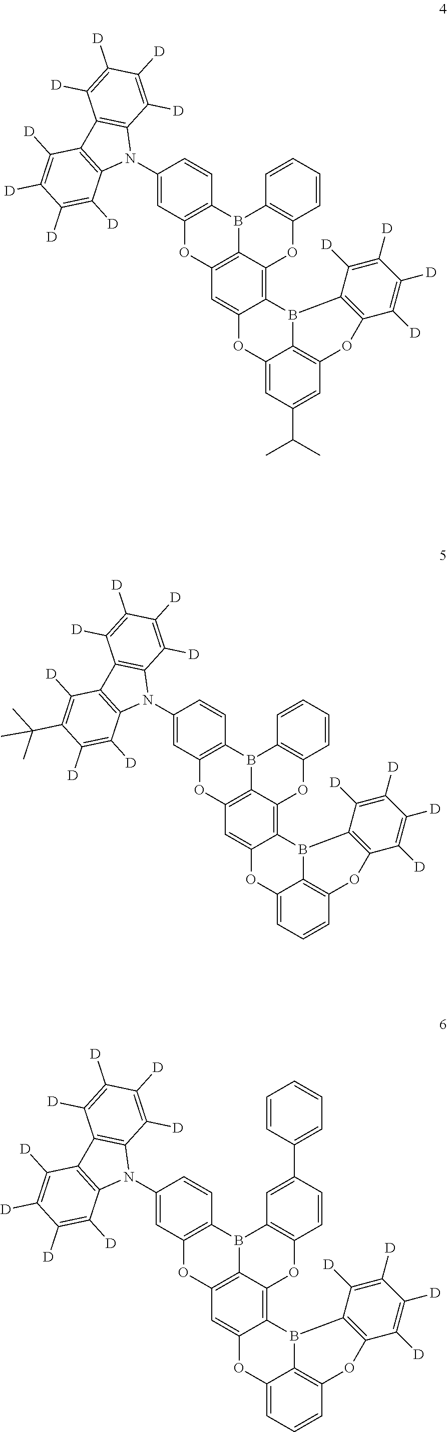 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3] 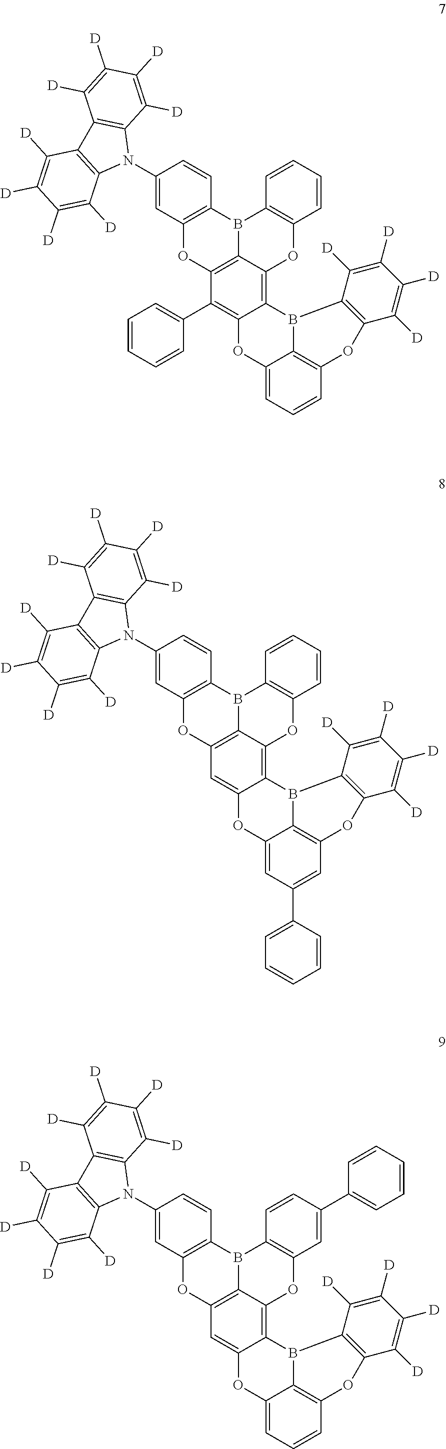 [SMILES: [2H]c1c([2H])c([2H])c2c(c1[2H])Oc1cccc3c1B2c1c2c4c(c(-c5ccccc5)c1O3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)O3] 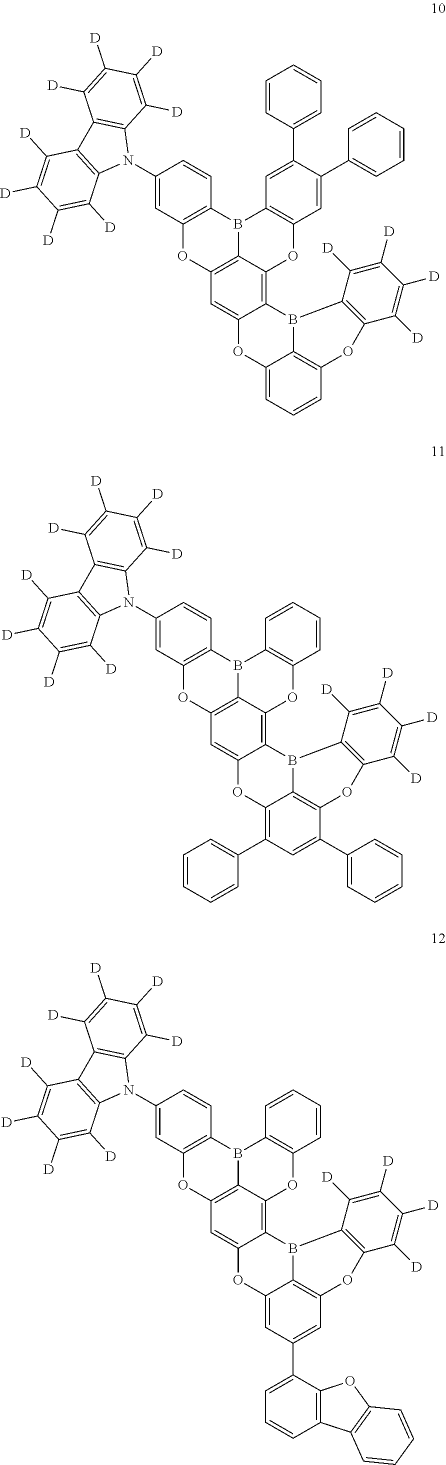 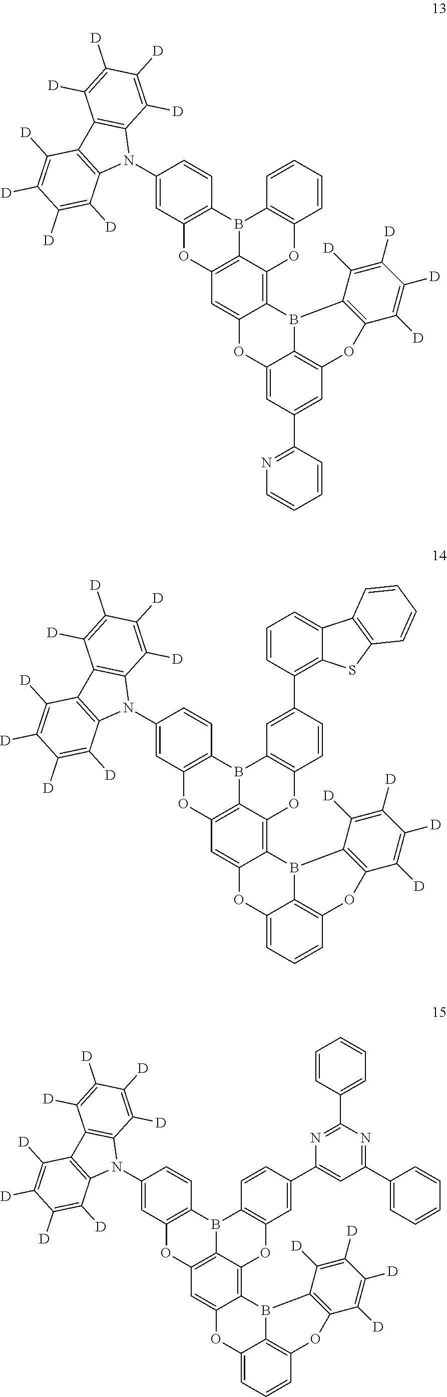 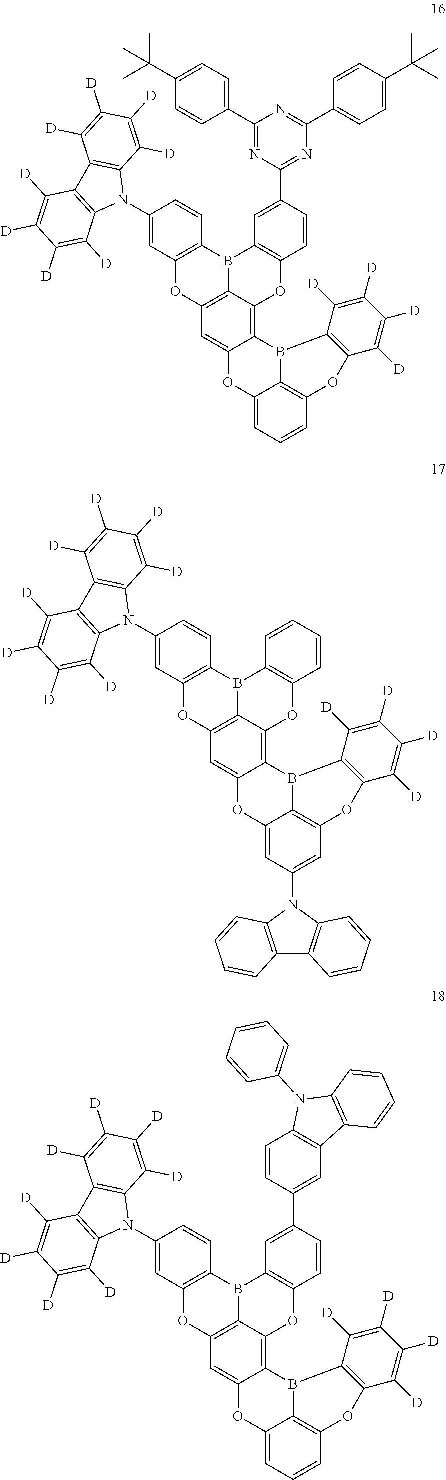 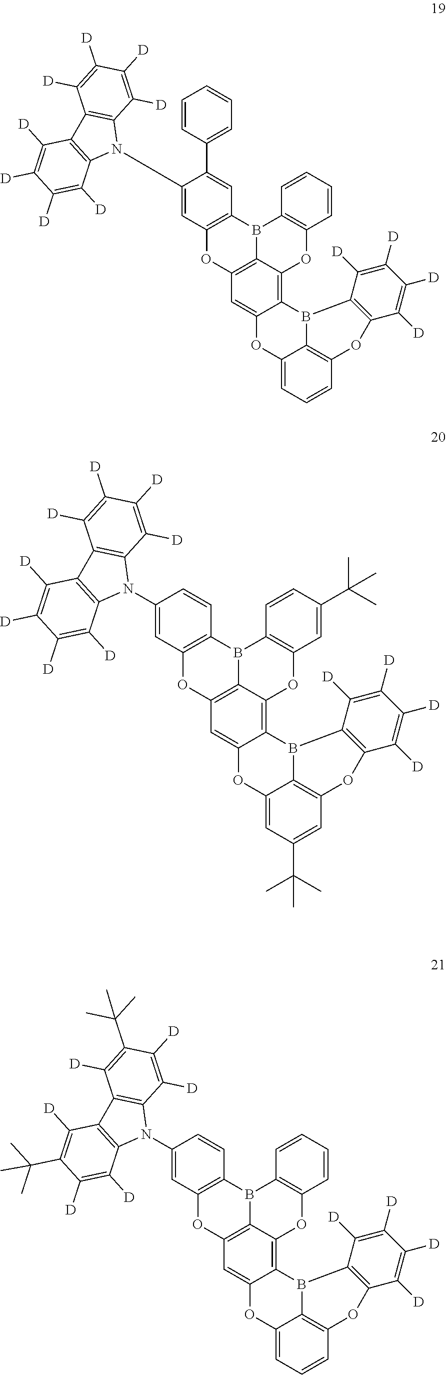 [SMILES: [2H]c1c([2H])c([2H])c2c(c1[2H])Oc1cccc3c1B2c1c(cc2c4c1Oc1ccccc1B4c1cc(-c4ccccc4)c(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(C(C)(C)C)cc3c1B2c1c(cc2c4c1Oc1cc(C(C)(C)C)ccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Oc1ccccc1B4c1ccc(-n4c5c([2H])c([2H])c(C(C)(C)C)c([2H])c5c5c([2H])c(C(C)(C)C)c([2H])c([2H])c54)cc1O2)O3] 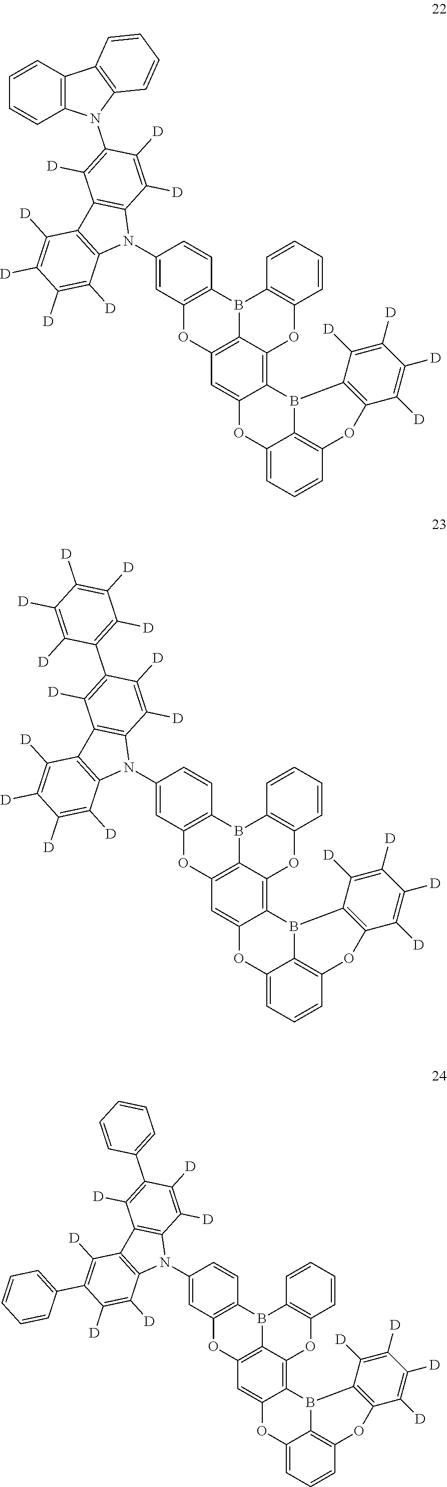 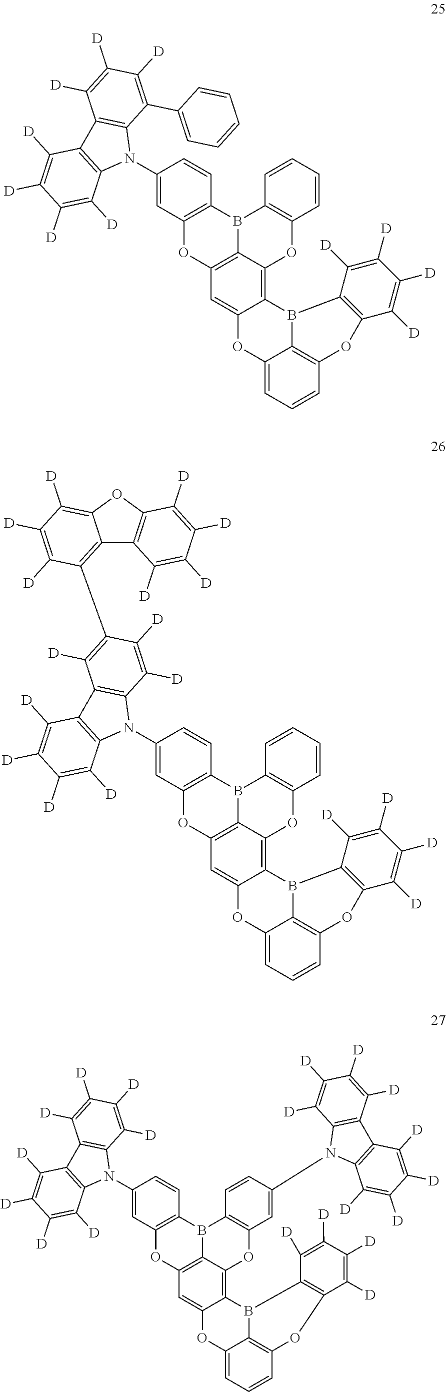 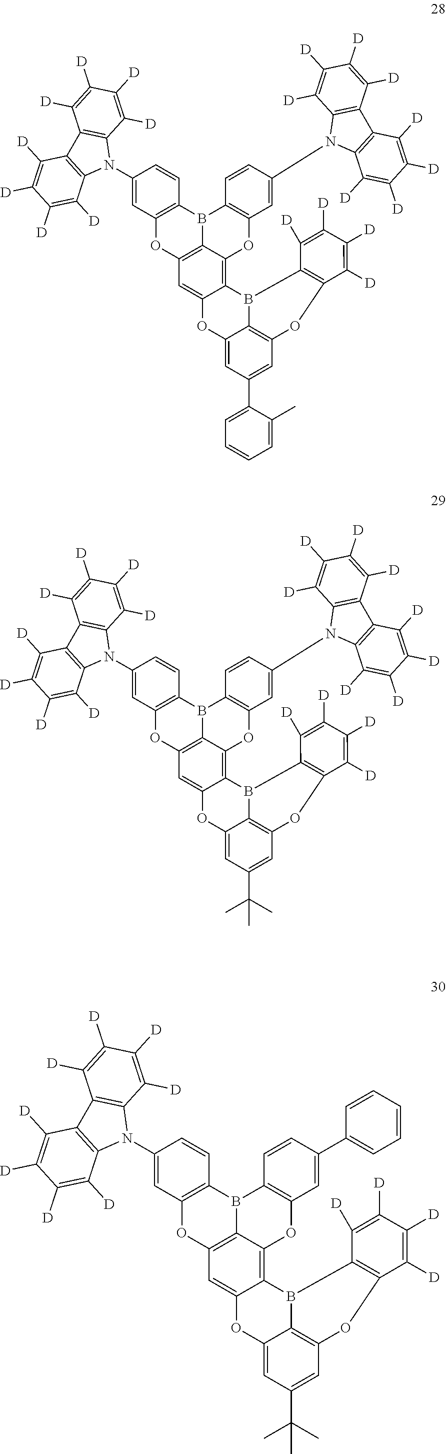 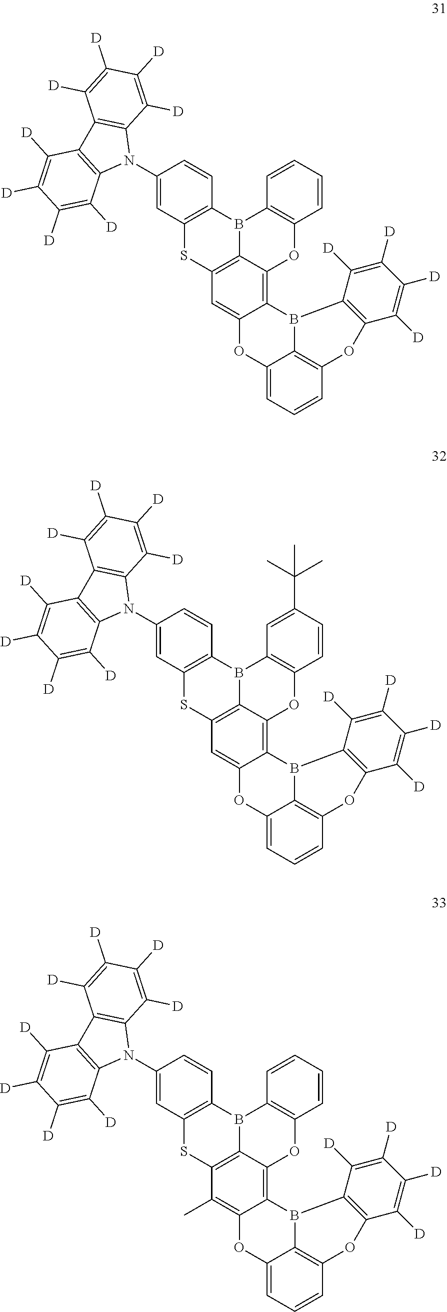 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1S2)O3] 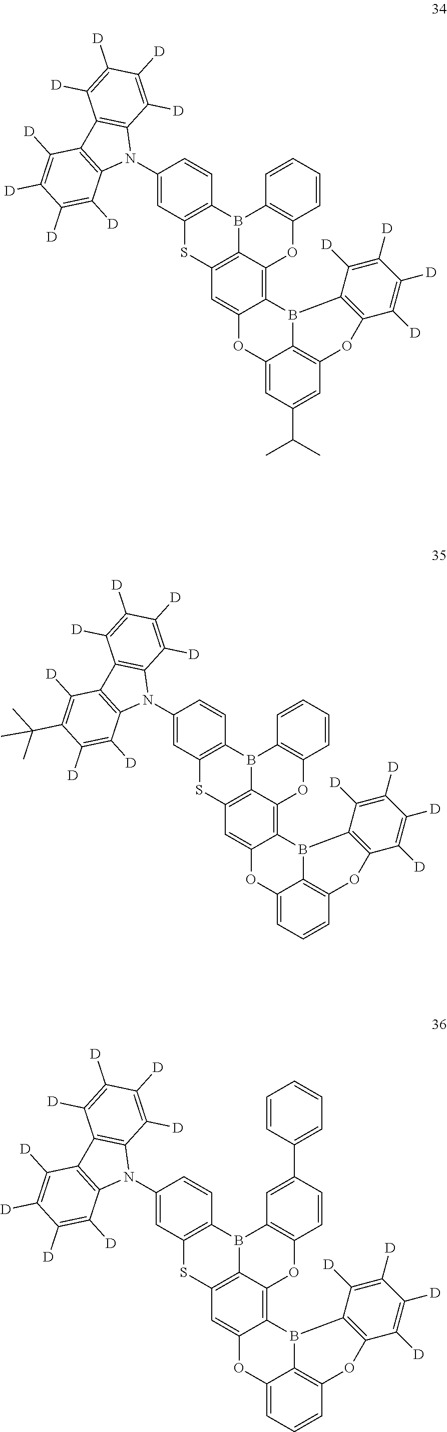 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1S2)O3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1S2)O3] 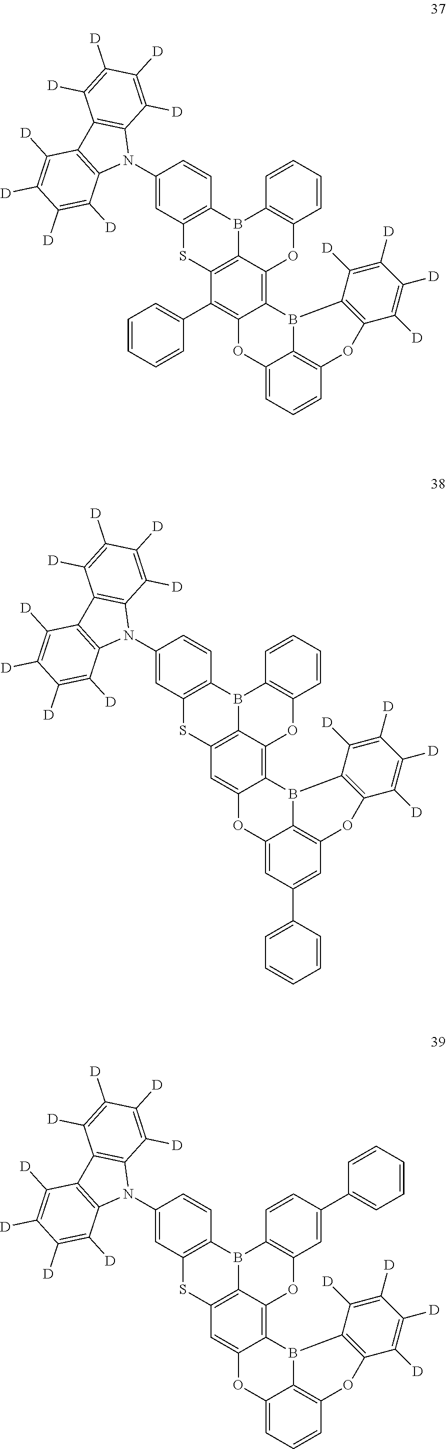 [SMILES: [2H]c1c([2H])c([2H])c2c(c1[2H])Oc1cccc3c1B2c1c2c4c(c(-c5ccccc5)c1O3)Sc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1S2)O3] 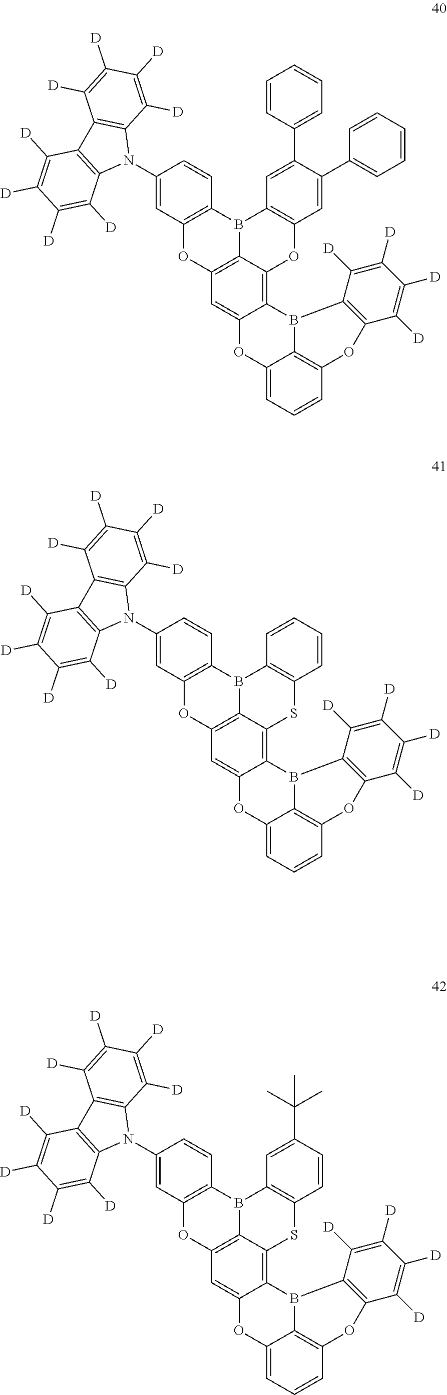 [SMILES: [2H]c1c([2H])c([2H])c2c(c1[2H])Oc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccc(C(C)(C)C)cc1B4c1ccc(-n4c5c([2H])c([2H])c([2H])c([2H])c5c5c([2H])c([2H])c([2H])c([2H])c54)cc1O2)O3] 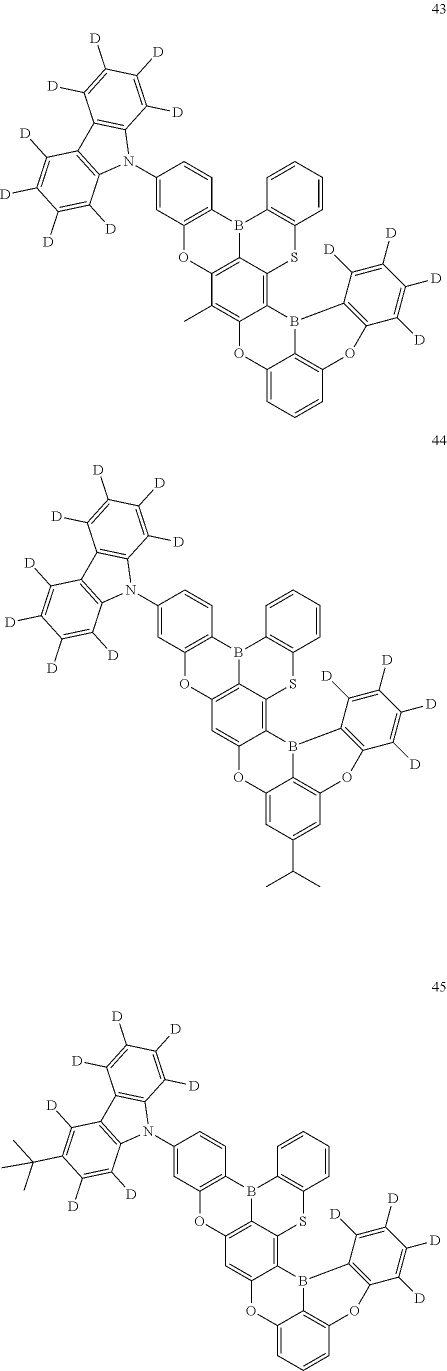 [SMILES: [2H]c1c([2H])c([2H])c2c(c1[2H])Oc1cccc3c1B2c1c(c(C)c2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(C(C)C)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c(C(C)(C)C)c([2H])c([2H])c54)cc1O2)O3] 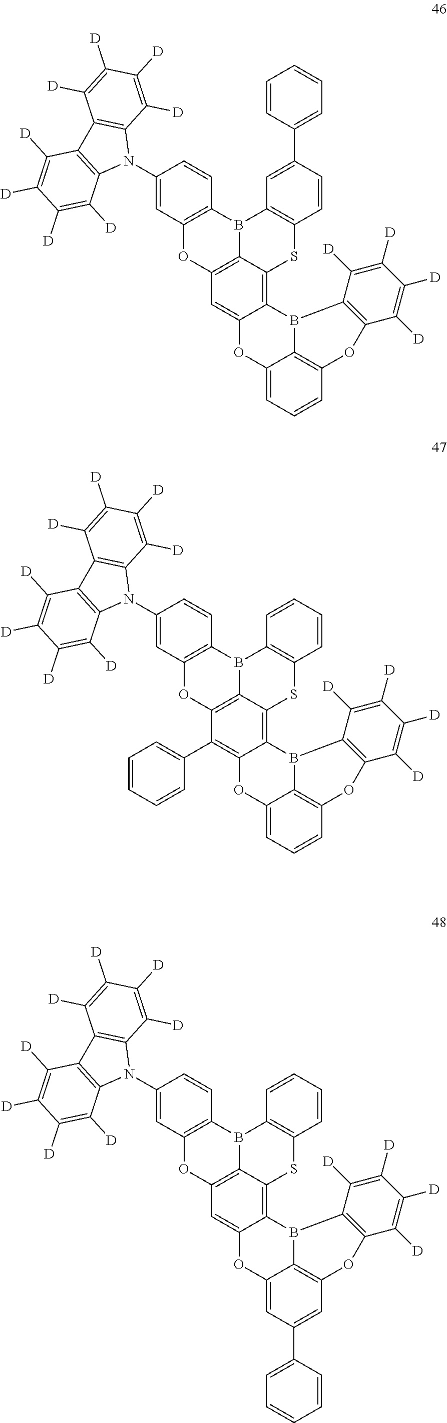 [SMILES: [2H]c1c([2H])c([2H])c2c(c1[2H])Oc1cccc3c1B2c1c(cc2c4c1Sc1ccc(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(c(-c2ccccc2)c2c4c1Sc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cc(-c3ccccc3)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1O2)O3] 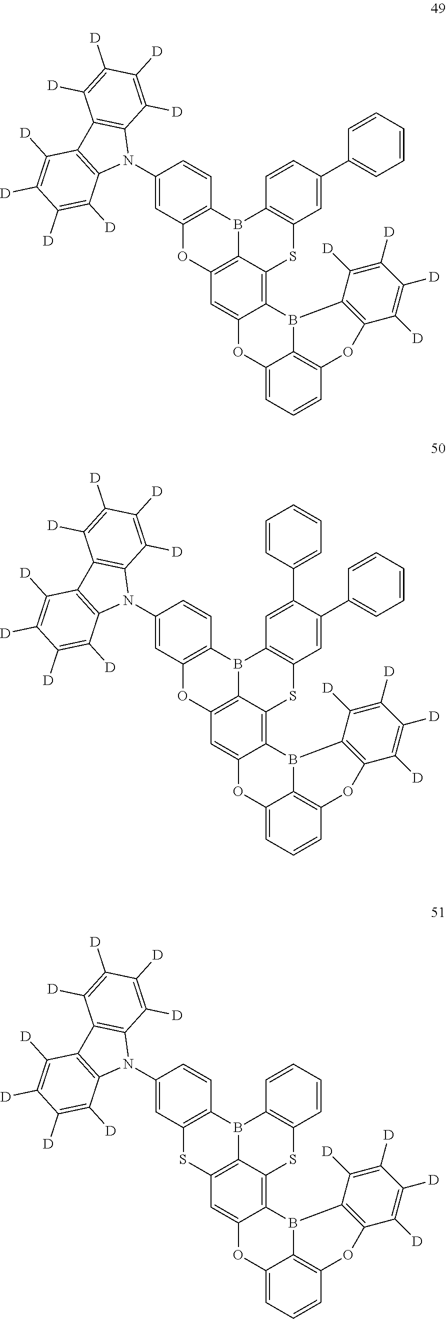 [SMILES: [2H]c1c([2H])c([2H])c2c(c1[2H])Oc1cccc3c1B2c1c(cc2c4c1Sc1cc(-c5ccccc5)ccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3] 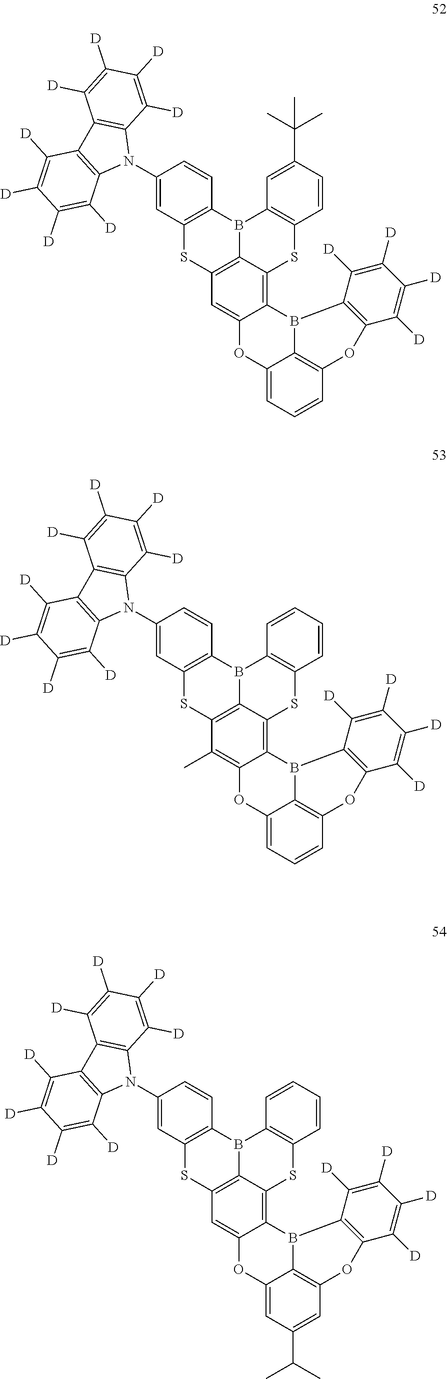 [SMILES: [2H]c1c([2H])c([2H])c2c(c1[2H])Oc1cccc3c1B2c1c(cc2c4c1Sc1ccc(C(C)(C)C)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(C)c2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cc(C(C)C)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3] 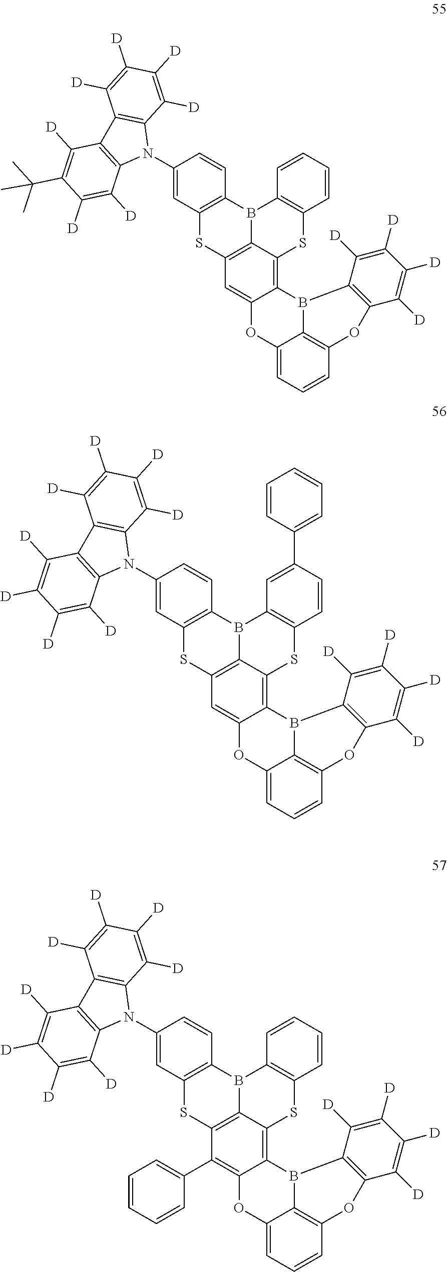 [SMILES: [2H]c1c([2H])c([2H])c2c(c1[2H])Oc1cccc3c1B2c1c(cc2c4c1Sc1ccccc1B4c1ccc(-n4c5c([2H])c([2H])c([2H])c([2H])c5c5c([2H])c(C(C)(C)C)c([2H])c([2H])c54)cc1S2)O3 ; [2H]c1c([2H])c([2H])c2c(c1[2H])Oc1cccc3c1B2c1c(cc2c4c1Sc1ccc(-c5ccccc5)cc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(c(-c2ccccc2)c2c4c1Sc1ccccc1B4c1ccc(-n4c5c([2H])c([2H])c([2H])c([2H])c5c5c([2H])c([2H])c([2H])c([2H])c54)cc1S2)O3] 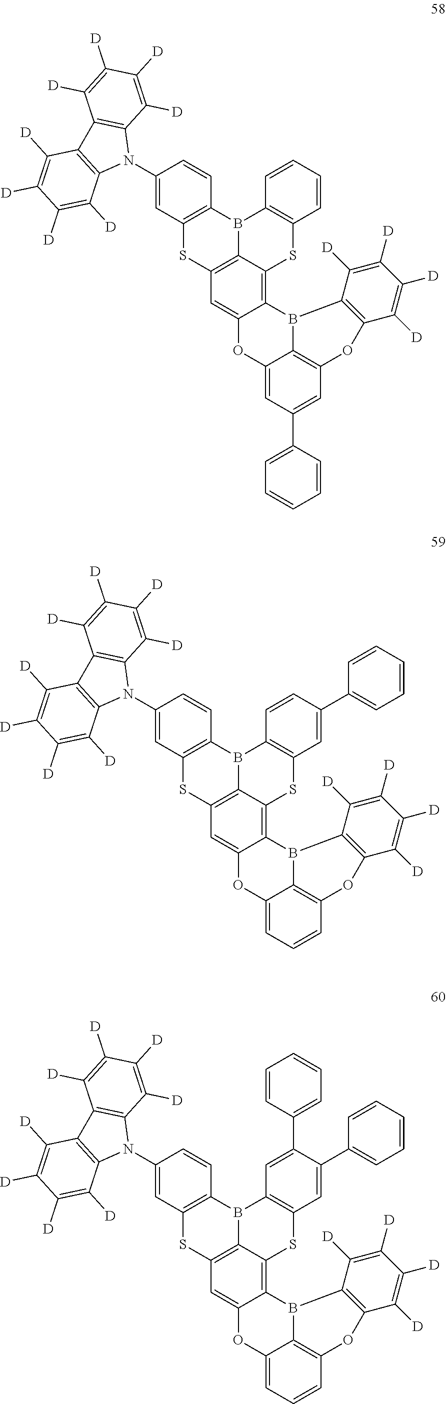 [SMILES: [2H]c1c([2H])c([2H])c2c(c1[2H])Oc1cc(-c3ccccc3)cc3c1B2c1c(cc2c4c1Sc1ccccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1cc(-c5ccccc5)ccc1B4c1ccc(-n4c5c([2H])c([2H])c([2H])c([2H])c5c5c([2H])c([2H])c([2H])c([2H])c54)cc1S2)O3 ; [2H]c1c([2H])c([2H])c2c(c1[2H])Oc1cccc3c1B2c1c(cc2c4c1Sc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1S2)O3] 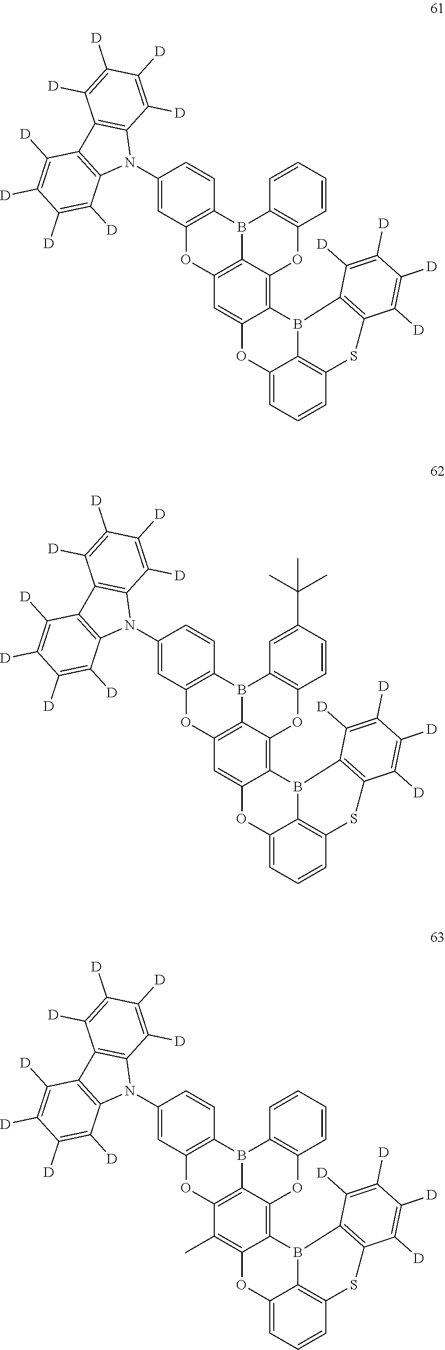 [SMILES: [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(c(C)c2c4c1Oc1ccccc1B4c1ccc(-n4c5c([2H])c([2H])c([2H])c([2H])c5c5c([2H])c([2H])c([2H])c([2H])c54)cc1O2)O3] 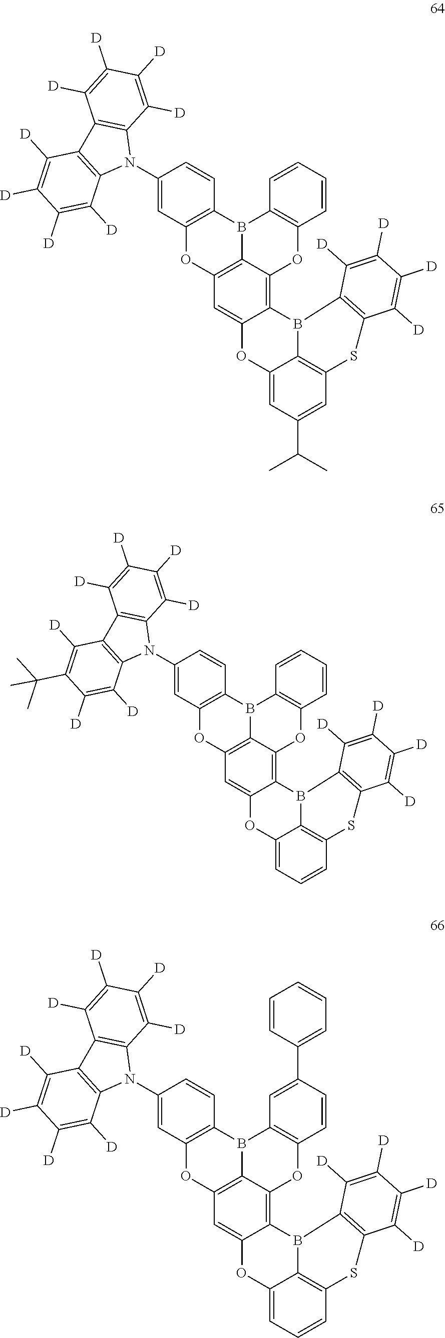 [SMILES: [2H]c1c([2H])c([2H])c2c(c1[2H])Sc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)O3 ; [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)O3] 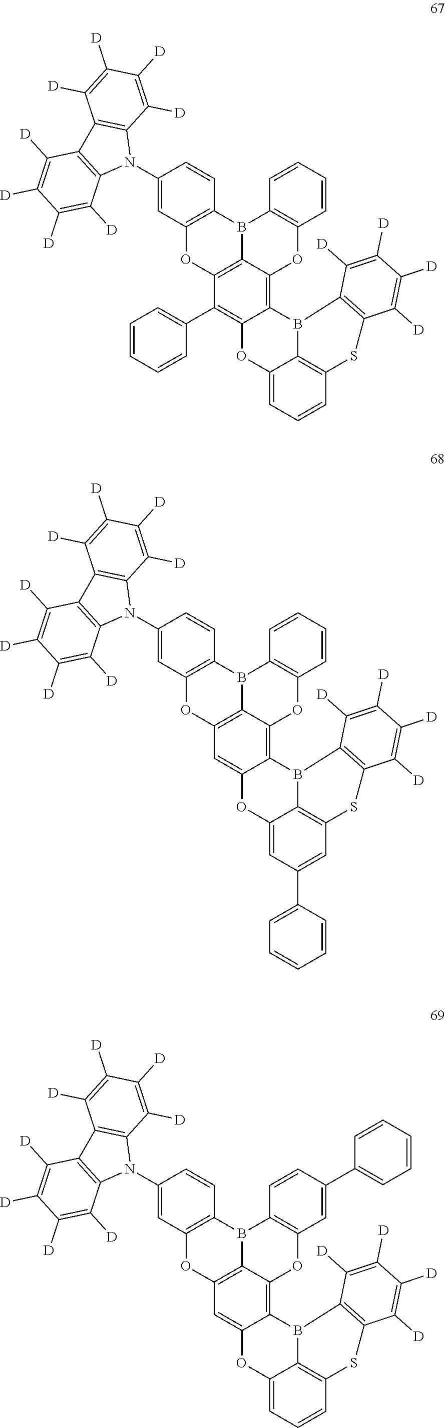 [SMILES: [2H]c1c([2H])c([2H])c2c(c1[2H])Sc1cccc3c1B2c1c2c4c(c(-c5ccccc5)c1O3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Sc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)O3 ; [2H]c1c([2H])c([2H])c2c(c1[2H])Sc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)O3] 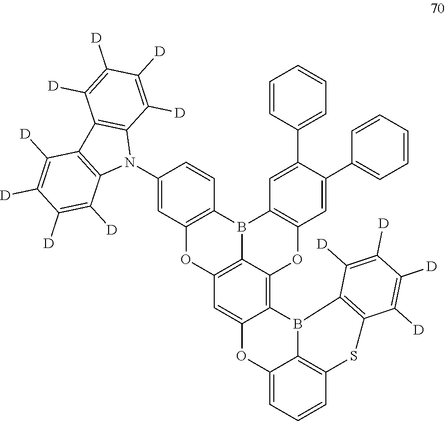 [SMILES: [2H]c1c([2H])c([2H])c2c(c1[2H])Sc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)O3] 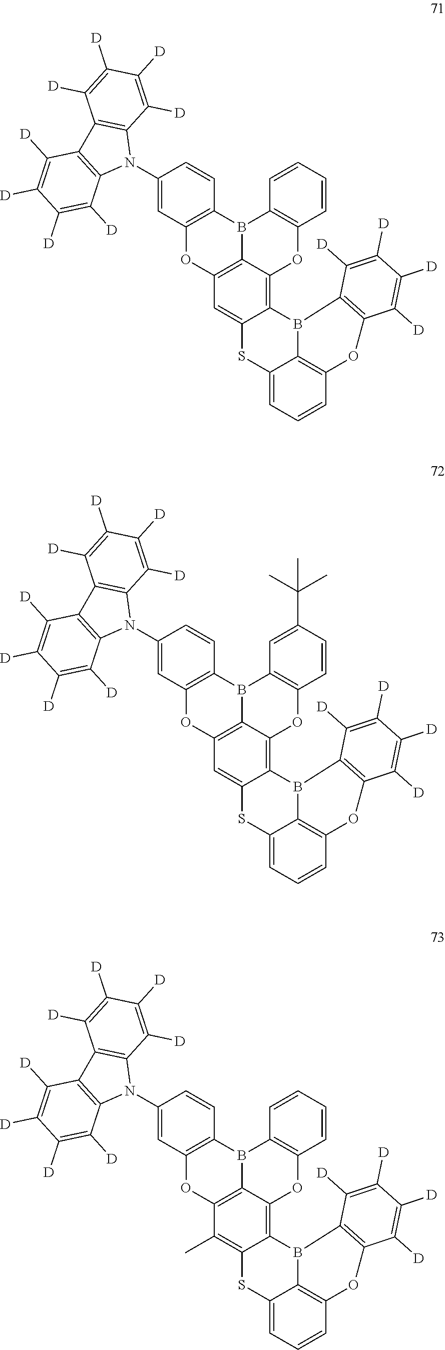 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c2c4c(c(C)c1S3)Oc1cc(-n3c5c([2H])c([2H])c([2H])c([2H])c5c5c([2H])c([2H])c([2H])c([2H])c53)ccc1B4c1ccccc1O2] 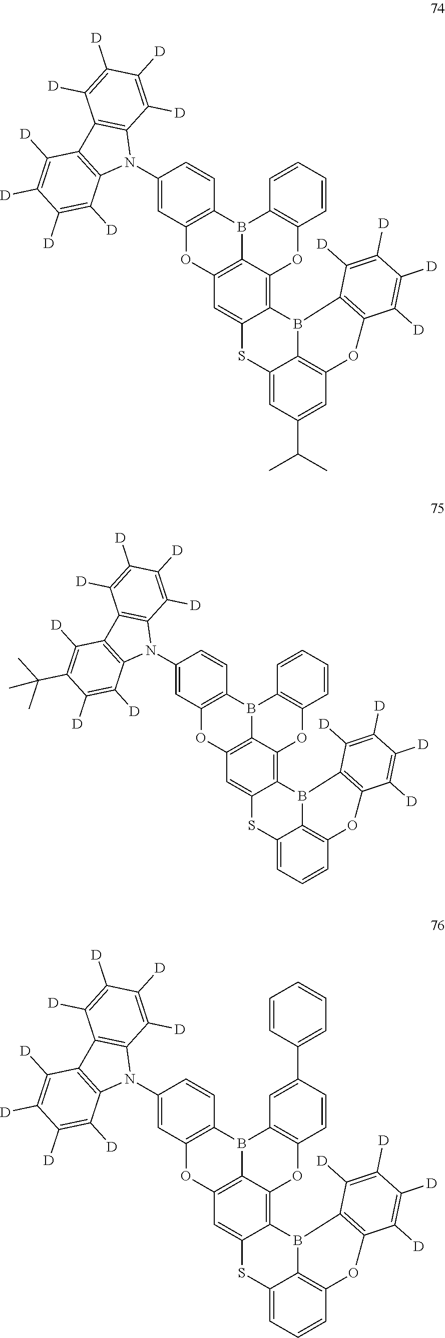 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)S3 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)S3] 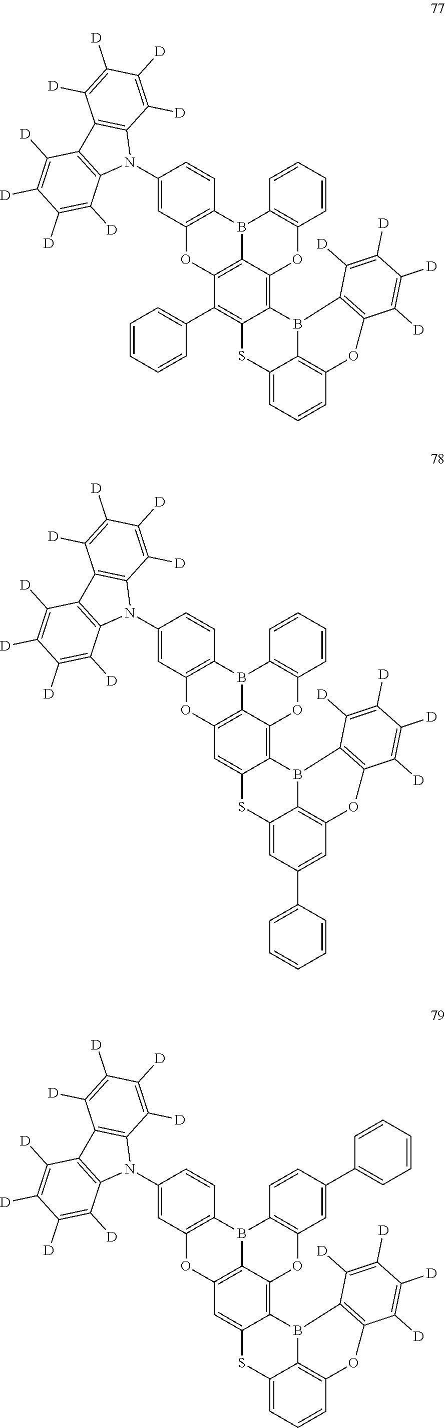 [SMILES: [2H]c1c([2H])c([2H])c2c(c1[2H])Oc1cccc3c1B2c1c2c4c(c(-c5ccccc5)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Oc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Oc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)S3] 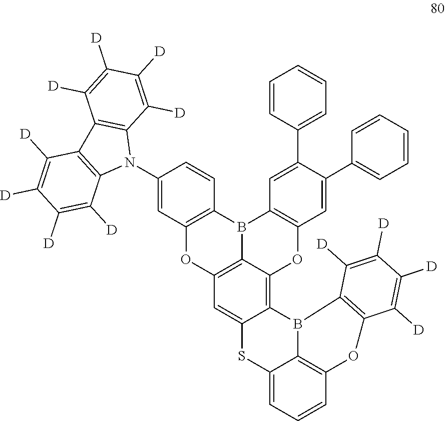 [SMILES: [2H]c1c([2H])c([2H])c2c(c1[2H])Oc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)S3] 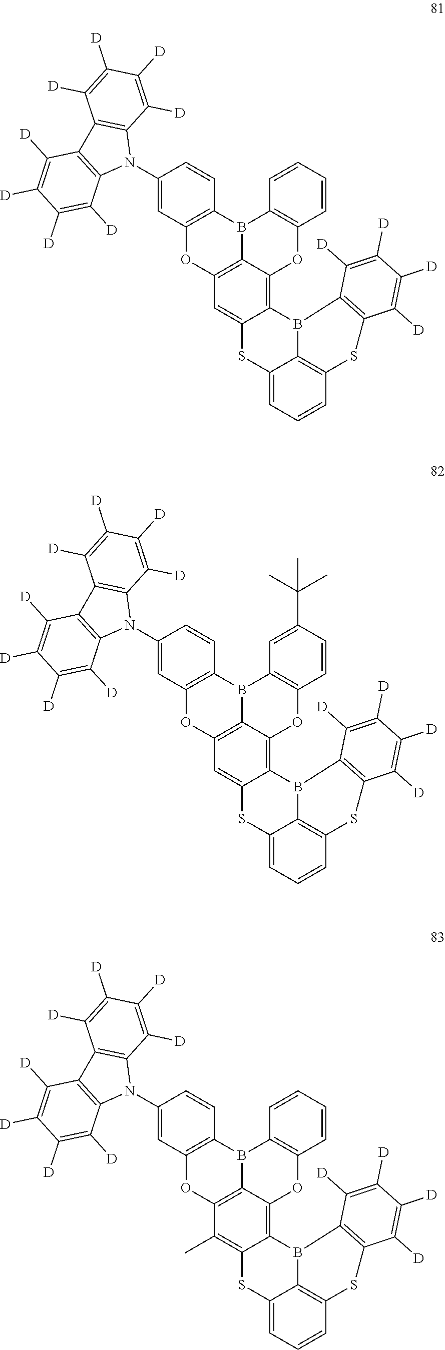 [SMILES: [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c2c4c(c(C)c1S3)Oc1cc(-n3c5c([2H])c([2H])c([2H])c([2H])c5c5c([2H])c([2H])c([2H])c([2H])c53)ccc1B4c1ccccc1O2] 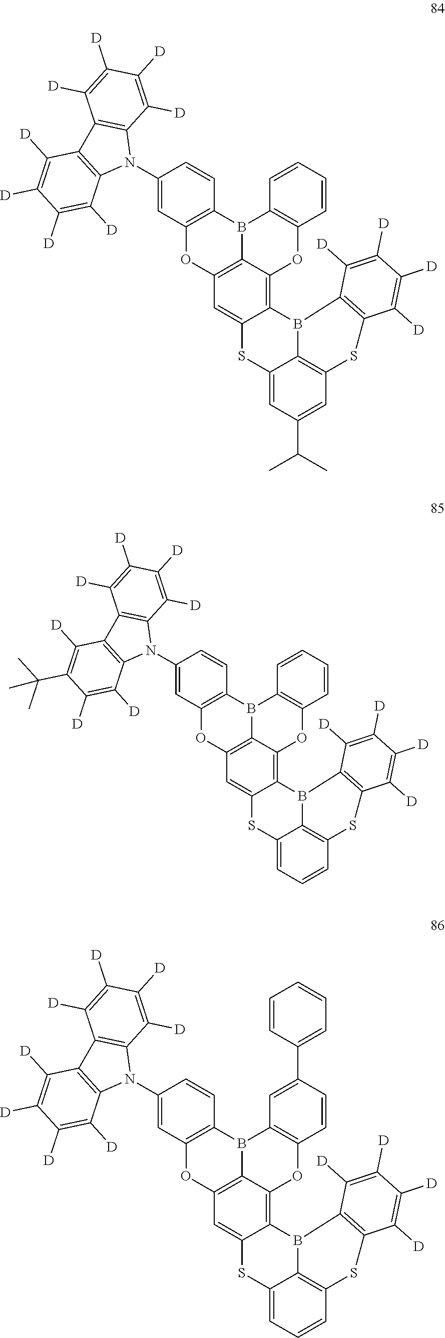 [SMILES: [2H]c1c([2H])c([2H])c2c(c1[2H])Sc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)S3 ; [2H]c1c([2H])c([2H])c2c(c1[2H])Sc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)S3] 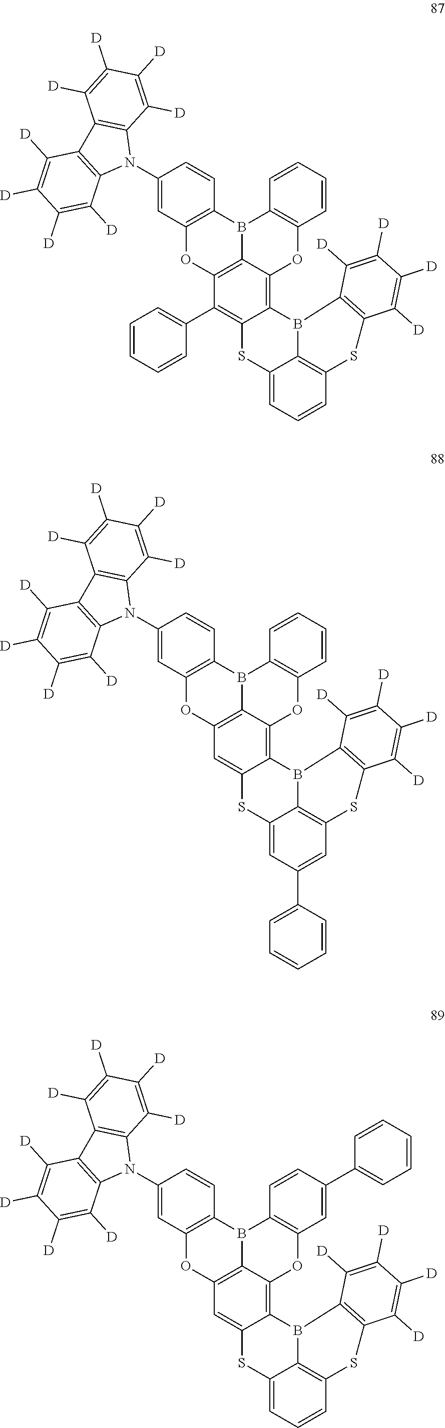 [SMILES: [2H]c1c([2H])c([2H])c2c(c1[2H])Sc1cccc3c1B2c1c2c4c(c(-c5ccccc5)c1S3)Oc1cc(-n3c5c([2H])c([2H])c([2H])c([2H])c5c5c([2H])c([2H])c([2H])c([2H])c53)ccc1B4c1ccccc1O2 ; [2H]c1c([2H])c([2H])c2c(c1[2H])Sc1cc(-c3ccccc3)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)S3 ; [2H]c1c([2H])c([2H])c2c(c1[2H])Sc1cccc3c1B2c1c(cc2c4c1Oc1cc(-c5ccccc5)ccc1B4c1ccc(-n4c5c([2H])c([2H])c([2H])c([2H])c5c5c([2H])c([2H])c([2H])c([2H])c54)cc1O2)S3] 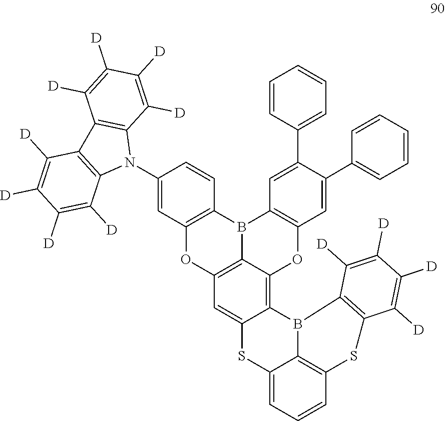 [SMILES: [2H]c1c([2H])c([2H])c2c(c1[2H])Sc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)S3] 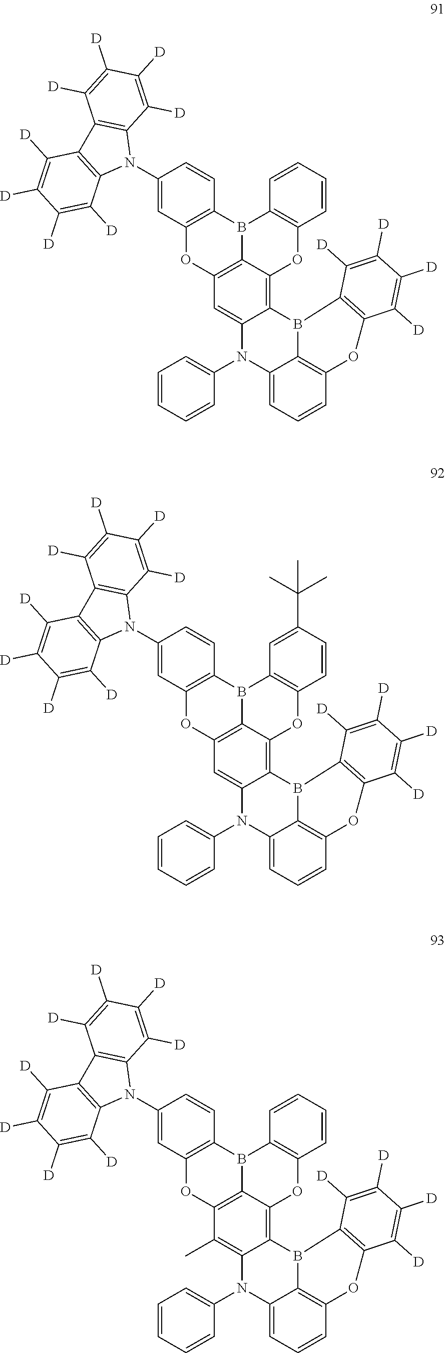 [SMILES: [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c(cc2c4c1Oc1ccc(C(C)(C)C)cc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c2c4c(c(C)c1N3c1ccccc1)Oc1cc(-n3c5c([2H])c([2H])c([2H])c([2H])c5c5c([2H])c([2H])c([2H])c([2H])c53)ccc1B4c1ccccc1O2] 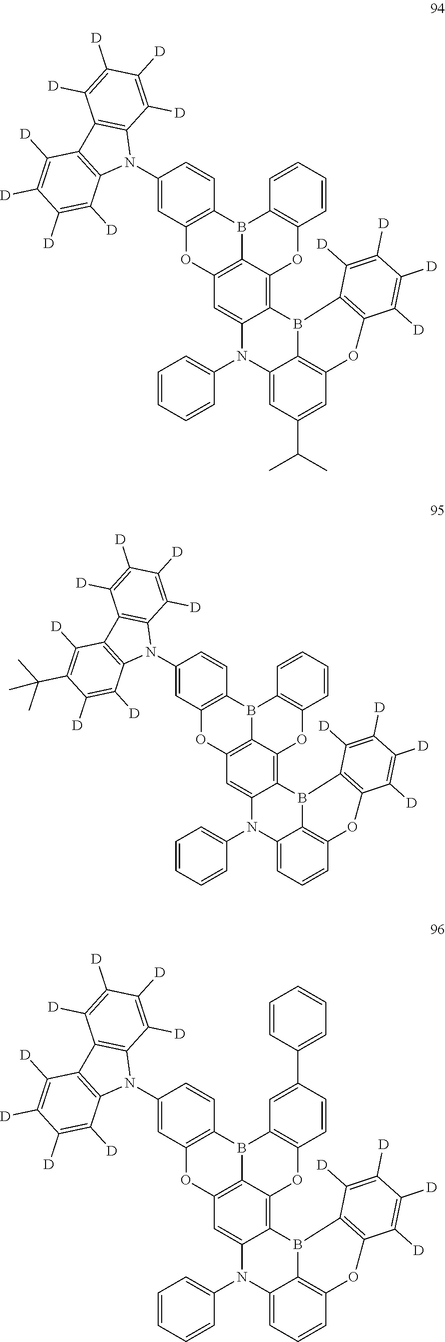 [SMILES: [2H]c1c([2H])c([2H])c2c(c1[2H])Oc1cc(C(C)C)cc3c1B2c1c(cc2c4c1Oc1ccccc1B4c1ccc(-n4c5c([2H])c([2H])c([2H])c([2H])c5c5c([2H])c([2H])c([2H])c([2H])c54)cc1O2)N3c1ccccc1 ; [2H]c1c([2H])c([2H])c2c(c1[2H])Oc1cccc3c1B2c1c(cc2c4c1Oc1ccccc1B4c1ccc(-n4c5c([2H])c([2H])c([2H])c([2H])c5c5c([2H])c(C(C)(C)C)c([2H])c([2H])c54)cc1O2)N3c1ccccc1 ; [2H]c1c([2H])c([2H])c2c(c1[2H])Oc1cccc3c1B2c1c(cc2c4c1Oc1ccc(-c5ccccc5)cc1B4c1ccc(-n4c5c([2H])c([2H])c([2H])c([2H])c5c5c([2H])c([2H])c([2H])c([2H])c54)cc1O2)N3c1ccccc1] 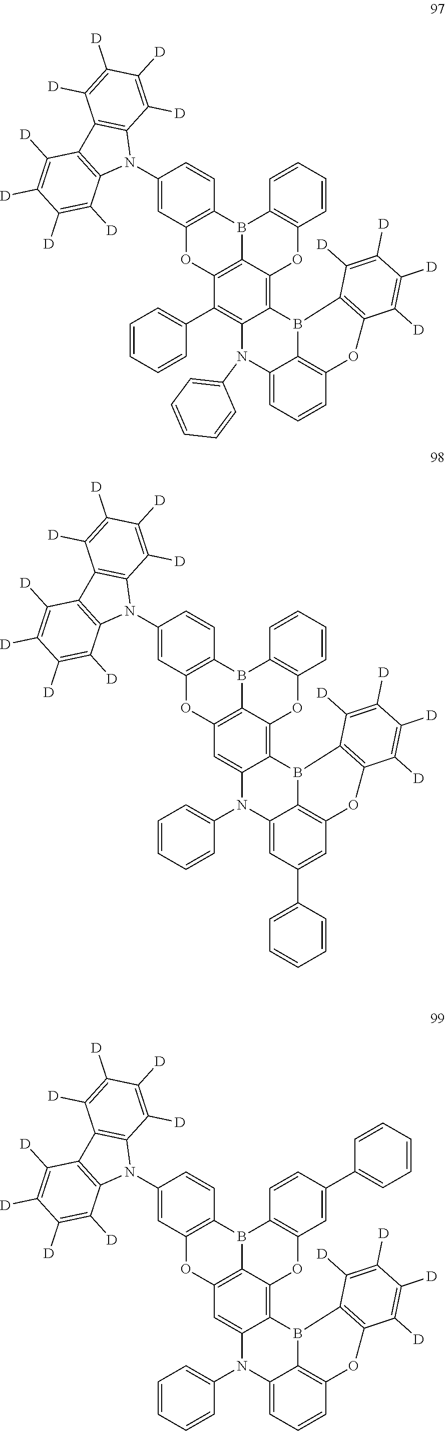 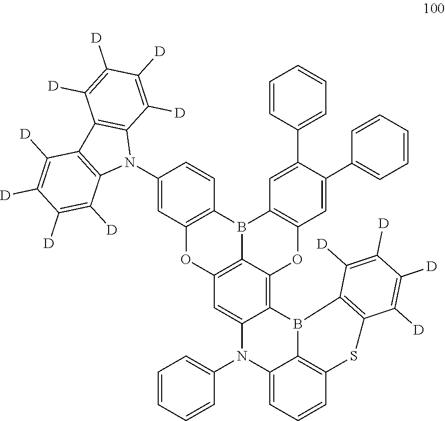 [SMILES: [2H]c1c([2H])c([2H])c2c(c1[2H])Sc1cccc3c1B2c1c(cc2c4c1Oc1cc(-c5ccccc5)c(-c5ccccc5)cc1B4c1ccc(-n4c5c([2H])c([2H])c([2H])c([2H])c5c5c([2H])c([2H])c([2H])c([2H])c54)cc1O2)N3c1ccccc1] 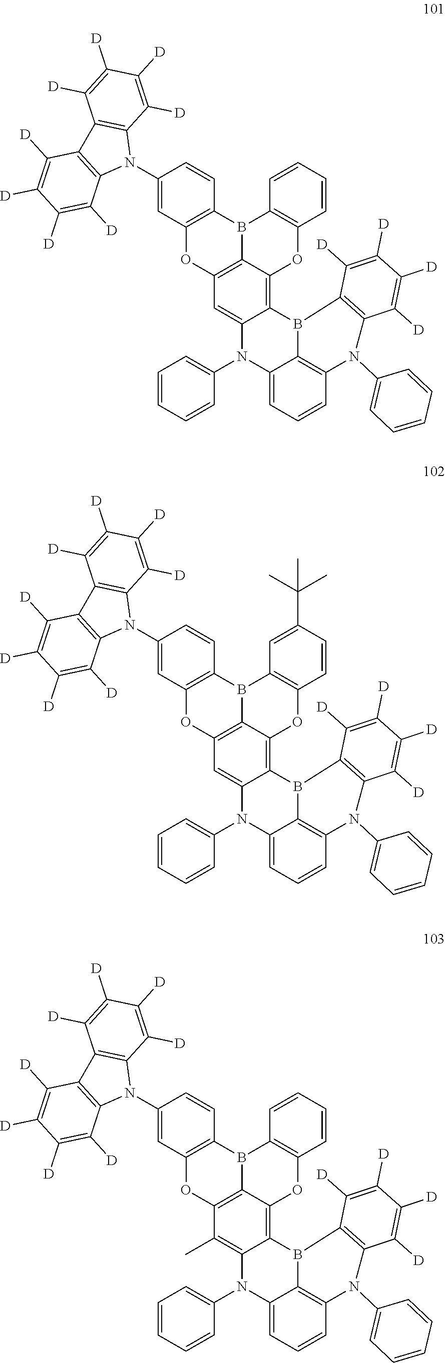 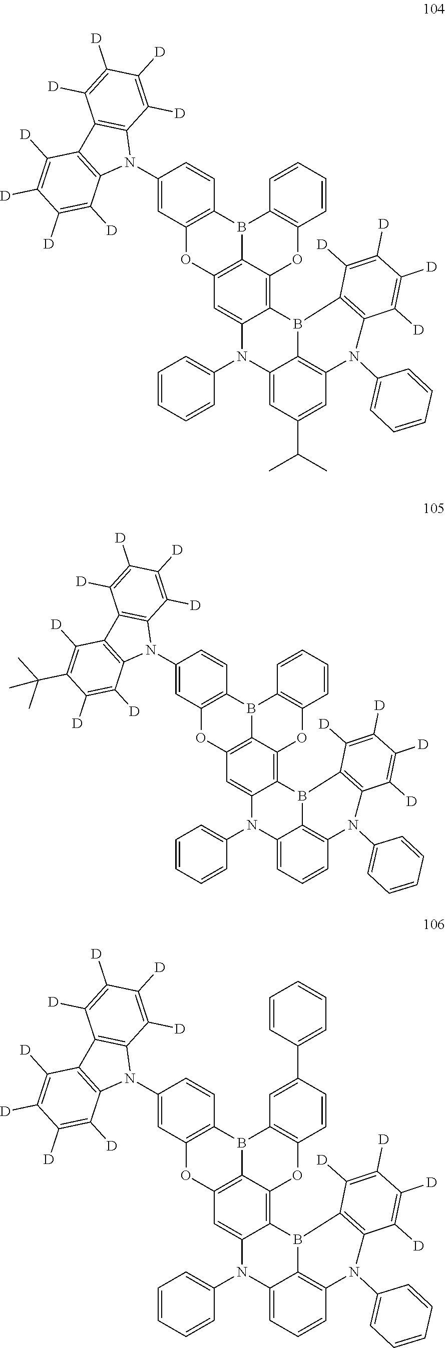 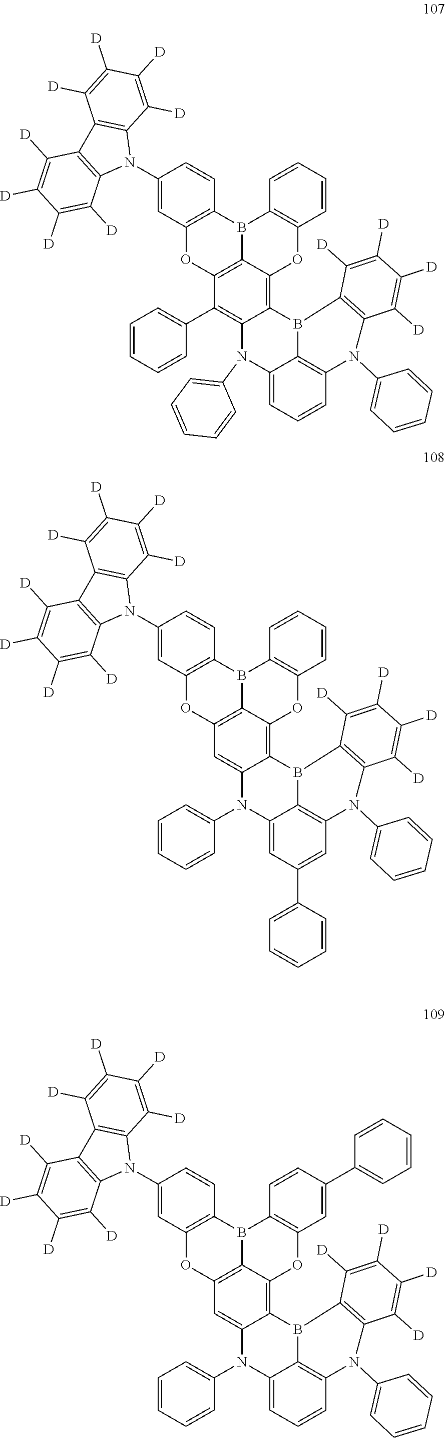 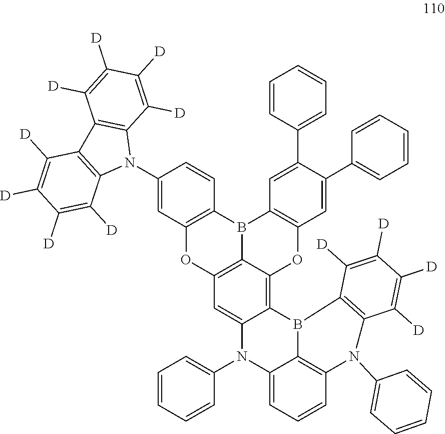 [SMILES: [2H]c1c([2H])c([2H])c2c(c1[2H])B1c3c(cccc3N2c2ccccc2)N(c2ccccc2)c2cc3c4c(c21)Oc1cc(-c2ccccc2)c(-c2ccccc2)cc1B4c1ccc(-n2c4c([2H])c([2H])c([2H])c([2H])c4c4c([2H])c([2H])c([2H])c([2H])c42)cc1O3] 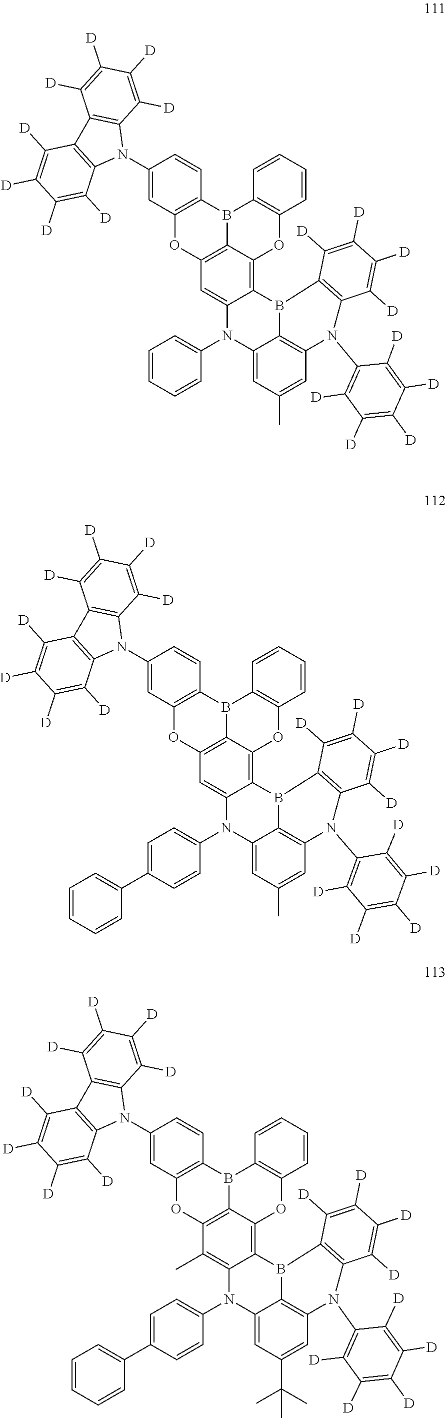 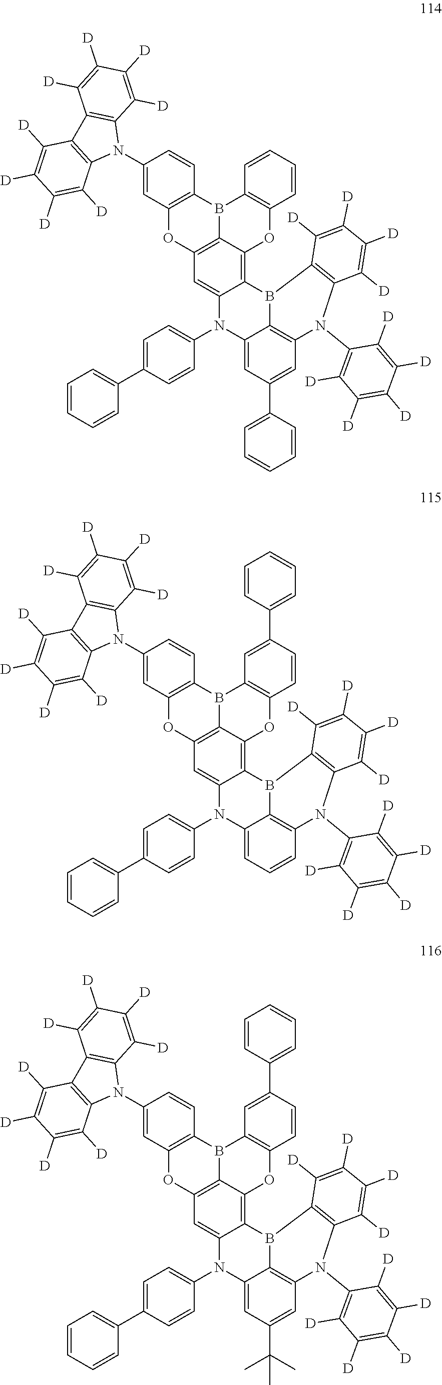 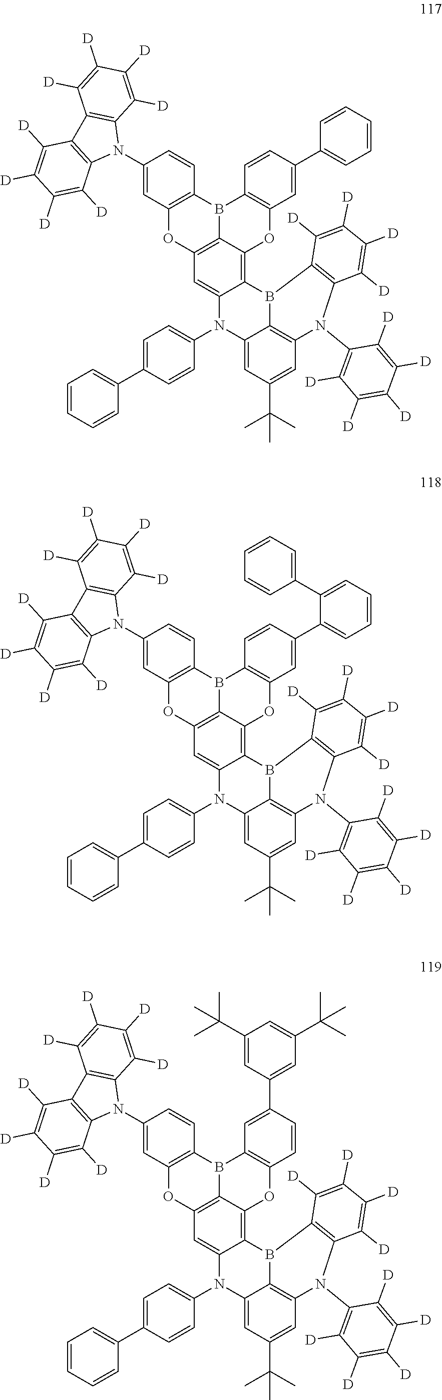 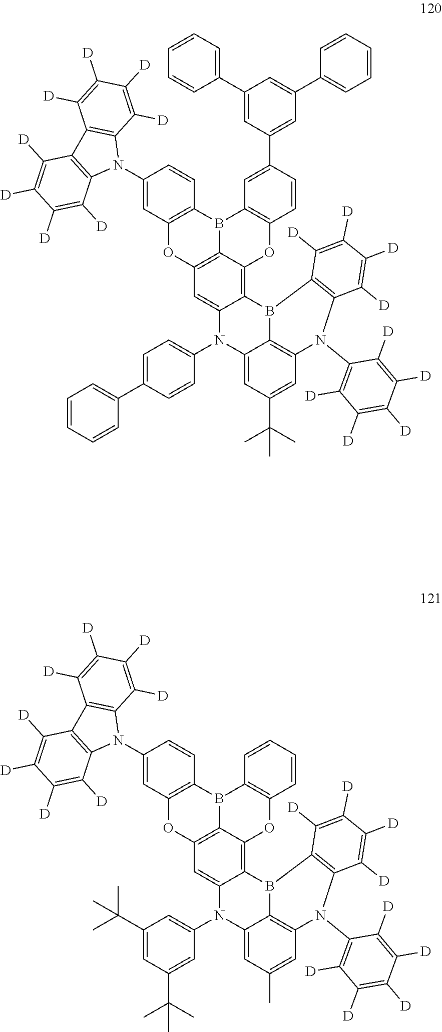 [SMILES: [2H]c1c([2H])c([2H])c(N2c3cc(C(C)(C)C)cc4c3B(c3c(cc5c6c3Oc3ccc(-c7cc(-c8ccccc8)cc(-c8ccccc8)c7)cc3B6c3ccc(-n6c7c([2H])c([2H])c([2H])c([2H])c7c7c([2H])c([2H])c([2H])c([2H])c76)cc3O5)N4c3ccc(-c4ccccc4)cc3)c3c([2H])c([2H])c([2H])c([2H])c32)c([2H])c1[2H] ; [2H]c1c([2H])c([2H])c(N2c3cc(C)cc4c3B(c3c(cc5c6c3Oc3ccccc3B6c3ccc(-n6c7c([2H])c([2H])c([2H])c([2H])c7c7c([2H])c([2H])c([2H])c([2H])c76)cc3O5)N4c3cc(C(C)(C)C)cc(C(C)(C)C)c3)c3c([2H])c([2H])c([2H])c([2H])c32)c([2H])c1[2H]] 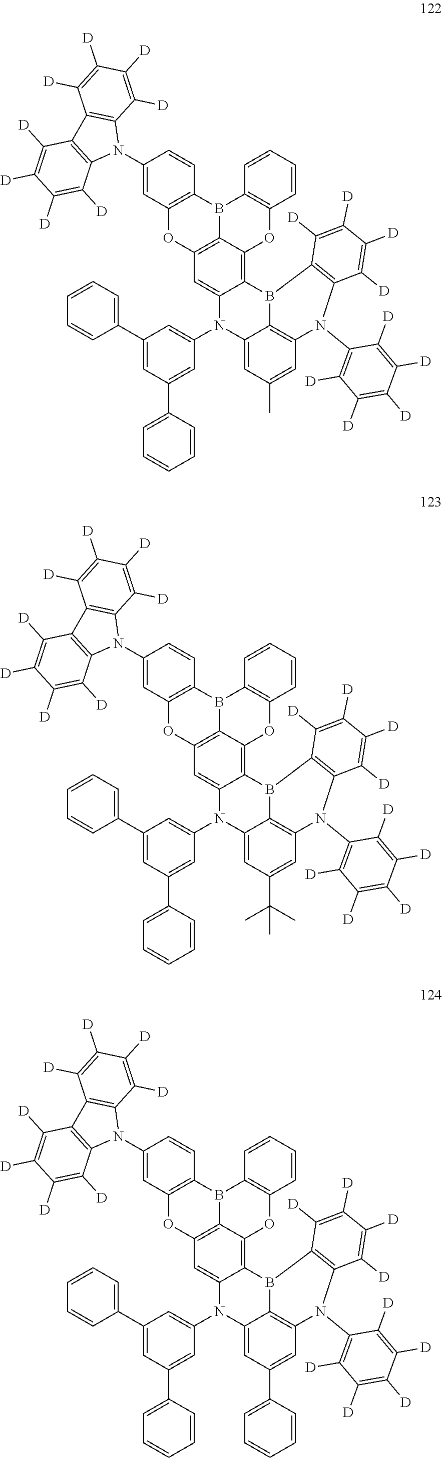 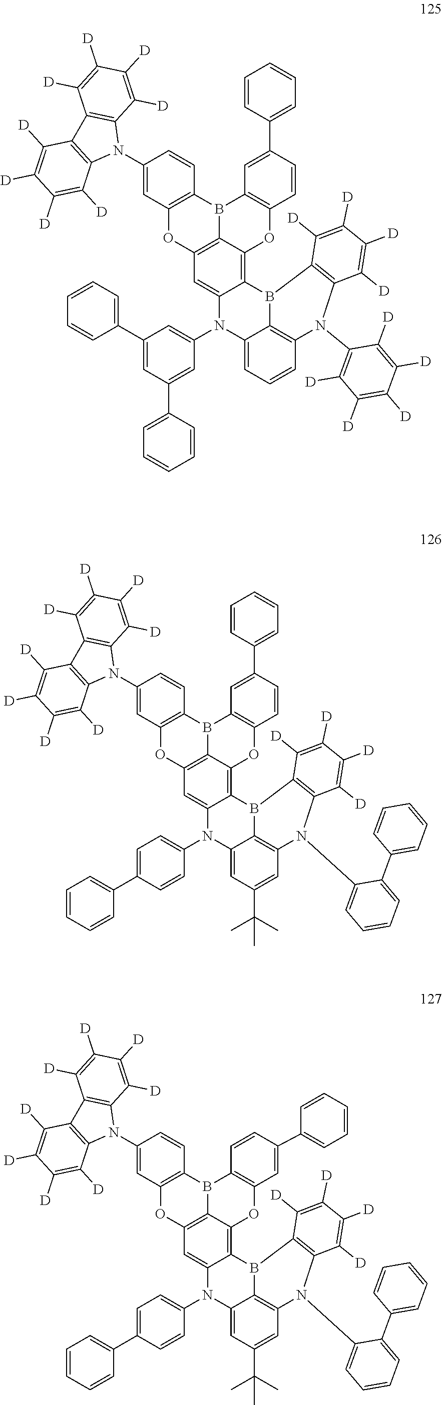 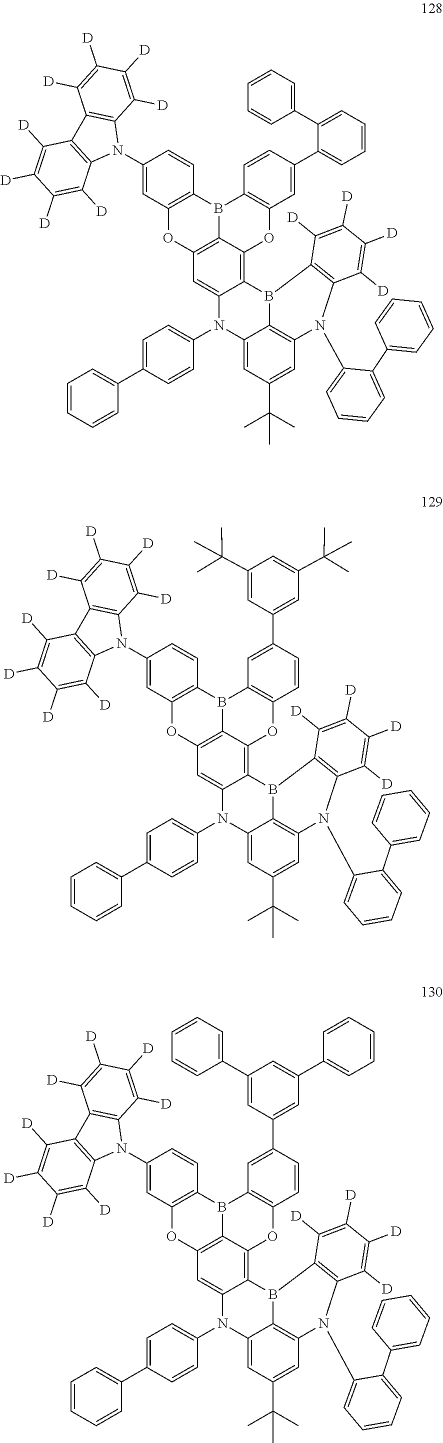 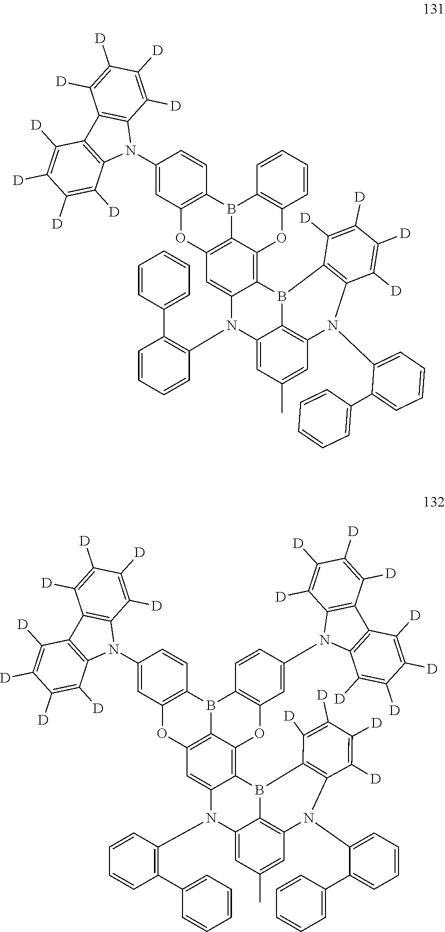 [SMILES: [2H]c1c([2H])c([2H])c2c(c1[2H])B1c3c(cc(C)cc3N2c2ccccc2-c2ccccc2)N(c2ccccc2-c2ccccc2)c2cc3c4c(c21)Oc1ccccc1B4c1ccc(-n2c4c([2H])c([2H])c([2H])c([2H])c4c4c([2H])c([2H])c([2H])c([2H])c42)cc1O3 ; [2H]c1c([2H])c([2H])c2c(c1[2H])B1c3c(cc(C)cc3N2c2ccccc2-c2ccccc2)N(c2ccccc2-c2ccccc2)c2cc3c4c(c21)Oc1cc(-n2c5c([2H])c([2H])c([2H])c([2H])c5c5c([2H])c([2H])c([2H])c([2H])c52)ccc1B4c1ccc(-n2c4c([2H])c([2H])c([2H])c([2H])c4c4c([2H])c([2H])c([2H])c([2H])c42)cc1O3] 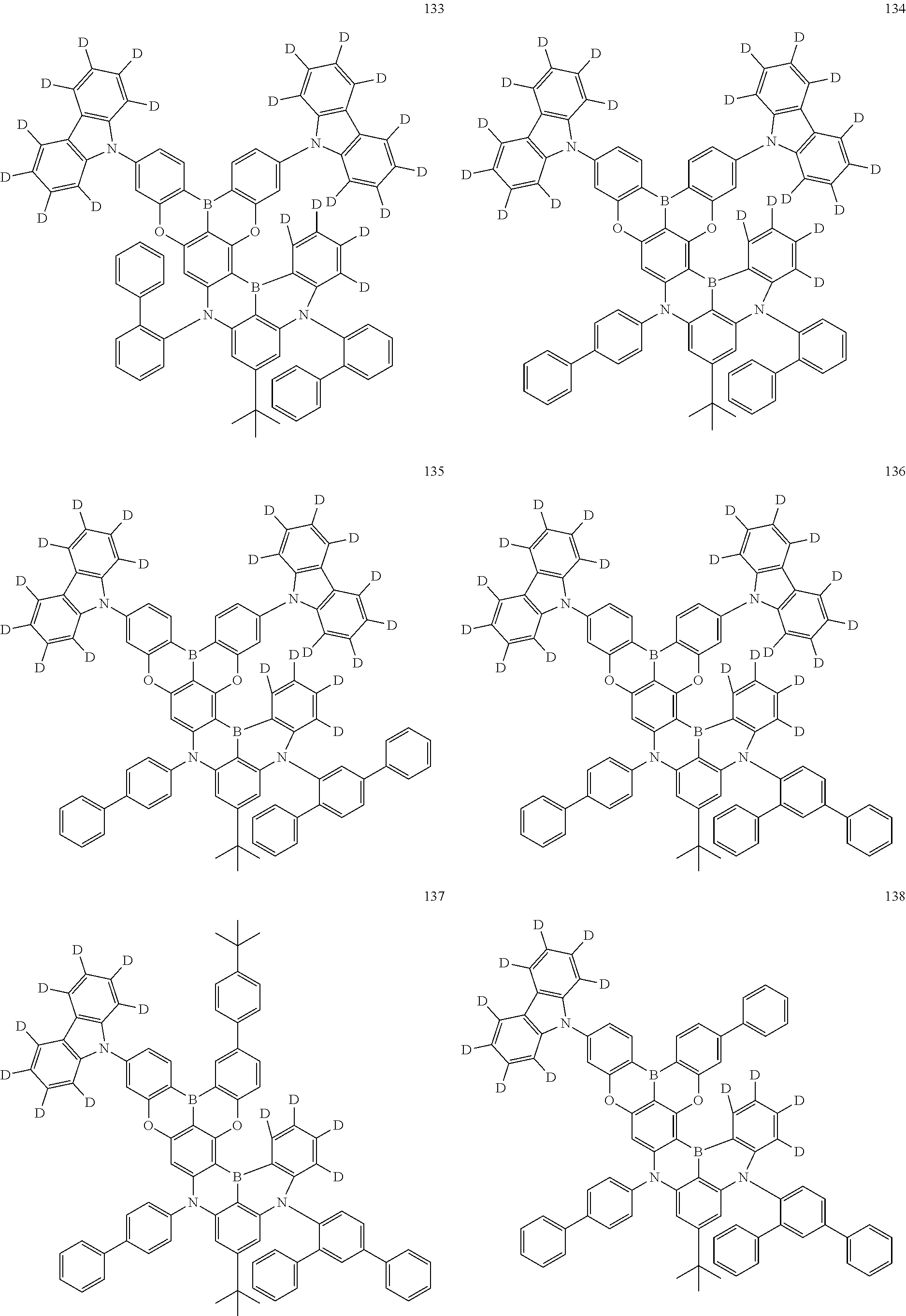 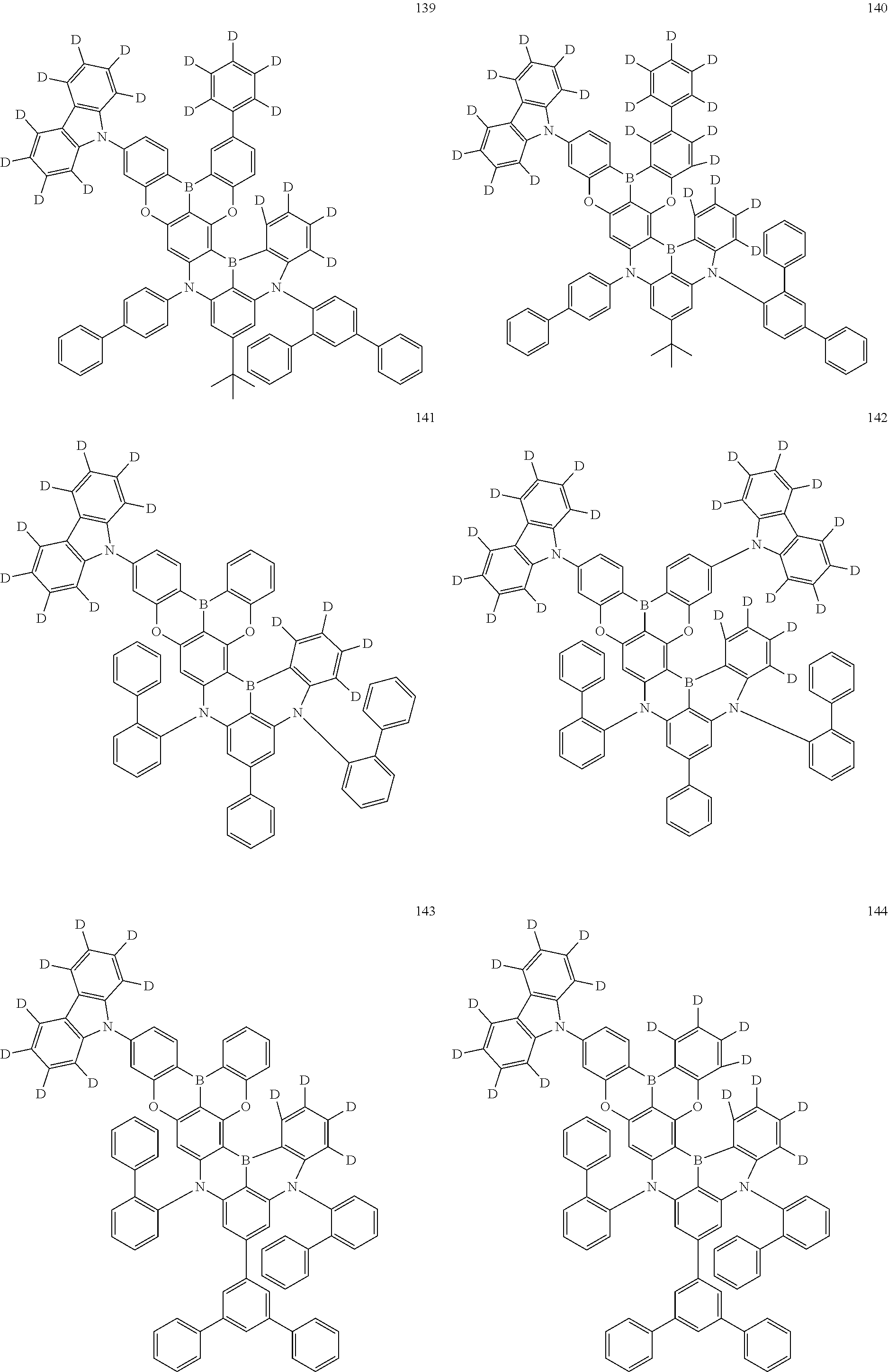 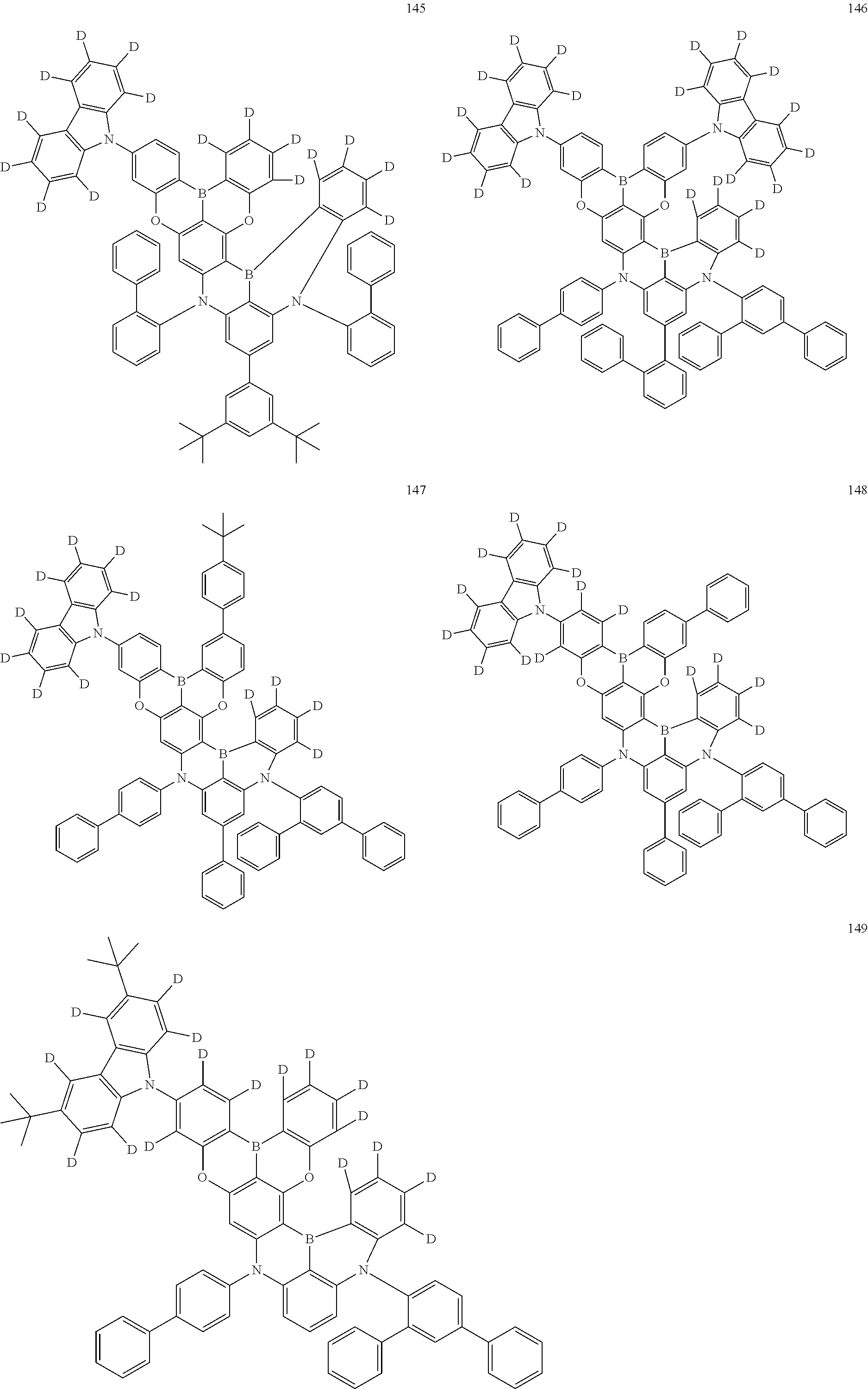 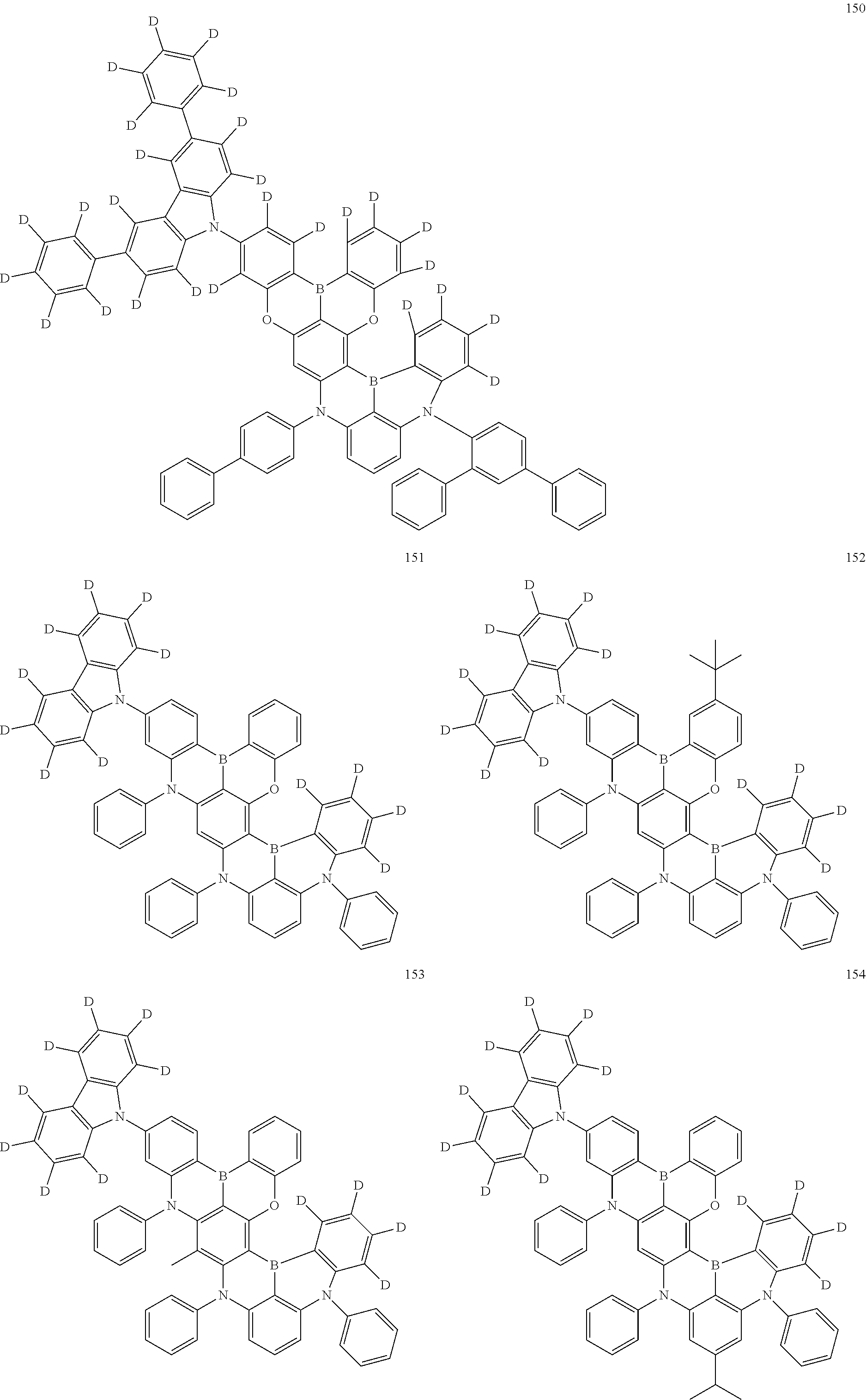 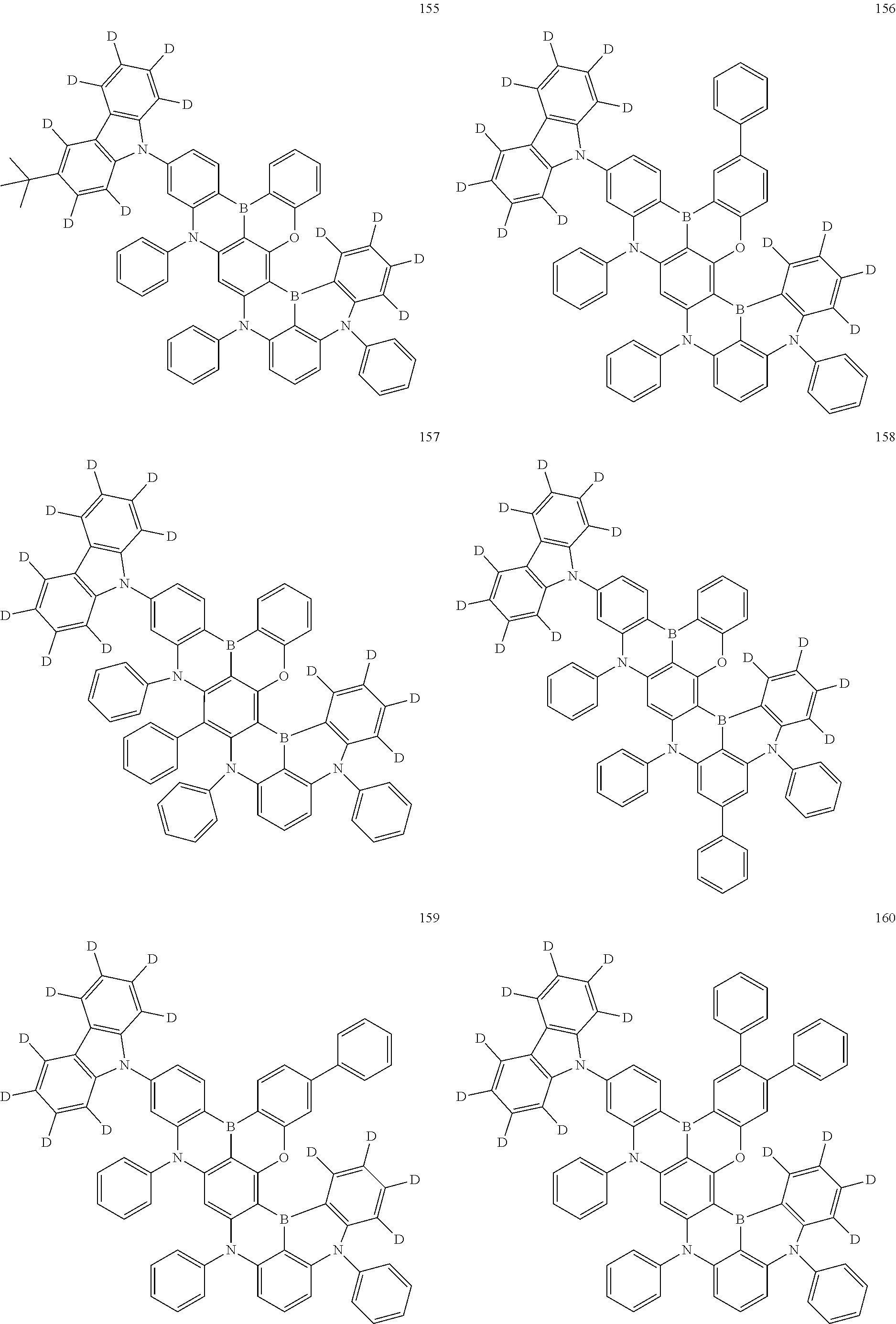 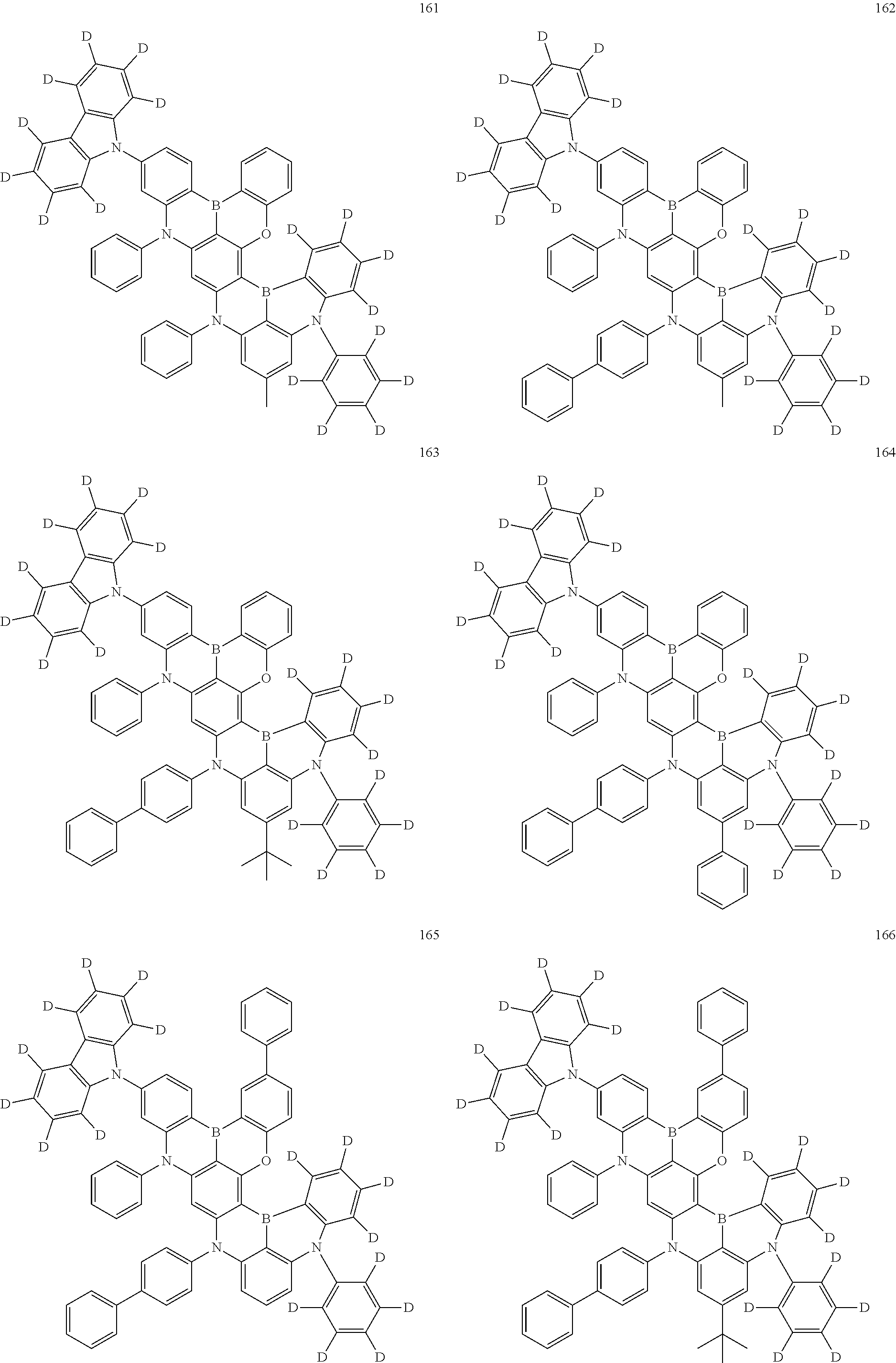 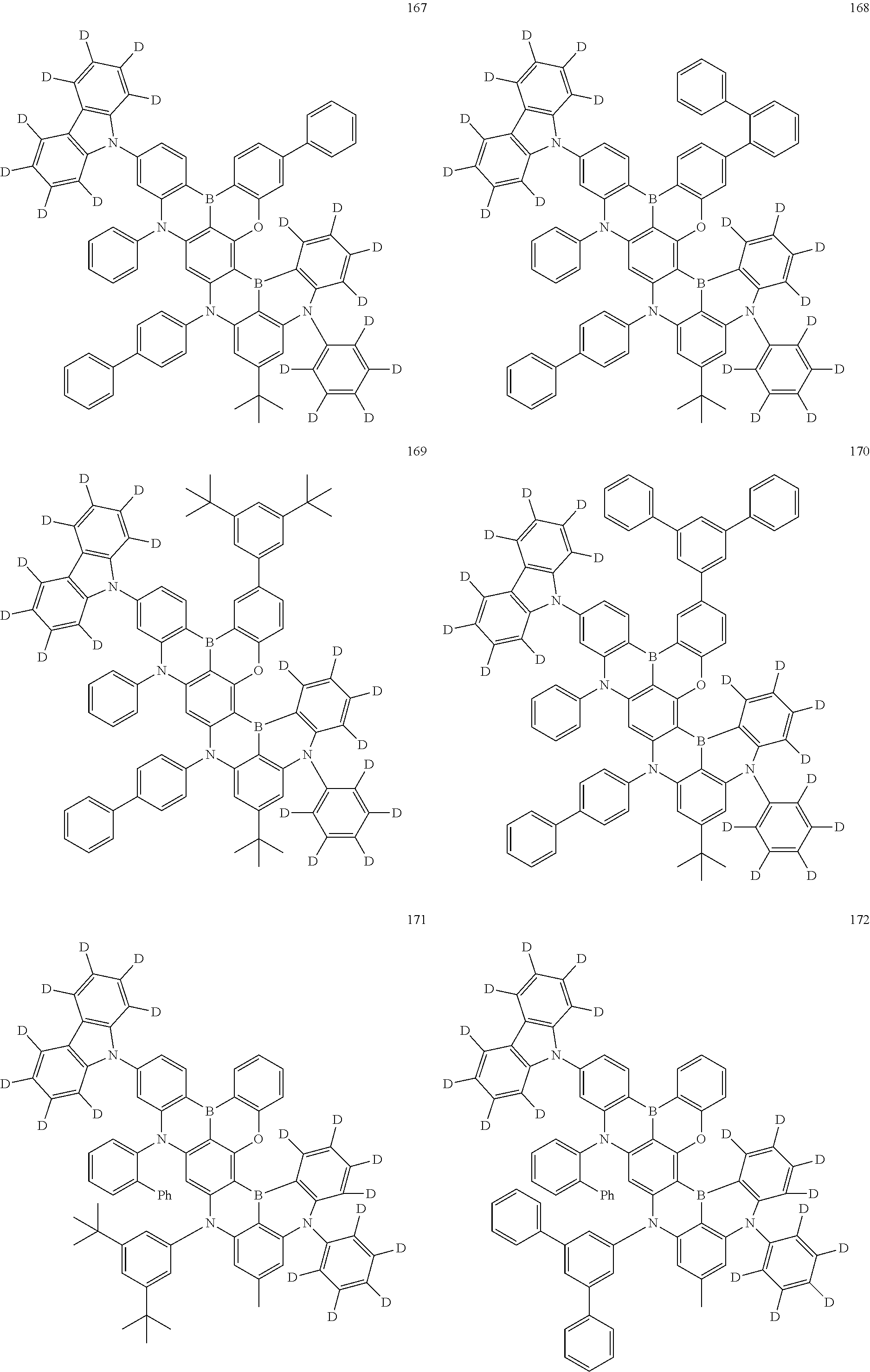 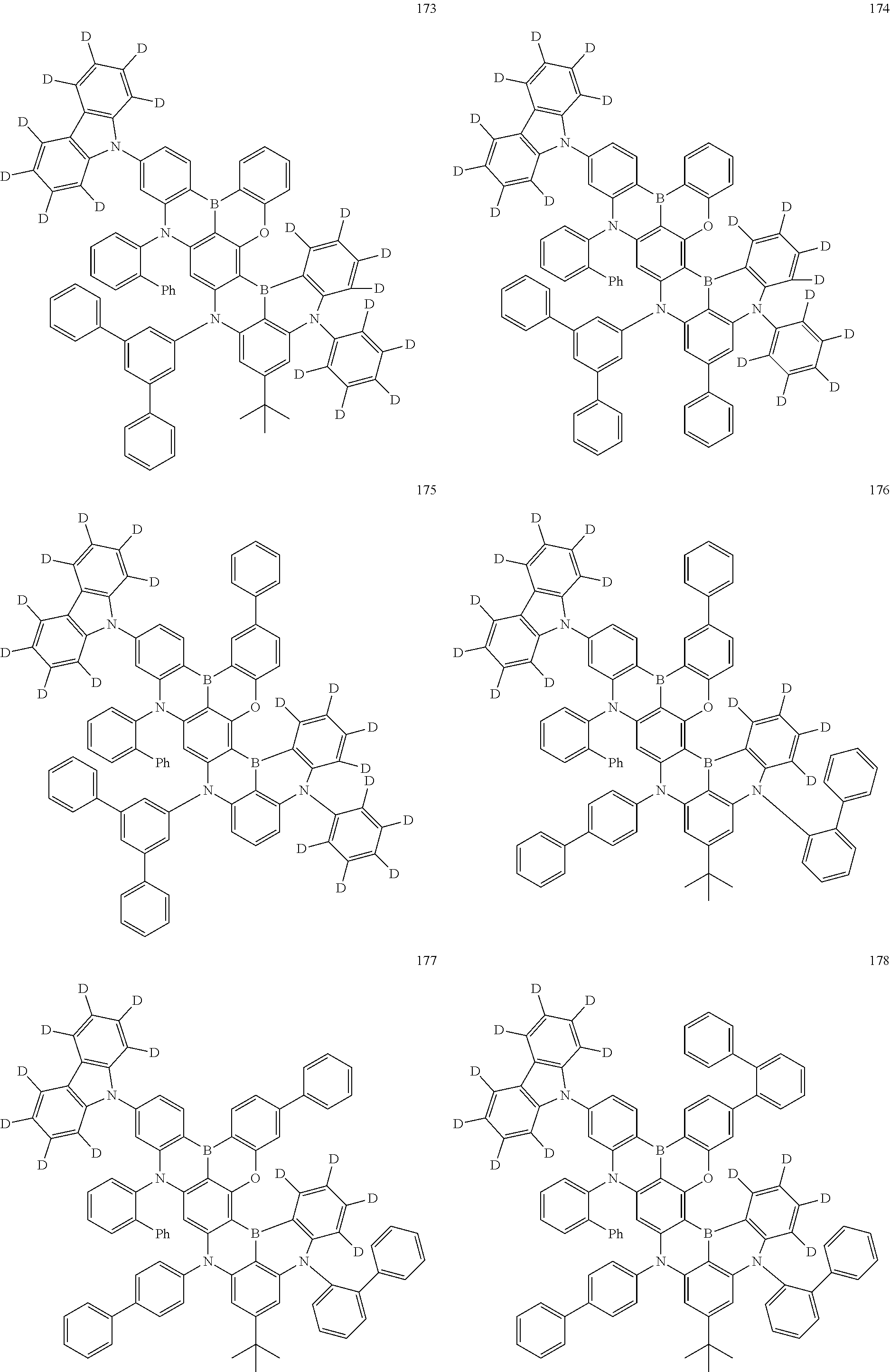 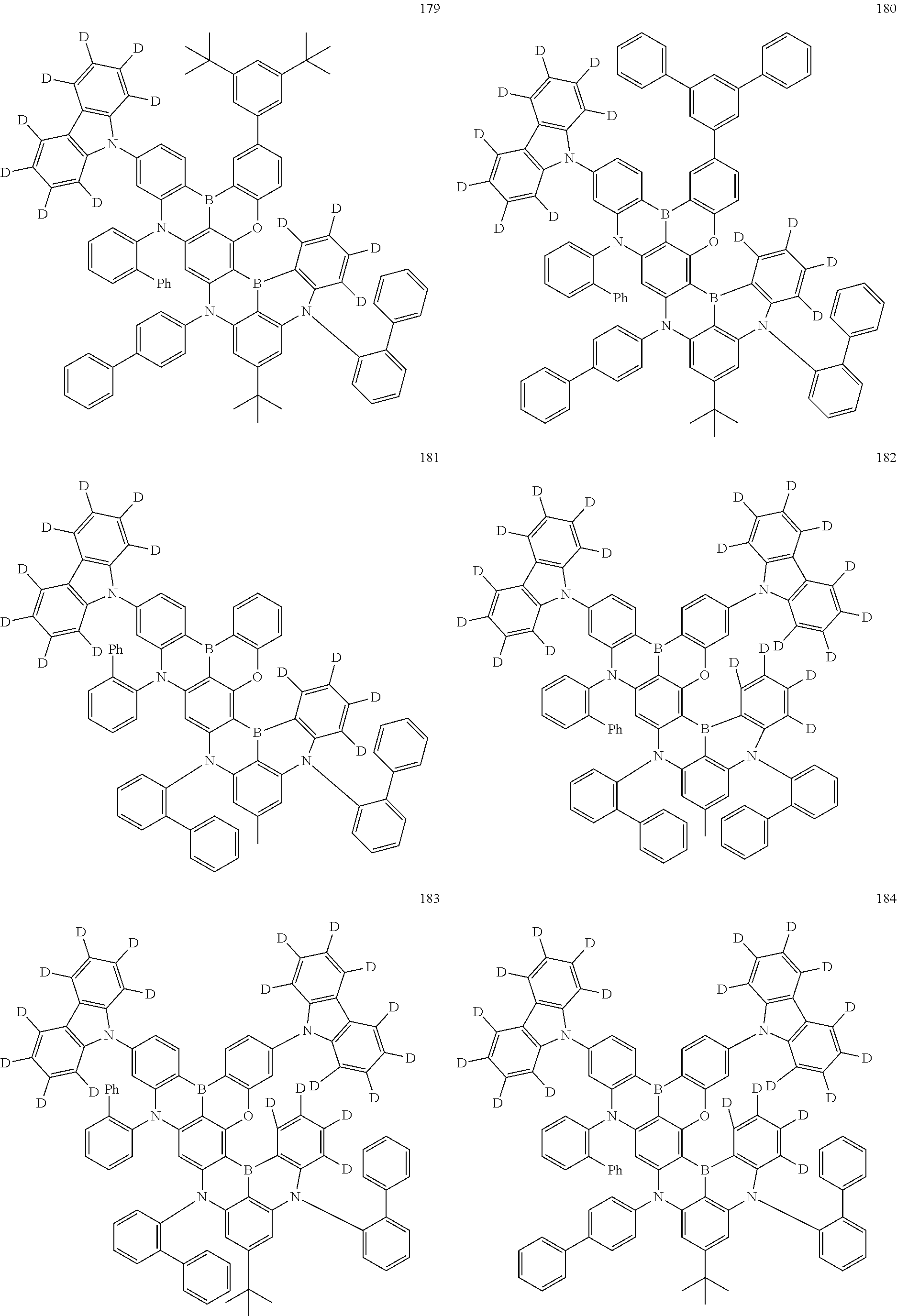 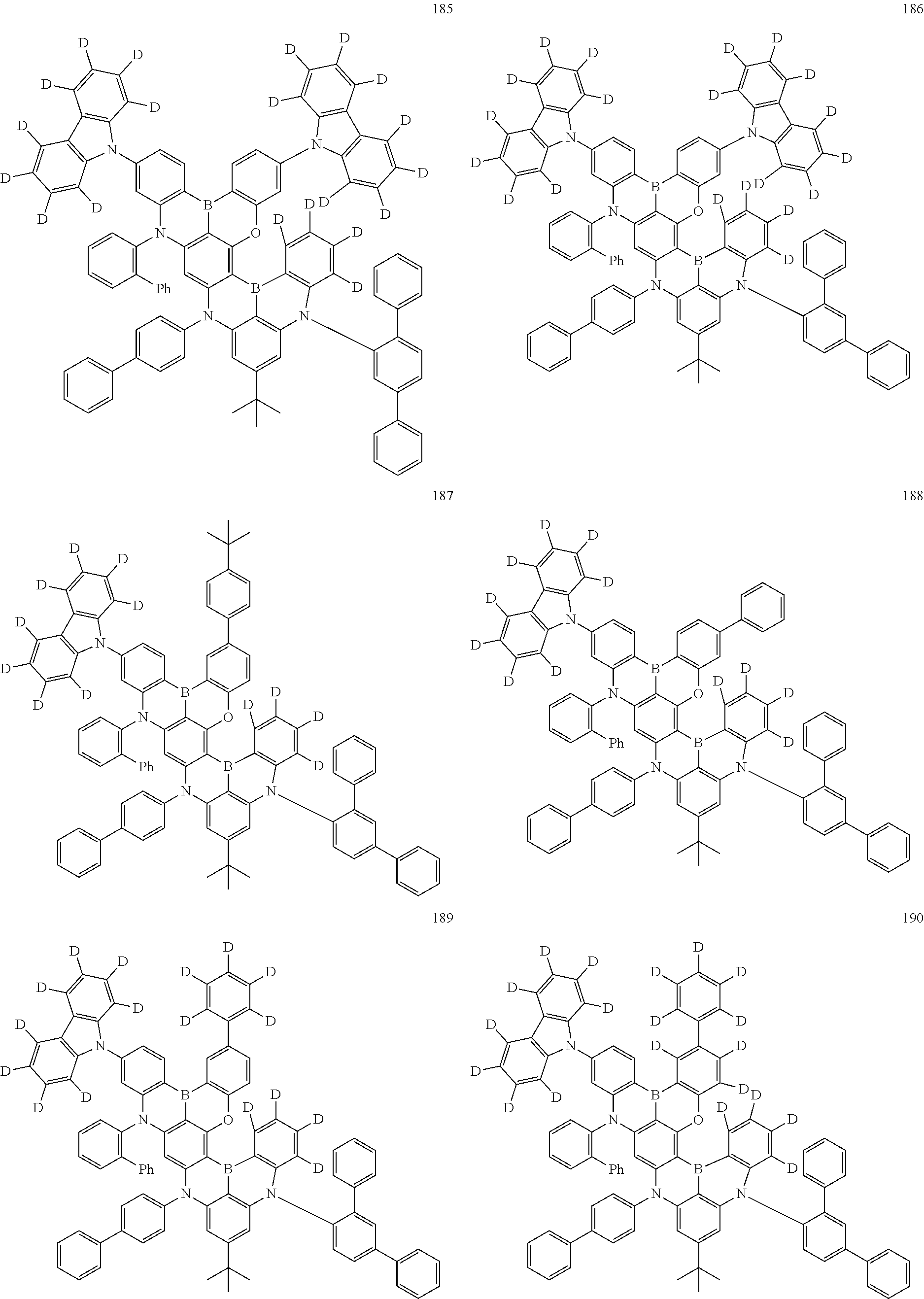 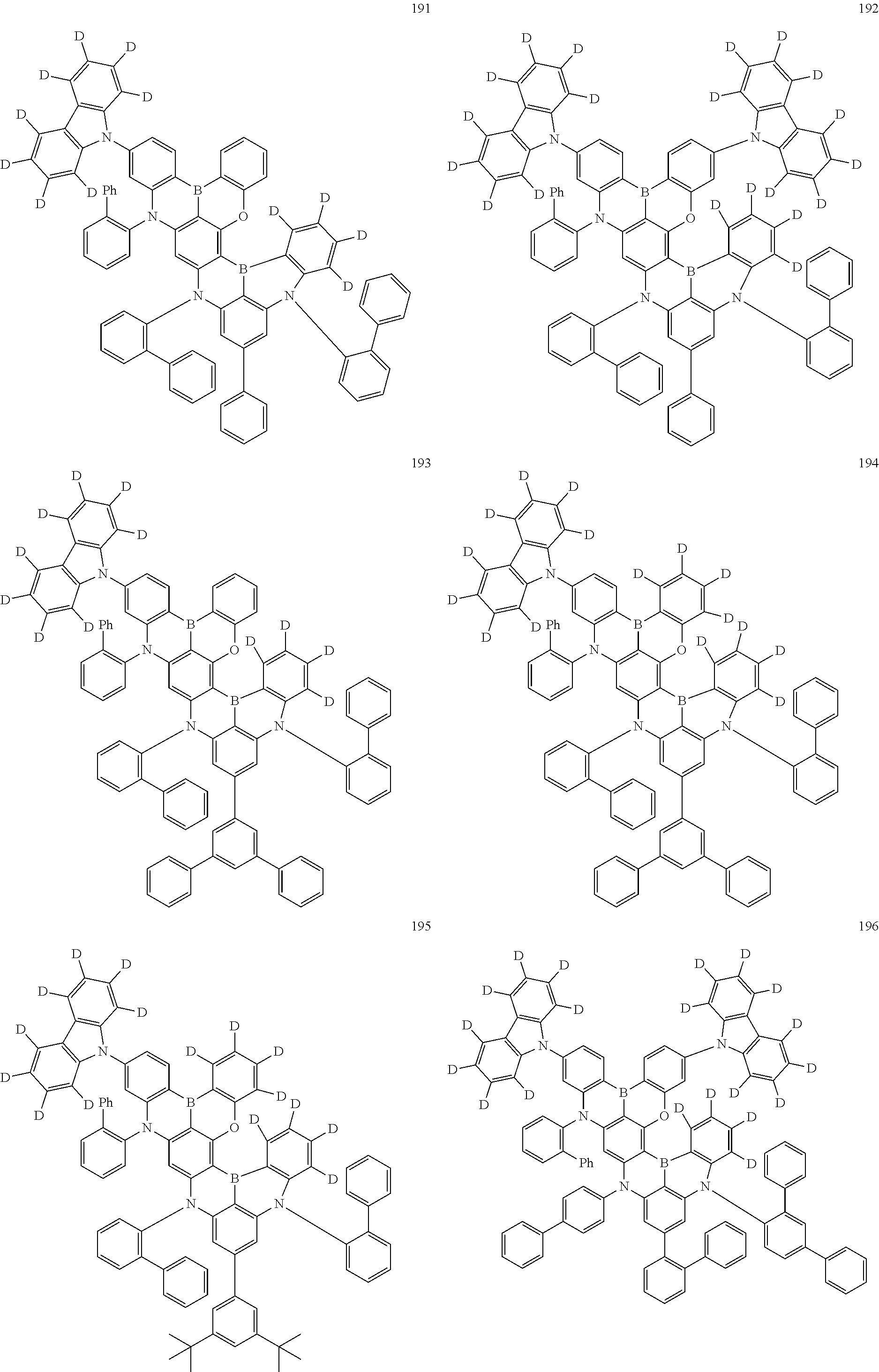 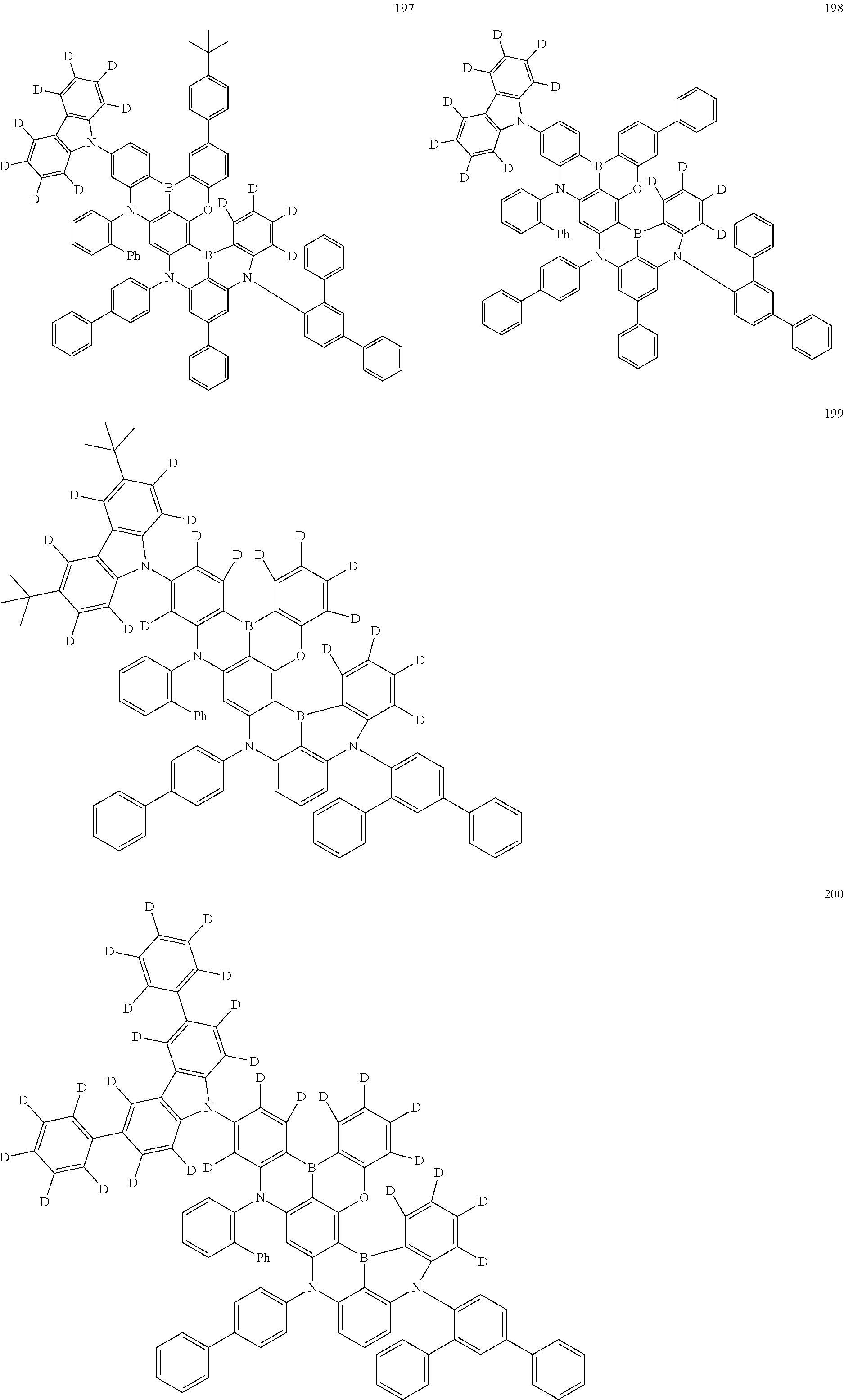
in Compound Group 1, D is a deuterium atom, and Ph is an unsubstituted phenyl group.
